(19) United States
(12) Patent Application Publication
(10) Pub. No.: US 2024/0083931 A1
(43) Pub. Date: Mar. 14, 2024

(54) DINUCLEAR PLATINUM(II) EMITTERS FOR RED AND/OR NEAR-INFRARED OLEDS

(71) Applicants: The University of Hong Kong, Hong Kong (CN); Hong Kong Quantum AI Lab Limited, Hong Kong (CN)

(72) Inventors: Kar-Wai Lo, Hong Kong (CN); Chi-Ming Che, Hong Kong (CN); Gang Cheng, Hong Kong (CN)

(21) Appl. No.: 18/361,411

(22) Filed: Jul. 28, 2023

Related U.S. Application Data
(60) Provisional application No. 63/398,029, filed on Aug. 15, 2022.

(51) Int. Cl. C07F 15/00; H10K 50/16; H10K 85/30

(52) U.S. Cl. CPC C07F 15/0086; H10K 50/166; H10K 85/346

(57) ABSTRACT

Described herein are dinuclear platinum(II) complexes and their methods of making and using thereof. The design of the dinuclear platinum(II) complexes results in red to deep-red photoluminescence with high quantum yields at room temperature, short emission lifetimes, and fast radiative decay rates. The dinuclear platinum(II) complexes can be used to fabricate red and/or NIR emitting OLEDs.

### CROSS-REFERENCE TO RELATED APPLICATIONS

This application claims the benefit of and priority to U.S. Application No. 63/398,029, filed Aug. 15, 2022, which is specifically incorporated by reference herein in its entirety.

### FIELD OF THE INVENTION

The disclosed invention is generally in the field of dinuclear platinum (II) complexes and their use in organic electronics, such as organic light-emitting devices (OLEDs), as red and/or NIR emitters.

### BACKGROUND OF THE INVENTION

Transition metal complexes have gained significant interest in commercial and academic settings as molecular probes, catalysts, and luminescent materials. As luminescent materials, transition metal complexes are increasingly being explored as potential alternatives to pure organic-based materials due to their potential for improved luminescence efficiency and device stability, compared to pure organic-based materials.

Currently, commercial red OLED emitters are dominated by iridium phosphors because of their practical operational stability in device. Tremendous efforts have been made to develop phosphorescent emitters based on other metals, such as osmium or platinum, or develop thermally activated delayed fluorescent (TADF) emitters. In particular, high-efficiency platinum(II) red or near-infrared (NIR) emitters with ease of preparation are of practical interest in OLED industry for potential applications such as diagnosis, therapy and biometric sensing. However, there are limited examples showing high performance in OLEDs, and most of them require high dopant concentration or non-doped device system to achieve low-energy emissions.

There remains a need to develop high-efficiency red or NIR emitters for OLED applications.

Therefore, it is an object of the present invention to provide new dinuclear platinum(II) complexes.

It is a further object of the present invention to provide new dinuclear platinum(II) complexes that emit in the red and/or NIR regions.

It is a further object of the present invention to provide devices containing the new dinuclear platinum(II) complexes that emit in the red and/or deep red regions.

It is a further object of the present invention to provide methods for using the new dinuclear platinum(II) complexes that emit in the red and/or deep red regions.

### SUMMARY OF THE INVENTION

Dinuclear platinum(II) complexes that can emit in the red, deep red, and/or NIR regions and methods of making and using thereof are described. The disclosed dinuclear platinum(II) complexes contain platinum(II) atoms complexed by 2-hydroxy-pyridine (N\hat{ }O) bridging ligands. The ligands of the disclosed dinuclear platinum(II) complexes include a phenyl ring and an imidazolyl N-heterocyclic carbene ring. The structure of the disclosed dinuclear platinum(II) complexes allows them to emit light in the red, deep red, and/or NIR regions with high efficiency, including a high emission quantum yield (i.e. Φₑₘ≥0.60 measured in thin films, such as about 0.78 or about 0.97), a short emission lifetime (i.e. τₑₘ≤2.5 μs, such as 1.7-1.9 μs), a fast radiative decay rate (i.e. kᵣ≥3.5×10⁵ s⁻¹, such as about 4.3×10⁵ s⁻¹ or about 5.5×10⁵ s⁻¹), and/or a slow non-radiative decay rate (i.e. kₙᵣ≤6×10⁵ s⁻¹, such as 0.16×10⁵-6×10⁵ s⁻¹ or 0.16×10⁵-1.4×10⁵ s⁻¹), at room temperature.

Exemplary dinuclear platinum (II) complexes can have a structure as follows:

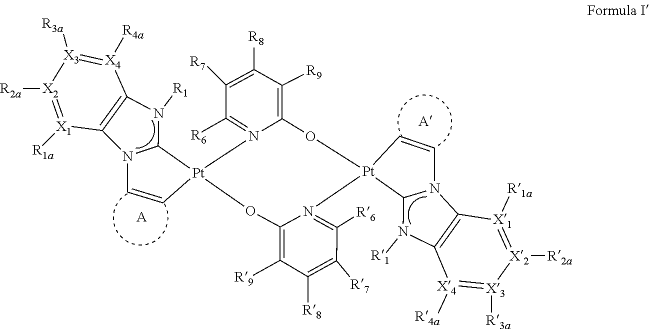

where: (i) the complex is an overall neutral, negative, or positive charge; (ii) X₁-X₄ and X′₁-X′₄ are independently carbon, nitrogen, sulfur, or oxygen; (iii) R₁ₐ-R₄ₐ, R′₁ₐ-R′₄ₐ, R₁, R′₁, R₆-R₉, and R′₆-R′₉ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, unsubstituted C₂-C₂₀ heterocyclyl, borenium cation, phosphonyl, sulfinyl, or sulfonyl, or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; (iv) A and A′ are independently a substituted cycloalkyl, an unsubstituted cycloalkyl, a substituted cycloalkenyl, an unsubstituted cycloalkenyl, a substituted cycloalkynyl, an unsubstituted cycloalkynyl, a substituted heterocyclyl, an unsubstituted heterocyclyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, or fused combinations thereof; preferably A and A′ are independently a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; and (v) each substituent is independently a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a carbonyl, an alkoxy, a halogen, a hydroxyl, a phenoxy, a thiol, an alkylthio, a phenylthio, an arylthio, a cyano, an isocyano, a nitro, a carboxyl, an amino, an amido, an oxo, a silyl, a sulfinyl, a sulfonyl, a sulfonic acid, a phosphonium, a phosphanyl, a phosphoryl, or a phosphonyl.

In some forms, the complex can have a structure:

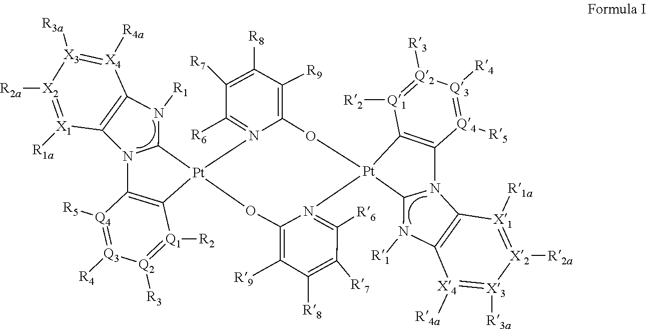

where: (i) the complex can have an overall neutral, negative, or positive charge; (ii) X₁-X₄, X′₁-X′₄, R₁ₐ-R₄ₐ, R′₁ₐ-R′₄ₐ, R₁, R₆-R₉, R′₁, and R′₆-R′₉ can be as defined above for Formula I′; (iii) Q₁-Q₄ and Q′₁-Q′₄ can be independently carbon, nitrogen, sulfur, or oxygen; (iv) R₂-R₅ and R′₂-R′₅ can be independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, unsubstituted C₂-C₂₀ heterocyclyl, borenium cation, phosphonyl, sulfinyl, or sulfonyl, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, fused combinations thereof, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; and (v) each substituent can be as defined above for Formula I′.

In some forms, the complex can have a structure:

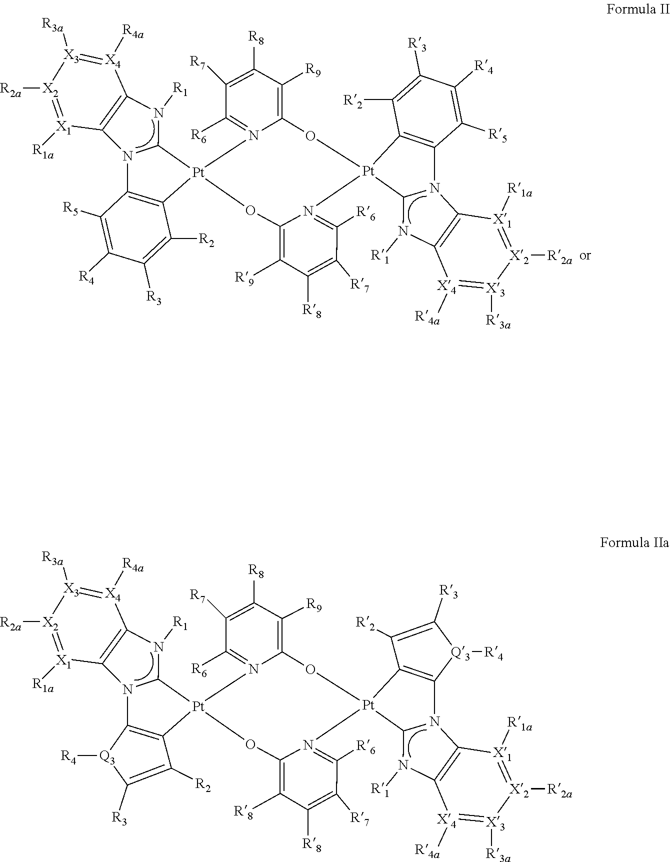

where the complex can have an overall neutral, negative, or positive charge; and X₁-X₄, X′₁-X′₄, Q₃, Q′₃, R₁ₐ-R₄ₐ, R′₁ₐ-R′₄ₐ, R₁-R₉, R′₁-R′₉ and the substituents can be as defined above for Formula I.

In some forms, the complex can have a structure:

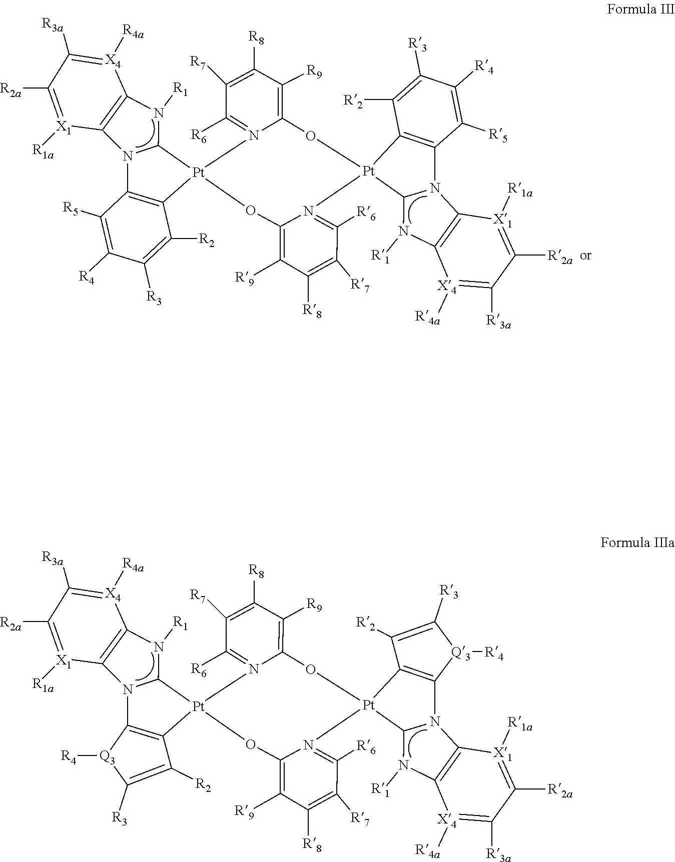

where the complex can have an overall neutral, negative, or positive charge; and X₁, X₄, X′₁, X′₄, Q₃, Q′₃, R₁ₐ-R₄ₐ, R′₁ₐ-R′₄ₐ, R₁-R₉, R′₁-R′₉ and the substituents can be as defined above for Formula I.

In some forms of Formulae III and/or IIIa, X₁, X₄, X′₁, and X′₄ are carbon. In some forms of Formulae III and/or IIIa, X₁, X₄, X′₁, and X′₄ are carbon; and R₁ₐ and R₂ₐ together, R₂ₐ and R₃ₐ together, R₃ₐ and R₄ₐ together, R′₁ₐ and R′₂ₐ together, R′₂ₐ and R′₃ₐ together, and/or R′₃ₐ and R′₄ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl.

In some forms of Formulae III and/or IIIa, X₁, X₄, X′₁, and X′₄ are nitrogen; and R₂ₐ and R₃ₐ together and/or R′₂ₐ and R′₃ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl.

In some forms, the complex can have a structure:

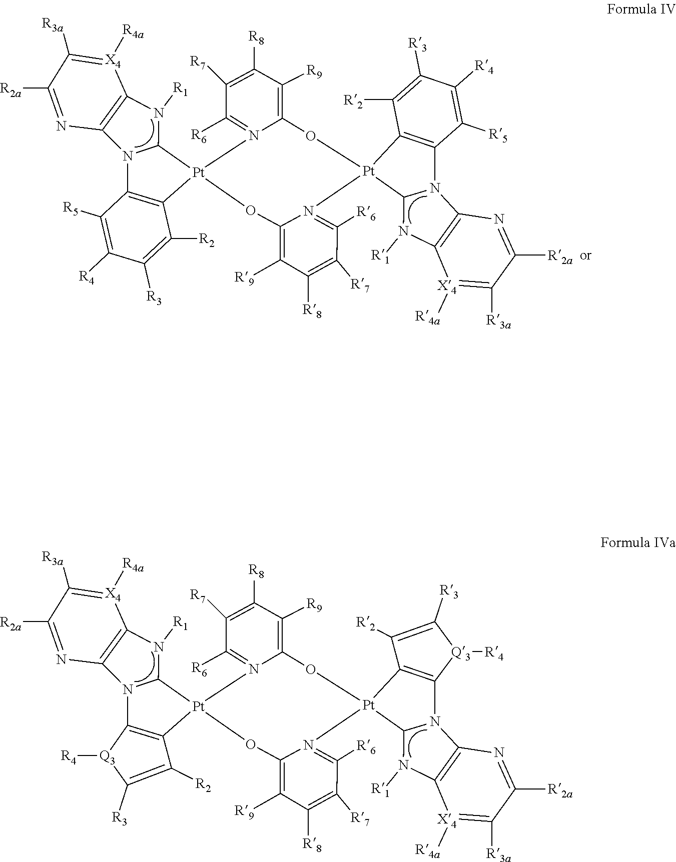

where the complex can have an overall neutral, negative, or positive charge; and X₄, X′₄, Q₃, Q′₃, R₁ₐ-R₄ₐ, R′₁ₐ-R′₄ₐ, R₁-R₉, R′₁-R′₉, and the substituents can be as defined above for Formula I.

In some forms, for any one of Formulae I-IV and Ia-IVa, X₄ and X′₄ can be carbon; and R₄ₐ and R′₄ₐ can be independently hydrogen, substituted alkyl, unsubstituted alkyl, substituted aryl, unsubstituted aryl, hydroxyl, unsubstituted heteroaryl, substituted heteroaryl, unsubstituted polyaryl, substituted polyaryl, unsubstituted polyheteroaryl, substituted polyheteroaryl, substituted C₂-C₂₀ heterocyclyl, or unsubstituted C₂-C₂₀ heterocyclyl.

In some forms, for any one of Formulae I-IV and Ia-IVa, X₄ and X′₄ can be carbon; and R₄ₐ and R′₄ₐ can be independently hydrogen, unsubstituted alkyl, unsubstituted aryl, unsubstituted polyaryl, hydroxyl, unsubstituted heteroaryl, unsubstituted polyheteroaryl, unsubstituted C₂-C₂₀ heterocyclyl, or unsubstituted alkylaryl.

In some forms, for any one of Formulae I-IV and Ia-IVa, X₄ and X′₄ can be nitrogen; and R₄ₐ and R′₄ₐ are absent.

In some forms, for any one of Formulae I-IV and Ia-IVa, R₁-R₉ and R′₁-R′₉ can be independently hydrogen, halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), unsubstituted polyaryl, substituted polyaryl, hydroxyl, unsubstituted heteroaryl, substituted heteroaryl, unsubstituted polyheteroaryl, substituted polyheteroaryl, unsubstituted C₂-C₂₀ heterocyclyl, substituted C₂-C₂₀ heterocyclyl, unsubstituted alkylaryl, substituted alkylaryl, alkoxy (e.g., —O-alkyl, —O-aryl, —O— polyaryl, etc.), borenium cation (e.g., —B(Mes)₂), phosphonyl (e.g., —P(═O)(Ph)₂, —P(═O)(alkyl)₂, etc.), sulfinyl (e.g., —S(═O)(Ph)₂, —S(═O)(alkyl)₂, etc.), or sulfonyl —S(═O)₂(Ph)₂, —S(═O)₂(alkyl)₂, etc.).

In some forms, for any one of Formulae I-IV and Ia-IVa, one or more of R₁-R₉ and R′₁-R′₉ can be an aryl, heteroaryl, or polyaryl having the structure of

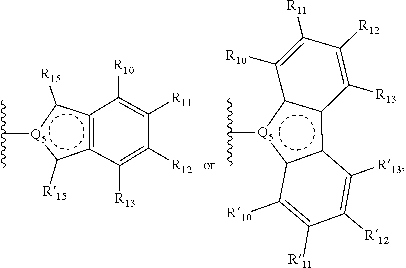

where Q₅ can be nitrogen or carbon; and R₁₀-R₁₃, R₁₅, R′₁₅, and R′₁₀-R′₁₃ can be independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be nitrogen; and R₁₀-R₁₃, R₁₅, R′₁₅, and R′₁₀-R′₁₃ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen.

In some forms, for any one of Formulae I-IV and Ia-IVa, at least one of R₂-R₅ and at least one of R′₂-R′₅, such as one or two of R₂-R₅ and/or one or two of R′₂-R′₅, can be independently halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), phosphonyl (e.g., —P(═O)(Ph)₂, —P(═O)(alkyl)₂, etc.), or an aryl, heteroaryl, or polyaryl described in the paragraph above, such as carbazolyl, fluorenyl, indenyl, or indolyl.

In some forms, for any one of Formulae I-IV and Ia-IVa, at least one of R₆-R₉ and at least one of R′₆-R′₉, such as one or two of R₆-R₉ and/or one or two of R′₆-R′₉, can be independently halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), phosphonyl (e.g., —P(═O)(Ph)₂, —P(═O)(alkyl)₂, etc.), or an aryl, heteroaryl, or polyaryl described in the paragraph above, such as carbazolyl, fluorenyl, indenyl, or indolyl; or R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or an unsubstituted aryl.

In some forms, for any one of Formulae I-IV and Ia-IVa, (i) R₂ and R₃ together and/or R′₂ and R′₃ together, or (ii) R₃ and R₄ together and/or R′₃ and R′₄ together, or (iii) R₄ and R₅ together and/or R′₄ and R′₅ together, with the atom to which they are attached, can form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl. For example, (i) R₂ and R₃ together and/or R′₂ and R′₃ together, or (ii) R₃ and R₄ together and/or R′₃ and R′₄ together, or (iii) R₄ and R₅ together and/or R′₄ and R′₅ together, can form

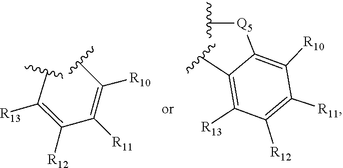

wherein Q₅ can be NR₁₄, CR₁₆R₁₇, or sulfur, or oxygen; and R₁₀-R₁₄, R₁₆, and R₁₇ can be independently absent, hydrogen, substituted alkyl, unsubstituted alkyl (e.g., methyl, ethyl, n-propyl, iso-propyl, n-butyl, iso-butyl, tert-butyl, etc.), substituted alkenyl, unsubstituted alkenyl, substituted alkynyl, unsubstituted alkynyl, substituted aryl (e.g., substituted phenyl), unsubstituted aryl (e.g., unsubstituted phenyl), halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be NR₁₄, sulfur, or oxygen, such as oxygen; and R₁₀-R₁₄ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen. In some forms, Q₅ can be CR₁₆R₁₇; and R₁₆ and R₁₇ can be independently hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen or unsubstituted alkyl (e.g., methyl, ethyl, n-propyl, iso-propyl, n-butyl, iso-butyl, tert-butyl, etc.).

In some forms, for any one of Formula Ia-IVa, Q₃ and Q′₃ can be independently sulfur or oxygen.

In some forms, for any one of Formulae I-IV and Ia-IVa, R₂-R₅, R′₂-R′₅, R₇, R₈, R′₇, and R′₈ can be hydrogen; and R₁, R₆, R₉, R′₁, R′₆, and R′₉ can be independently hydrogen, halogen, unsubstituted alkyl, unsubstituted aryl, substituted aryl (e.g., aryl substituted with one or more alkyls, such as methyl, ethyl, n-propyl, isopropyl, n-butyl, sec-butyl, isobutyl, tert-butyl, etc.), hydroxyl, unsubstituted heteroaryl (e.g., carbazolyl, fluorenyl, indenyl, indolyl, etc.), unsubstituted polyheteroaryl, unsubstituted C₂-C₂₀ heterocyclyl, unsubstituted alkylaryl, alkoxy (e.g., —O-alkyl such as methoxy, ethoxy, and phenoxy, —O-aryl, —O-polyaryl, etc.), borenium cation (e.g., —B(Mes)₂), phosphonyl (e.g. —P(═O)(Ph)₂), sulfinyl (e.g., —S(═O)(Ph)₂, —S(═O)(alkyl)₂, etc.), or sulfonyl (—S(═O)₂(Ph)₂, —S(═O)₂(alkyl)₂, etc.). In some forms, for any one of Formulae I-IV and Ia-IVa, R₂-R₅, R′₂-R′₅, R₇, R₈, R′₇, and R's can be hydrogen; and R₁, R₆, R₉, R′₁, R′₆, and R′₉ can be independently unsubstituted alkyl, unsubstituted aryl, or substituted aryl (e.g., aryl substituted with one or more alkyls, such as methyl, ethyl, n-propyl, isopropyl, n-butyl, sec-butyl, isobutyl, tert-butyl, etc.).

In some forms, the complex can have any one of the following structures:

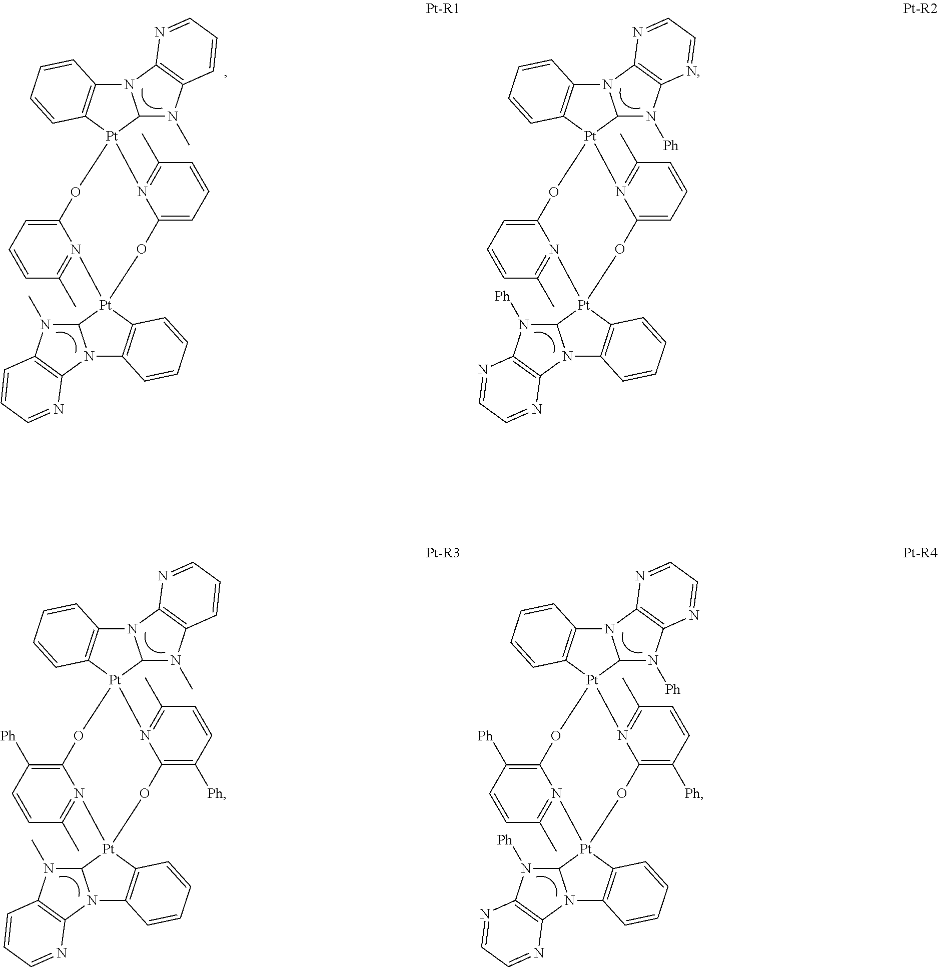

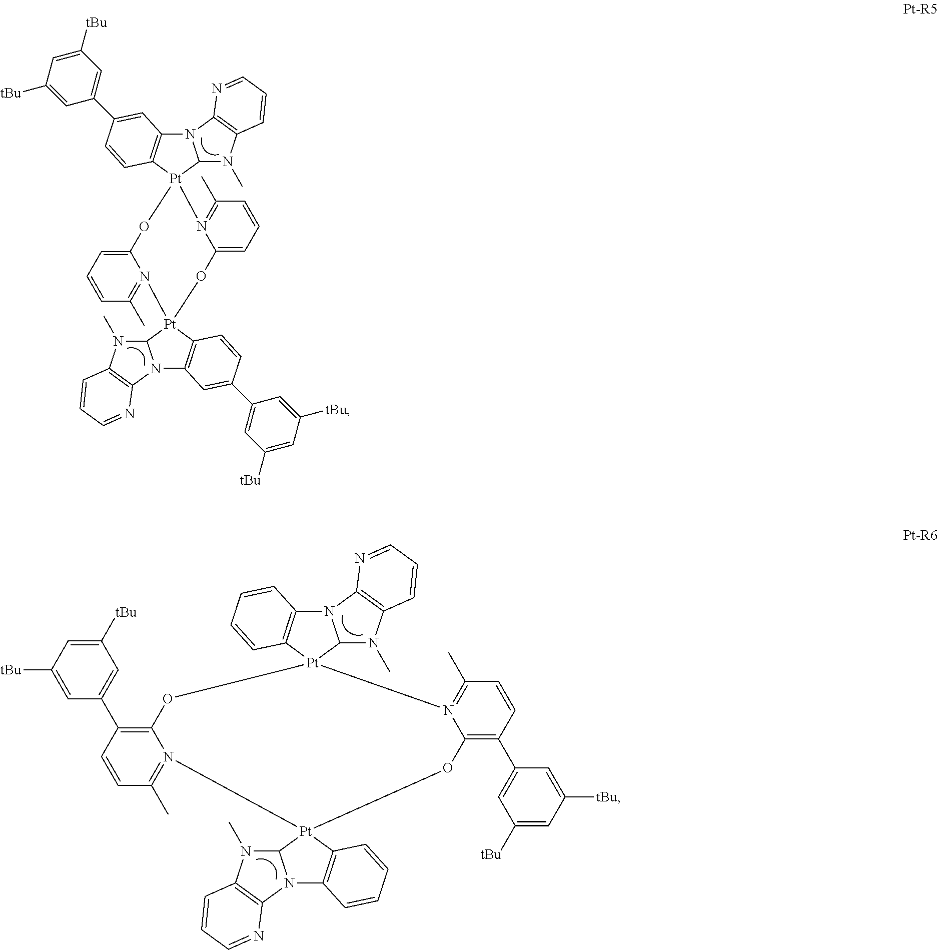

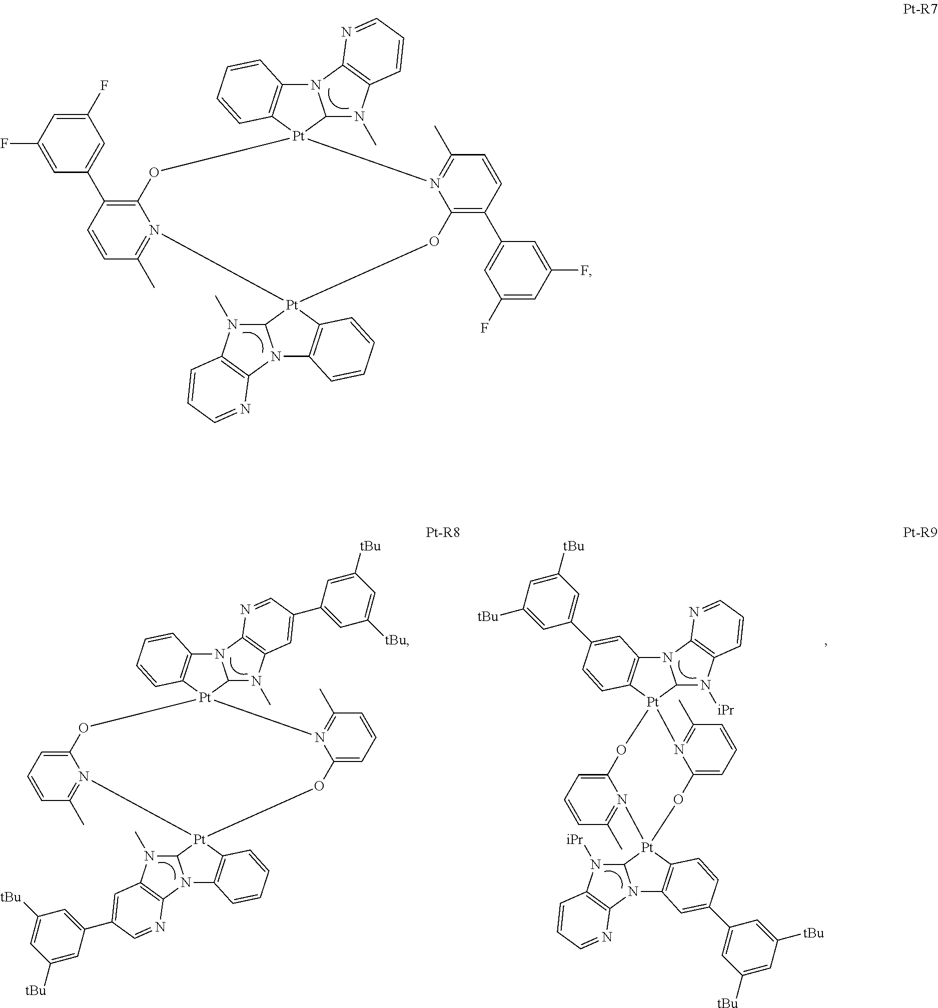

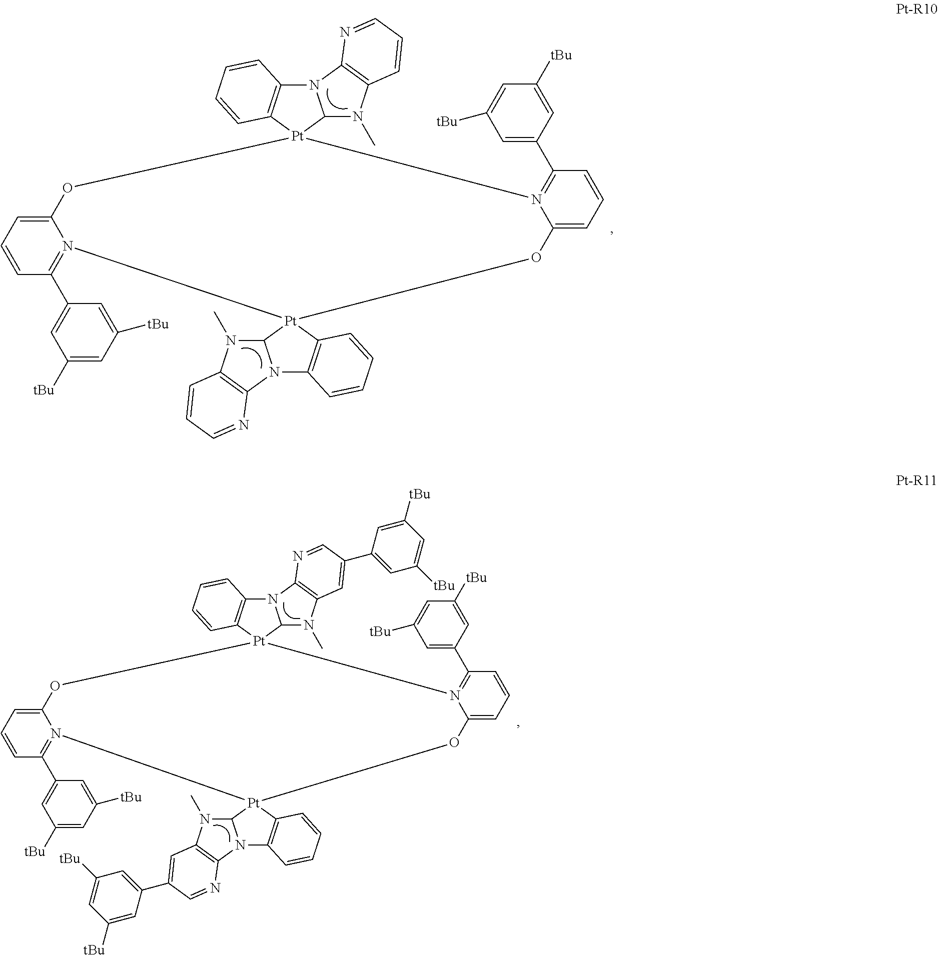

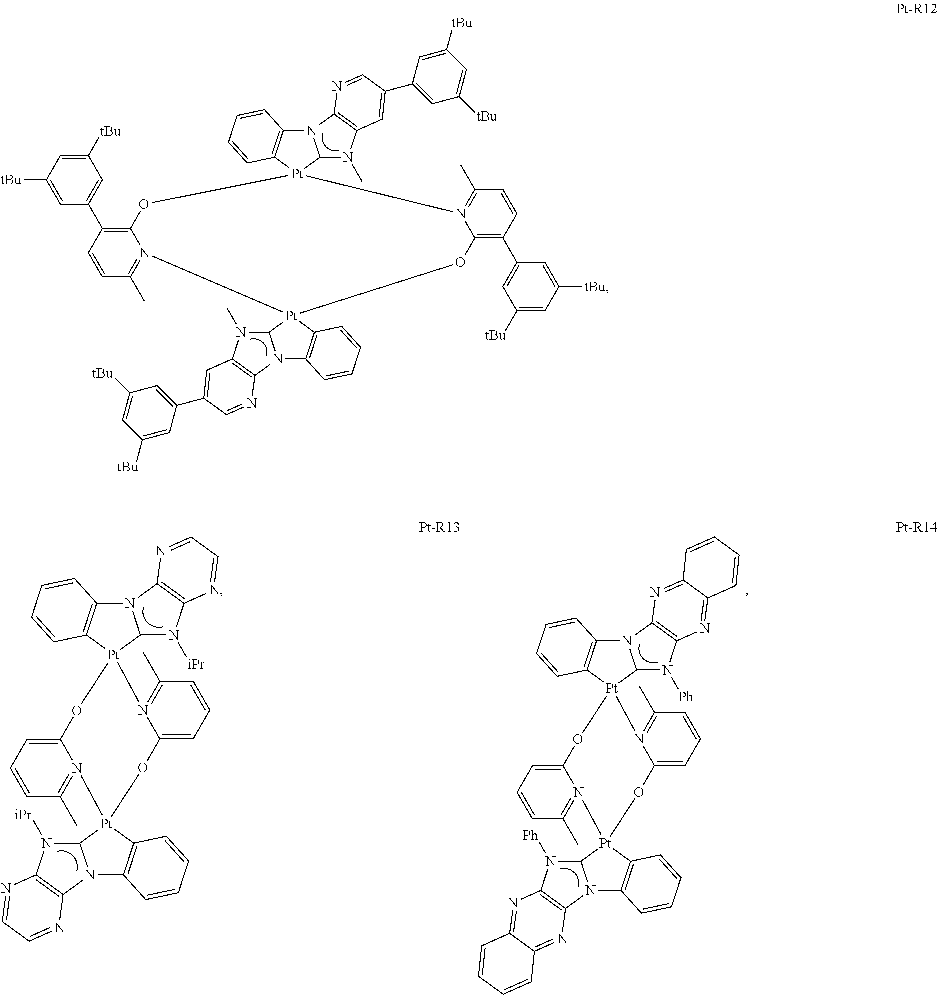

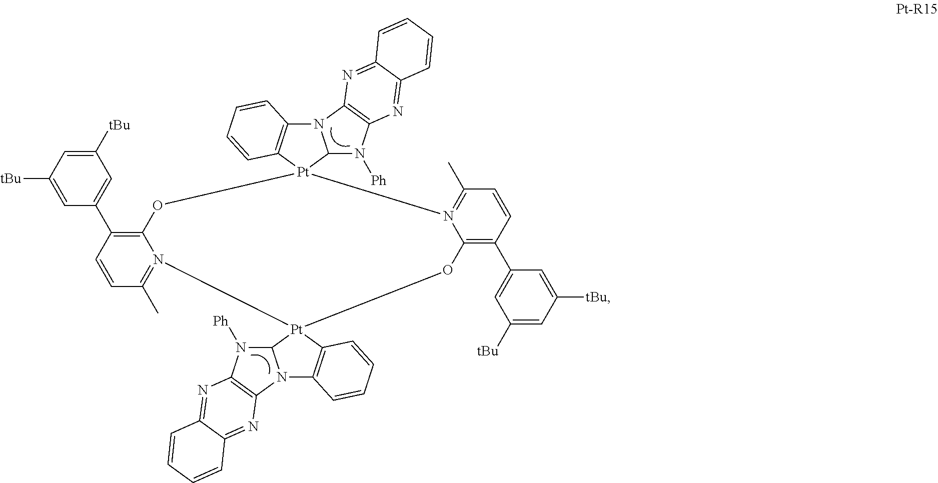

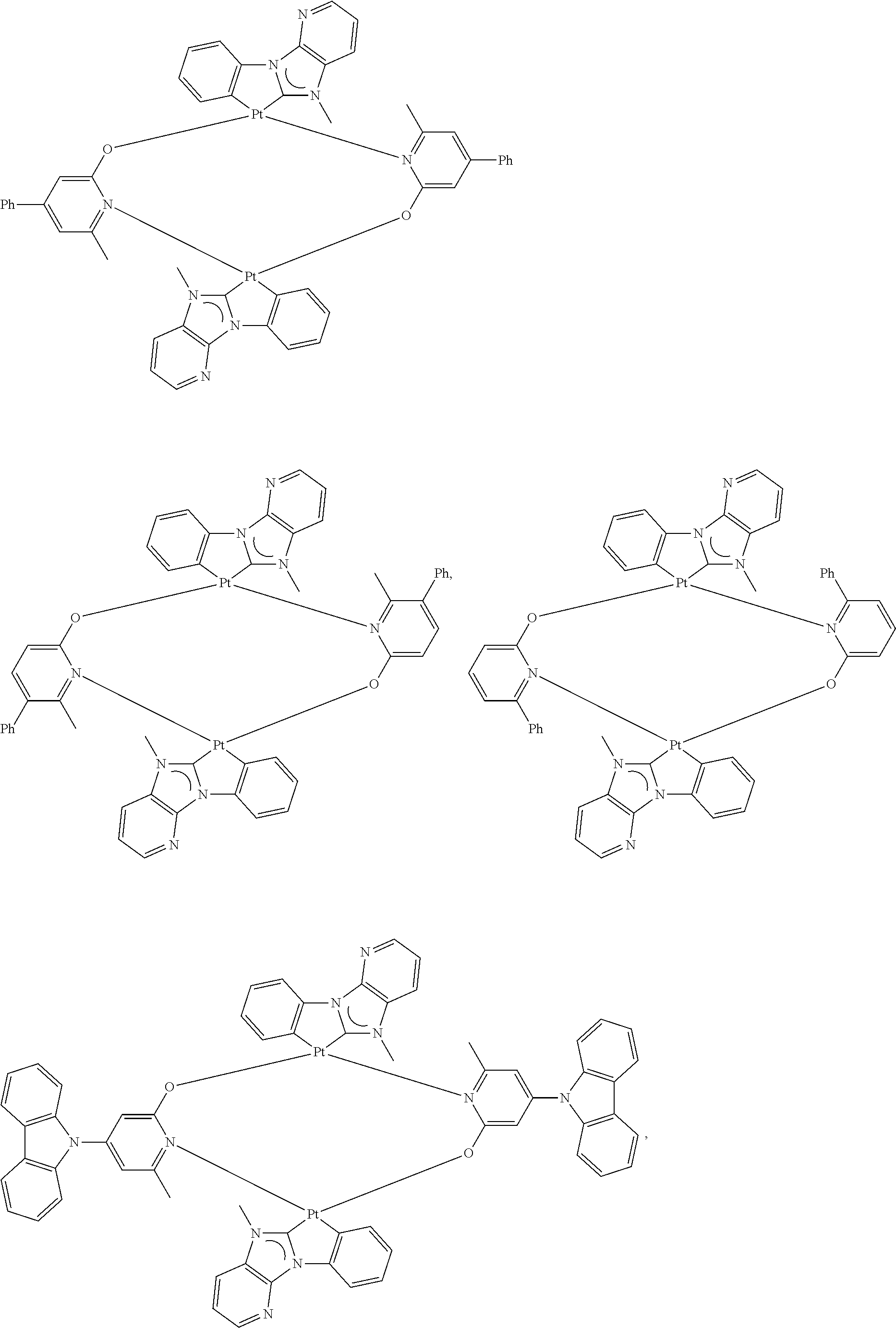

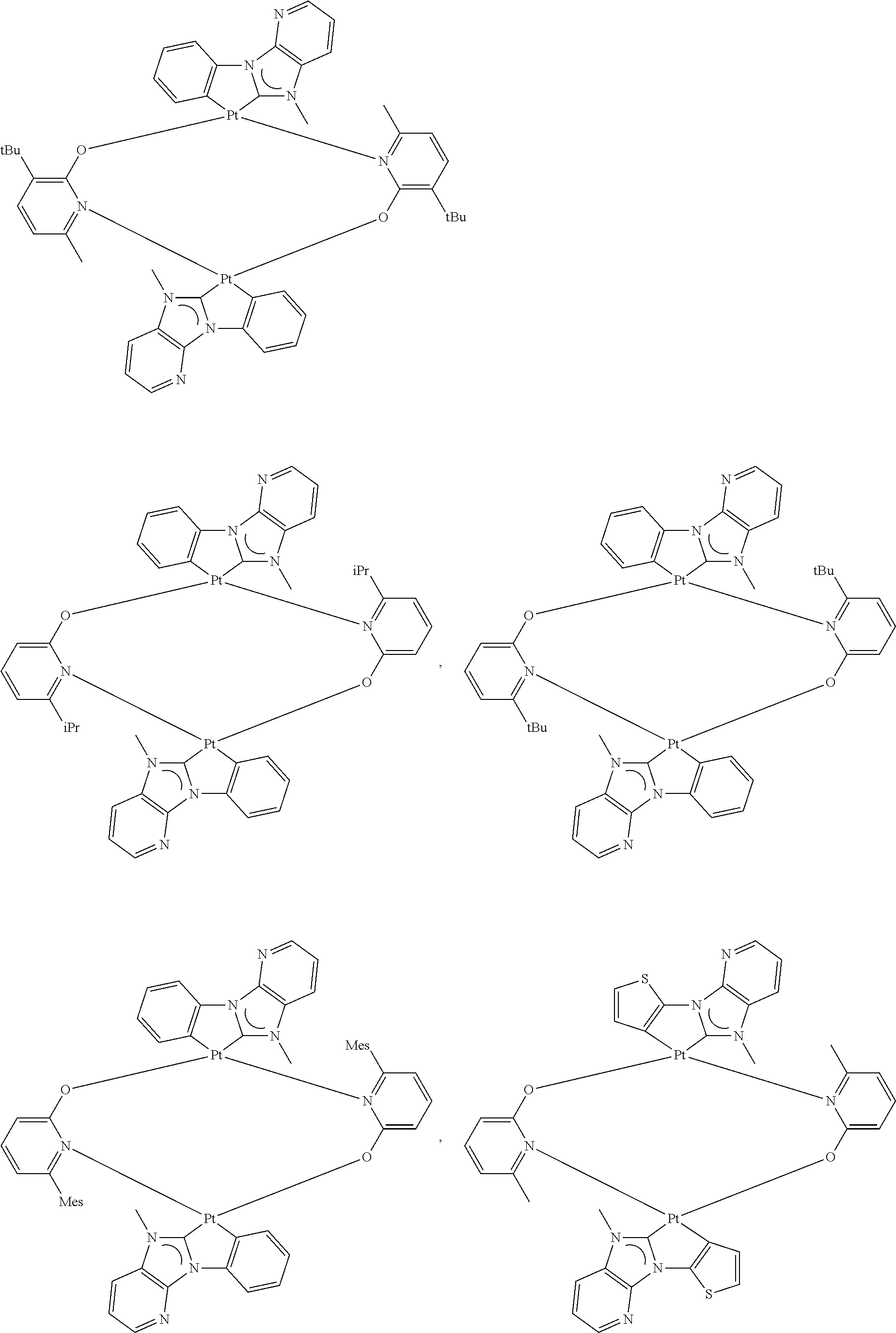

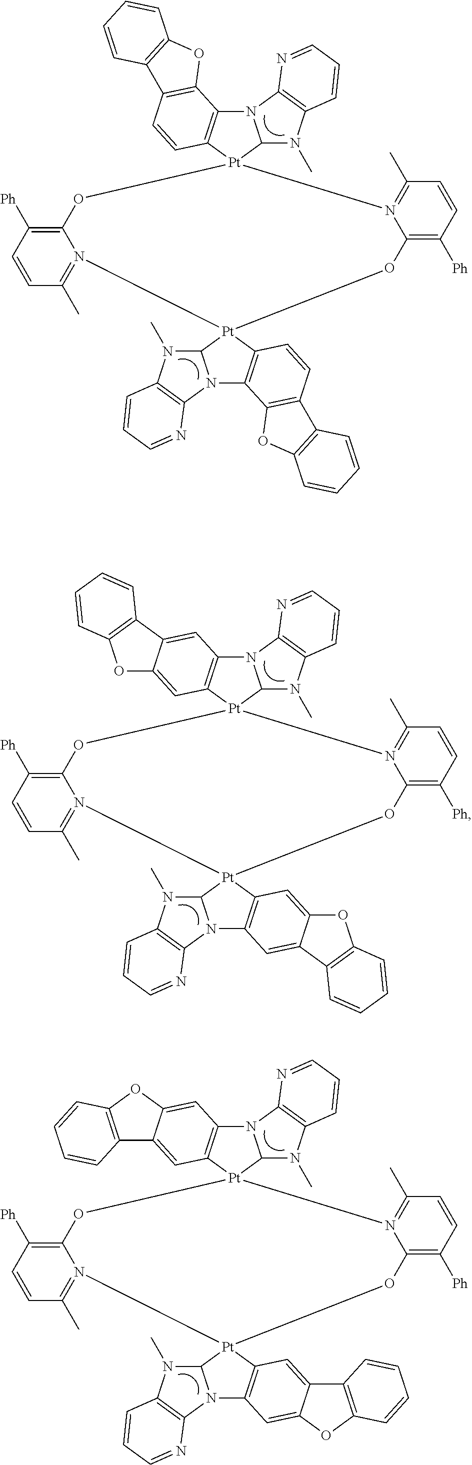

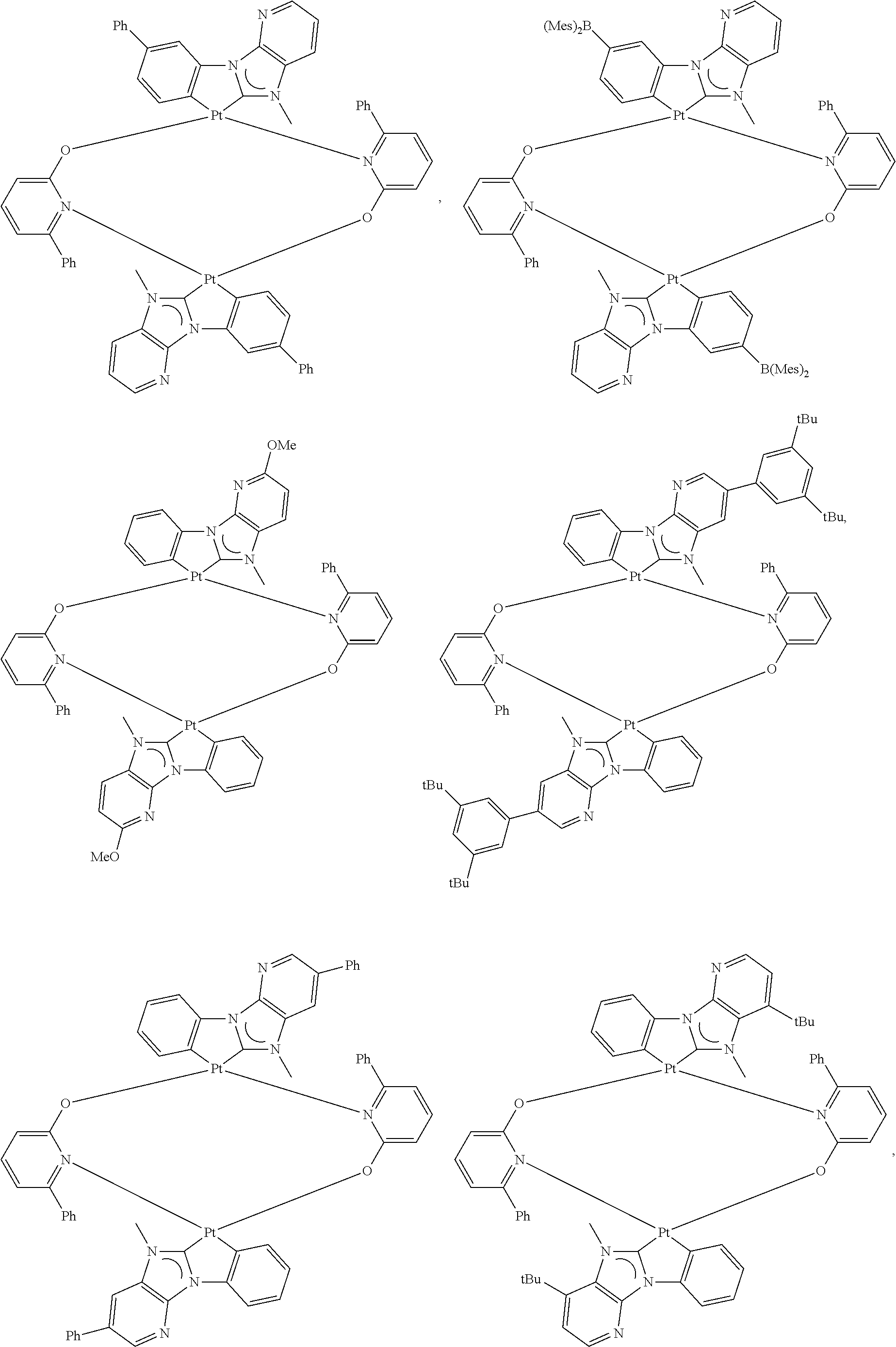

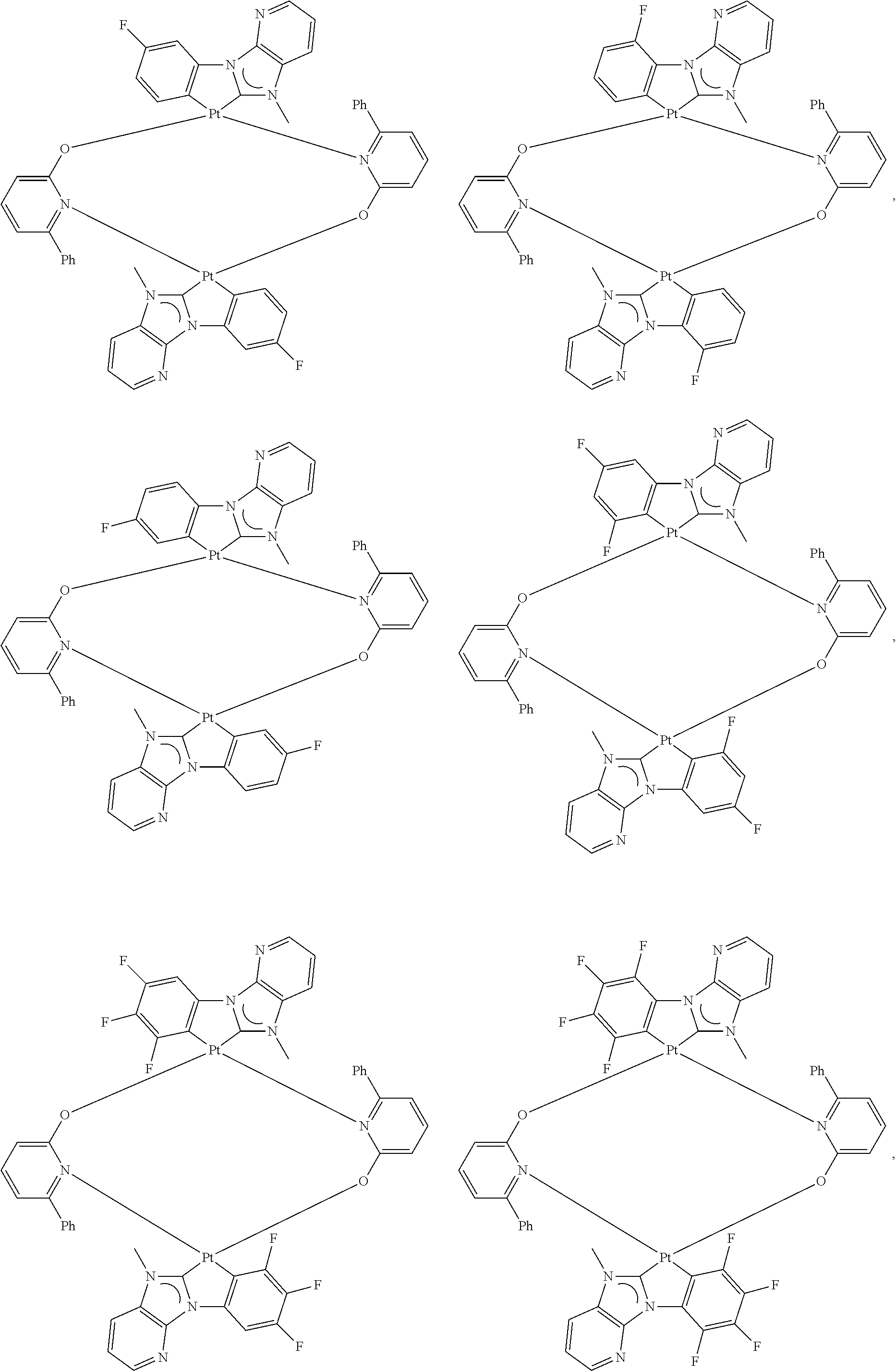

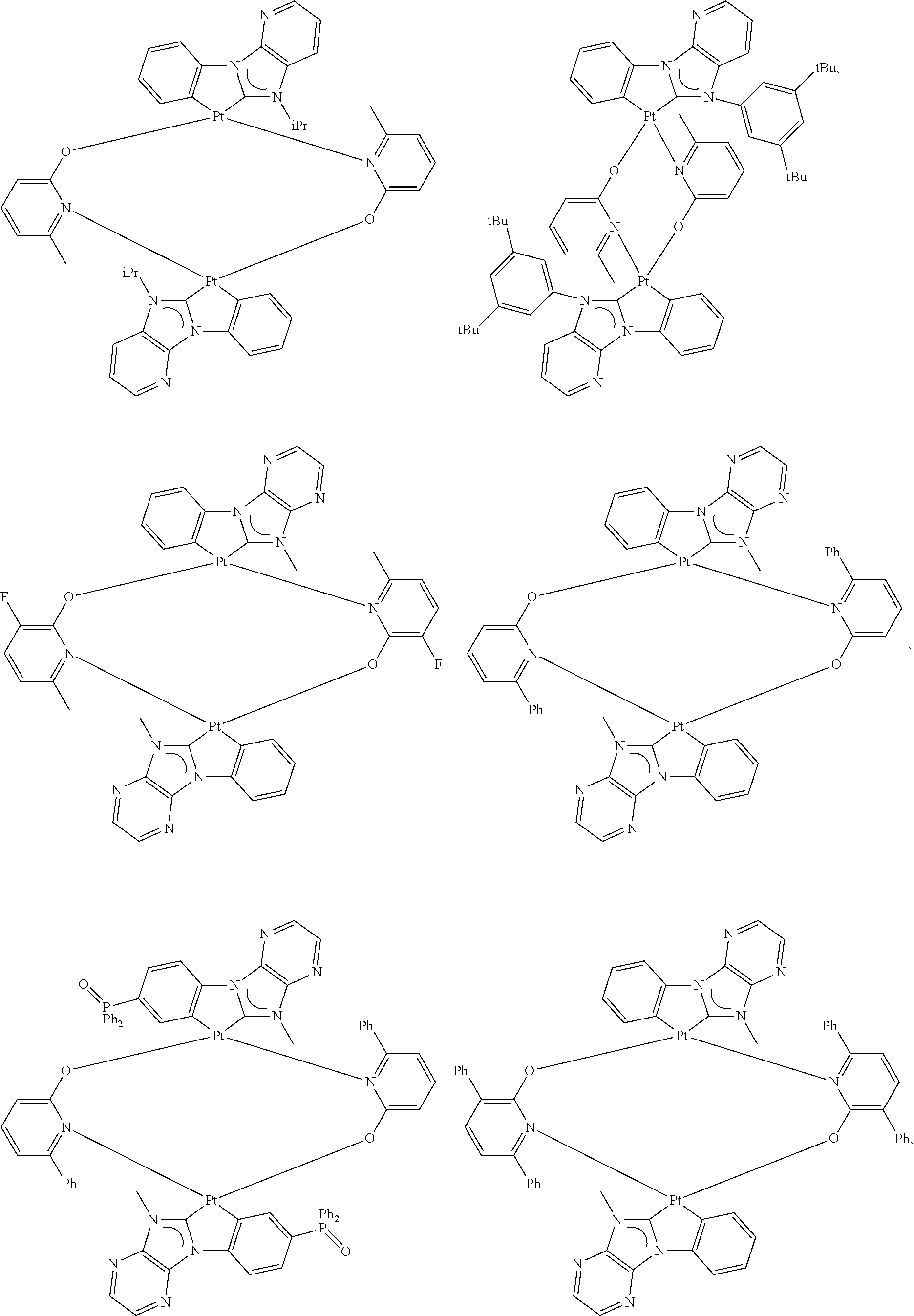

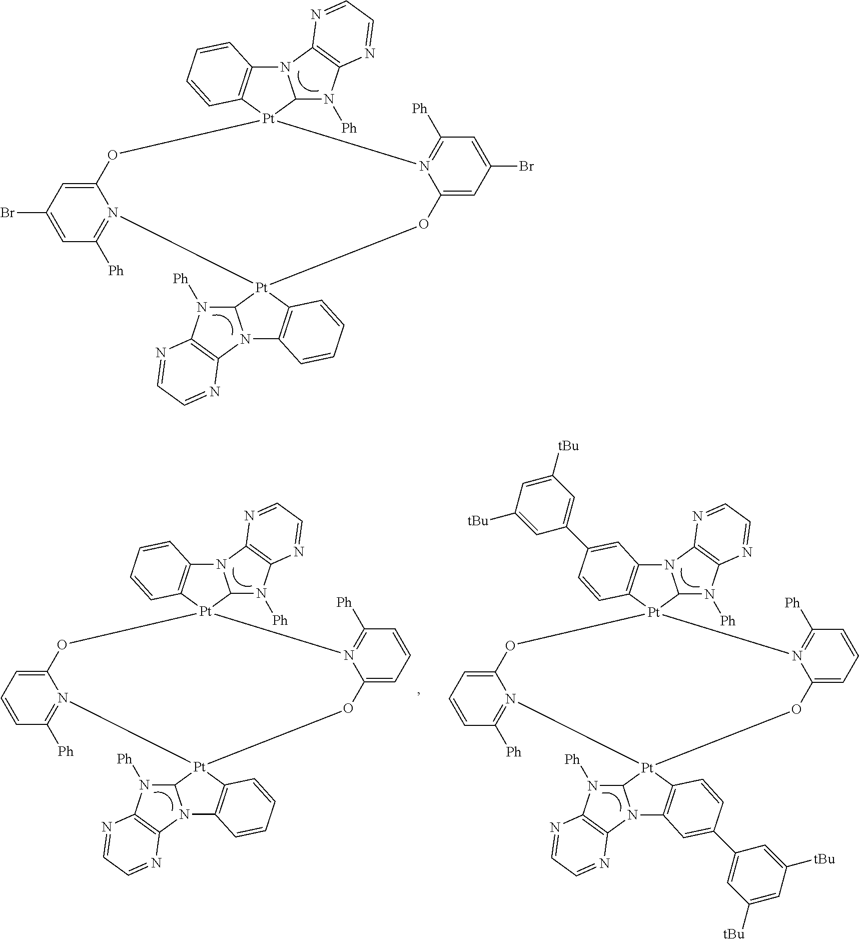

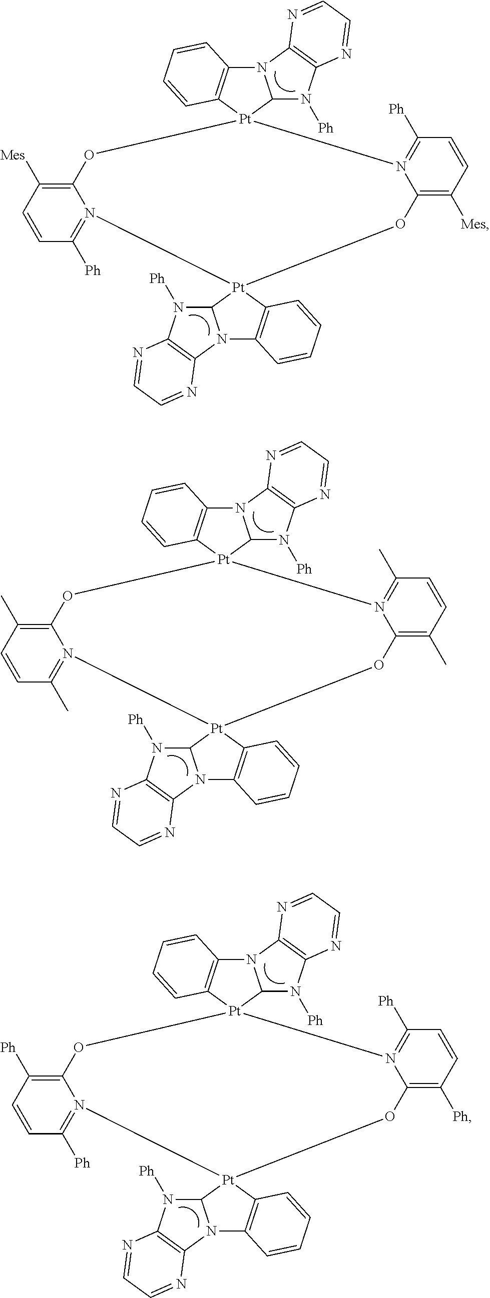

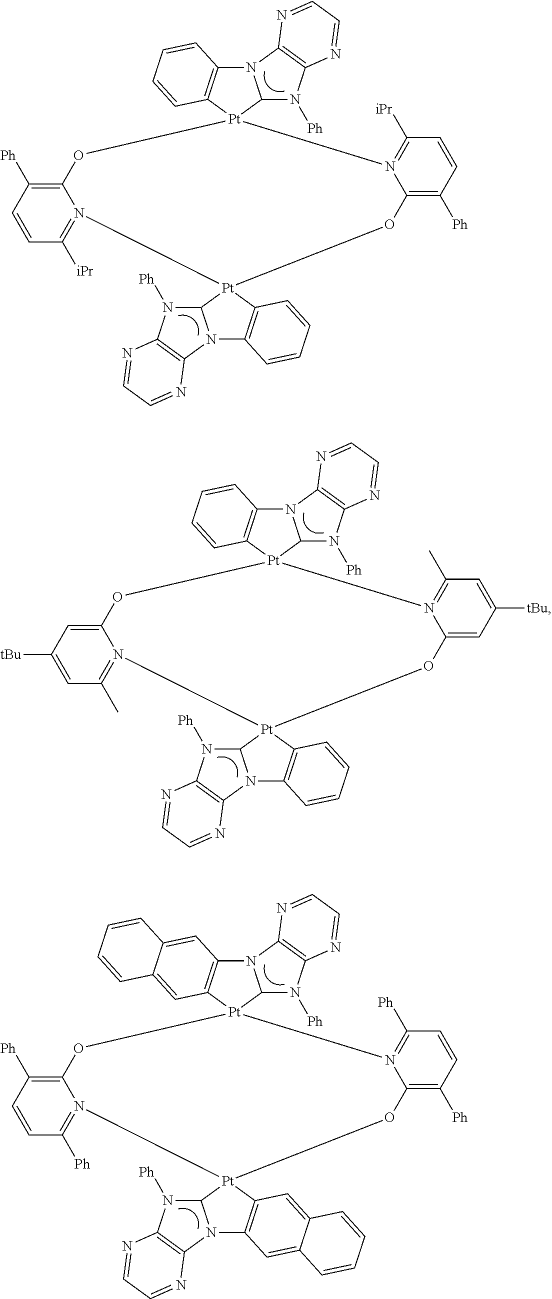

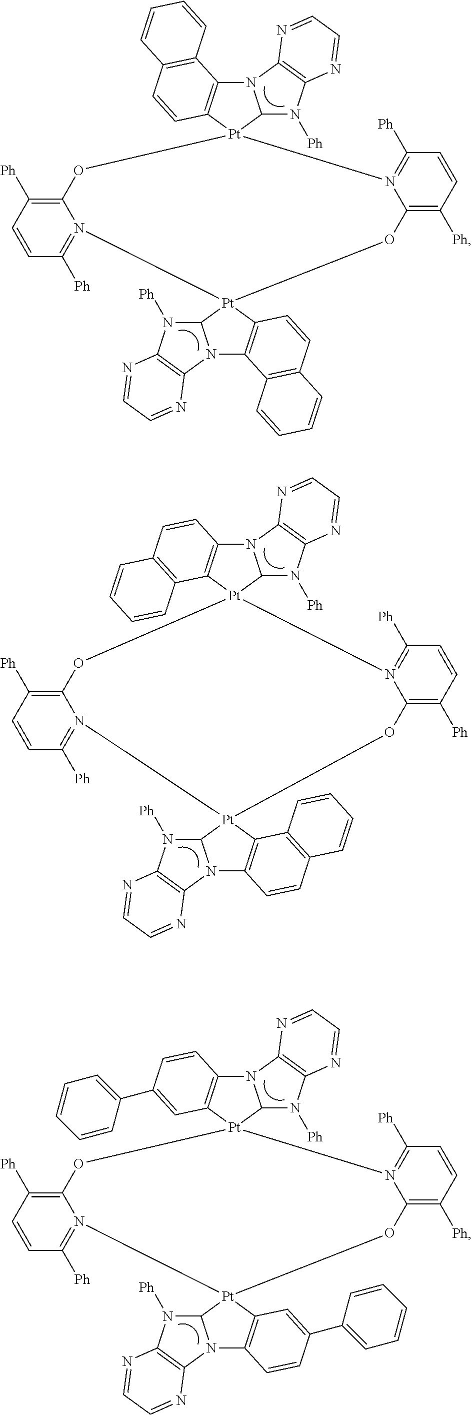

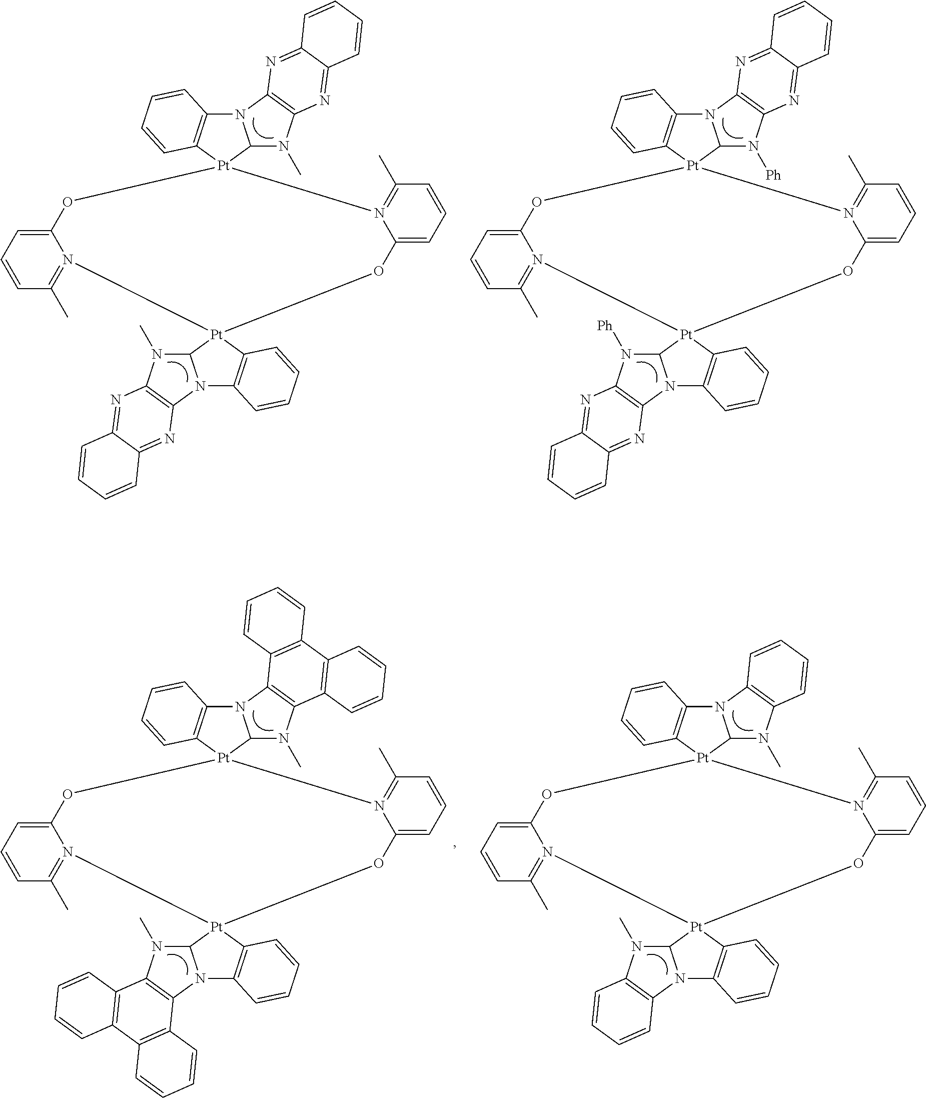

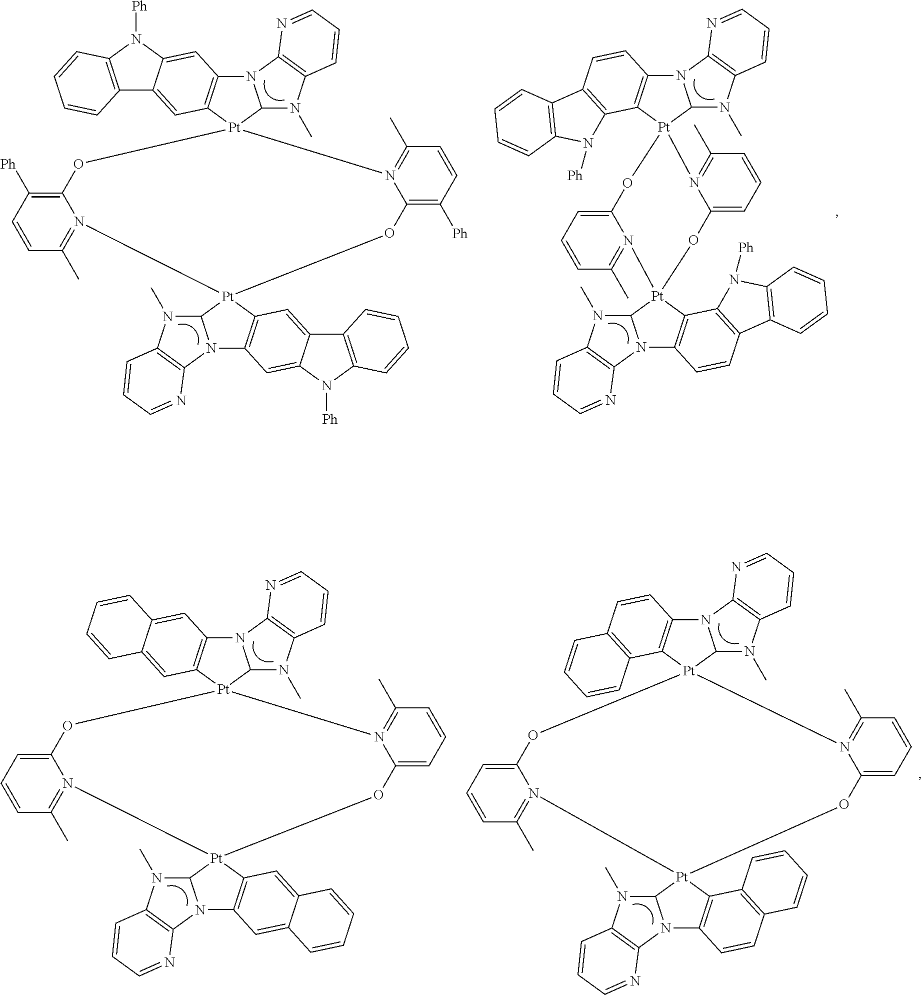

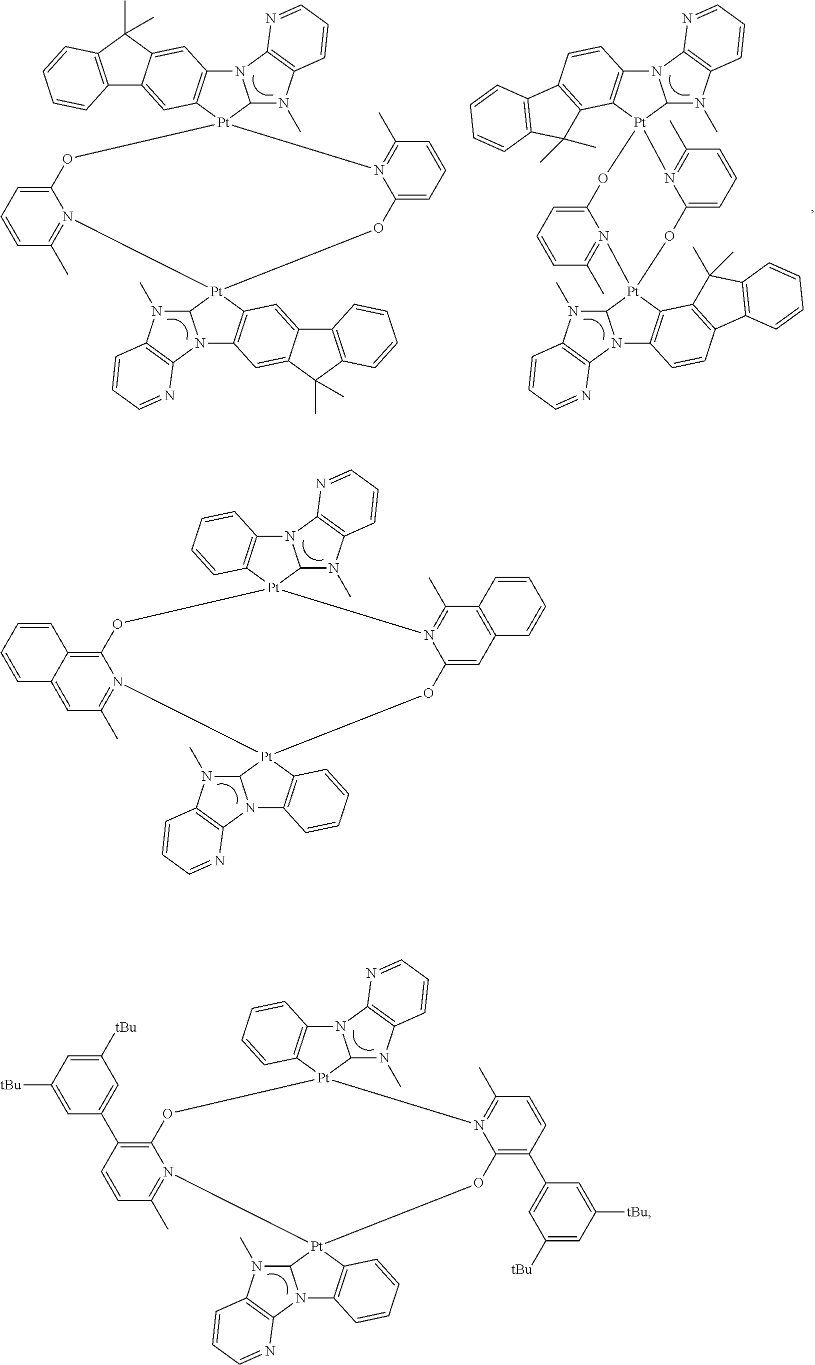

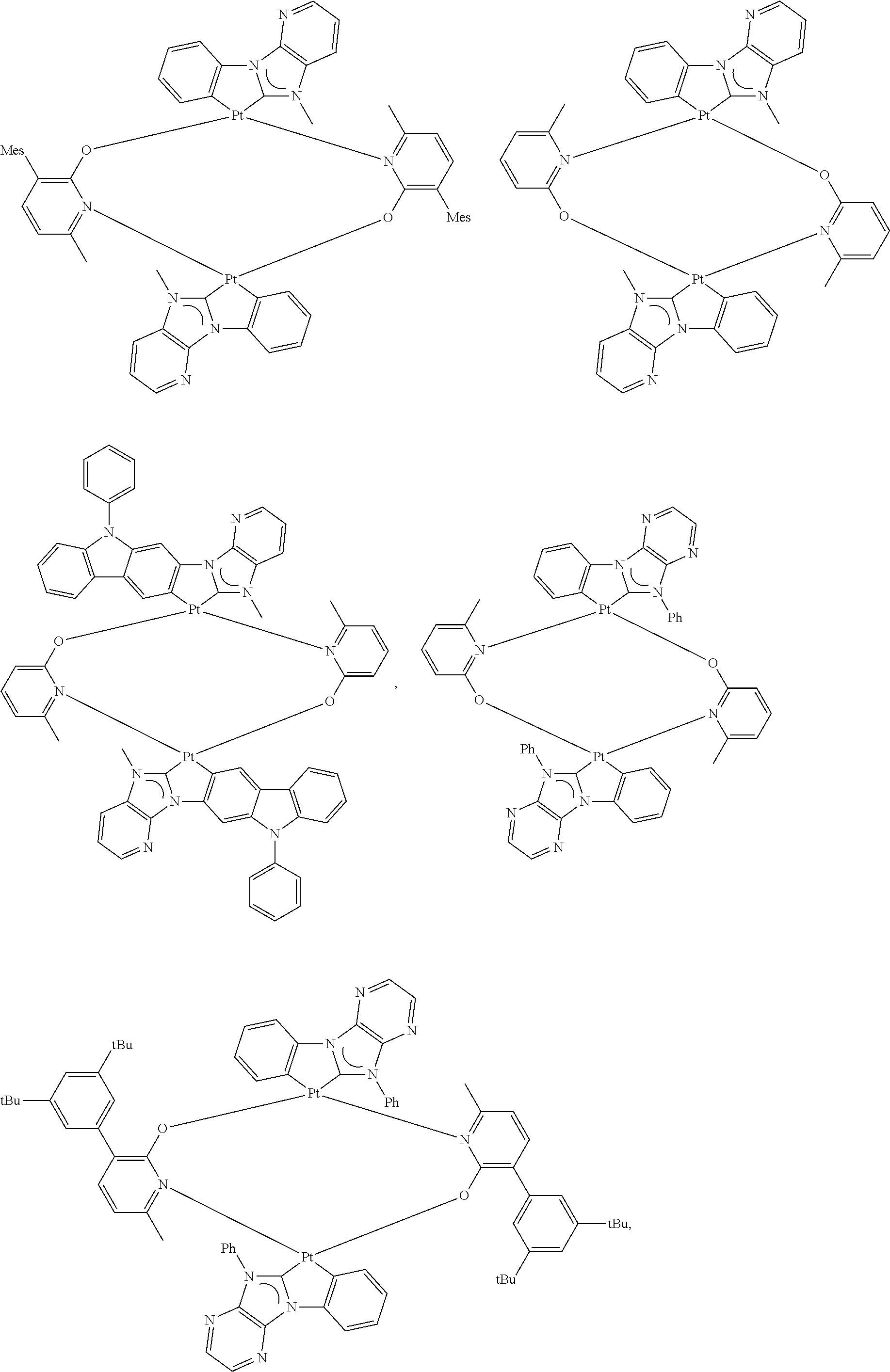

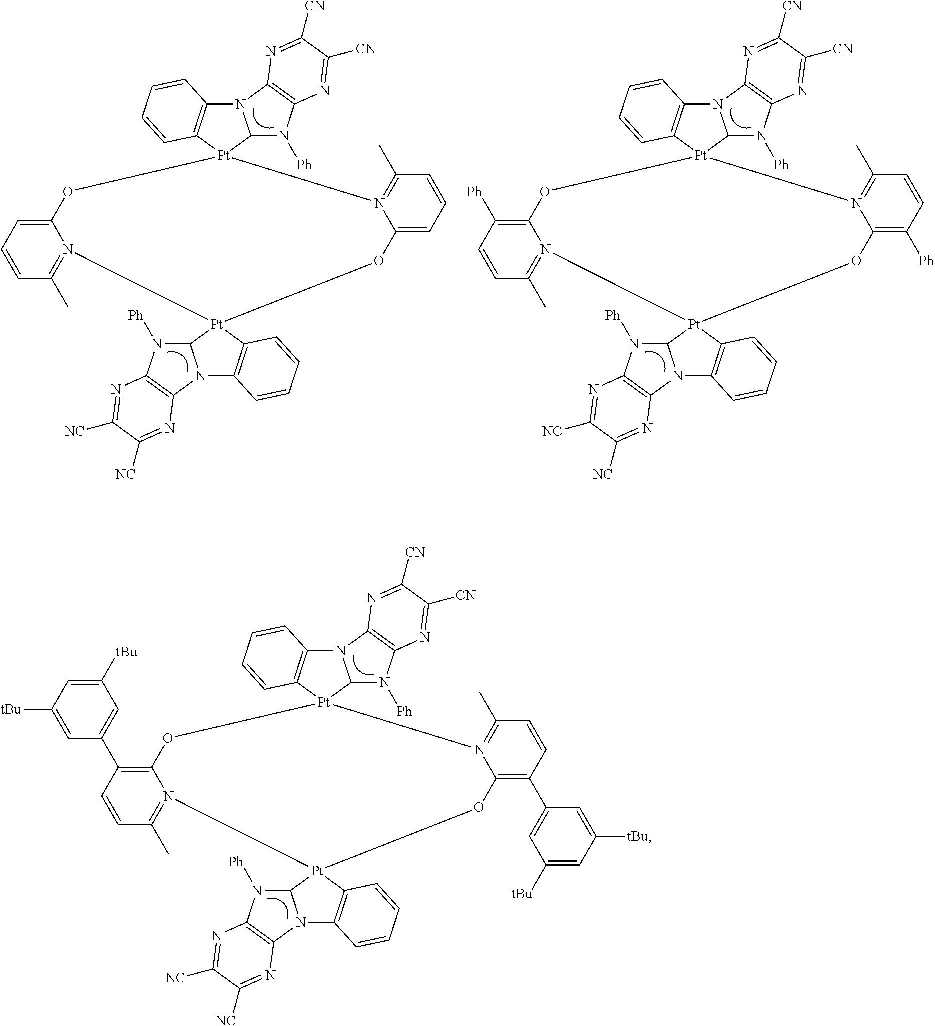

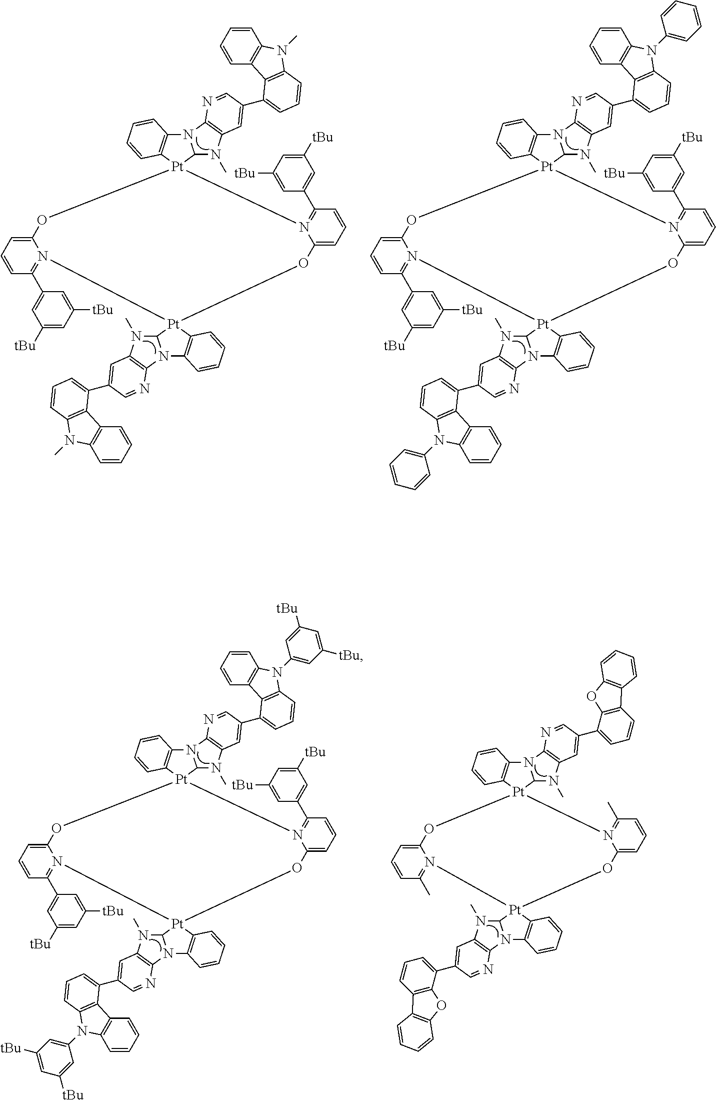

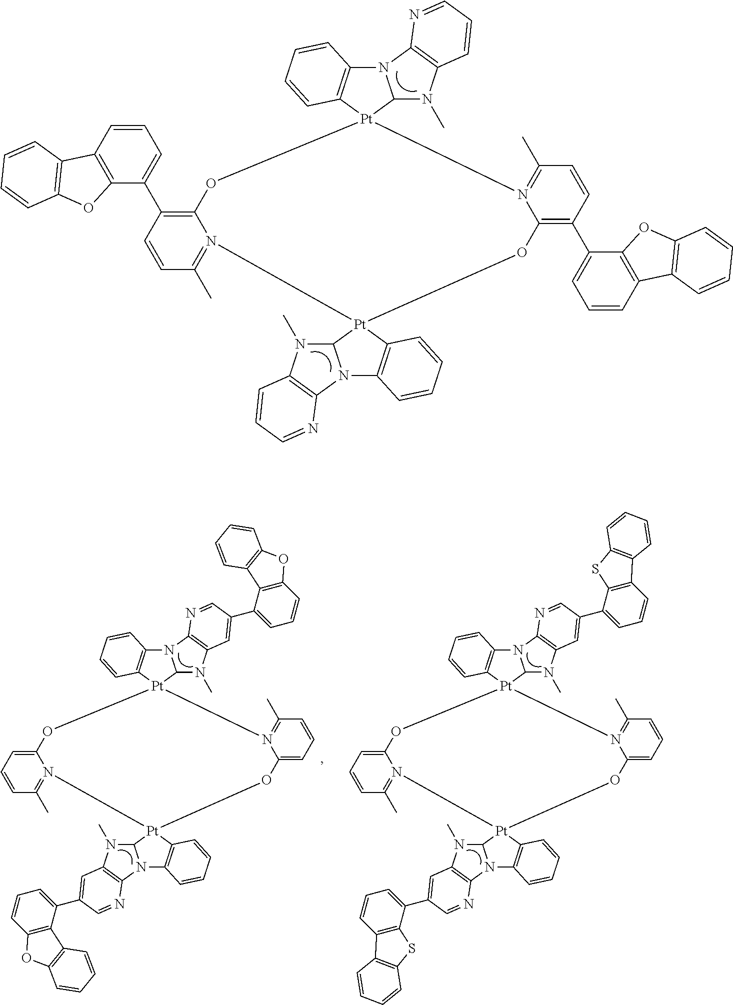

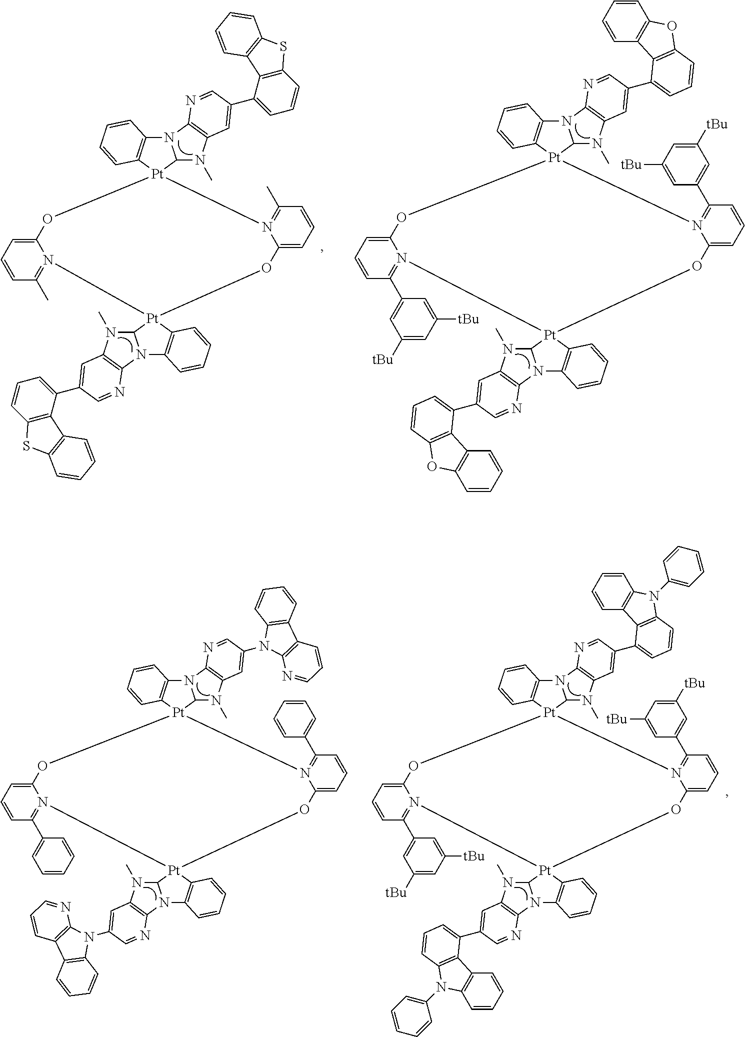

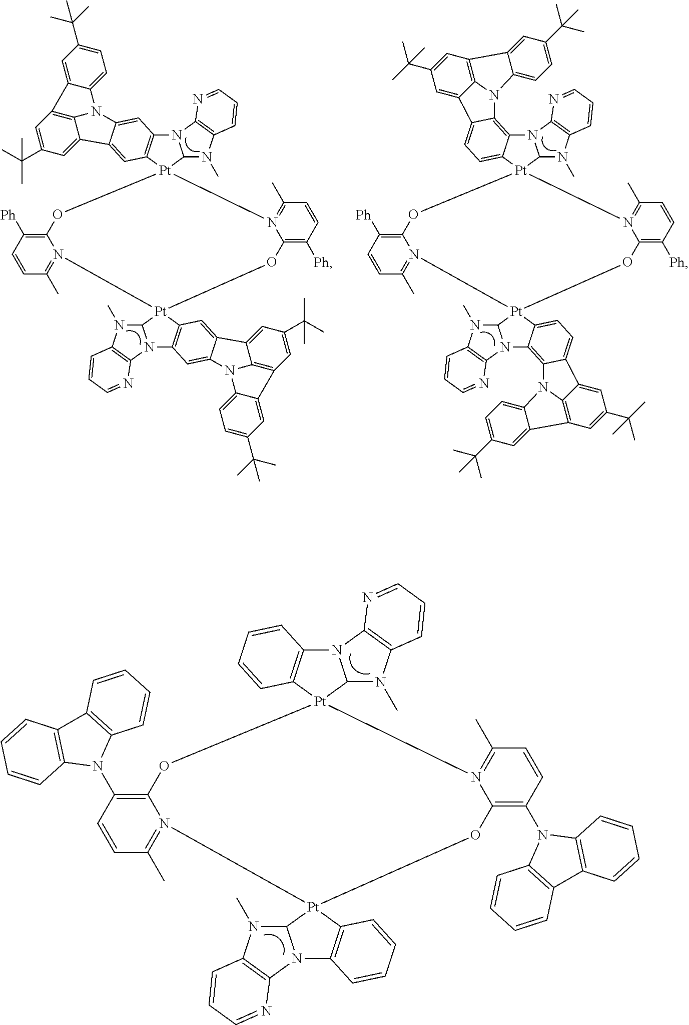

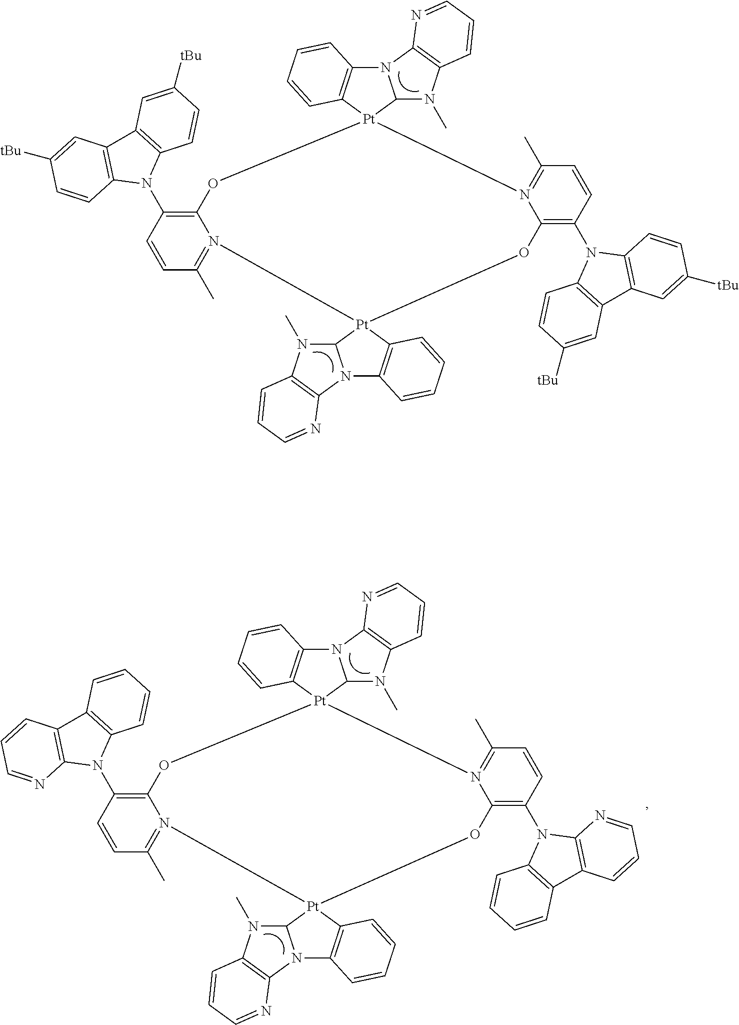

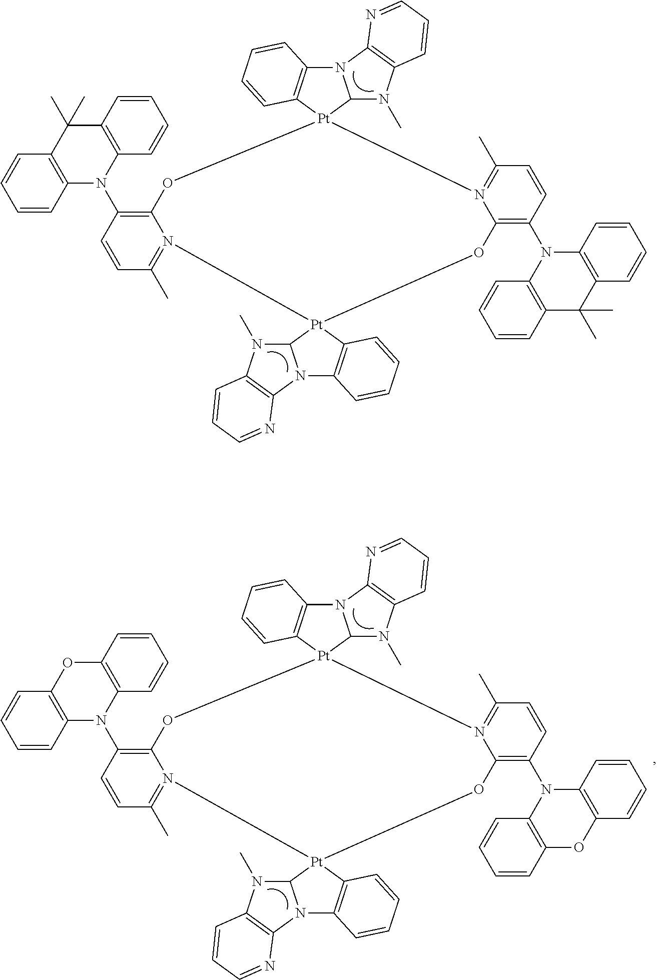

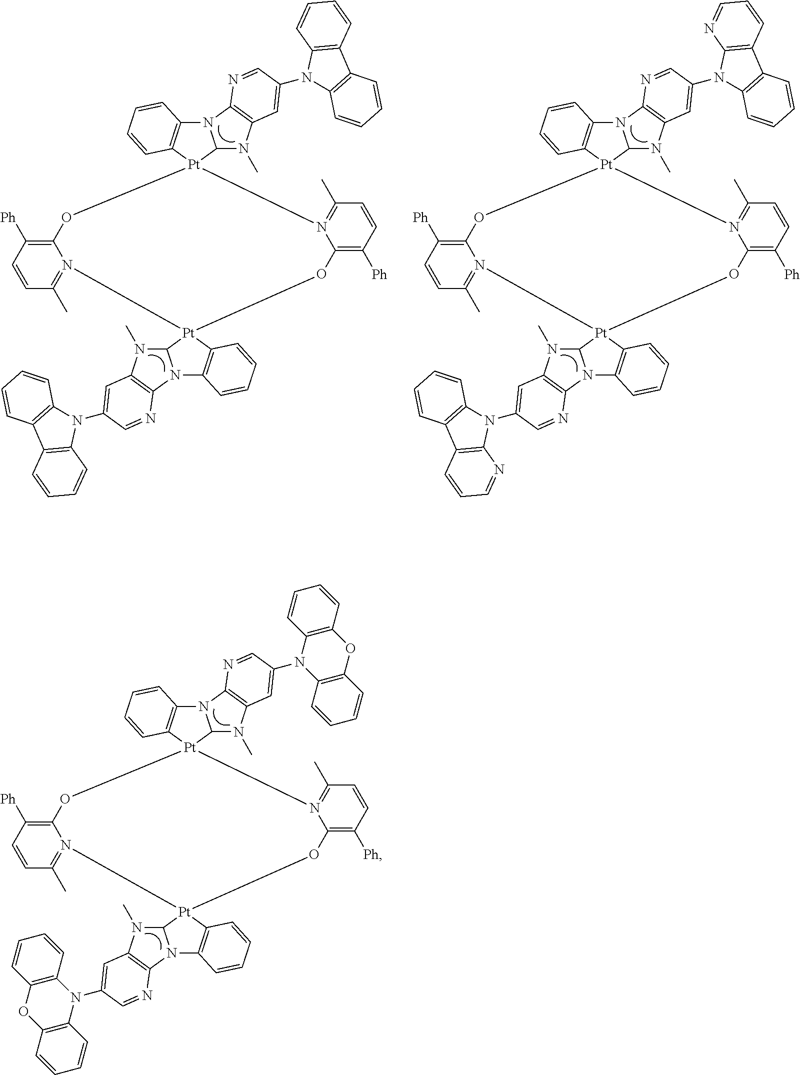

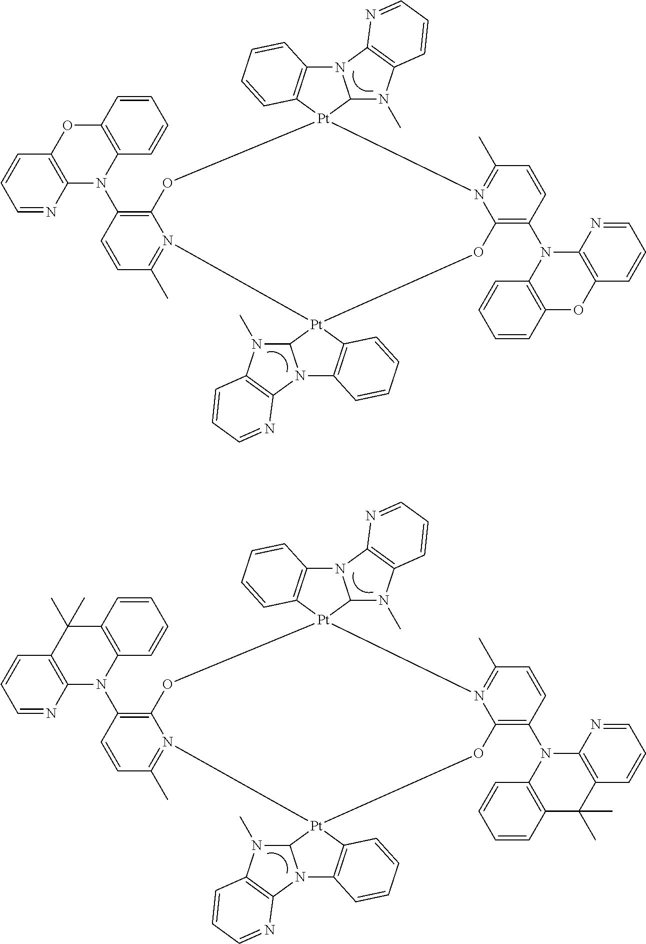

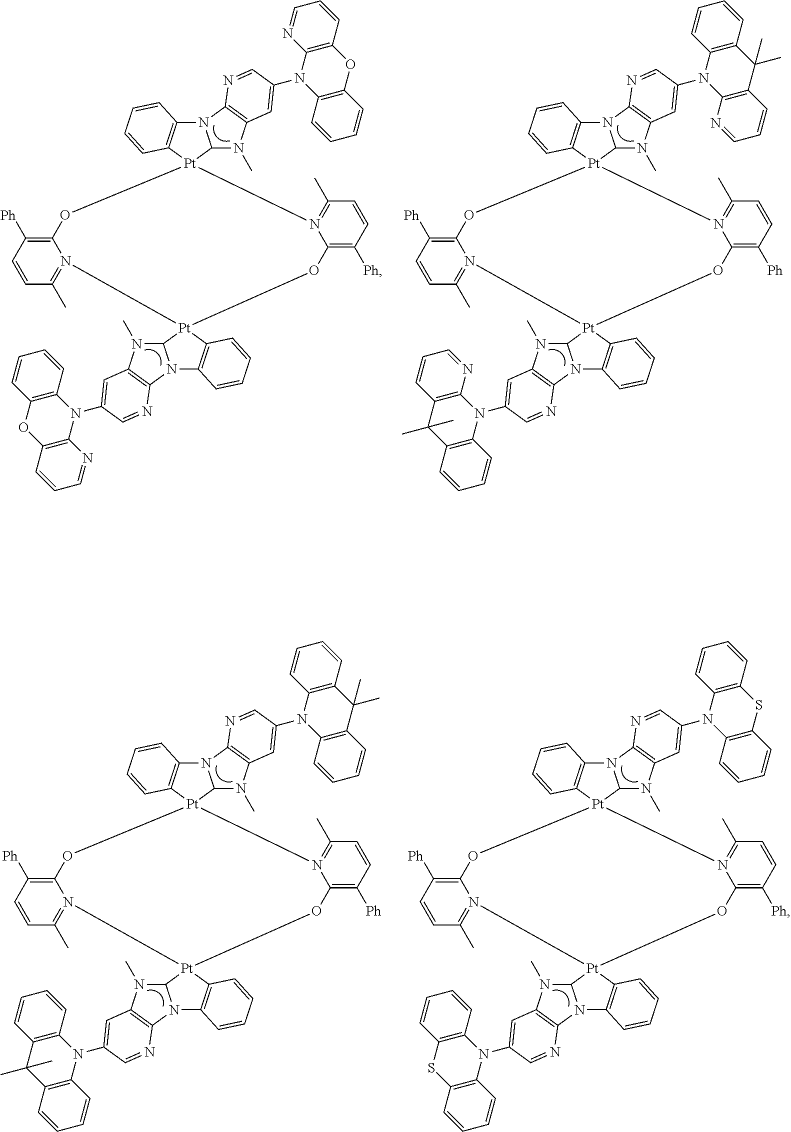

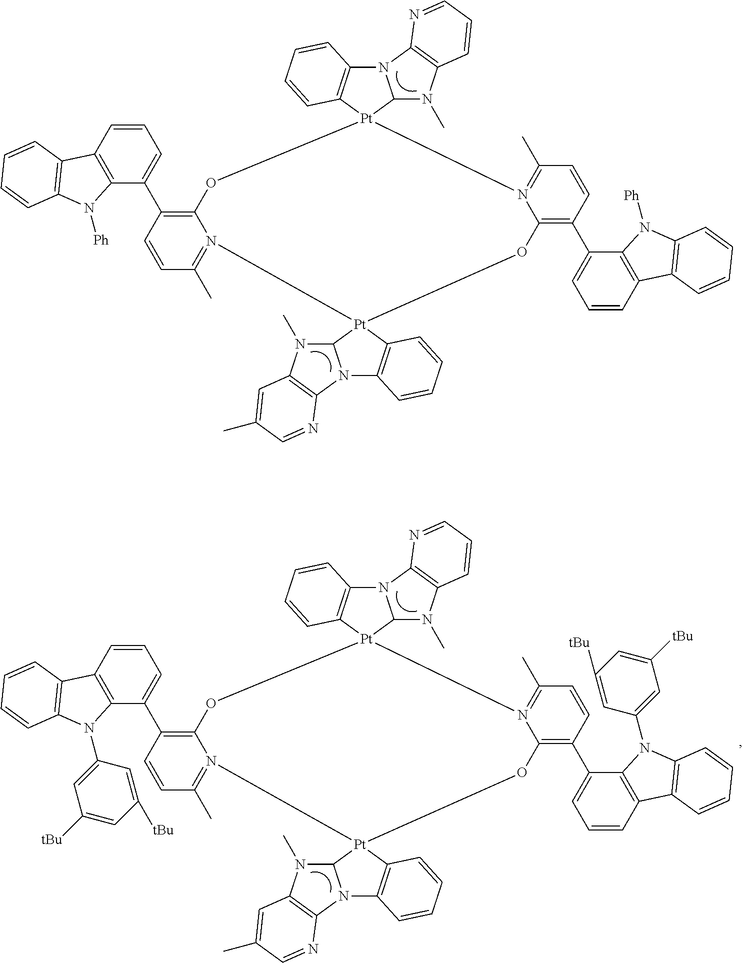

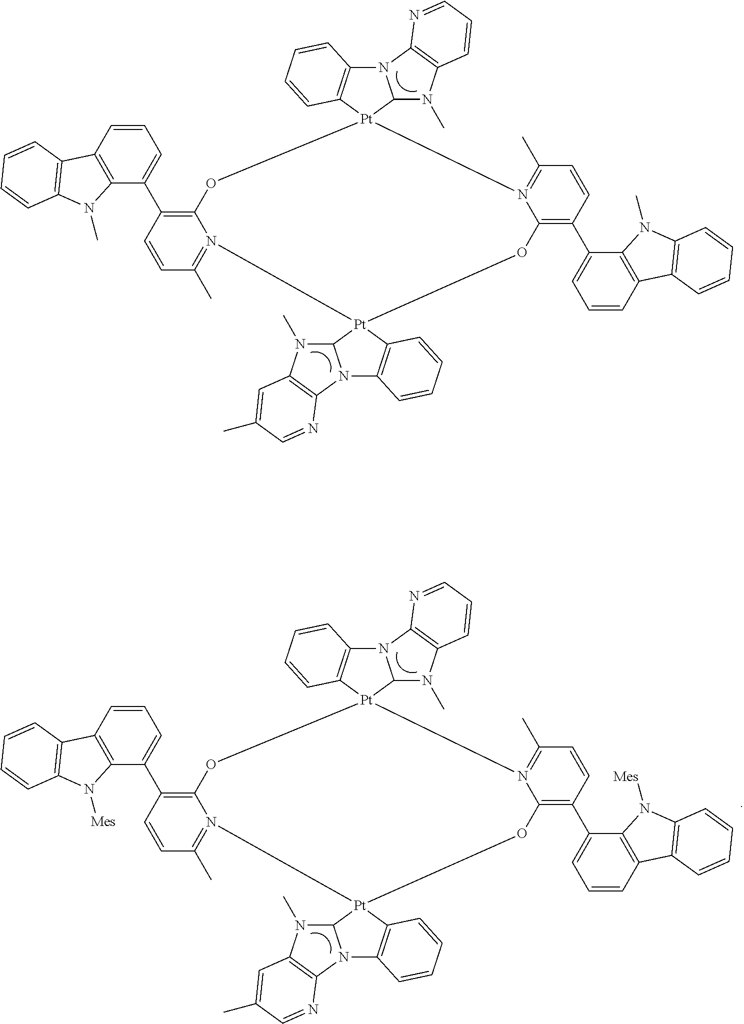

Typically, the complex emits in the red-deep red or NIR region with a maximum emission wavelength (λₘₐₓ) in a range from 600 nm to 1000 nm, from 600 nm to 900 nm, from 600 nm to 800 nm, from 600 nm to 700 nm, from 600 nm to 680 nm, from 620 nm to 710 nm, or from 612 nm to 685 nm.

In some forms, the complex can have an emission lifetime (τₑₘ) of up to 2.5 μs, up to 2.0 μs, up to 1.9 μs, up to 1.8 μs, in a range from 0.5 μs to 2.0 μs, from 0.8 μs to 2.0 μs, from 1.0 μs to 2.0 μs, from 0.5 μs to 1.9 μs, from 0.8 μs to 1.9 μs, from 1.0 μs to 1.9 μs, from 1.2 μs to 1.9 μs, such as from 1.7 μs to 1.9 μs; a radiative decay rate (kᵣ) of at least 4.0×10⁵ s⁻¹, in a range from 4.0×10⁵ s⁻¹ to 10.0×10⁵ s⁻¹, from 4.0×10⁵ s⁻¹ to 8.0×10⁵ s⁻¹, from 4.0×10⁵ s⁻¹ to 6.0×10⁵ s⁻¹, from 4.0×10⁵ s⁻¹ to 5.5×10⁵ s⁻¹, from 4.2×10⁵ s⁻¹ to 10.0×10⁵ s⁻¹, from 4.2×10⁵ s⁻¹ to 8.0×10⁵ s⁻¹, from 4.2×10⁵ s⁻¹ to 6.0×10⁵ s⁻¹, from 4.2×10⁵ s⁻¹ to 5.5×10⁵ s⁻¹, or from 4.3×10⁵ s⁻¹ to 5.5×10⁵ s⁻¹; a non-radiative decay rate (kₘr) of less than 2.0×10⁵ s⁻¹, less than 1.8×10⁵ s⁻¹, less than 1.5×10⁵ s⁻¹, down to 0.15×10⁵ s⁻¹, in a range from 0.15×10⁵ s⁻¹ to 2.0×10⁵ s⁻¹, from 0.16×10⁵ s⁻¹ to 2.0×10⁵ s⁻¹, from 0.15×10⁵ s⁻¹ to 1.8×10⁵ s⁻¹, from 0.16×10⁵ s⁻¹ to 1.8×10⁵ s⁻¹, from 0.15×10⁵ s⁻¹ to 1.6×10⁵ s⁻¹, from 0.16×10⁵ s⁻¹ to 1.6×10⁵ s⁻¹, from 0.15×10⁵ s⁻¹ to 1.5×10⁵ s⁻¹, or from 0.16×10⁵ s⁻¹ to 1.4×10⁵ s⁻¹; and/or an emission quantum yield (Φₑₘ) of at least 60%, at least 65%, at least 70%, at least 75%, in a range from 60% to 97%, from 65% to 97%, from 70% to 97%, from 75% to 97%, or from 78% to 97%, measured in solution or films, at room temperature.

Organic light-emitting components, such as organic light-emitting diode (“OLED”) or light-emitting electrochemical cell (“LEEC”), containing one or more light-emitting layer or two or more light-emitting layers formed using the disclosed dinuclear platinum(II) complexes are also disclosed. Generally, the total concentration of the dinuclear platinum(II) complexes in the light-emitting layer or each light-emitting layer of the two or more light-emitting layers in the organic light-emitting component is up to 50 wt %, such as in a range from about 1 wt % to about 16 wt %, for example, about 4 wt %, about 8 wt %, or about 12 wt %. These organic light-emitting components can emit light in the red to deep red region or in the NIR region, with high efficiency at room temperature.

For examples, the organic light-emitting component can emit light in the red to deep red region with a maximum brightness (L) of at least 20000 cd m⁻², at least 25000 cd m⁻², at least 30000 cd m⁻², at least 35000 cd m⁻², at least 40000 cd m⁻², in a range from 20000 cd m⁻² to 100000 cd m⁻², from 30000 cd m⁻² to 100000 cd m⁻², from 20000 cd m⁻² to 80000 cd m⁻², from 30000 cd m⁻² to 80000 cd m⁻², from 20000 cd m⁻² to 60000 cd m⁻², from 30000 cd m⁻² to 60000 cd m⁻², from 20000 cd m⁻² to 50000 cd m⁻² from 30000 cd m⁻² to 100000 cd m⁻², from 20000 cd m⁻² to 50000 cd m⁻², from 30000 cd m⁻² to 50000 cd m⁻², from 35000 cd m⁻² to 100000 cd m⁻², from 40000 cd m⁻² to 100000 cd m⁻², from 35000 cd m⁻² to 80000 cd m⁻², from 40000 cd m⁻² to 80000 cd m⁻², from 35000 cd m⁻² to 60000 cd m⁻², from 40000 cd m⁻² to 60000 cd m⁻², from 35000 cd m⁻² to 50000 cd m⁻², or from 40000 cd m⁻² to 50000 cd m⁻²; a current efficiency (CE) at 1000 cd/m² of at least 20 cd A⁻¹, at least 22 cd/A, in a range from 20 cd/A to 60 cd/A, from 22 cd/A to 60 cd/A, from 20 cd/A to 50 cd/A, from 22 cd/A to 50 cd/A, from 20 cd/A to 40 cd/A, or from 20 cd/A to 30 cd/A; a power efficiency (PE) at 1000 cd/m² of at least 10 1 m/W, in a range from 10 1 m/W to 60 1 m/W, from 15 1 m/W to 60 1 m/W, from 10 1 m/W to 50 1 m/W, from 15 1 m/W to 50 1 m/W, from 10 1 m/W to 40 1 m/W, from 15 1 m/W to 40 1 m/W, from 10 1m/W to 30 1 m/W, from 15 1 m/W to 30 1 m/W, or from 10 1 m/W to 20 1 m/W; and/or an external quantum efficiency (EQE) at 1000 cd/m² of at least 10%, at least 11%, at least 12%, at least 13%, at least 14%, at least 15%, in a range from 10% to 40%, from 10% to 20%, from 10% to 20%, from 11% to 40%, from 11% to 30%, from 11% to 20%, from 12% to 20%, from 12% to 40%, from 12% to 30%, from 13% to 20%, from 13% to 40%, from 13% to 30%, from 14% to 20%, from 14% to 40%, from 14% to 30%, from 15% to 40%, from 15% to 30%, or from 15% to 20%.

Alternatively, the organic light-emitting component can emit light in the NIR region with an L of at least 1000 cd m⁻², at least 2000 cd m⁻², at least 3000 cd m⁻², at least 4000 cd m⁻², at least 4200 cd m⁻², at least 4500 cd m⁻², in a range from 1000 cd m⁻² to 40000 cd m⁻², from 2000 cd m⁻² to 40000 cd m⁻², from 3000 cd m⁻² to 40000 cd m⁻², from 4000 cd m⁻² to 40000 cd m⁻², from 4500 cd m⁻² to 40000 cd m⁻², from 1000 cd m⁻² to 30000 cd m⁻², from 2000 cd m⁻² to 30000 cd m⁻², from 3000 cd m⁻² to 30000 cd m⁻², from 4000 cd m⁻² to 30000 cd m⁻², from 4500 cd m⁻² to 30000 cd m⁻², from 1000 cd m⁻² to 20000 cd m⁻², from 2000 cd m⁻² to 20000 cd m⁻², from 3000 cd m⁻² to 20000 cd m⁻², from 4000 cd m⁻² to 20000 cd m⁻², from 4500 cd m⁻² to 20000 cd m⁻², from 1000 cd m⁻² to 10000 cd m⁻², from 2000 cd m⁻² to 10000 cd m⁻², from 3000 cd m⁻² to 10000 cd m⁻², from 4000 cd m⁻² to 10000 cd m⁻², or from 4500 cd m⁻² to 10000 cd m⁻²; a CE at 1000 cd m⁻² of at least 0.2 cd A⁻¹, at least 0.4 cd A⁻¹, at least 0.8 cd A⁻¹, in a range from 0.2 cd/A to 10 cd/A, from 0.2 cd/A to 8 cd/A, from 0.2 cd/A to 5 cd/A, from 0.2 cd/A to 3 cd/A, from 0.2 cd/A to 2 cd/A, from 0.4 cd/A to 10 cd/A, from 0.4 cd/A to 8 cd/A, from 0.4 cd/A to 5 cd/A, from 0.4 cd/A to 3 cd/A, from 0.4 cd/A to 2 cd/A, from 0.8 cd/A to 10 cd/A, from 0.8 cd/A to 8 cd/A, from 0.8 cd/A to 5 cd/A, from 0.8 cd/A to 3 cd/A, or from 0.8 cd/A to 2 cd/A; a PE at 1000 cd/m² of at least 0.1 1 m/W, at least 0.2 1 m/W, in a range from 0.1 1 m/W to 5 1 m/W, from 0.1 1 m/W to 4 1 m/W, from 0.1 1 m/W to 3 1 m/W, from 0.1 1m/W to 2 1 m/W, from 0.1 1 m/W to 1 1 m/W, from 0.1 1 m/W to 0.5 1 m/W, from 0.2 1 m/W to 5 1 m/W, from 0.2 1 m/W to 4 1 m/W, from 0.2 1 m/W to 3 1 m/W, from 0.2 1 m/W to 2 1m/W, from 0.2 1 m/W to 1 1 m/W, or from 0.2 1 m/W to 0.5 1 m/W; and/or an EQE at 1000 cd/m² of at least 1%, at least 2%, at least 4%, at least 5%, at least 6%, in a range from 1% to 20%, from 2% to 20%, from 4% to 20%, from 5% to 20%, from 5% to 18%, from 1% to 15%, from 2% to 15%, from 4% to 15%, from 5% to 15%, from 1% to 10%, from 2% to 10%, from 4% to 10%, or from 5% to 10% These organic red/NIR light-emitting components containing the dinuclear platinum(II) complexes disclosed herein can be used in a variety of devices, such as a stationary visual display unit, a mobile visual display unit, an illumination device, a wearable device, or a medical monitoring device.

### BRIEF DESCRIPTION OF THE DRAWINGS

FIG. 1A is a graph showing the photoluminescence (PL) spectra of Pt—R1, Pt—R2, Pt—R3, Pt—R4, Pt—R5, and Pt—R6 in PMMA films with doping concentration of 4 wt %. FIG. 1B is a graph showing the emission spectra of Pt—R7 to Pt—R13 in PMMA films at room temperature. FIG. 1C is a graph showing the emission spectra of Pt—R14 and Pt—R15 in PMMA films at room temperature.

FIGS. 2A-2D are electroluminescence (EL) spectra (FIG. 2A) and performance characteristics of devices of Pt—R1 with doping concentrations of 4-12 wt %, respectively. The performance characteristics of this device include external quantum efficiency (EQE) (FIG. 2B), luminance (FIG. 2C), and current density (CE) (FIG. 2D). The device structure is: ITO/HAT-CN (5 nm)/TAPC (40 nm)/TCTA (10 nm)/TCTA: TPBi: Pt—R1 (20 nm)/TPBi (50 nm)/LiF (1 nm)/Al (100 nm).

FIGS. 3A-3D are EL spectra (FIG. 3A) and performance characteristics of devices of Pt—R2 with doping concentration of 4 and 8 wt %, respectively. The performance characteristics of this device include EQE (FIG. 3B), luminance (FIG. 3C), and CE (FIG. 3D). The device structure is: ITO/HAT-CN (5 nm)/TAPC (40 nm)/TCTA (10 nm)/TCTA: TPBi: Pt—R2 (20 nm)/TPBi (50 nm)/LiF (1 nm)/Al (100 nm).

FIGS. 4A-4D are EL spectra (FIG. 4A) and performance characteristics of a first device fabricated with Pt—R3 with doping concentration of 4, 8, 12, and 16 wt %, respectively. The performance characteristics of this device include EQE (FIG. 4B), luminance (FIG. 4C), and CE (FIG. 4D). The device structure is: ITO/HAT-CN (5 nm)/TAPC (40 nm)/TCTA (10 nm)/TCTA: TPBi: Pt—R3 (20 nm)/TPBi (50 nm)/LiF (1 nm)/Al (100 nm).

FIGS. 5A-5D are EL spectra (FIG. 5A) and performance characteristics of a second device fabricated with Pt—R3 with doping concentration of 1, 2, and 4 wt %, respectively. The performance characteristics of this device include EQE (FIG. 5B), luminance (FIG. 5C), and CE (FIG. 5D). The device structure is: ITO/HAT-CN (10 nm)/FSFA (120 nm)/FSF4A (5 nm)/Pt—R3:DMIC-Cz: DMIC-Trz (30 nm)/ANT-Biz (5 nm)/ANT-Biz:Liq (1:1) (25 nm)/Liq (2 nm)/Al (100 nm).

FIGS. 6A-6C are graphs showing the lifetime data of the second device fabricated with Pt—R3 with doping concentration of 1 wt % (FIG. 6A), 2 wt % (FIG. 6B), and 4 wt % (FIG. 6C), respectively.

FIGS. 7A-7D are EL spectra (FIG. 7A) and performance characteristics of a first device fabricated with Pt—R4 with doping concentration of 2, 4, and 8 wt %, respectively. The performance characteristics of this device include EQE (FIG. 7B), luminance (FIG. 7C), and CE (FIG. 7D). The device structure is: ITO/HAT-CN (5 nm)/TAPC (40 nm)/TCTA (10 nm)/TCTA:TPBi:Pt—R4 (20 nm)/TPBi (50 nm)/LiF (1 nm)/Al (100 nm).

FIGS. 8A-8D are EL spectra (FIG. 8A) and performance characteristics of a second device fabricated with Pt—R4 with doping concentration of 2, 4, and 8 wt %, respectively. The performance characteristics of this device include EQE (FIG. 8B), luminance (FIG. 8C), and CE (FIG. 8D). The device structure is: ITO/HAT-CN (10 nm)/BPBPA (120 nm)/EB (5 nm)/Pt—R4:RH (40 nm)/HB (5 nm)/ZADN:Liq (35:65) (35 nm)/Liq (2 nm)/Al (100 nm).

FIGS. 9A-9C are graphs showing the lifetime data of the second device fabricated with Pt—R4 with doping concentration of 2 wt % (FIG. 9A), 4 wt % (FIG. 9B), and 8 wt % (FIG. 9C), respectively.

FIGS. 10A-10D are EL spectra (FIG. 10A) and performance characteristics of devices fabricated with Pt—R5 with doping concentration of 2, 6, and 10 wt %, respectively. The performance characteristics of this device include EQE (FIG. 10B), luminance (FIG. 10C), and CE (FIG. 10D). The device structure is: ITO/HAT-CN (10 nm)/BPBPA (40 nm)/EB (5 nm)/Pt—R5:RH (40 nm)/HB (5 nm)/ZADN:Liq (35:65) (35 nm)/Liq (2 nm)/Al (100 nm).

FIG. 11 is a graph showing the lifetime data of the device fabricated with Pt—R5 with doping concentration of 6 wt %.

FIG. 12 shows a non-limiting example of an organic light-emitting diode device, 100, having a multilayer architecture.

FIGS. 13A-13D are EL spectra (FIG. 13A) and performance characteristics of devices fabricated with Pt—R6 with doping concentration of 2, 6, and 10 wt %, respectively. The performance characteristics of this device include EQE (FIG. 13B), luminance (FIG. 13C), and CE (FIG. 13D). The device structure is: ITO/HAT-CN (10 nm)/BPBPA (40 nm)/EB (5 nm)/Pt—R6:RH (40 nm)/HB (5 nm)/ZADN:Liq (35:65) (35 nm)/Liq (2 nm)/Al (100 nm).

FIGS. 14A-14B are graphs showing the lifetime data of the device fabricated with Pt—R6 with doping concentration of 2 wt % (FIG. 14A) and 10 wt % (FIG. 14B).

FIGS. 15A-15D are EL spectra (FIG. 15A) and performance characteristics of devices fabricated with Pt—R8 with doping concentration of 2, 6, and 10 wt %, respectively. The performance characteristics of this device include EQE (FIG. 15B), luminance (FIG. 15C), and CE (FIG. 15D). The device structure is: ITO/HAT-CN (10 nm)/BPBPA (40 nm)/EB (5 nm)/Pt—R8:RH (40 nm)/HB (5 nm)/ZADN:Liq (35:65) (35 nm)/Liq (2 nm)/Al (100 nm).

FIG. 16 is a graph showing the lifetime data of the device fabricated with Pt—R8 with doping concentration of 10 wt %.

FIGS. 17A-17D are EL spectra (FIG. 17A) and performance characteristics of devices fabricated with Pt—R11 with doping concentration of 2, 6, and 10 wt %, respectively. The performance characteristics of this device include EQE (FIG. 17B), luminance (FIG. 17C), and CE (FIG. 17D). The device structure is: ITO/HAT-CN (10 nm)/BPBPA (40 nm)/NPB—BC (5 nm)/Pt—R11:RH (40 nm)/HB (5 nm)/ZADN:Liq (35:65) (35 nm)/Liq (2 nm)/Al (100 nm).

FIGS. 18A-18D are EL spectra (FIG. 18A) and performance characteristics of devices fabricated with Pt—R12 with doping concentration of 2, 6, and 10 wt %, respectively. The performance characteristics of this device include EQE (FIG. 18B), luminance (FIG. 18C), and CE (FIG. 18D). The device structure is: ITO/HAT-CN (10 nm)/BPBPA (40 nm)/NPB—BC (5 nm)/Pt—R12:RH (40 nm)/HB (5 nm)/ZADN:Liq (35:65) (35 nm)/Liq (2 nm)/Al (100 nm).

FIGS. 19A-19D are EL spectra (FIG. 19A) and performance characteristics of devices fabricated with Pt—R8 and MR—R1. The performance characteristics of this device include EQE (FIG. 19B), luminance (FIG. 19C), and CE (FIG. 19D). The device structure is: ITO/HAT-CN (10 nm)/BPBPA (40 nm)/EB (5 nm)/Pt—R8: MR—R1: RH (40 nm)/HB (5 nm)/ZADN:Liq (35:65) (35 nm)/Liq (2 nm)/Al (100 nm).

FIG. 20 is a graph showing the lifetime data of the device fabricated with Pt—R8 and MR—R1.

FIGS. 21A-21C are ECL spectra (FIG. 21A) and performance characteristics of devices fabricated with Pt—R14 with doping concentration of 2, 4, 6, and 8 wt %, respectively. The performance characteristics of this device include EQE (FIG. 21B), luminance (FIG. 21C, right y-axis), and CE (FIG. 21C, left y-axis). The device structure is: ITO/PEDOT:PSS(40 nm)/PVK(10 nm)/Pt—R14:CBP/DPEPO (10 nm)/TPBi (40 nm)/Liq (2 nm)/Al (100 nm).

FIG. 22A is a schematic showing a first view of the X-ray single crystal structure of Pt—R10. FIG. 22B is a schematic showing a second view of the X-ray single crystal structure of Pt—R10.

### DETAILED DESCRIPTION OF THE INVENTION

### I. Definitions

It is to be understood that the disclosed compounds, compositions, and methods are not limited to specific synthetic methods, specific analytical techniques, or to particular reagents unless otherwise specified, and, as such, may vary. It is also to be understood that the terminology used herein is for the purpose of describing particular forms and embodiments only and is not intended to be limiting.

“Substituted,” as used herein, refers to all permissible substituents of the compounds or functional groups described herein. In the broadest sense, the permissible substituents include acyclic and cyclic, branched and unbranched, carbocyclic and heterocyclic, aromatic and nonaromatic substituents of organic compounds. Illustrative substituents include, but are not limited to, halogens, hydroxyl groups, or any other organic groupings containing any number of carbon atoms, preferably 1-14 carbon atoms, and optionally include one or more heteroatoms such as oxygen, sulfur, or nitrogen grouping in linear, branched, or cyclic structural formats. Representative substituents include a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, an amino acid. Such a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, and an amino acid can be further substituted.

Heteroatoms such as nitrogen may have hydrogen substituents and/or any permissible substituents of organic compounds described herein which satisfy the valences of the heteroatoms. It is understood that “substitution” or “substituted” includes the implicit proviso that such substitution is in accordance with permitted valence of the substituted atom and the substituent, and that the substitution results in a stable compound, i.e., a compound that does not spontaneously undergo transformation such as by rearrangement, cyclization, elimination, etc.

“Alkyl,” as used herein, refers to the radical of saturated aliphatic groups, including straight-chain alkyl groups, branched-chain alkyl, and cycloalkyl (alicyclic). In some forms, a straight chain or branched chain alkyl has 30 or fewer carbon atoms in its backbone (e.g., C₁-C₃₀ for straight chains, C₃-C₃₀ for branched chains), 20 or fewer, 15 or fewer, or 10 or fewer. Alkyl includes methyl, ethyl, n-propyl, isopropyl, n-butyl, isobutyl, t-butyl, pentyl, hexyl, heptyl, octyl, decyl, tetradecyl, hexadecyl, eicosyl, tetracosyl and the like. Likewise, a cycloalkyl is a non-aromatic carbon-based ring composed of at least three carbon atoms, such as a nonaromatic monocyclic or nonaromatic polycyclic ring containing 3-30 carbon atoms, 3-20 carbon atoms, or 3-10 carbon atoms in their ring structure, and have 5, 6 or 7 carbons in the ring structure. Cycloalkyls containing a polycyclic ring system can have two or more non-aromatic rings in which two or more carbons are common to two adjoining rings (i.e., “fused cycloalkyl rings”). Examples of cycloalkyl groups include, but are not limited to, cyclopropyl, cyclobutyl, cyclopentyl, cyclohexyl, cycloheptyl, cyclooctanyl, etc.

“Substituted alkyl” refers to alkyl moieties having one or more substituents replacing a hydrogen on one or more carbons of the hydrocarbon backbone. Such substituents can be any substituents described above, e.g., halogen (such as fluorine, chlorine, bromine, or iodine), hydroxyl, carbonyl (such as a carboxyl, alkoxycarbonyl, formyl, or an acyl), thiocarbonyl (such as a thioester, a thioacetate, or a thioformate), aryl, alkoxyl, aralkyl, phosphonium, phosphanyl, phosphonyl, phosphoryl, phosphate, phosphonate, a phosphinate, amino, amido, amidine, imine, cyano, nitro, azido, oxo, sulfhydryl, thiol, alkylthio, silyl, sulfinyl, sulfate, sulfonate, sulfamoyl, sulfonamido, sulfonyl, heterocyclyl, an aromatic or heteroaromatic moiety. —NRR′, wherein R and R′ are independently hydrogen, alkyl, or aryl, and wherein the nitrogen atom is optionally quaternized; —SR, wherein R is a phosphonyl, a sulfinyl, a silyl a hydrogen, an alkyl, or an aryl; —CN; —NO₂; —COOH; carboxylate; —COR, —COOR, or —CON(R)₂, wherein R is hydrogen, alkyl, or aryl; imino, silyl, ether, haloalkyl (such as —CF₃, —CH₂—CF₃, —CCl₃); —CN; —NCOCOCH₂CH₂; —NCOCOCHCH; and —NCS; and combinations thereof.

It will be understood by those skilled in the art that the moieties substituted on the hydrocarbon chain can themselves be substituted, if appropriate. For instance, the substituents of a substituted alkyl may include halogen, hydroxy, nitro, thiols, amino, aralkyl, azido, imino, amido, phosphonium, phosphanyl, phosphoryl (including phosphonate and phosphinate), oxo, sulfonyl (including sulfate, sulfonamido, sulfamoyl and sulfonate), and silyl groups, as well as ethers, alkylthiols, carbonyls (including ketones, aldehydes, carboxylates, and esters), haloalkyls, —CN and the like. Cycloalkyls can be substituted in the same manner.

Unless the number of carbons is otherwise specified, “lower alkyl” as used herein means an alkyl group, as defined above, but having from one to ten carbons, more preferably from one to six carbon atoms in its backbone structure. Likewise, “lower alkenyl” and “lower alkynyl” have similar chain lengths.

“Heteroalkyl,” as used herein, refers to straight or branched chain, or cyclic carbon-containing alkyl radicals, or combinations thereof, containing at least one heteroatom on the carbon backbone. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkyl group” is a cycloalkyl group as defined above where at least one of the carbon atoms of the ring is substituted with a heteroatom such as, but not limited to, nitrogen, oxygen, sulphur, or phosphorus.

The term “alkenyl” as used herein is a hydrocarbon group of from 2 to 24 carbon atoms and structural formula containing at least one carbon-carbon double bond. Alkenyl groups include straight-chain alkenyl groups, branched-chain alkenyl, and cycloalkenyl. A cycloalkenyl is a non-aromatic carbon-based ring composed of at least three carbon atoms and at least one carbon-carbon double bond, such as a nonaromatic monocyclic or nonaromatic polycyclic ring containing 3-30 carbon atoms and at least one carbon-carbon double bond, 3-20 carbon atoms and at least one carbon-carbon double bond, or 3-10 carbon atoms and at least one carbon-carbon double bond in their ring structure, and have 5, 6 or 7 carbons and at least one carbon-carbon double bond in the ring structure. Cycloalkenyls containing a polycyclic ring system can have two or more non-aromatic rings in which two or more carbons are common to two adjoining rings (i.e., “fused cycloalkenyl rings”) and contain at least one carbon-carbon double bond. Asymmetric structures such as (AB)C═C(C′D) are intended to include both the E and Z isomers. This may be presumed in structural formulae herein wherein an asymmetric alkene is present, or it may be explicitly indicated by the bond symbol C. The term “alkenyl” as used throughout the specification, examples, and claims is intended to include both “unsubstituted alkenyls” and “substituted alkenyls,” the latter of which refers to alkenyl moieties having one or more substituents replacing a hydrogen on one or more carbons of the hydrocarbon backbone. The term “alkenyl” also includes “heteroalkenyl.”

The term “substituted alkenyl” refers to alkenyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, oxo, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof.

“Heteroalkenyl,” as used herein, refers to straight or branched chain, or cyclic carbon-containing alkenyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkenyl group” is a cycloalkenyl group where at least one of the carbon atoms of the ring is substituted with a heteroatom such as, but not limited to, nitrogen, oxygen, sulphur, or phosphorus.

The term “alkynyl group” as used herein is a hydrocarbon group of 2 to 24 carbon atoms and a structural formula containing at least one carbon-carbon triple bond. Alkynyl groups include straight-chain alkynyl groups, branched-chain alkynyl, and cycloalkynyl. A cycloalkynyl is a non-aromatic carbon-based ring composed of at least three carbon atoms and at least one carbon-carbon triple bond, such as a nonaromatic monocyclic or nonaromatic polycyclic ring containing 3-30 carbon atoms and at least one carbon-carbon triple bond, 3-20 carbon atoms and at least one carbon-carbon triple bond, or 3-10 carbon atoms and at least one carbon-carbon triple bond in their ring structure, and have 5, 6 or 7 carbons and at least one carbon-carbon triple bond in the ring structure. Cycloalkynyls containing a polycyclic ring system can have two or more non-aromatic rings in which two or more carbons are common to two adjoining rings (i.e., “fused cycloalkynyl rings”) and contain at least one carbon-carbon triple bond. Asymmetric structures such as (AB)C≡C(C″D) are intended to include both the E and Z isomers. This may be presumed in structural formulae herein wherein an asymmetric alkyne is present, or it may be explicitly indicated by the bond symbol C. The term “alkynyl” as used throughout the specification, examples, and claims is intended to include both “unsubstituted alkynyls” and “substituted alkynyls,” the latter of which refers to alkynyl moieties having one or more substituents replacing a hydrogen on one or more carbons of the hydrocarbon backbone. The term “alkynyl” also includes “heteroalkynyl.”

The term “substituted alkynyl” refers to alkynyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof.

“Heteroalkynyl,” as used herein, refers to straight or branched chain, or cyclic carbon-containing alkynyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkynyl group” is a cycloalkynyl group where at least one of the carbon atoms of the ring is substituted with a heteroatom such as, but not limited to, nitrogen, oxygen, sulphur, or phosphorus.

“Aryl,” as used herein, refers to C₄-C₂₆-membered aromatic rings or fused ring systems containing one aromatic ring and optionally one or more non-aromatic rings. Examples of aryl groups are benzene, tetralin, indane, etc.

The term “substituted aryl” refers to an aryl group, wherein one or more hydrogen atoms on one or more aromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), aryl, heteroaryl, and combinations thereof.

“Heterocyclo” and “heterocyclyl” are used interchangeably, and refer to a cyclic radical attached via a ring carbon or nitrogen atom of a monocyclic ring or polycyclic ring system containing 3-30 ring atoms, 3-20 ring atoms, 3-10 ring atoms, or 5-6 ring atoms, where the polycyclic ring system contains one or more non-aromatic rings and optionally one or more aromatic rings, where at least one non-aromatic ring contains carbon and one to four heteroatoms each selected from the group consisting of non-peroxide oxygen, sulfur, and N(Y) wherein Y is absent or is H, O, C₁-C₁₀ alkyl, phenyl or benzyl, and optionally containing 1-3 double bonds and optionally substituted with one or more substituents. Heterocyclyl are distinguished from heteroaryl by definition. Heterocycles can be a heterocycloalkyl, a heterocycloalkenyl, a heterocycloalkynyl, etc, such as piperazinyl, piperidinyl, piperidonyl, 4-piperidonyl, dihydrofuro[2,3-b]tetrahydrofuran, morpholinyl, piperazinyl, piperidinyl, piperidonyl, 4-piperidonyl, piperonyl, pyranyl, 2H-pyrrolyl, 4H-quinolizinyl, quinuclidinyl, tetrahydrofuranyl, 6H-1,2,5-thiadiazinyl. Heterocyclic groups can optionally be substituted with one or more substituents as defined above for alkyl and aryl.

The term “heteroaryl” refers to C₃-C₂₆-membered aromatic rings or fused ring systems containing one aromatic ring and one or more non-aromatic rings, in which one or more carbon atoms on the aromatic ring structure have been substituted with a heteroatom. Suitable heteroatoms include, but are not limited to, oxygen, sulfur, and nitrogen. Examples of heteroaryl groups pyrrole, furan, thiophene, imidazole, oxazole, thiazole, triazole, tetrazole, pyrazole, pyridine, pyrazine, pyridazine and pyrimidine, and the like. Examples of heteroaryl rings include, but are not limited to, benzimidazolyl, benzofuranyl, benzothiofuranyl, benzothiophenyl, benzoxazolyl, benzoxazolinyl, benzthiazolyl, benztriazolyl, benztetrazolyl, benzisoxazolyl, benzisothiazolyl, benzimidazolinyl, carbazolyl, 4aH-carbazolyl, carbolinyl, chromanyl, chromenyl, cinnolinyl, decahydroquinolinyl, 2H,6H-1,5,2-dithiazinyl, furanyl, furazanyl, imidazolidinyl, imidazolinyl, imidazolyl, 1H-indazolyl, indolenyl, indolinyl, indolizinyl, indolyl, 3H-indolyl, isatinoyl, isobenzofuranyl, isochromanyl, isoindazolyl, isoindolinyl, isoindolyl, isoquinolinyl, isothiazolyl, isoxazolyl, methylenedioxyphenyl, naphthyridinyl, octahydroisoquinolinyl, 1,2,3-oxadiazolyl, 1,2,4-oxadiazolyl, 1,2,5-oxadiazolyl, 1,3,4-oxadiazolyl, oxazolidinyl, oxazolyl, oxindolyl, pyrimidinyl, phenanthridinyl, phenanthrolinyl, phenazinyl, phenothiazinyl, phenoxathinyl, phenoxazinyl, phthalazinyl, pteridinyl, purinyl, pyrazinyl, pyrazolidinyl, pyrazolinyl, pyrazolyl, pyridazinyl, pyridooxazole, pyridoimidazole, pyridothiazole, pyridinyl, pyridyl, pyrimidinyl, pyrrolidinyl, pyrrolinyl, pyrrolyl, quinazolinyl, quinolinyl, quinoxalinyl, tetrahydroisoquinolinyl, tetrahydroquinolinyl, tetrazolyl, 1,2,3-thiadiazolyl, 1,2,4-thiadiazolyl, 1,2,5-thiadiazolyl, 1,3,4-thiadiazolyl, thianthrenyl, thiazolyl, thienyl, thienothiazolyl, thienooxazolyl, thienoimidazolyl, thiophenyl and xanthenyl. One or more of the rings can be substituted as defined below for “substituted heteroaryl.”

The term “substituted heteroaryl” refers to a heteroaryl group in which one or more hydrogen atoms on one or more heteroaromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), aryl, heteroaryl, and combinations thereof.

The term “polyaryl” refers to a fused ring system that includes two or more aromatic rings and optionally one or more non-aromatic rings. Examples of polyaryl groups are naphthalene, anthracene, phenanthrene, chrysene, pyrene, corannulene, coronene, etc. When a fused ring system containing two or more aromatic rings and optionally one or more non-aromatic rings, in which one or more carbon atoms on one or more aromatic ring structures have been substituted with a heteroatom, the fused ring system can be referred to as a “heteropolyaryl” or “polyheteroaryl”. The terms “heteropolyaryl” and “polyheteroaryl” are used interchangeably herein.

The term “substituted polyaryl” refers to a polyaryl in which one or more of the aryls are substituted, with one or more substituents including, but not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfoxide, sulfonamido, sulfonyl, heterocyclyl, alkylaryl, haloalkyl, aryl, heteroaryl, and combinations thereof. When a polyheteroaryl is involved, the chemical moiety can be referred to as a “substituted polyheteroaryl.”

The term “cyclic ring” or “cyclic group” refers to a substituted or unsubstituted monocyclic ring or a substituted or unsubstituted polycyclic ring (such as those formed from single or fused ring systems), such as a substituted or unsubstituted cycloalkyl, a substituted or unsubstituted cycloalkenyl, a substituted or unsubstituted cycloalkynyl, or a substituted or unsubstituted heterocyclyl, that have from three to 30 carbon atoms, as geometric constraints permit. The substituted cycloalkyls, cycloalkenyls, cycloalkynyls, and heterocyclyls are substituted as defined above for the alkyls, alkenyls, alkynyls, and heterocyclyls, respectively.

The term “aralkyl” as used herein is an aryl group or a heteroaryl group having an alkyl, alkynyl, or alkenyl group as defined above attached to the aromatic group, such as an aryl, a heteroaryl, a polyaryl, or a polyheteroaryl. An example of an aralkyl group is a benzyl group.

The terms “alkoxyl” or “alkoxy,” “aroxy” or “aryloxy,” generally describe compounds represented by the formula —OR^{v}, wherein R^{v} includes, but is not limited to, a substituted or unsubstituted alkyl, a substituted or unsubstituted alkenyl, a substituted or unsubstituted alkynyl, a substituted or unsubstituted cycloalkyl, a substituted or unsubstituted heterocyclyl, a substituted or unsubstituted cycloalkenyl, a substituted or unsubstituted heterocycloalkenyl, a substituted or unsubstituted aryl, a substituted or unsubstituted heteroaryl, a substituted or unsubstituted polyaryl, a substituted or unsubstituted polyheteroaryl, a substituted or unsubstituted arylalkyl, a substituted or unsubstituted heteroalkyl, a substituted or unsubstituted alkylaryl, a substituted or unsubstituted alkylheteroaryl, a substituted or unsubstituted aralkyl, a substituted or unsubstituted carbonyl, a phosphonium, a phosphanyl, a phosphonyl, a sulfinyl, a silyl, a thiol, an amido, and an amino. Exemplary alkoxyl groups include methoxy, ethoxy, propyloxy, tert-butoxy and the like. A “lower alkoxy” group is an alkoxy group containing from one to six carbon atoms. An “ether” is two functional groups covalently linked by an oxygen as defined below. Accordingly, the substituent of an alkyl that renders that alkyl an ether is or resembles an alkoxyl, such as can be represented by one of —O-alkyl, —O-alkenyl, —O-alkynyl, —O— aralkyl, —O-aryl, —O-heteroaryl, —O-polyaryl, —O-polyheteroaryl, —O-heterocyclyl, etc.

The term “substituted alkoxy” refers to an alkoxy group having one or more substituents replacing one or more hydrogen atoms on one or more carbons of the alkoxy backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, oxo, sulfate, sulfonate, sulfamoyl, sulfonamido, sulfonyl, heterocyclyl, alkylaryl, haloalkyl, aryl, heteroaryl, and combinations thereof.

The term “ether” as used herein is represented by the formula A²OA¹, where A² and A¹ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a phosphonyl, a sulfinyl, a silyl, a thiol, a substituted or unsubstituted carbonyl, an alkoxy, an amido, or an amino, described above.

The term “polyether” as used herein is represented by the formula:

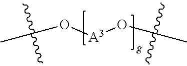

where A³ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a substituted or unsubstituted carbonyl, an alkoxy, an amido, or an amino, described above; g can be a positive integer from 1 to 30.

The term “phenoxy” is art recognized and refers to a compound of the formula —OR^{v} wherein R^{v} is C₆H₅ (i.e., —O—C₆H₅). One of skill in the art recognizes that a phenoxy is a species of the aroxy genus.

The term “substituted phenoxy” refers to a phenoxy group, as defined above, having one or more substituents replacing one or more hydrogen atoms on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, and combinations thereof.

The terms “aroxy” and “aryloxy,” as used interchangeably herein, are represented by —O-aryl or —O-heteroaryl, wherein aryl and heteroaryl are as defined herein.

The terms “substituted aroxy” and “substituted aryloxy,” as used interchangeably herein, represent —O-aryl or —O-heteroaryl, having one or more substituents replacing one or more hydrogen atoms on one or more ring atoms of the aryl and heteroaryl, as defined herein. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof.

The term “amino” as used herein includes the group

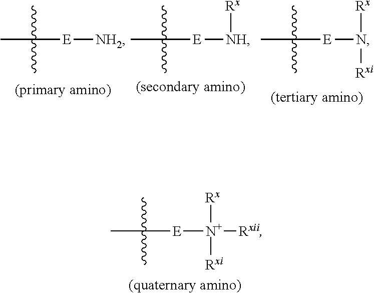

wherein, E is absent, or E is substituted or unsubstituted alkyl, substituted or unsubstituted alkenyl, substituted or unsubstituted alkynyl, substituted or unsubstituted aralkyl, substituted or unsubstituted aryl, substituted or unsubstituted heteroaryl, a substituted or unsubstituted polyaryl, a substituted or unsubstituted polyheteroaryl, substituted or unsubstituted heterocyclyl, wherein independently of E, R^{x}, R^{xi}, and R^{xii} each independently represent a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. The term “quaternary amino” also includes the groups where the nitrogen, R^{x}, R^{xi}, and R^{xii} with the N⁺ to which they are attached complete a heterocyclyl or heteroaryl having from 3 to 14 atoms in the ring structure. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The terms “amide” or “amido” are used interchangeably, refer to both “unsubstituted amido” and “substituted amido” and are represented by the general formula:

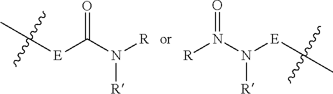

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted aryl, substituted or unsubstituted heteroaryl, a substituted or unsubstituted polyaryl, a substituted or unsubstituted polyheteroaryl, or a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. In some forms, when E is oxygen, a carbamate is formed. It is understood by those of ordinary skill in the art, that the E groups listed above are divalent (e.g., methylene, ethane-1,2-diyl, ethene-1,2-diyl, 1,4-phenylene, cyclohexane-1,2-diyl).

“Carbonyl,” as used herein, is art-recognized and includes such moieties as can be represented by the general formula:

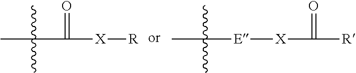

wherein X is a bond, or represents an oxygen or a sulfur, and R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″, or a pharmaceutical acceptable salt; E″ is absent, or E″ is a substituted or unsubstituted alkyl, a substituted or unsubstituted alkenyl, a substituted or unsubstituted alkynyl, a substituted or unsubstituted aralkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl; R′ represents a hydrogen, a substituted or unsubstituted alkyl, a substituted or unsubstituted alkenyl, a substituted or unsubstituted alkynyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″; R″ represents a hydroxyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, and combinations thereof. It is understood by those of ordinary skill in the art, that the E″ groups listed above are divalent (e.g., methylene, ethane-1,2-diyl, ethene-1,2-diyl, 1,4-phenylene, cyclohexane-1,2-diyl). Where X is oxygen and R is defined as above, the moiety is also referred to as a carboxyl group. When X is oxygen and R is hydrogen, the formula represents a “carboxylic acid.” Where X is oxygen and R′ is hydrogen, the formula represents a “formate.” Where X is oxygen and R or R′ is not hydrogen, the formula represents an “ester.” In general, where the oxygen atom of the above formula is replaced by a sulfur atom, the formula represents a “thiocarbonyl” group. Where X is sulfur and R or R′ is not hydrogen, the formula represents a “thioester.” Where X is sulfur and R is hydrogen, the formula represents a “thiocarboxylic acid.” Where X is sulfur and R′ is hydrogen, the formula represents a “thioformate.” Where X is a bond and R is not hydrogen, the above formula represents a “ketone.” Where X is a bond and R is hydrogen, the above formula represents an “aldehyde.”

The term “phosphanyl” is represented by the formula

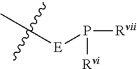

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi} and R^{vii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonium” is represented by the formula

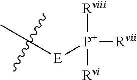

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi}, R^{vii}, and R^{viii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi}, R^{vii}, and R^{viii} taken together with the P⁺ atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonyl” is represented by the formula

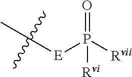

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, oxygen, alkoxy, aroxy, or substituted alkoxy or substituted aroxy, wherein, independently of E, R^{vi} and R^{vii} are independently a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphoryl” defines a phosphonyl in which E is absent, oxygen, alkoxy, aroxy, substituted alkoxy or substituted aroxy, as defined above, and independently of E, R^{vi} and R^{vii} are independently hydroxyl, alkoxy, aroxy, substituted alkoxy or substituted aroxy, as defined above. When E is oxygen, the phosphoryl cannot be attached to another chemical species, such as to form an oxygen-oxygen bond, or other unstable bonds, as understood by one of ordinary skill in the art. When E, R^{vi} and R^{vii} are substituted, the substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfinyl” is represented by the formula

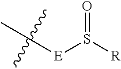

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a silyl, a thiol, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonyl” is represented by the formula

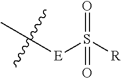

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonic acid” refers to a sulfonyl, as defined above, wherein R is hydroxyl, and E is absent, or E is substituted or unsubstituted cycloalkyl, substituted or unsubstituted heterocyclyl, substituted or unsubstituted alkylaryl, substituted or unsubstituted arylalkyl, substituted or unsubstituted aryl, a substituted or unsubstituted polyaryl, a substituted or unsubstituted polyheteroaryl, or substituted or unsubstituted heteroaryl. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfate” refers to a sulfonyl, as defined above, wherein E is absent, oxygen, alkoxy, aroxy, substituted alkoxy or substituted aroxy, as defined above, and R is independently hydroxyl, alkoxy, aroxy, substituted alkoxy or substituted aroxy, as defined above. When E is oxygen, the sulfate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonate” refers to a sulfonyl, as defined above, wherein E is oxygen, alkoxy, aroxy, substituted alkoxy or substituted aroxy, as defined above, and R is independently hydrogen, substituted or unsubstituted alkyl, substituted or unsubstituted alkenyl, substituted or unsubstituted alkynyl, substituted or unsubstituted amino, substituted or unsubstituted cycloalkyl, substituted or unsubstituted heterocyclyl, substituted or unsubstituted aralkyl, substituted or unsubstituted alkylaryl, substituted or unsubstituted arylalkyl, substituted or unsubstituted aryl, substituted or unsubstituted heteroaryl, a substituted or unsubstituted polyaryl, a substituted or unsubstituted polyheteroaryl, —(CH₂)ₘ—R′″, R′″ represents a hydroxy group, substituted or unsubstituted carbonyl group, an aryl, a cycloalkyl ring, a cycloalkenyl ring, a heterocycle, an amido, an amino, or a polycycle; and m is zero or an integer ranging from 1 to 8. When E is oxygen, sulfonate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfamoyl” refers to a sulfonamide or sulfonamide represented by the formula

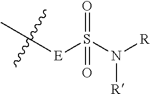

wherein E is absent, or E is substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted cycloalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “silyl group” as used herein is represented by the formula —SiRR′R″ where R, R′, and R″ can be, independently, a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, a phosphonyl, a sulfinyl, a thiol, an amido, an amino, an alkoxy, or an oxo, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof.

The terms “thiol” are used interchangeably and are represented by —SR, where R can be a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, an amido, an amino, an alkoxy, an oxo, a phosphonyl, a sulfinyl, or a silyl, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, aryl, heteroaryl, polyaryl, polyheteroaryl, and combinations thereof.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted, independently, with the substituents described above in the definition of “substituted.”

The numerical ranges disclose individually each possible number that such a range could reasonably encompass, as well as any sub-ranges and combinations of sub-ranges encompassed therein. For example, in a given range carbon range of C₃-C₉, the range also discloses C₃, C₄, C₅, C₆, C₇, C₈, and C₉, as well as any subrange between these numbers (for example, C₄-C₆), and any possible combination of ranges possible between these values. In yet another example, a given temperature range may be from about 25° C. to 30° C., where the range also discloses temperatures that can be selected independently from about 25, 26, 27, 28, 29, and 30° C., as well as any range between these numbers (for example, 26 to 28° C.), and any possible combination of ranges between these values.

Use of the term “about” is intended to describe values either above or below the stated value, which the term “about” modifies, to be within a range of approximately +/−10%. When the term “about” is used before a range of numbers (i.e., about 1-5) or before a series of numbers (i.e., about 1, 2, 3, 4, etc.) it is intended to modify both ends of the range of numbers and/or each of the numbers recited in the entire series, unless specified otherwise.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted with, independently, with the substituents described above in the definition of “substituted.”

### II. Compositions

Described are a class of dinuclear cyclometalated platinum(II) carbene complexes containing 2-oxy-pyridine (N\hat{ }O) bridging ligands as red or NIR emitters (also referred herein as “dinuclear platinum(II) emitters”). Without being bound to theories, it is believed that the molecular system of the N\hat{ }O bridging ligands of the disclosed compounds allows strong metal-metal interactions between two platinum(II) metal centers in a paddle-wheel structure, which gives rise to low-energy MMLCT excited states. Additionally, it is believed that the imidazolyl N-heterocyclic carbene ring contributes to the high emission quantum yield of the disclosed binuclear platinum(II) emitters. It is believed that the combination of the 2-oxy-pyridine (N\hat{ }O) bridging ligands and imidazolyl N-heterocyclic carbene ring allows for stable red/NIR emitters with high emission quantum yield. The disclosed dinuclear platinum(II) emitters show red to deep-red or NIR photoluminescence (λₘₐₓ at 600-1000 nm, such as 612-685 nm) with a high emission quantum yield (i.e. (Φₑₘ≥0.60 measured in thin films, such as about 0.78 or about 0.97), a short emission lifetime (i.e. τₑₘ≤2.5 μs, such as 1.7-1.9 μs), a fast radiative decay rate (i.e. kᵣ≥4.5×10⁵ s⁻¹, such as about 4.3×10⁵ s⁻¹ or about 5.5×10⁵ s⁻¹), and/or a slow non-radiative decay rate (i.e. kₙᵣ≤6×10⁵ s⁻¹, such as 0.16×10⁵-6×10⁵ s⁻¹ or 0.16×10⁵-1.4×10⁵ s⁻¹), at room temperature.

Organic light-emitting components, such as light-emitting diodes (OLEDs), containing the dinuclear platinum(II) emitters disclosed herein are also described. The Examples below demonstrated that doped OLEDs containing exemplary dinuclear platinum(II) emitters disclosed herein show electroluminescence spanning from red to NIR spectral region (λₘₐₓ at 622-706 nm) with an external quantum efficiencies (EQE) of 9.1-15.8%, at 1000 cd m⁻².

A. Dinuclear Platinum(II) Complexes

The disclosed dinuclear platinum(II) complexes can have the structure of Formula I′:

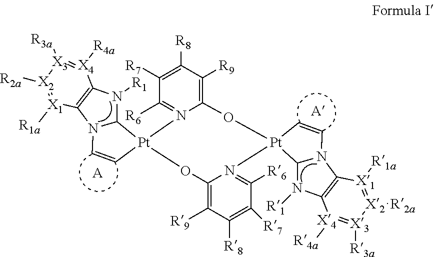

where: (i) the complex can have an overall neutral, negative, or positive charge; (ii) X₁-X₄ and X′₁-X′₄ can be independently carbon, nitrogen, sulfur, or oxygen; (iii) R₁ₐ-R₄ₐ, R′₁ₐ-R′₄ₐ, R₁, R′₁, R₆-R₉, and R′₆-R′₉ can be independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, unsubstituted C₂-C₂₀ heterocyclyl, borenium cation, phosphonyl, sulfinyl, or sulfonyl, or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, fused combinations thereof, or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; (iv) A and A′ can be independently a substituted cycloalkyl, an unsubstituted cycloalkyl, a substituted cycloalkenyl, an unsubstituted cycloalkenyl, a substituted cycloalkynyl, an unsubstituted cycloalkynyl, a substituted heterocyclyl, an unsubstituted heterocyclyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, or fused combinations thereof, preferably A and A′ are independently a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; and (v) each substituent can be independently a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a carbonyl, an alkoxy, a halogen, a hydroxyl, a phenoxy, a thiol, an alkylthio, a phenylthio, an arylthio, a cyano, an isocyano, a nitro, a carboxyl, an amino, an amido, an oxo, a silyl, a sulfinyl, a sulfonyl, a sulfonic acid, a phosphonium, a phosphanyl, a phosphoryl, or a phosphonyl.

In some forms, the disclosed binuclear platinum (II) complexes can have the structure of Formula I:

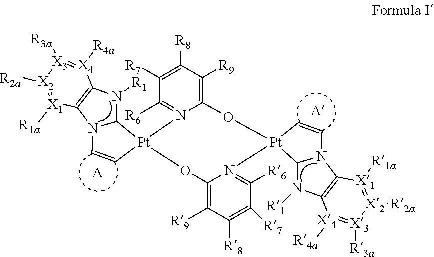

where: (i) the complex can have an overall neutral, negative, or positive charge; (ii) X₁-X₄, X′₁-X′₄, R₁ₐ-R₄ₐ, R′₁ₐ-R′₄ₐ, R₁, R′₁, R₆-R₉, and R′₆-R′₉ can be as defined above for Formula I′; (iii) Q₁-Q₄ and Q′₁-Q′₄ can be independently carbon, nitrogen, sulfur, or oxygen; (iv) R₂-R₅ and R′₂-R′₅ can be independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, unsubstituted C₂-C₂₀ heterocyclyl, borenium cation, phosphonyl, sulfinyl, or sulfonyl, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, fused combinations thereof, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; and (v) each substituent can be as defined above for Formula I′.

In some forms, the disclosed binuclear platinum (II) complexes can have the structure of Formula Ia:

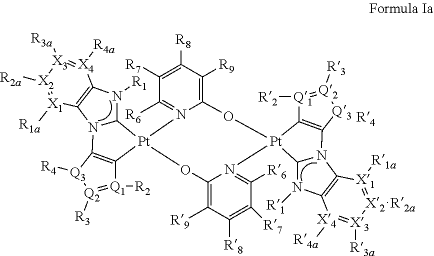

where: the complex can have an overall neutral, negative, or positive charge; and X₁-X₄, X′₁-X′₄, Q₁-Q₃, Q′₁-Q′₃, R₁ₐ-R₄ₐ, R′₁ₐ-R′₄ₐ, R₁-R₄, R₆-R₉, R′₁-R′₄, and R′₆-R′₉ can be as defined above for Formula I. In some forms of Formula Ta, Q₁-Q₃ and Q′₁-Q′₃ can be independently carbon, oxygen, or sulfur.

In some forms, the disclosed dinuclear platinum(II) complexes can have the structure of Formula II:

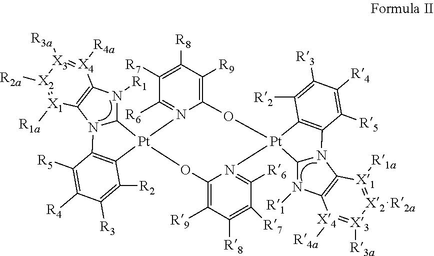

where the complex can have an overall neutral, negative, or positive charge; and X₁-X₄, X′₁-X′₄, R₁ₐ-R₄ₐ, R′₁ₐ-R′₄ₐ, R₁-R₉, R′₁-R′₉, and the substituents can be as defined above for Formula I.

In some forms, the disclosed binuclear platinum (II) complexes can have the structure of Formula IIa:

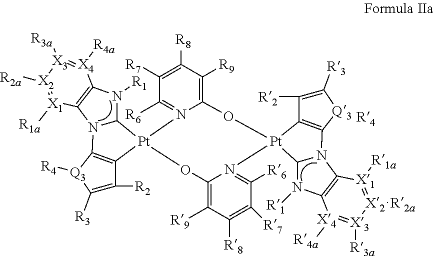

where: the complex can have an overall neutral, negative, or positive charge; and X₁-X₄, X′₁-X′₄, Q₃, Q′₃, R₁ₐ-R₄ₐ, R′₁ₐ-R′₄ₐ, R₁-R₄, R₆-R₉, R′₁-R′₄, and R′₆-R′₉ can be as defined above for Formula I.

In some forms, the disclosed dinuclear platinum(II) complexes can have the structure of Formula III:

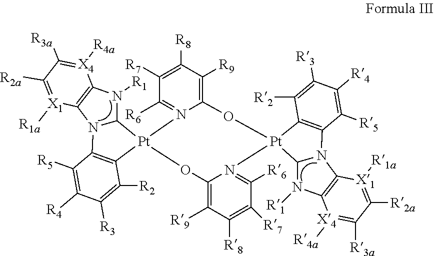

where the complex can have an overall neutral, negative, or positive charge; and X₁, X₄, X′₁, X′₄ R₁ₐ-R₄ₐ, R′₁ₐ-R′₄ₐ, R₁-R₉, R′₁-R′₉, and the substituents can be as defined above for Formula I.

In some forms, the disclosed dinuclear platinum(II) complexes can have the structure of Formula IIIa:

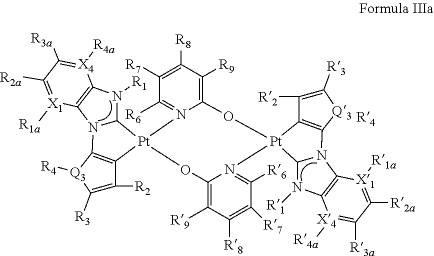

where: the complex can have an overall neutral, negative, or positive charge; and X₁-X₄, X′₁-X′₄, Q₃, Q′₃, R₁ₐ-R₄ₐ, R′₁ₐ-R′₄ₐ, R₁-R₄, R₆-R₉, R′₁-R′₄, and R′₆-R′₉ can be as defined above for Formula I.

In some forms of Formulae III and/or IIIa, X₁, X₄, X′₁, and X′₄ can be carbon. In some forms of Formula III and/or IIIa, X₁, X₄, X′₁, and X′₄ can be carbon; and R₁ₐ-R₄ₐ and R′₁ₐ-R′₄ₐ can be as defined above for Formula I, such as independently hydrogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), or alkoxy (e.g., —O-alkyl, —O-aryl, —O-polyaryl, etc.), or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, and/or R′₃ₐ and R′₄ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl. For example, X₁, X₄, X′₁, and X′₄ are carbon; and R₁ₐ-R₄ₐ and R′₁ₐ-R′₄ₐ are as defined above for Formula I, such as independently hydrogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), or alkoxy (e.g., —O-alkyl, —O-aryl, —O-polyaryl, etc.), or R₁ₐ and R₂ₐ together, R₃ₐ and R₄ₐ together, R′₁ₐ and R′₂ₐ together, and/or R′₃ₐ and R′₄ₐ together, with the atom to which they are attached, form a substituted aryl or unsubstituted aryl.

In some forms of Formulae III and/or IIIa, X₁, X₄, X′₁, and X′₄ are nitrogen; and R₂ₐ and R₃ₐ together and/or R′₂ₐ and R′₃ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl.

In some forms, the disclosed dinuclear platinum(II) complexes can have the structure of Formula IV:

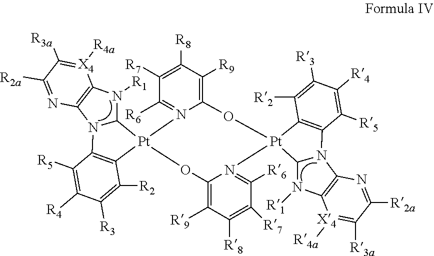

where the complex can have an overall neutral, negative, or positive charge; and X₄, X′₄ R₂ₐ-R₄ₐ, R′₂ₐ-R′₄ₐ, R₁-R₉, R′₁-R′₉, and the substituents can be as defined above for Formula I.

In some forms, the disclosed dinuclear platinum(II) complexes can have the structure of Formula IVa:

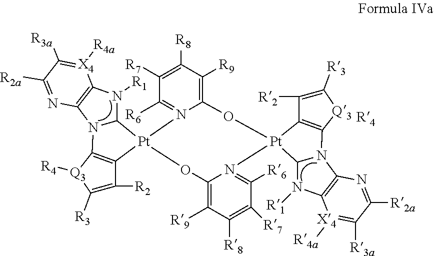

where: the complex can have an overall neutral, negative, or positive charge; and X₄, X′₄, Q₃, Q′₃, R₂ₐ-R₄ₐ, R′₂ₐ-R′₄ₐ, R₁-R₄, R₆-R₉, R′₁-R′₄, and R′₆-R′₉ can be as defined above for Formula I.

In some forms of Formulae IV and/or IVa, R₂ₐ and R₃ₐ together, R₃ₐ and R₄ₐ together, R′₂ₐ and R′₃ₐ together, and/or R′₃ₐ and R′₄ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl.

In some forms of Formula IV, X₄ and/or X′₄ is nitrogen and R₄ₐ and/or R′₄ₐ is absent. In some forms of Formula IVa, X₄ and/or X′₄ is nitrogen and R₄ₐ and/or R′₄ₐ is absent. In some forms of Formulae IV and/or IVa, X₄ and X′₄ are nitrogen and R₄ₐ and R′₄ₐ are absent, and R₂ₐ, R₃ₐ, R′₂ₐ, and R′₃ₐ can be hydrogen or R₂ₐ and R₃ₐ together and/or R′₂ₐ and R′₃ₐ together, with the atom to which they are attached, form a substituted aryl or unsubstituted aryl.

In some forms of Formulae IV and/or IVa, X₄ and/or X′₄ is carbon, and R₂ₐ-R₄ₐ and/or R′₂ₐ-R′₄ₐ is as defined above for Formula I, such as independently hydrogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), or alkoxy (e.g., —O-alkyl, —O-aryl, —O-polyaryl, etc.), or R₂ₐ and R₃ₐ together, R₃ₐ and R₄ₐ together, R′₂ₐ and R′₃ₐ together, and/or R′₃ₐ and R′₄ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl.

In some forms, for any one of Formulae I-IV, R₄ and R₅ together and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, or an unsubstituted heterocyclyl, such as a substituted aryl, an unsubstituted aryl, a substituted heteroaryl, or an unsubstituted heteroaryl.

In some forms, for any one of Formulae I-IV, R₃ and R₄ together and/or R′₃ and R′₄ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, or an unsubstituted heterocyclyl, such as a substituted aryl, an unsubstituted aryl, a substituted heteroaryl, or an unsubstituted heteroaryl.

In some forms, for any one of Formulae I-IV, R₂ and R₃ together and/or R′₂ and R′₃ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, or an unsubstituted heterocyclyl, such as a substituted aryl, an unsubstituted aryl, a substituted heteroaryl, or an unsubstituted heteroaryl.

In some forms, for any one of Formulae I-IV, R₄ and R₅ together and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, or an unsubstituted heteroaryl. In some forms, for any one of Formulae I-IV, R₄ and R₅ together and/or R′₄ and R′₅ together is(are)

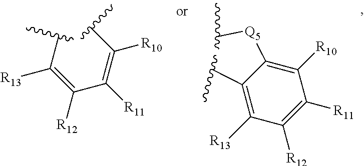

wherein Q₅ can be NR₁₄, CR₁₆R₁₇, sulfur, or oxygen; and R₁₀-R₁₄, R₁₆ and R₁₇ can be independently absent, hydrogen, substituted alkyl, unsubstituted alkyl (e.g., methyl, ethyl, n-propyl, iso-propyl, n-butyl, iso-butyl, tert-butyl, etc.), substituted alkenyl, unsubstituted alkenyl, substituted alkynyl, unsubstituted alkynyl, substituted aryl (e.g., substituted phenyl), unsubstituted aryl (e.g., unsubstituted phenyl), halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be NR₁₄, sulfur, or oxygen; and R₁₀-R₁₄ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl. In some forms, Q₅ can be CR₁₆R₁₇; and R₁₆ and R₁₇ can be independently hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen or unsubstituted alkyl (e.g., methyl, ethyl, n-propyl, iso-propyl, n-butyl, iso-butyl, tert-butyl, etc.). In some forms, Q₅ can be oxygen; and R₁₀-R₁₄ can be hydrogen. In some forms, Q₅ can be sulfur; and R₁₀-R₁₄ can be hydrogen.

In some forms, for any one of Formulae I-IV, R₃ and R₄ together and/or R′₃ and R′₄ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, or an unsubstituted heteroaryl. In some forms, for any one of Formulae I-IV, R₃ and R₄ together and/or R′₃ and R′₄ together is(are)

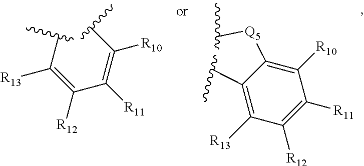

wherein Q₅ can be NR₁₄, CR₁₆R₁₇, sulfur, or oxygen; R₁₀-R₁₄, R₁₆ and R₁₇ can be independently absent, hydrogen, substituted alkyl, unsubstituted alkyl (e.g., methyl, ethyl, n-propyl, iso-propyl, n-butyl, iso-butyl, tert-butyl, etc.), substituted alkenyl, unsubstituted alkenyl, substituted alkynyl, unsubstituted alkynyl, substituted aryl (e.g., substituted phenyl), unsubstituted aryl (e.g., unsubstituted phenyl), halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be NR₁₄, sulfur or oxygen; and R₁₀-R₁₄ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl. In some forms, Q₅ can be CR₁₆R₁₇; and R₁₆ and R₁₇ can be independently hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen or unsubstituted alkyl (e.g., methyl, ethyl, n-propyl, iso-propyl, n-butyl, iso-butyl, tert-butyl, etc.). In some forms, Q₅ can be oxygen; and R₁₀-R₁₄ can be hydrogen. In some forms, Q₅ can be sulfur; and R₁₀-R₁₄ can be hydrogen.

In some forms, for any one of Formulae I-IV, R₂ and R₃ together and/or R′₂ and R′₃ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, or an unsubstituted heteroaryl. In some forms, for any one of Formulae I-IV, R₂ and R₃ together and/or R′₂ and R′₃ together is(are)

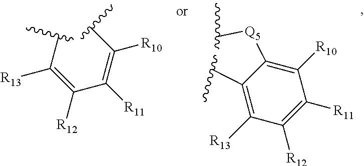

wherein Q₅ can be NR₁₄, CR₁₆R₁₇, sulfur, or oxygen; R₁₀-R₁₄, R₁₆ and R₁₇ can be independently absent, hydrogen, substituted alkyl, unsubstituted alkyl (e.g., methyl, ethyl, n-propyl, iso-propyl, n-butyl, iso-butyl, tert-butyl, etc.), substituted alkenyl, unsubstituted alkenyl, substituted alkynyl, unsubstituted alkynyl, substituted aryl (e.g., substituted phenyl), unsubstituted aryl (e.g., unsubstituted phenyl), halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be NR₁₄, sulfur, or oxygen; and R₁₀-R₁₄ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl. In some forms, Q₅ can be CR₁₆R₁₇; and R₁₆ and R₁₇ can be independently hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen or unsubstituted alkyl (e.g., methyl, ethyl, n-propyl, iso-propyl, n-butyl, iso-butyl, tert-butyl, etc.). In some forms, Q₅ can be oxygen; and R₁₀-R₁₄ can be hydrogen. In some forms, Q₅ can be sulfur; and R₁₀-R₁₄ can be hydrogen.

In some forms, for any one of Formulae I-IV, at least one of R₂-R₅ and at least one of R′₂-R′₅, such as one or two of R₂-R₅ and/or one or two of R′₂-R′₅, can be independently halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), or phosphonyl (e.g., —P(═O)(Ph)₂, —P(═O)(alkyl)₂, etc.).

In some forms, for any one of Formulae Ia-IVa, at least one of R₂-R₄ and at least one of R′₂-R′₄, such as one of R₂-R₄ and/or one of R′₂-R′₄, can be independently halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), phosphonyl (e.g., —P(═O)(Ph)₂, —P(═O)(alkyl)₂, etc.), and the heteroaryl described above.

In some forms, for any one of Formulae Ia-IVa, R₂ and R₃ together and/or R′₂ and R′₃ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, or an unsubstituted heterocyclyl, such as a substituted aryl, an unsubstituted aryl, a substituted heteroaryl, or an unsubstituted heteroaryl.

In some forms, for any one of Formulae Ia-IVa, R₃ and R₄ together and/or R′₃ and R′₄ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, or an unsubstituted heterocyclyl, such as a substituted aryl, an unsubstituted aryl, a substituted heteroaryl, or an unsubstituted heteroaryl.

In some forms, for any one of Formulae Ia-IVa, R₂ and R₃ together and/or R′₂ and R′₃ together, with the atom to which they are attached, form a substituted cycloalkyl, an unsubstituted cycloalkyl, a substituted cycloalkenyl, an unsubstituted cycloalkenyl, a substituted aryl, an unsubstituted aryl, a substituted heteroaryl, an unsubstituted heteroaryl, a substituted heterocyclyl, or an unsubstituted heterocyclyl. In some forms, for any one of Formulae Ia-IVa, R₂ and R₃ together and/or R′₂ and R′₃ together is(are)

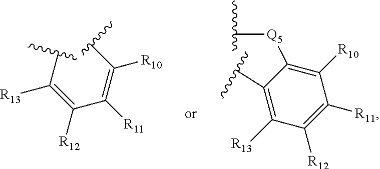

wherein Q₅ can be NR₁₄, CR₁₆R₁₇, or sulfur, or oxygen; R₁₀-R₁₄, R₁₆, and R₁₇ can be independently absent, hydrogen, substituted alkyl, unsubstituted alkyl (e.g., methyl, ethyl, n-propyl, iso-propyl, n-butyl, iso-butyl, tert-butyl, etc.), substituted alkenyl, unsubstituted alkenyl, substituted alkynyl, unsubstituted alkynyl, substituted aryl (e.g., substituted phenyl), unsubstituted aryl (e.g., unsubstituted phenyl), halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be NR₁₄, sulfur, or oxygen; and R₁₀-R₁₄ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl. In some forms, Q₅ can be CR₁₆R₁₇; and R₁₆ and R₁₇ can be independently hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen or unsubstituted alkyl (e.g., methyl, ethyl, n-propyl, iso-propyl, n-butyl, iso-butyl, tert-butyl, etc.). In some forms, Q₅ can be oxygen; and R₁₀-R₁₄ can be hydrogen. In some forms, Q₅ can be sulfur; and R₁₀-R₁₄ can be hydrogen.

In some forms, for any one of Formulae Ia-IVa, R₃ and R₄ together and/or R′₃ and R′₄ together, with the atom to which they are attached, form a substituted cycloalkyl, an unsubstituted cycloalkyl, a substituted cycloalkenyl, an unsubstituted cycloalkenyl, a substituted aryl, an unsubstituted aryl, a substituted heteroaryl, an unsubstituted heteroaryl, a substituted heterocyclyl, or an unsubstituted heterocyclyl. In some forms, for any one of Formulae Ia-IVa, R₃ and R₄ together and/or R′₃ and R′₄ together is(are)

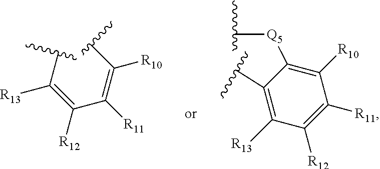

wherein Q₅ can be NR₁₄, CR₁₆R₁₇, or sulfur, or oxygen; R₁₀-R₁₄, R₁₆, and R₁₇ can be independently absent, hydrogen, substituted alkyl, unsubstituted alkyl (e.g., methyl, ethyl, n-propyl, iso-propyl, n-butyl, iso-butyl, tert-butyl, etc.), substituted alkenyl, unsubstituted alkenyl, substituted alkynyl, unsubstituted alkynyl, substituted aryl (e.g., substituted phenyl), unsubstituted aryl (e.g., unsubstituted phenyl), halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be NR₁₄, sulfur, or oxygen; and R₁₀-R₁₄ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl. In some forms, Q₅ can be CR₁₆R₁₇; and R₁₆ and R₁₇ can be independently hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen or unsubstituted alkyl (e.g., methyl, ethyl, n-propyl, iso-propyl, n-butyl, iso-butyl, tert-butyl, etc.). In some forms, Q₅ can be oxygen; and R₁₀-R₁₄ can be hydrogen. In some forms, Q₅ can be sulfur; and R₁₀-R₁₄ can be hydrogen.

In some forms, for any one of Formulae Ia-IVa, Q₃ and Q′₃ can be sulfur or oxygen. In some forms, for any one of Formulae Ia-IVa, Q₃ and Q′₃ can be sulfur. In some forms, for any one of Formulae Ia-IVa, Q₃ and Q′₃ can be oxygen.

In some forms, for any one of Formulae I-IV and Ia-IVa, at least one of R₆-R₉ and at least one of R′₆-R′₉, such as one or two of R₆-R₉ and/or one or two of R′₆-R′₉, can be independently halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), phosphonyl (e.g., —P(═O)(Ph)₂, —P(═O)(alkyl)₂, etc.); or R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or an unsubstituted aryl.

In some forms, for any of Formulae I-IV and Ia-IVa, X₄ and X′₄ are carbon; R₄ₐ and R′₄ₐ are independently hydrogen, substituted alkyl, unsubstituted alkyl, substituted alkenyl, unsubstituted alkenyl, substituted alkynyl, unsubstituted alkynyl, substituted aryl, unsubstituted aryl, unsubstituted polyaryl, substituted polyaryl, hydroxyl, amino, amido, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, substituted C₂-C₂₀ heterocyclyl, or unsubstituted C₂-C₂₀ heterocyclyl; and the substituents are as defined above for Formula I.

In some forms, for any of Formulae I-IV and Ia-IVa, X₄ and X′₄ are carbon; R₄ₐ and R′₄ₐ are independently hydrogen, substituted alkyl, unsubstituted alkyl, substituted aryl, unsubstituted aryl, unsubstituted polyaryl, substituted polyaryl, hydroxyl, unsubstituted heteroaryl, substituted heteroaryl, unsubstituted polyheteroaryl, substituted polyheteroaryl, substituted C₂-C₂₀ heterocyclyl, or unsubstituted C₂-C₂₀ heterocyclyl; and the substituents are as defined above for Formula I.

In some forms, for any of Formulae I-IV and Ia-IVa, X₄ and X′₄ are carbon; and R₄ₐ and R′₄ₐ are independently hydrogen, unsubstituted alkyl, unsubstituted aryl, unsubstituted polyaryl, hydroxyl, unsubstituted heteroaryl, unsubstituted polyheteroaryl, unsubstituted C₂-C₂₀ heterocyclyl, or unsubstituted alkylaryl.

In some forms, for any of Formulae I-IV and Ia-IVa, X₄ and X′₄ are carbon; and R₄ₐ and R′₄ₐ are hydrogen.

In some forms, for any of Formulae I-IV and Ia-IVa, X₄ and X′₄ are nitrogen; R₄ₐ and R′₄ₐ are absent.

In some forms, for any of Formulae I-IV and Ia-IVa, R₁-R₉ and R′₁-R′₉ are independently hydrogen, halogen, substituted alkyl, unsubstituted alkyl, substituted aryl, unsubstituted aryl (e.g., unsubstituted phenyl), substituted polyaryl, unsubstituted polyaryl, hydroxyl, unsubstituted heteroaryl, substituted heteroaryl, unsubstituted polyheteroaryl, substituted polyheteroaryl, substituted C₂-C₂₀ heterocyclyl, unsubstituted C₂-C₂₀ heterocyclyl, alkoxy, borenium cation, phosphonyl, sulfinyl, or sulfonyl; and the substituents are as defined above for Formula I.

In some forms, for any of Formulae I-IV and Ia-IVa, R₁-R₉ and R′₁-R′₉ are independently hydrogen, halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), unsubstituted polyaryl, substituted polyaryl, hydroxyl, unsubstituted heteroaryl, substituted heteroaryl, unsubstituted polyheteroaryl, substituted polyheteroaryl, unsubstituted C₂-C₂₀ heterocyclyl, substituted C₁-C₂₀ heterocyclyl, unsubstituted alkylaryl, substituted alkylaryl, alkoxy (e.g., —O-alkyl, —O-aryl, —O— polyaryl, etc.), borenium cation (e.g., —B(Mes)₂), phosphonyl (e.g. —P(═O)(Ph)₂, —P(═O)(alkyl)₂, etc.), sulfinyl (e.g., —S(═O)(Ph)₂, —S(═O)(alkyl)₂, etc.), or sulfonyl —S(═O)₂(Ph)₂, —S(═O)₂(alkyl)₂, etc.).

In some forms, for any of Formulae I-IV and Ia-IVa, one or more of R₁-R₉ and R′₁-R′₉ can be

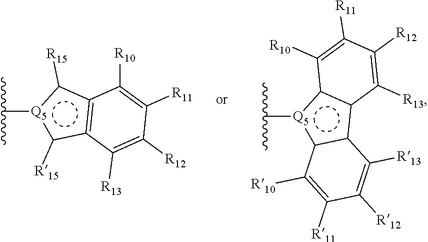

where Q₅ can be nitrogen or carbon; and R₁₀-R₁₃, R₁₅, R′₁₅, and R′₁₀-R′₁₃ can be independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl. In some forms, Q₅ can be nitrogen or carbon; and R₁₀-R₁₃, R₁₅, R′₁₅, and R′₁₀-R′₁₃ can be independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl. In some forms, Q₅ can be nitrogen or carbon; and R₁₀-R₁₃, R₁₅, R′₁₅, and R′₁₀-R′₁₃ can be hydrogen, i.e., carbazolyl, fluorenyl, indenyl, or indolyl.

In some forms, for any of Formulae I-IV and Ia-IVa, R₂-R₅, R′₂-R′₅, R₇, R₈, R′₇, and R′₈ are hydrogen; and R₁, R₆, R₉, R′₁, R′₆, and/or R′₉ are independently hydrogen, halogen, unsubstituted alkyl (e.g., methyl, ethyl, n-propyl, isopropyl, n-butyl, sec-butyl, isobutyl, tert-butyl, etc.), unsubstituted aryl, substituted aryl (e.g., mesitylene or other aryl substituted with one or more alkyls, such as methyl, ethyl, n-propyl, isopropyl, n-butyl, sec-butyl, isobutyl, tert-butyl, etc.), unsubstituted polyaryl, substituted polyaryl, hydroxyl, unsubstituted heteroaryl (e.g., carbazolyl, fluorenyl, indenyl, indolyl, etc.), unsubstituted polyheteroaryl, unsubstituted C₂-C₂₀ heterocyclyl, unsubstituted alkylaryl, alkoxy (e.g., —O-alkyl such as methoxy, ethoxy, and phenoxy, —O-aryl, —O-polyaryl, etc.), borenium cation (e.g., —B(Mes)₂), phosphonyl (e.g. —P(═O)(Ph)₂), sulfinyl (e.g., —S(═O)(Ph)₂, —S(═O)(alkyl)₂, etc.), or sulfonyl —S(═O)₂(Ph)₂, —S(═O)₂(alkyl)₂, etc.).

In some forms, for any of Formulae I-IV and Ia-IVa, R₂-R₅, R′₂-R′₅, R₇, R₈, R′₇, and R′₈ are hydrogen; and R₁, R₆, R₉, R′₁, R′₆, and/or R′₉ are independently hydrogen, halogen, unsubstituted alkyl, unsubstituted aryl, substituted aryl (e.g., aryl substituted with one or more alkyls, such as methyl, ethyl, n-propyl, isopropyl, n-butyl, sec-butyl, isobutyl, tert-butyl, etc.), unsubstituted polyaryl, substituted polyaryl, hydroxyl, unsubstituted heteroaryl (e.g., carbazolyl, fluorenyl, indenyl, indolyl, etc.), unsubstituted polyheteroaryl, unsubstituted C₂-C₂₀ heterocyclyl, unsubstituted alkylaryl, alkoxy (e.g., —O-alkyl such as methoxy, ethoxy, and phenoxy, —O-aryl, —O-polyaryl, etc.), borenium cation (e.g., —B(Mes)₂), phosphonyl (e.g. —P(═O)(Ph)₂), sulfinyl (e.g., —S(═O)(Ph)₂, —S(═O)(alkyl)₂, etc.), or sulfonyl —S(═O)₂(Ph)₂, —S(═O)₂(alkyl)₂, etc.).

In some forms, for any of Formulae I-IV and Ia-IVa, R₂-R₅, R′₂-R′₅, R₇, R₈, R′₇, and R's are hydrogen; and R₁, R₆, R₉, R′₁, R′₆, and/or R′₉ are independently unsubstituted alkyl, unsubstituted aryl, or substituted aryl (e.g., aryl substituted with one or more alkyls, such as methyl, ethyl, n-propyl, isopropyl, n-butyl, sec-butyl, isobutyl, tert-butyl, etc.).

In some forms, for any of Formulae I-IV and Ia-IVa, the substituents can be independently a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, a substituted or unsubstituted alkylaryl (e.g. benzyl), a carbonyl (e.g. carboxyl, ester, etc.), an alkoxy (e.g. methoxy, ethoxy, aryloxy, benzoether, etc.), a halide, a hydroxyl, or a haloalkyl, or a combination thereof.

For any of Formulae I-IV and Ia-IVa, the alkyl can be a linear alkyl, a branched alkyl, or a cyclic alkyl (either monocyclic or polycyclic). The terms “cyclic alkyl” and “cycloalkyl” are used interchangeably herein. Exemplary alkyl include a linear C₁-C₃₀ alkyl, a branched C₄-C₃₀ alkyl, a cyclic C₃-C₃₀ alkyl, a linear C₁-C₂₀ alkyl, a branched C₄-C₂₀ alkyl, a cyclic C₃-C₂₀ alkyl, a linear C₁-C₁₀ alkyl, a branched C₄-C₁₀ alkyl, a cyclic C₃-C₁₀ alkyl, a linear C₁-C₆ alkyl, a branched C₄-C₆ alkyl, a cyclic C₃-C₆ alkyl, a linear C₁-C₄ alkyl, cyclic C₃-C₄ alkyl, such as a linear C₁-C₁₀, C₁-C₉, C₁-C₈, C₁-C₇, C₁-C₆, C₁-C₅, C₁-C₄, C₁-C₃, or C₁-C₂ alkyl group, a branched C₃-C₉, C₃-C₉, C₃-C₈, C₃-C₇, C₃-C₆, C₃-C₅, or C₃-C₄ alkyl group, or a cyclic C₃-C₉, C₃-C₉, C₃-C₈, C₃-C₇, C₃-C₆, C₃-C₅, or C₃-C₄ alkyl group. The cyclic alkyl can be a monocyclic or polycyclic alkyl, such as a C₄-C₃₀, C₄-C₂₅, C₄-C₂₀, C₄-C₁₈, C₄-C₁₆, C₄-C₁₅, C₄-C₁₄, C₄-C₁₃, C₄-C₁₂, C₄-C₁₀, C₄-C₉, C₄-C₈, C₄-C₇, C₄-C₆, or C₄-C₅ monocyclic or polycyclic alkyl group.

For any of Formulae I-IV and Ia-IVa, the alkenyl can be a linear alkenyl, a branched alkenyl, or a cyclic alkenyl (either monocyclic or polycyclic). The terms “cyclic alkenyl” and “cycloalkenyl” are used interchangeably herein. Exemplary alkenyl include a linear C₂-C₃₀ alkenyl, a branched C₄-C₃₀ alkenyl, a cyclic C₃-C₃₀ alkenyl, a linear C₂-C₂₀ alkenyl, a branched C₄-C₂₀ alkenyl, a cyclic C₃-C₂₀ alkenyl, a linear C₂-C₁₀ alkenyl, a branched C₄-C₁₀ alkenyl, a cyclic C₃-C₁₀ alkenyl, a linear C₂-C₆ alkenyl, a branched C₄-C₆ alkenyl, a cyclic C₃-C₆ alkenyl, a linear C₂-C₄ alkenyl, cyclic C₃-C₄ alkenyl, such as a linear C₂-C₁₀, C₂-C₉, C₂-C₈, C₂-C₇, C₂-C₆, C₂-C₅, C₂-C₄, C₂-C₃, C₂ alkenyl group, a branched C₃-C₉, C₃-C₉, C₃-C₈, C₃-C₇, C₃-C₆, C₃-C₅, C₃-C₄ alkenyl group, or a cyclic C₃-C₉, C₃-C₉, C₃-C₈, C₃-C₇, C₃-C₆, C₃-C₅, C₃-C₄ alkenyl group. The cyclic alkenyl can be a monocyclic or polycyclic alkenyl, such as a C₄-C₃₀, C₄-C₂₅, C₄-C₂₀, C₄-C₁₈, C₄-C₁₆, C₄-C₁₅, C₄-C₁₄, C₄-C₁₃, C₄-C₁₂, C₄-C₁₀, C₄-C₉, C₄-C₈, C₄-C₇, C₄-C₆, or C₄-C₅ monocyclic or polycyclic alkenyl group.

For any of Formulae I-IV and Ia-IVa, the alkynyl can be a linear alkynyl, a branched alkynyl, or a cyclic alkynyl (either monocyclic or polycyclic). The terms “cyclic alkynyl” and “cycloalkynyl” are used interchangeably herein. Exemplary alkynyl include a linear C₂-C₃₀ alkynyl, a branched C₄-C₃₀ alkynyl, a cyclic C₃-C₃₀ alkynyl, a linear C₂-C₂₀ alkynyl, a branched C₄-C₂₀ alkynyl, a cyclic C₃-C₂₀ alkynyl, a linear C₂-C₁₀ alkynyl, a branched C₄-C₁₀ alkynyl, a cyclic C₃-C₁₀ alkynyl, a linear C₂-C₆ alkynyl, a branched C₄-C₆ alkynyl, a cyclic C₃-C₆ alkynyl, a linear C₂-C₄ alkynyl, cyclic C₃-C₄ alkynyl, such as a linear C₂-C₁₀, C₂-C₉, C₂-C₈, C₂-C₇, C₂-C₆, C₂-C₅, C₂-C₄, C₂-C₃, C₂ alkynyl group, a branched C₃-C₉, C₃-C₉, C₃-C₈, C₃-C₇, C₃-C₆, C₃-C₅, C₃-C₄ alkynyl group, or a cyclic C₃-C₉, C₃-C₉, C₃-C₈, C₃-C₇, C₃-C₆, C₃-C₅, C₃-C₄ alkynyl group. The cyclic alkynyl can be a monocyclic or polycyclic alkynyl, such as a C₄-C₃₀, C₄-C₂₅, C₄-C₂₀, C₄-C₁₈, C₄-C₁₆, C₄-C₁₅, C₄-C₁₄, C₄-C₁₃, C₄-C₁₂, C₄-C₁₀, C₄-C₉, C₄-C₈, C₄-C₇, C₄-C₆, or C₄-C₅ monocyclic or polycyclic alkynyl group.

It is understood that any of the exemplary alkyl, alkenyl, and alkynyl groups can be heteroalkyl, heteroalkenyl, and heteroalkynyl, respectively.

For any of Formulae I-IV and Ia-IVa, the aryl group can be a C₅-C₃₀ aryl, a C₅-C₂₀ aryl, a C₅-C₁₂ aryl, a C₅-C₁₁ aryl, a C₅-C₉ aryl, a C₆-C₂₀ aryl, a C₆-C₁₂ aryl, a C₆-C₁₁ aryl, or a C₆-C₉ aryl. It is understood that the aryl can be a heteroaryl, such as a C₅-C₃₀ heteroaryl, a C₅-C₂₀ heteroaryl, a C₅-C₁₂ heteroaryl, a C₅-C₁₁ heteroaryl, a C₅-C₉ heteroaryl, a C₆-C₃₀ heteroaryl, a C₆-C₂₀ heteroaryl, a C₆-C₁₂ heteroaryl, a C₆-C₁ heteroaryl, or a C₆-C₉ heteroaryl. For any of Formulae I, Ia, II, III, and IV, the polyaryl group can be a C₁₀-C₃₀ polyaryl, a C₁₀-C₂₀ polyaryl, a C₁₀-C₁₂ polyaryl, a C₁₀-C₁₁ polyaryl, or a C₁₂-C₂₀ polyaryl. It is understood that the aryl can be a polyheteroaryl, such as a C₁₀-C₃₀ polyheteroaryl, a C₁₀-C₂₀ polyheteroaryl, a C₁₀-C₁₂ polyheteroaryl, a C₁₀-C₁₁ polyheteroaryl, or a C₁₂-C₂₀ polyheteroaryl.

In some forms, the dinuclear platinum(II) complex has a structure:

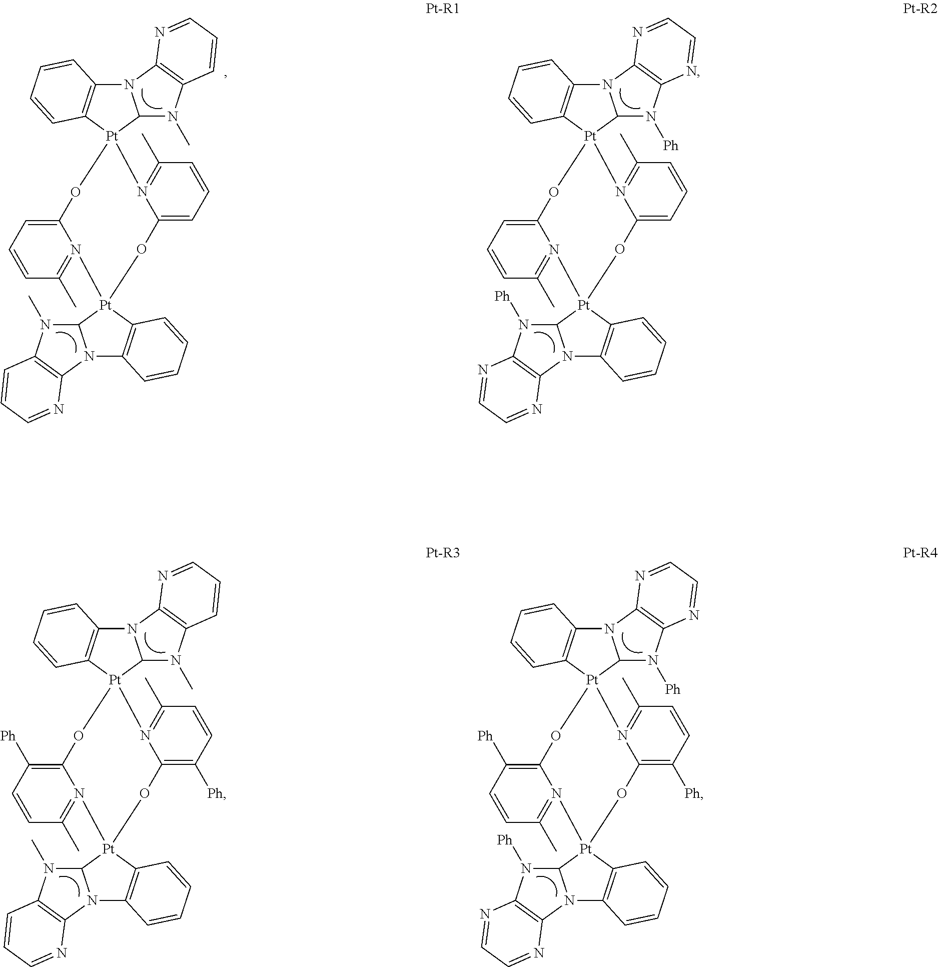

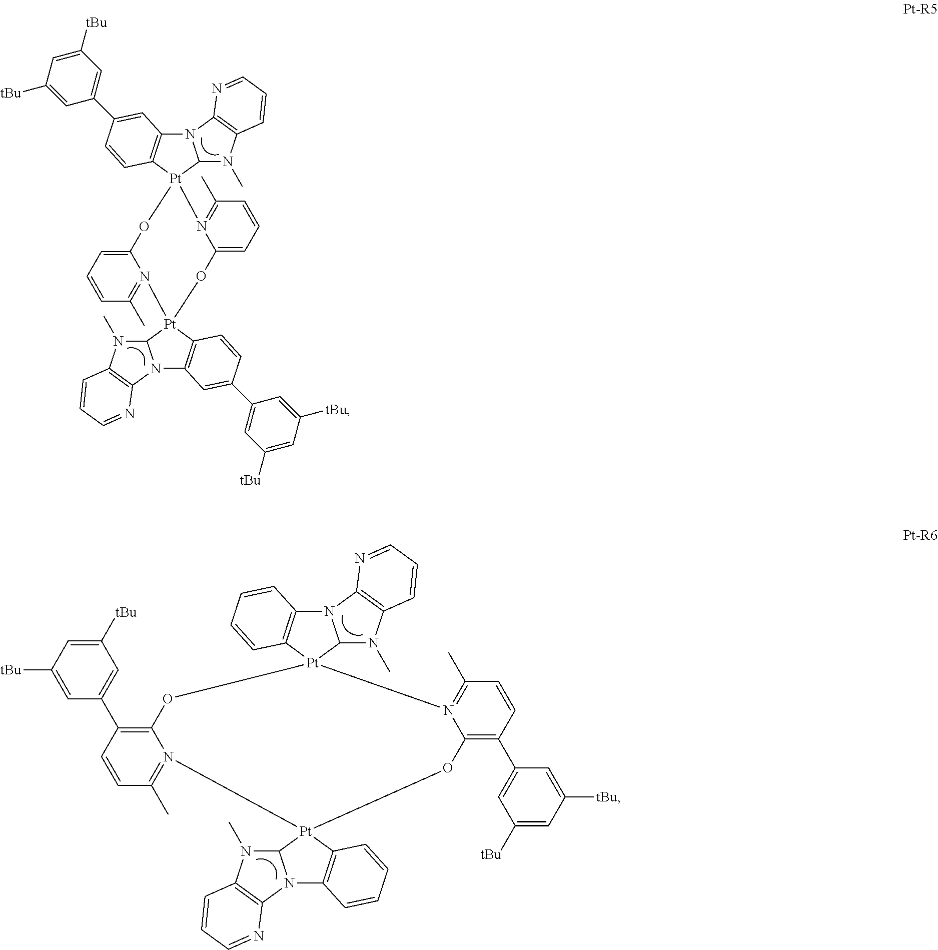

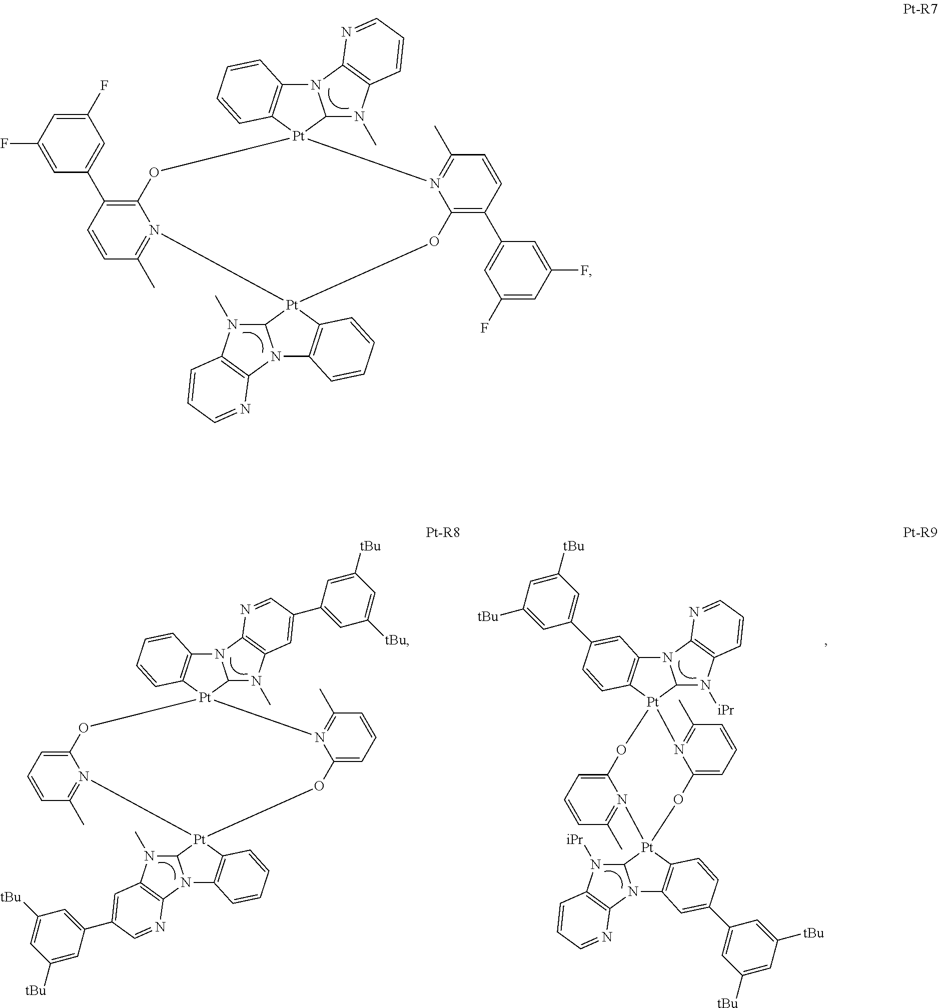

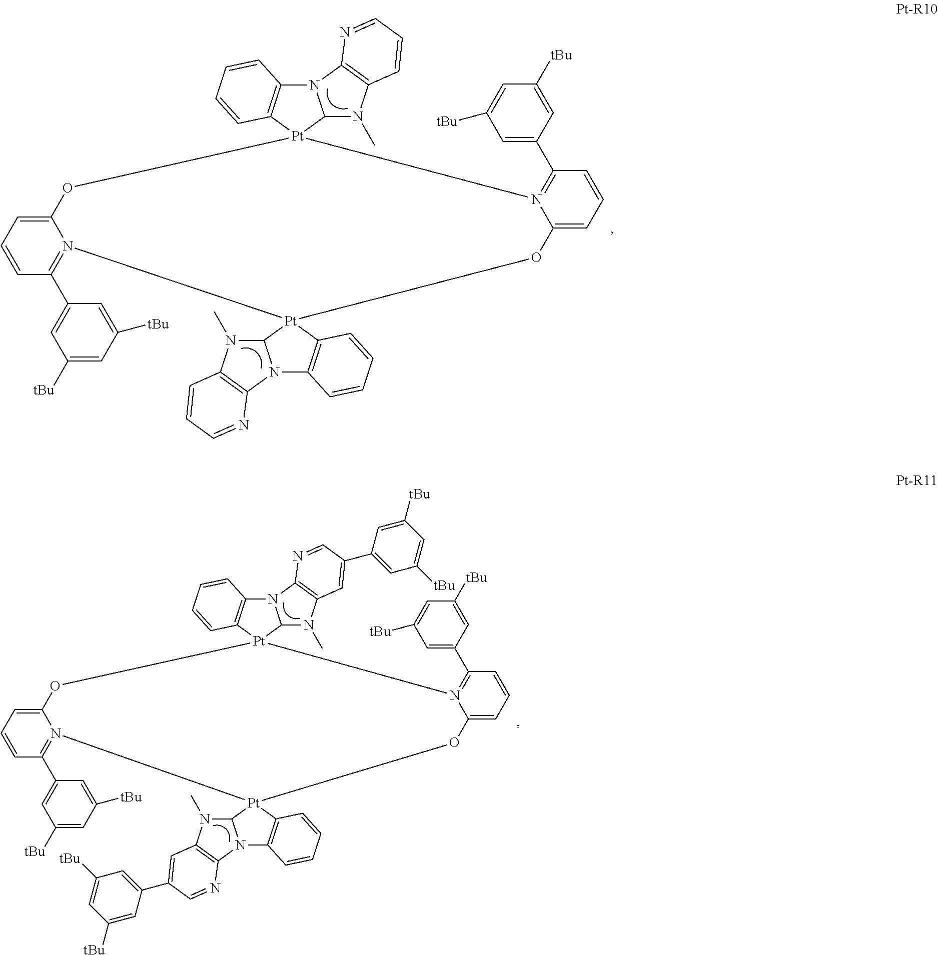

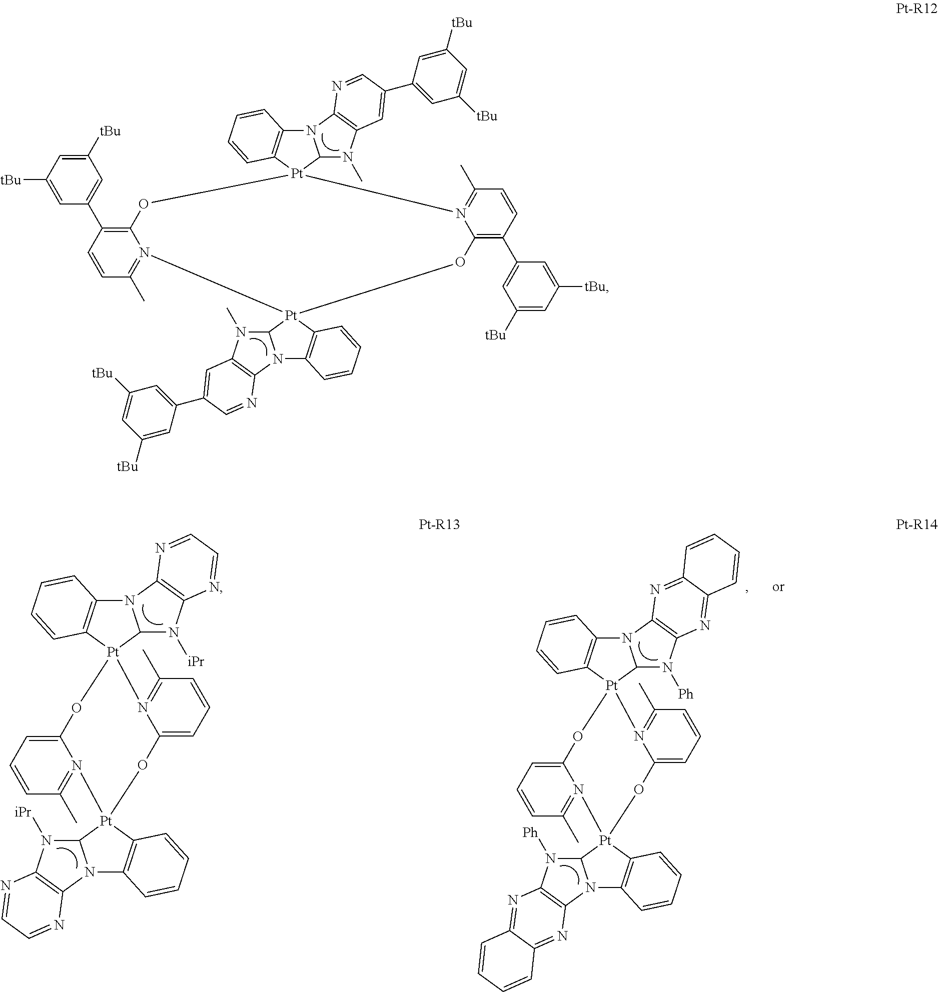

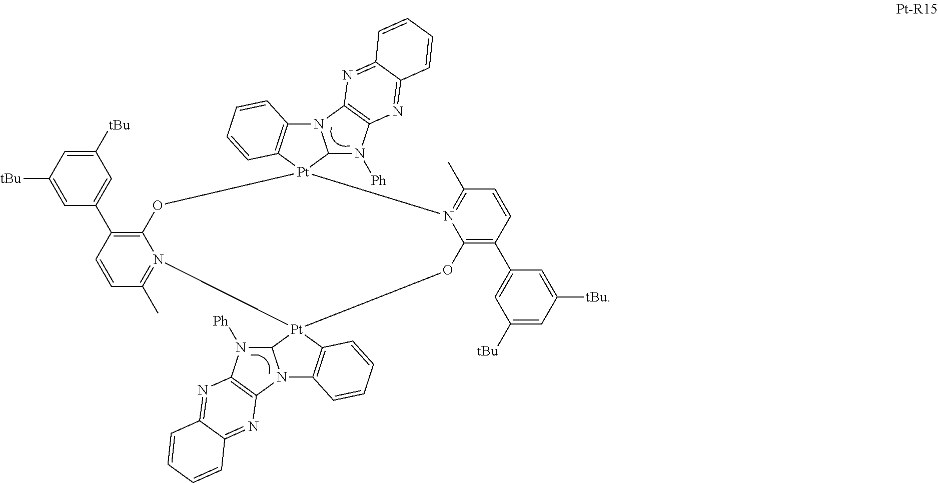

Additional exemplary dinuclear platinum(II) complexes are shown below.

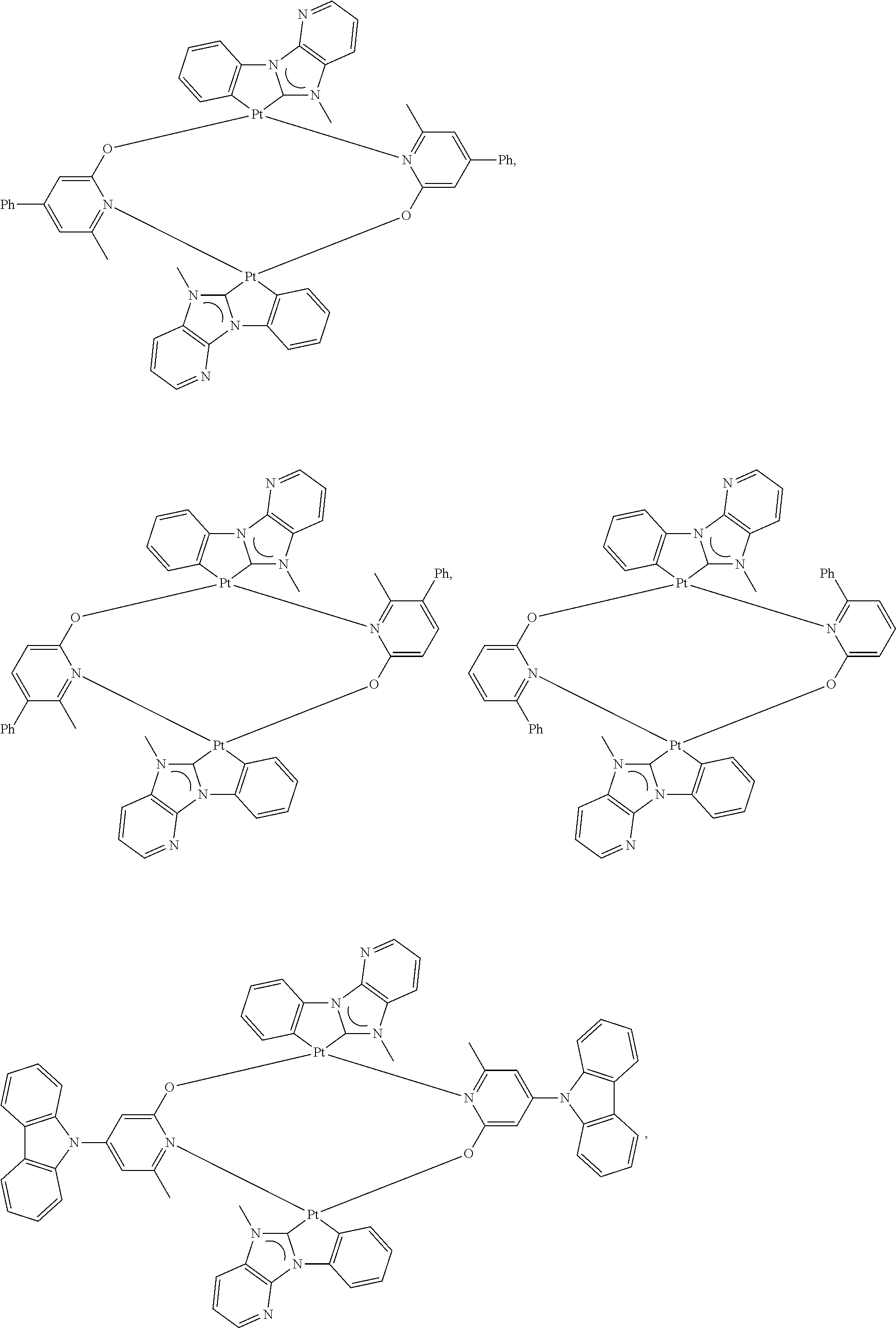

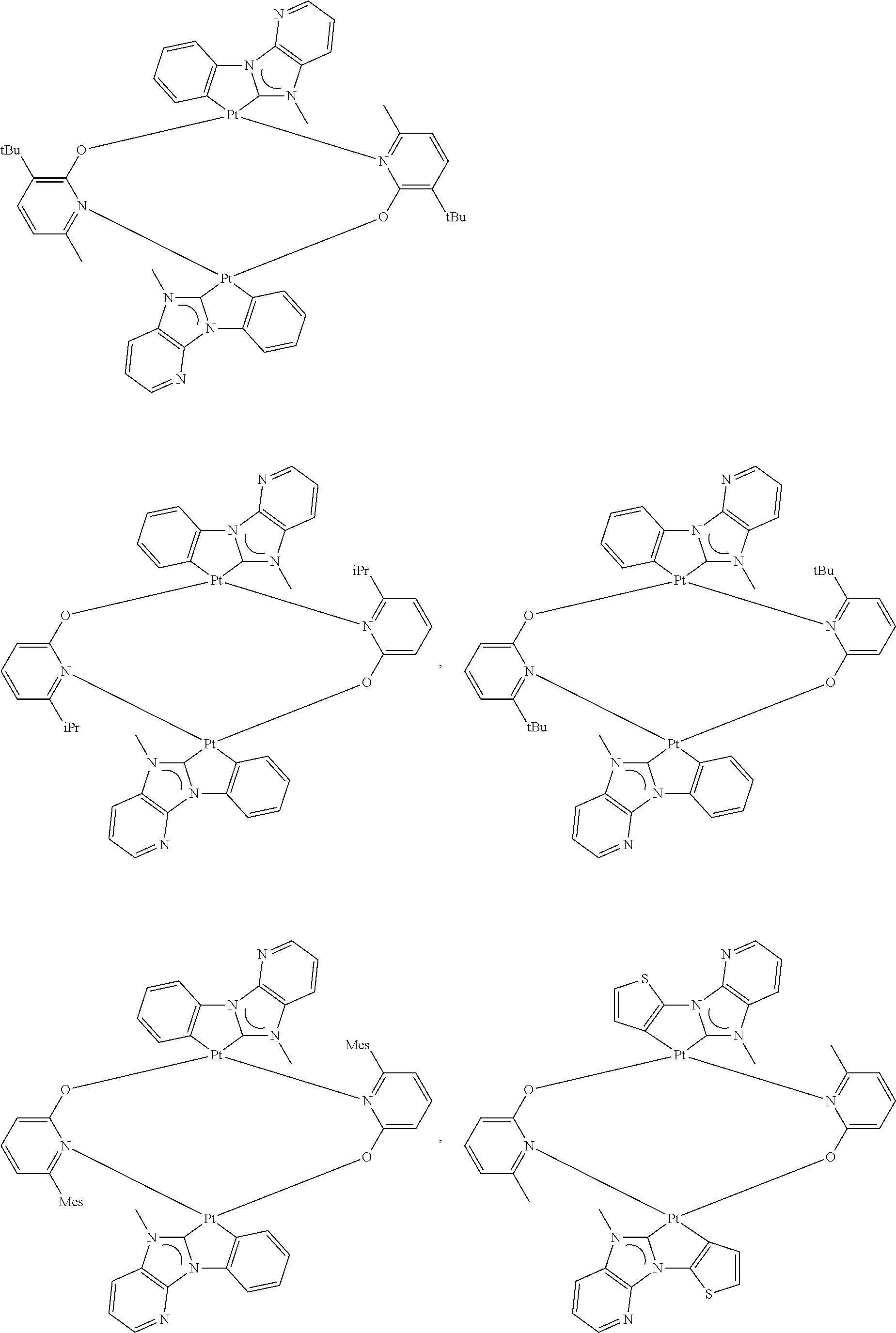

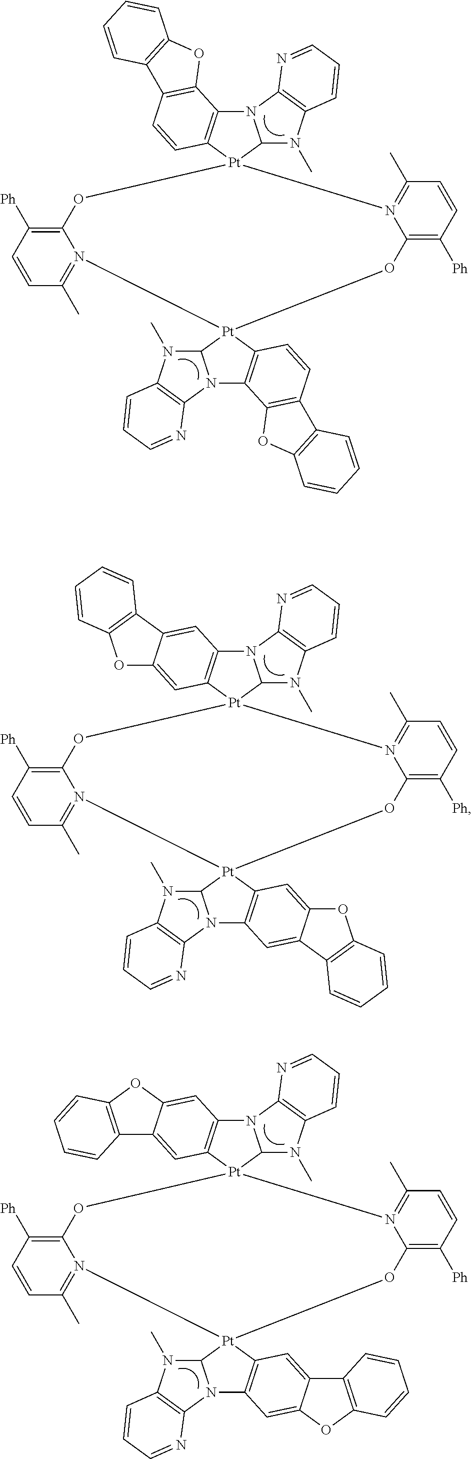

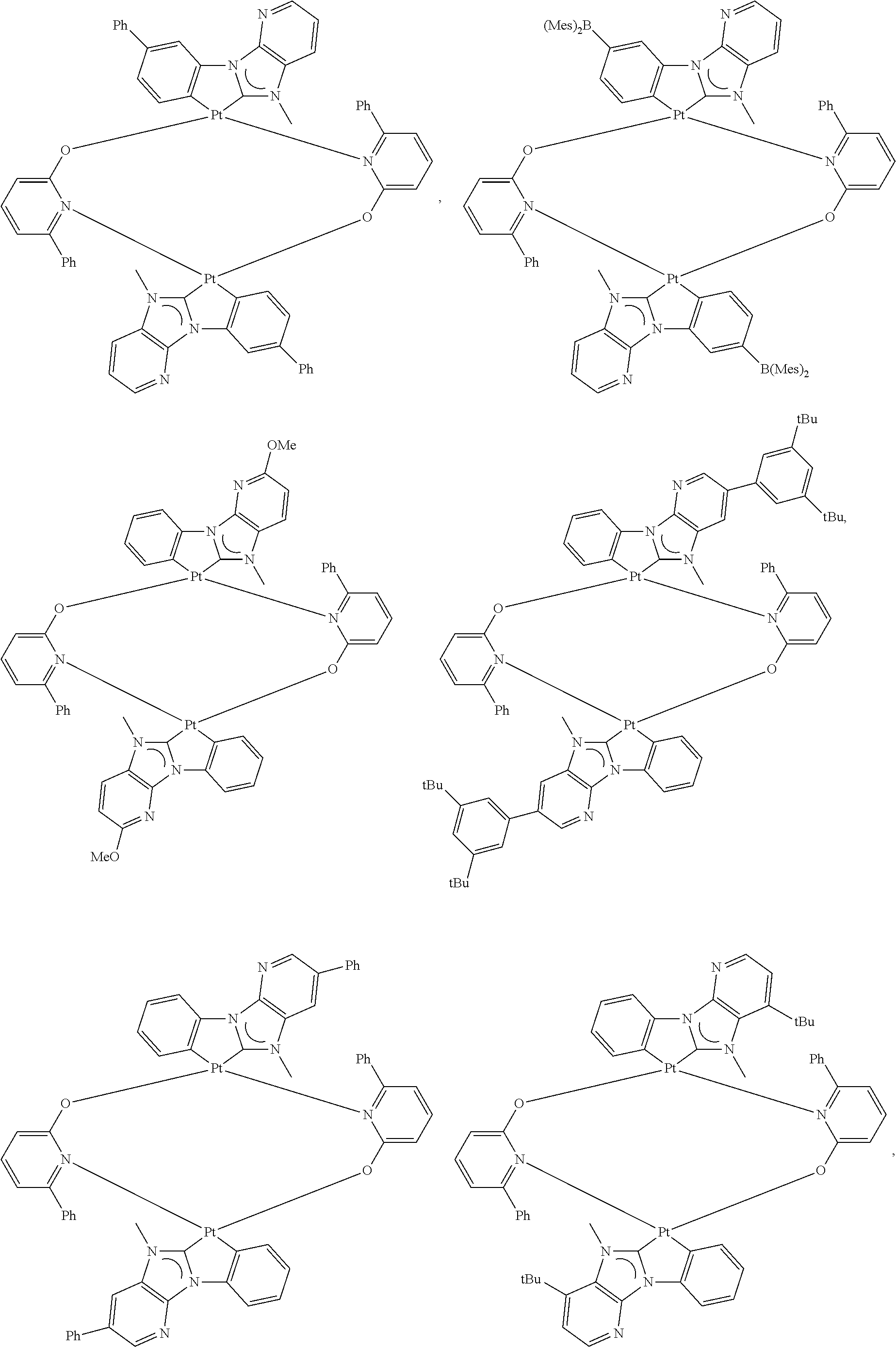

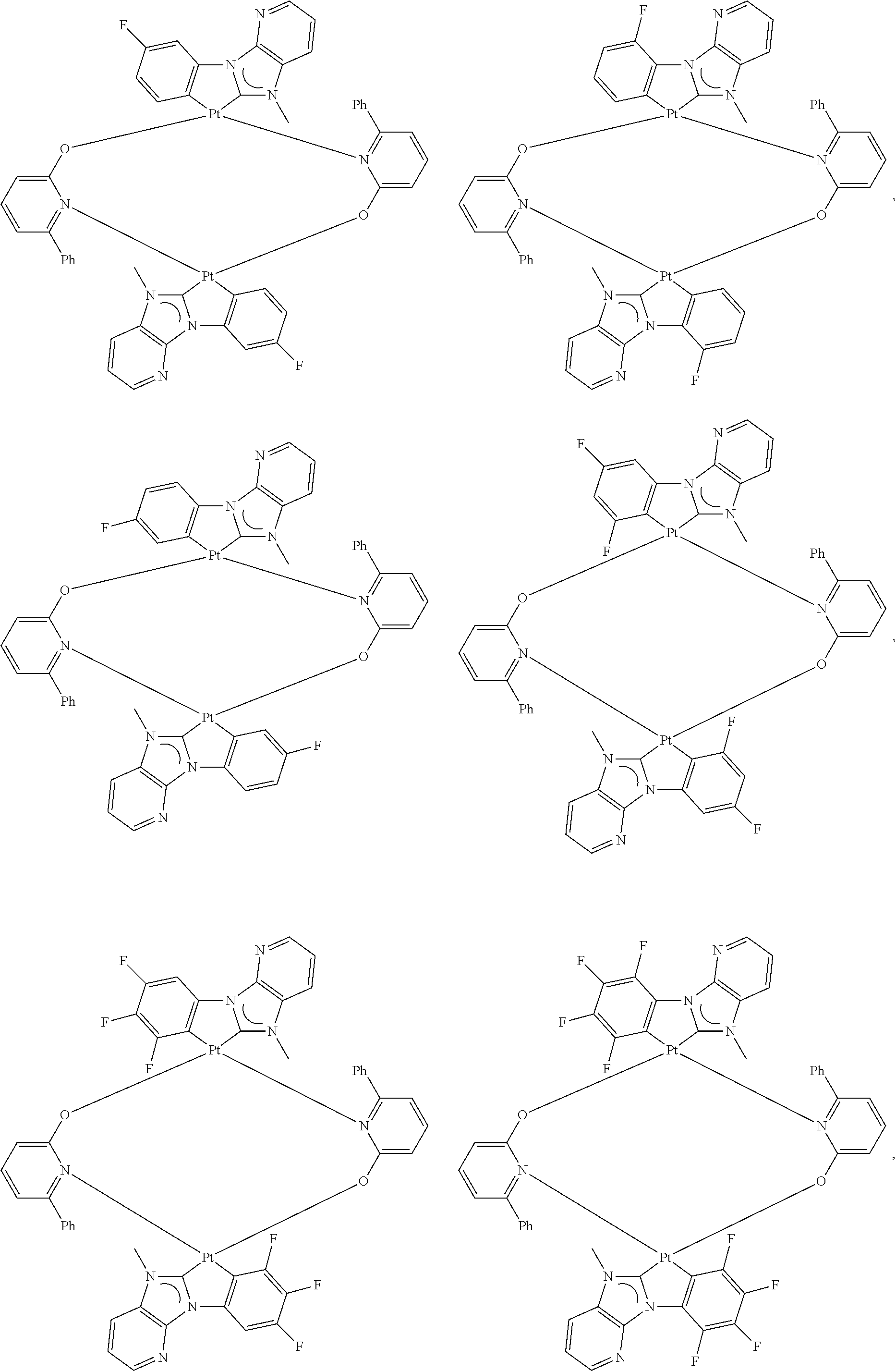

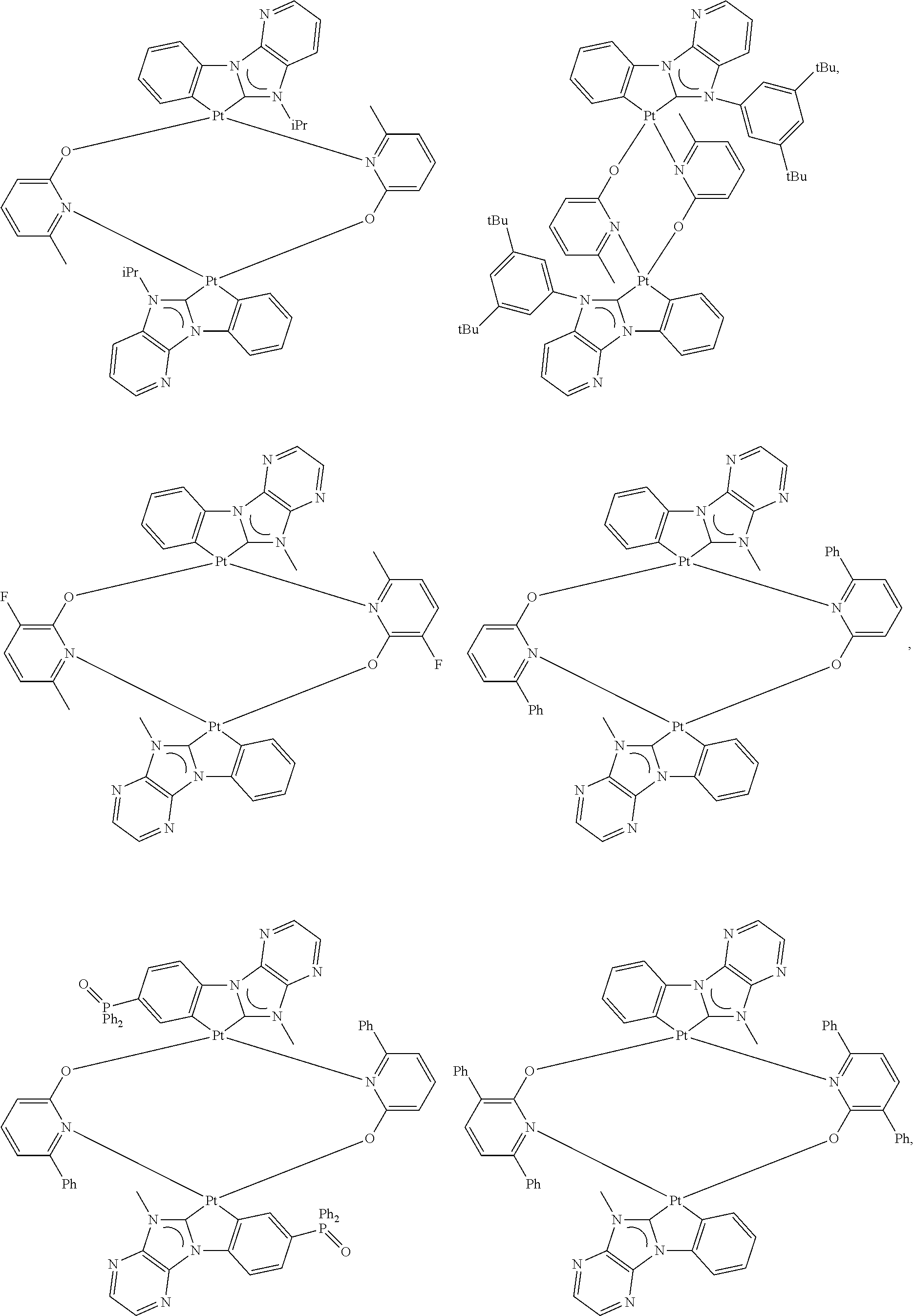

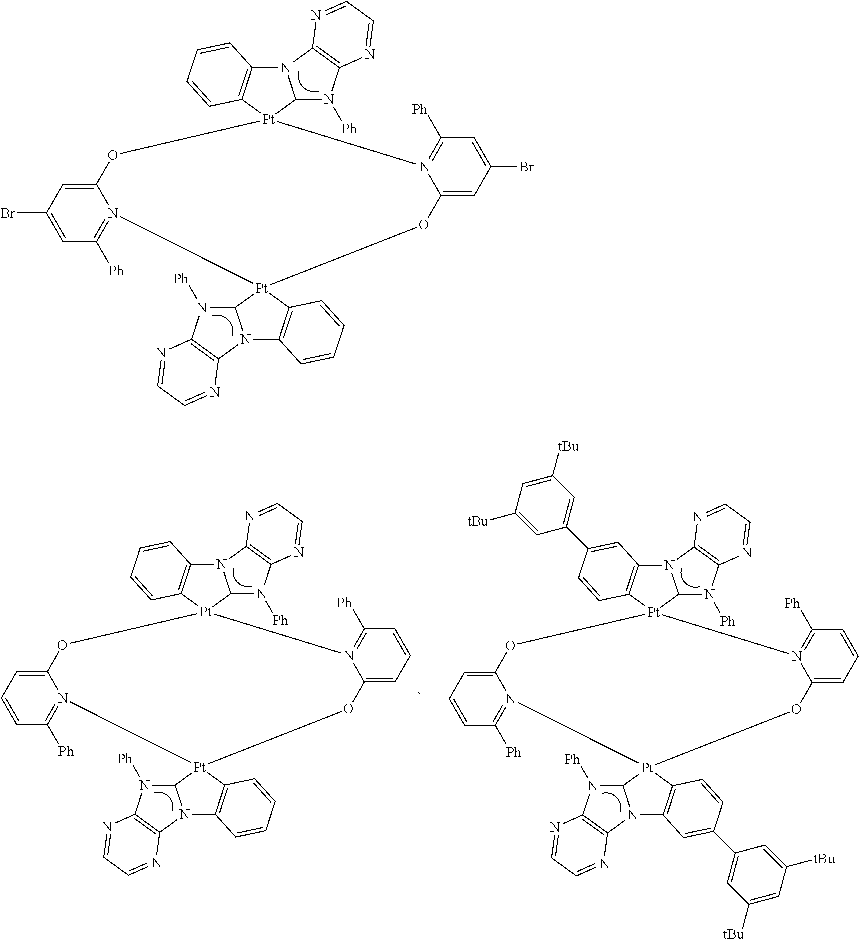

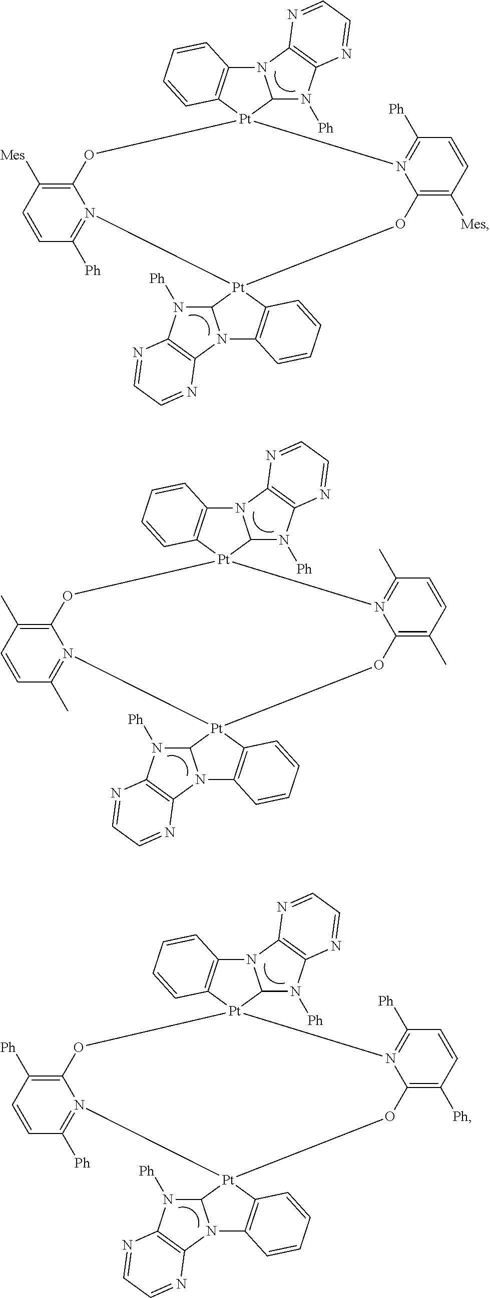

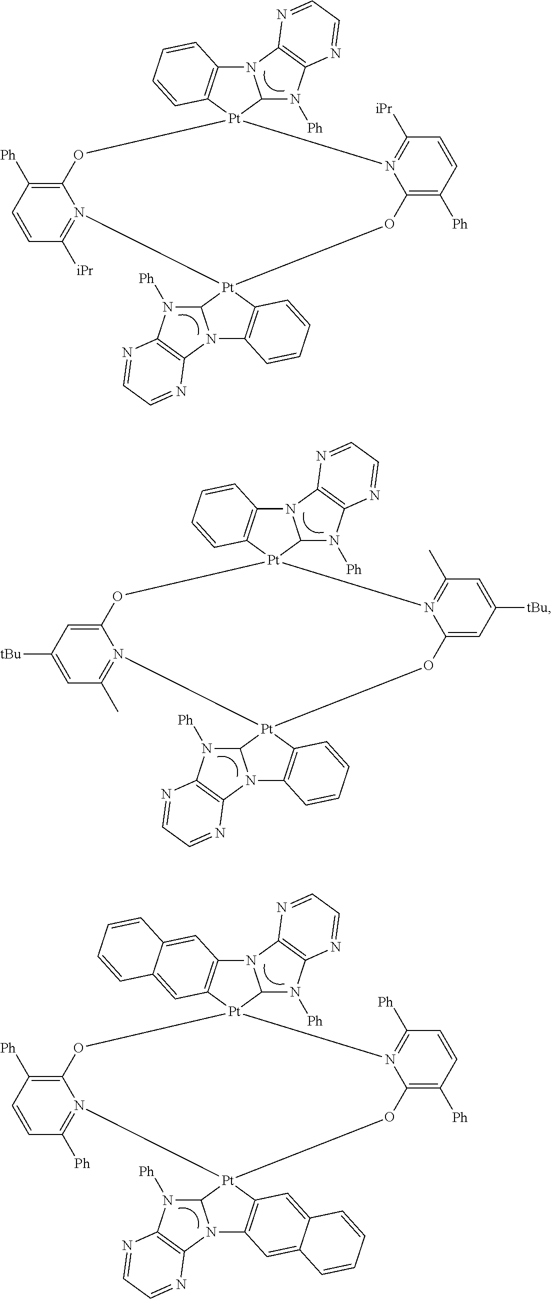

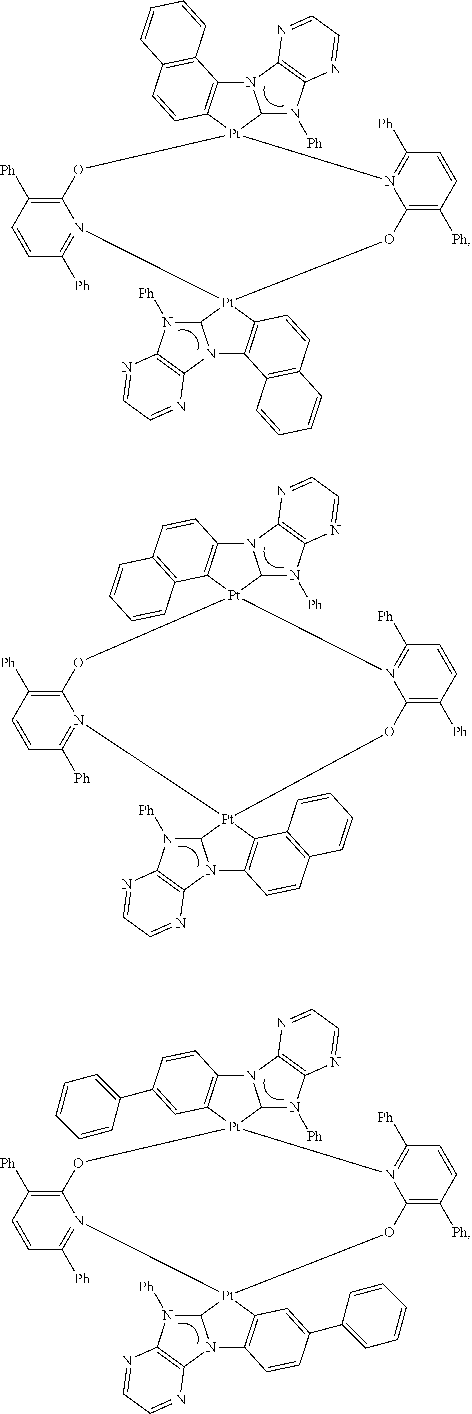

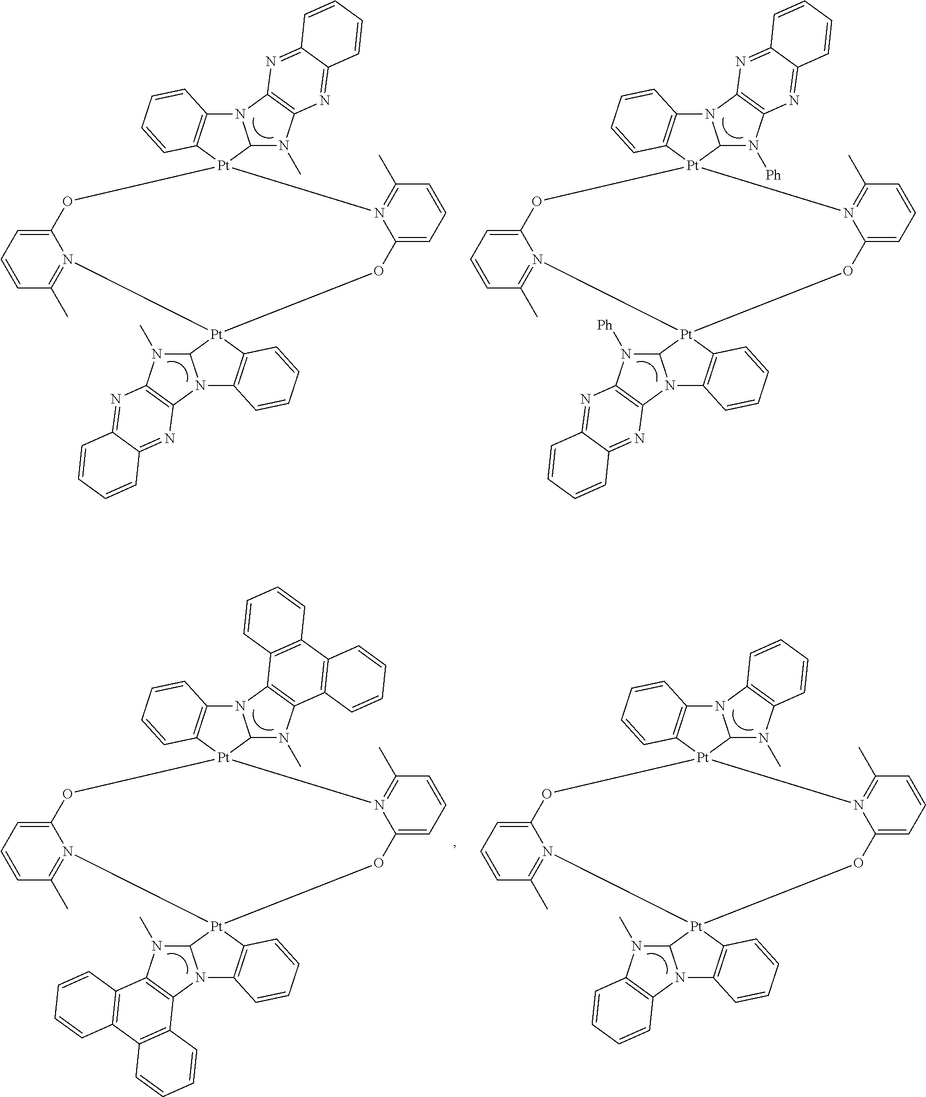

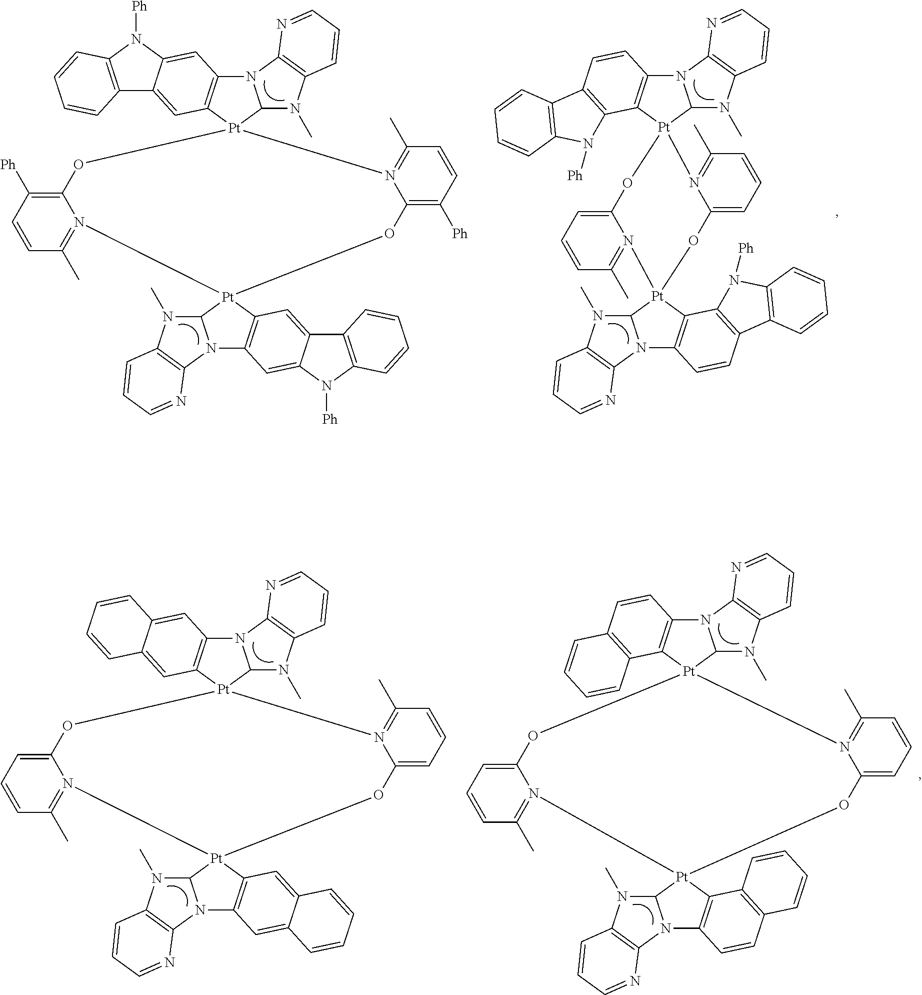

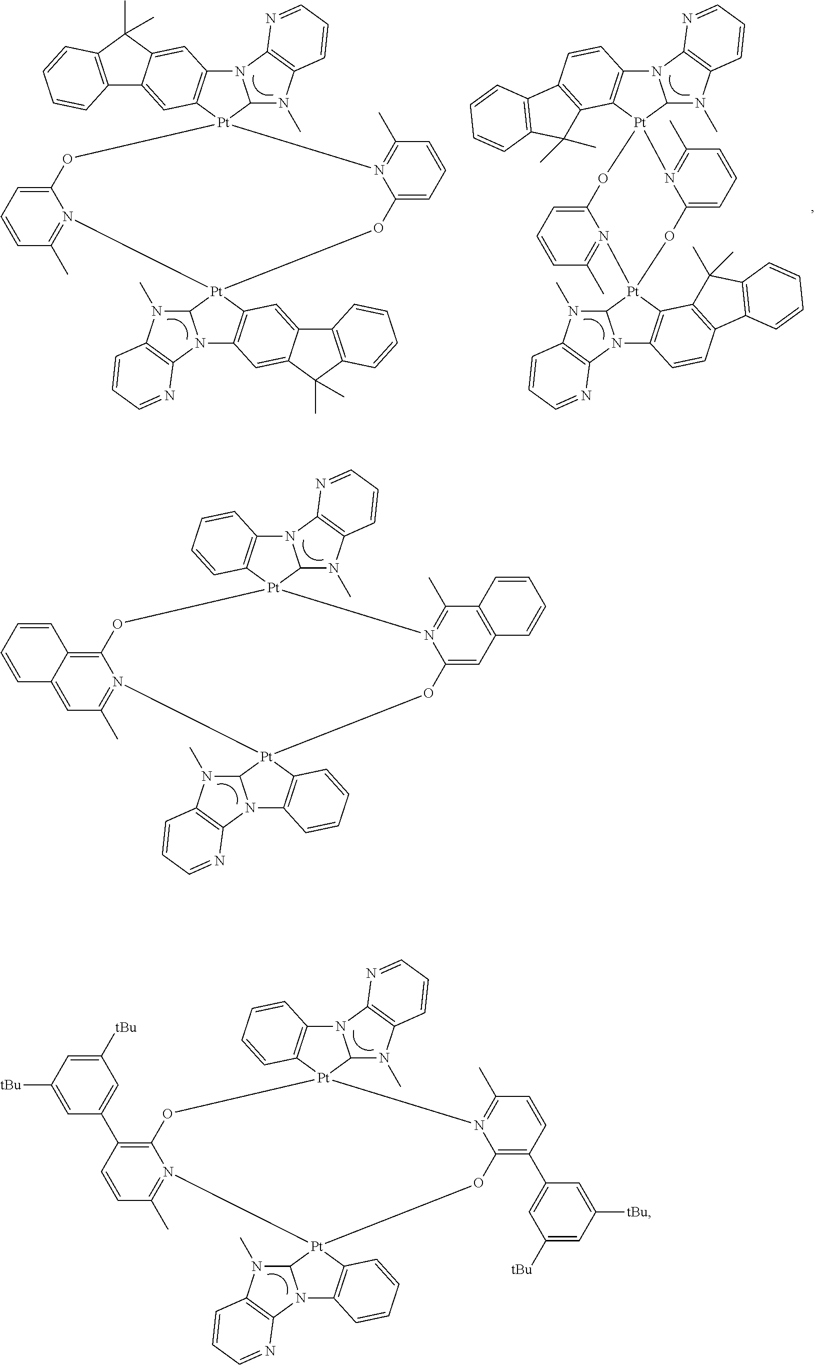

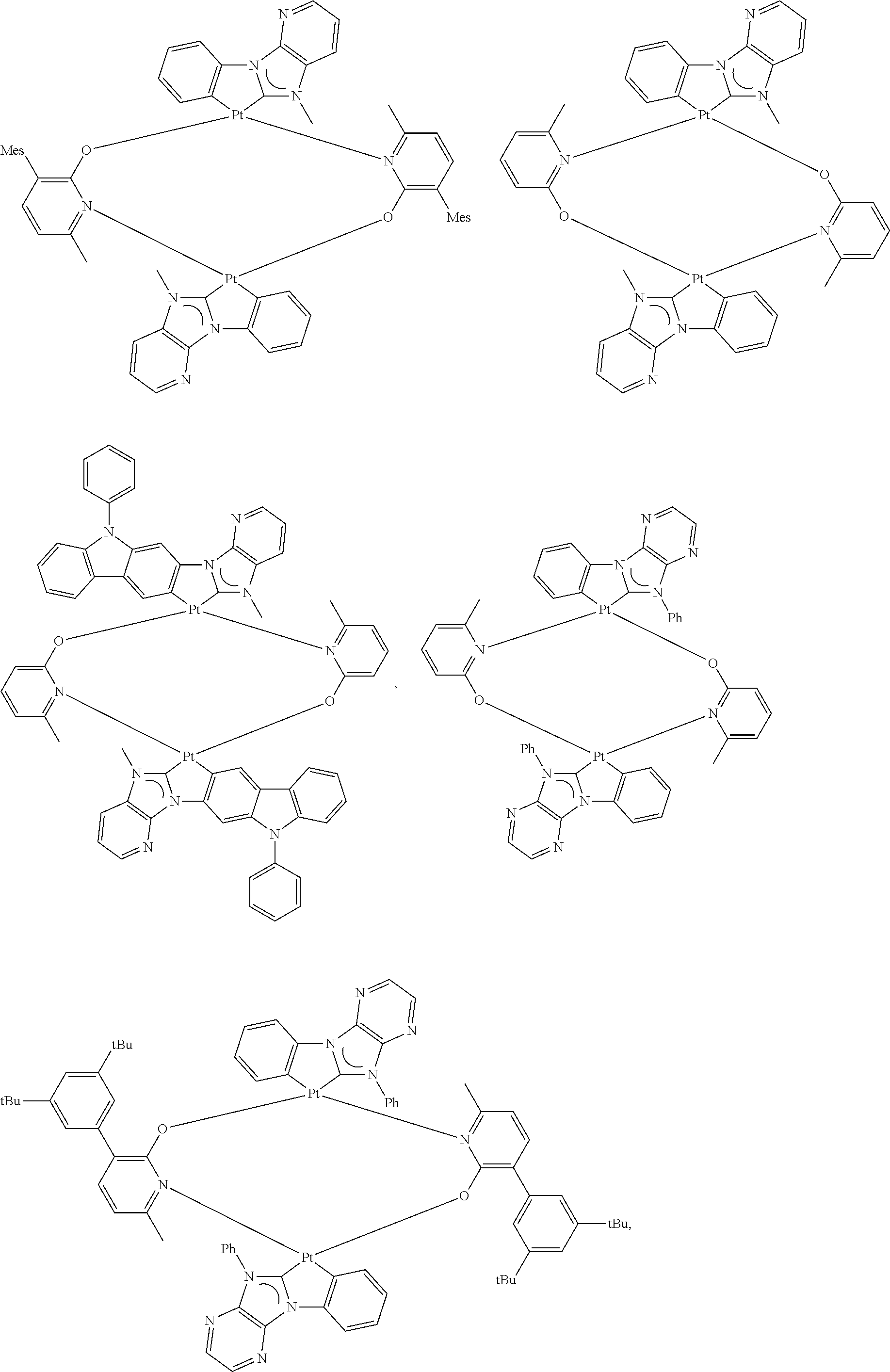

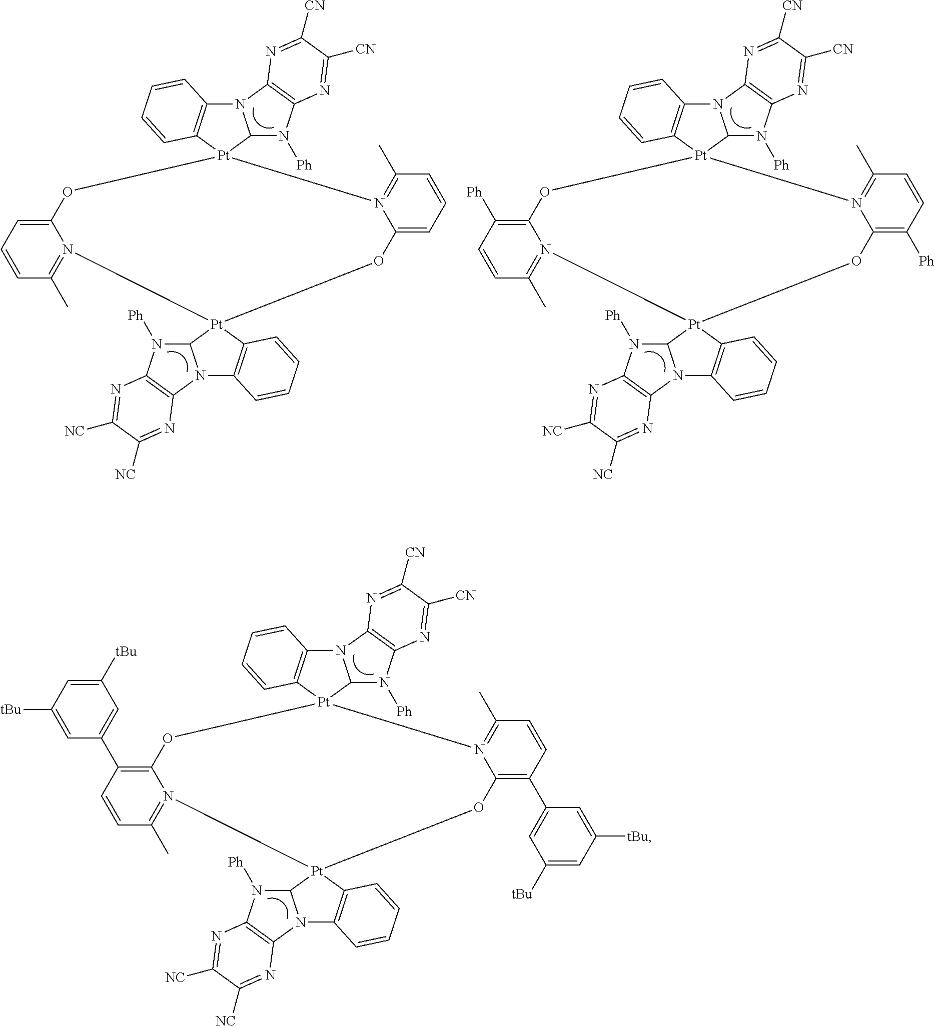

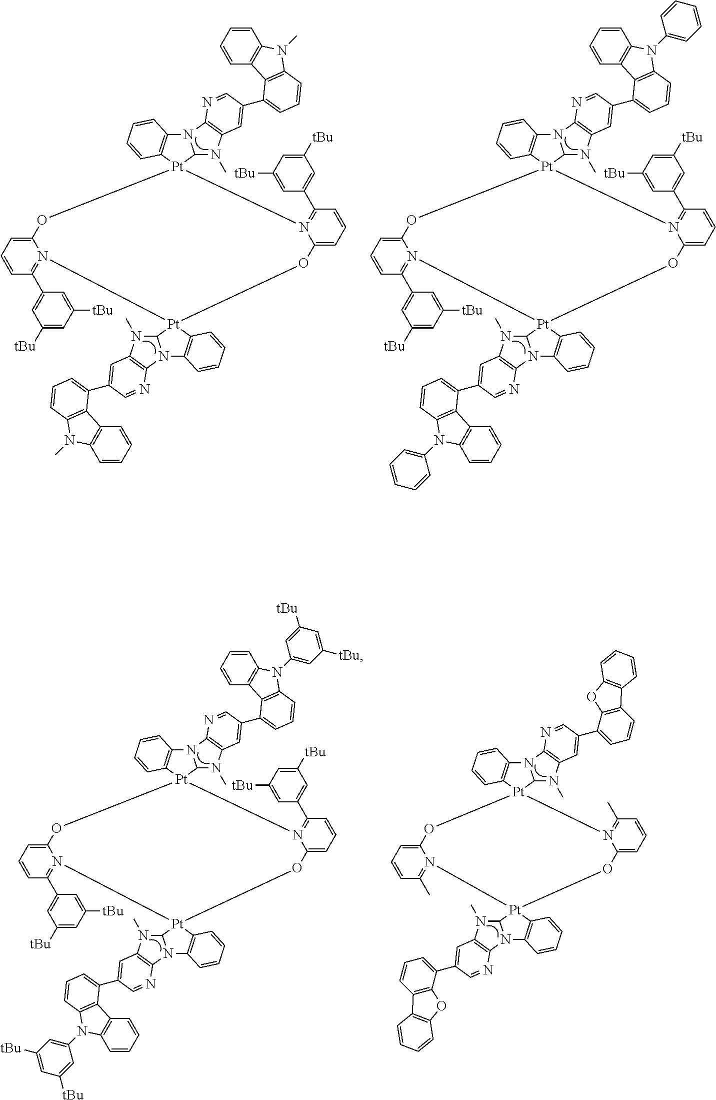

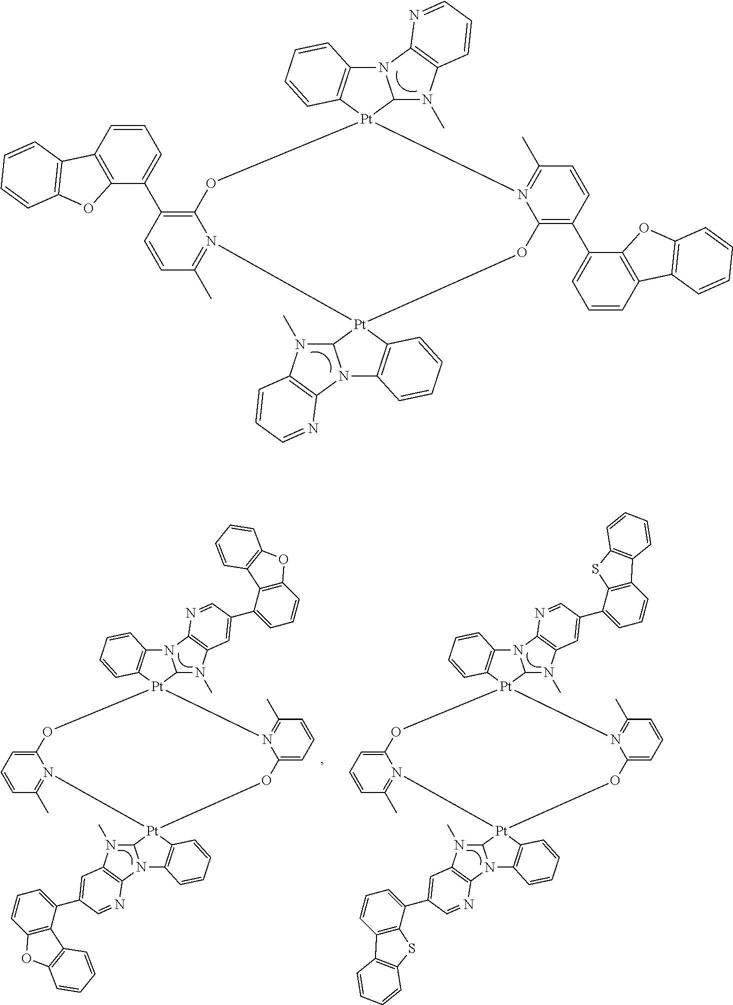

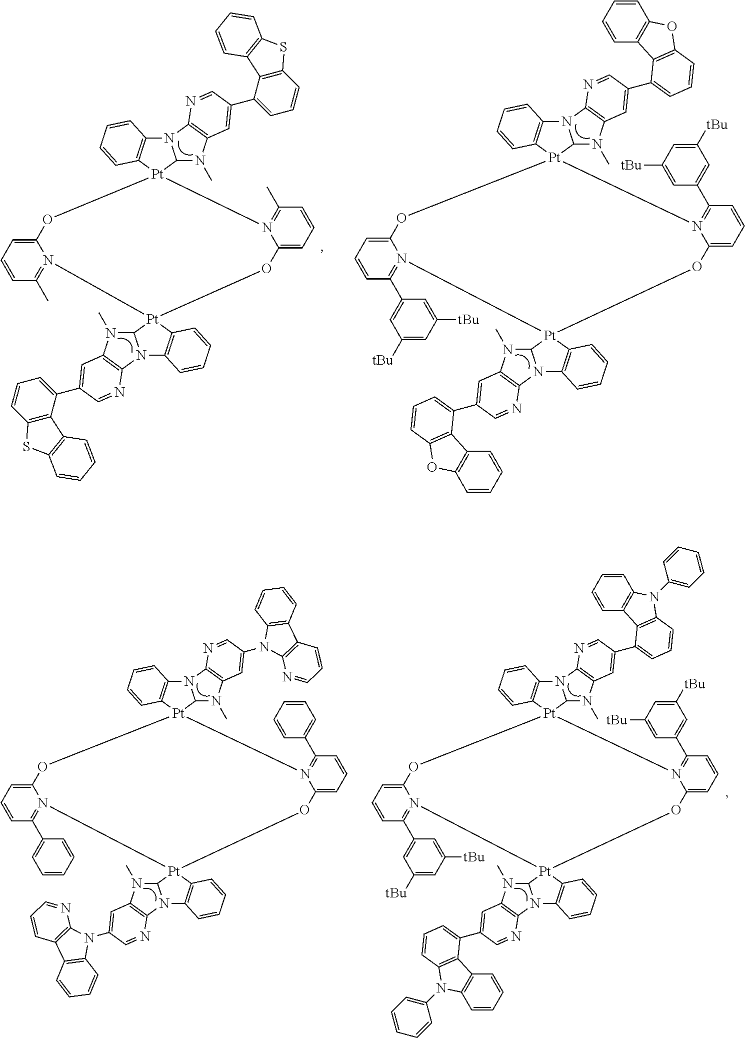

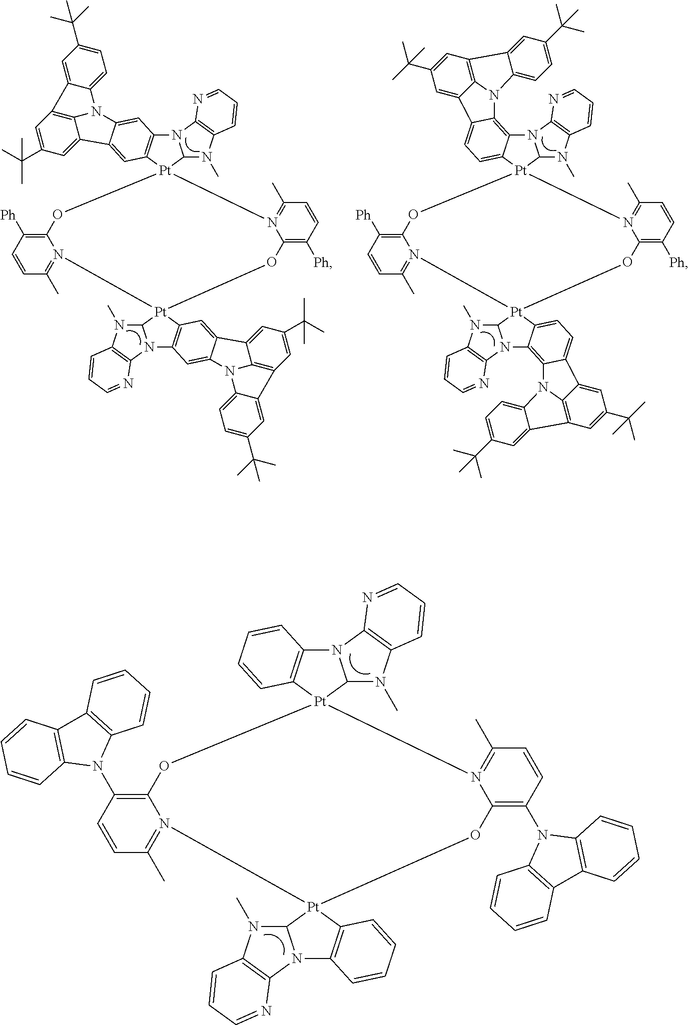

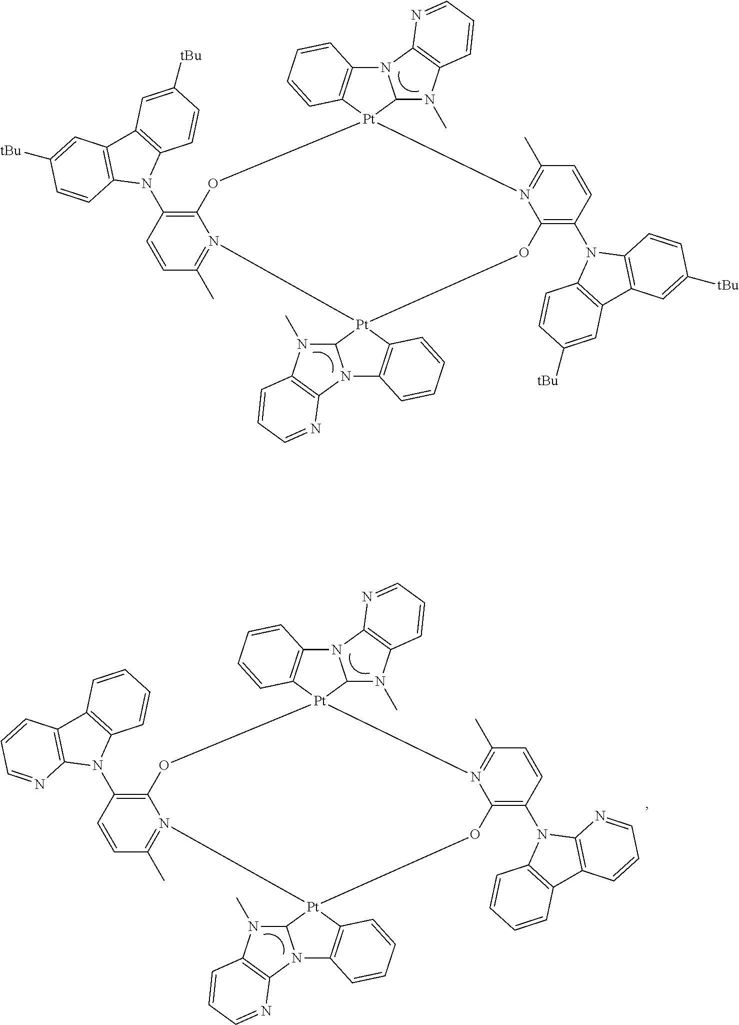

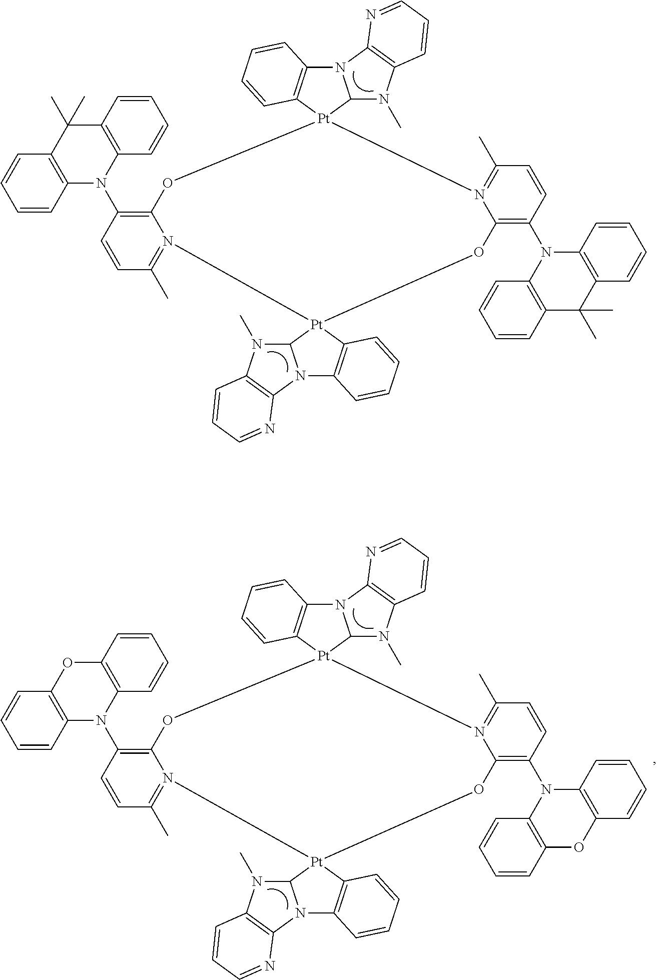

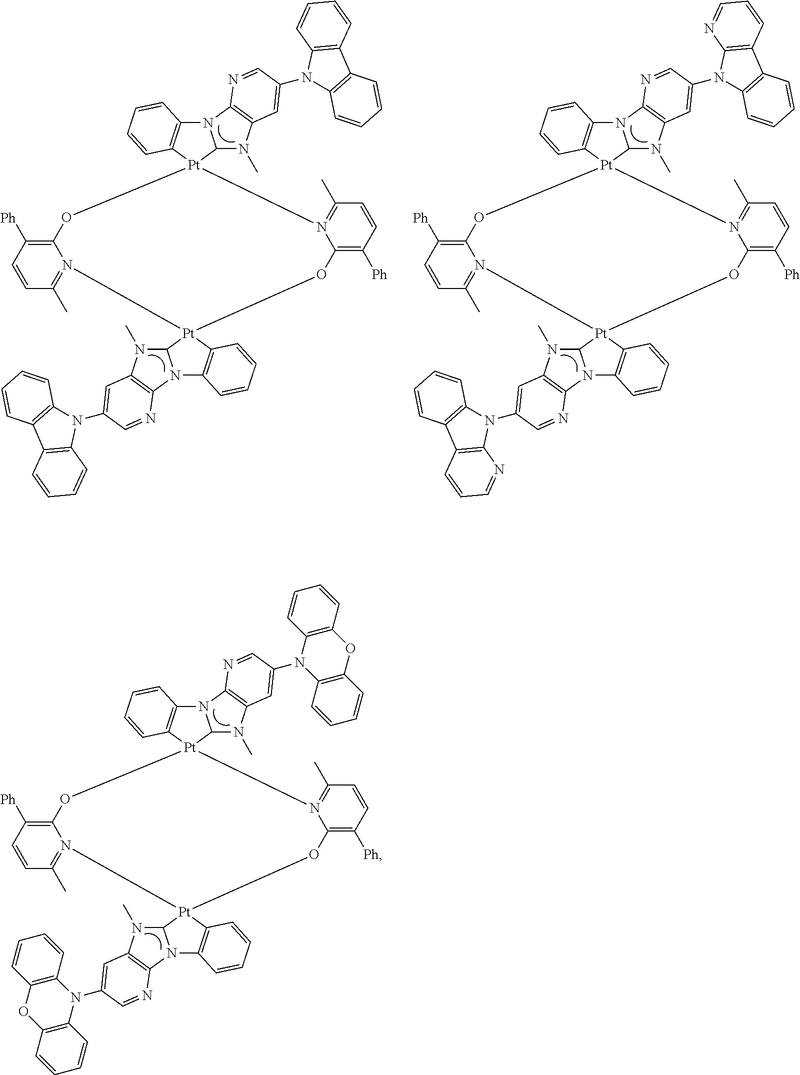

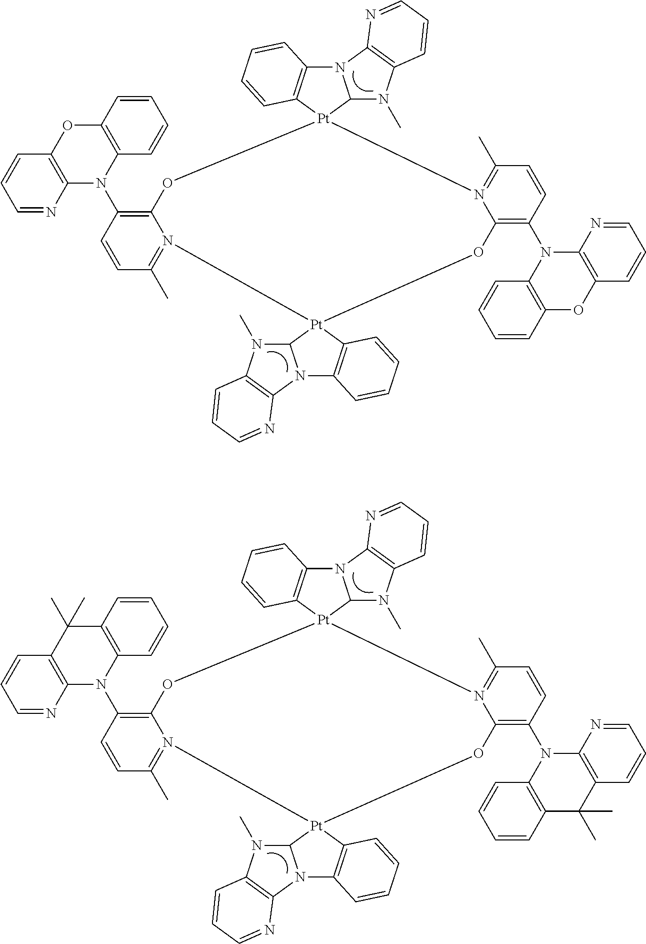

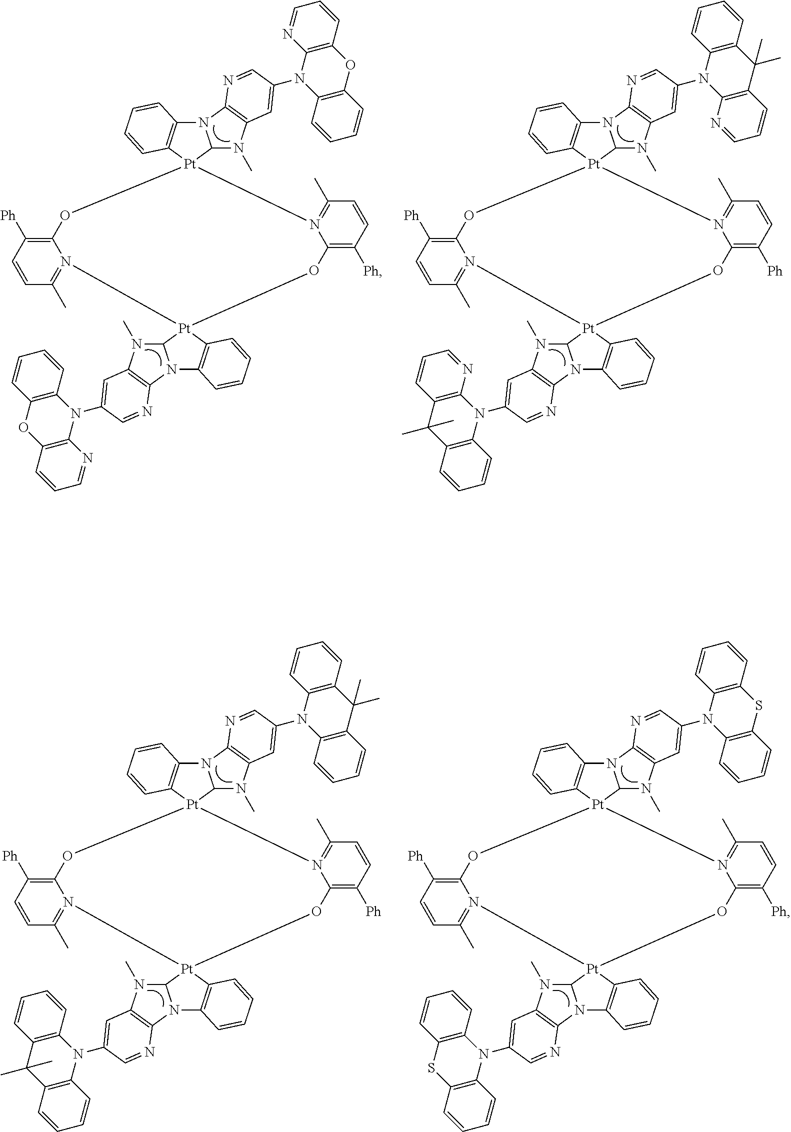

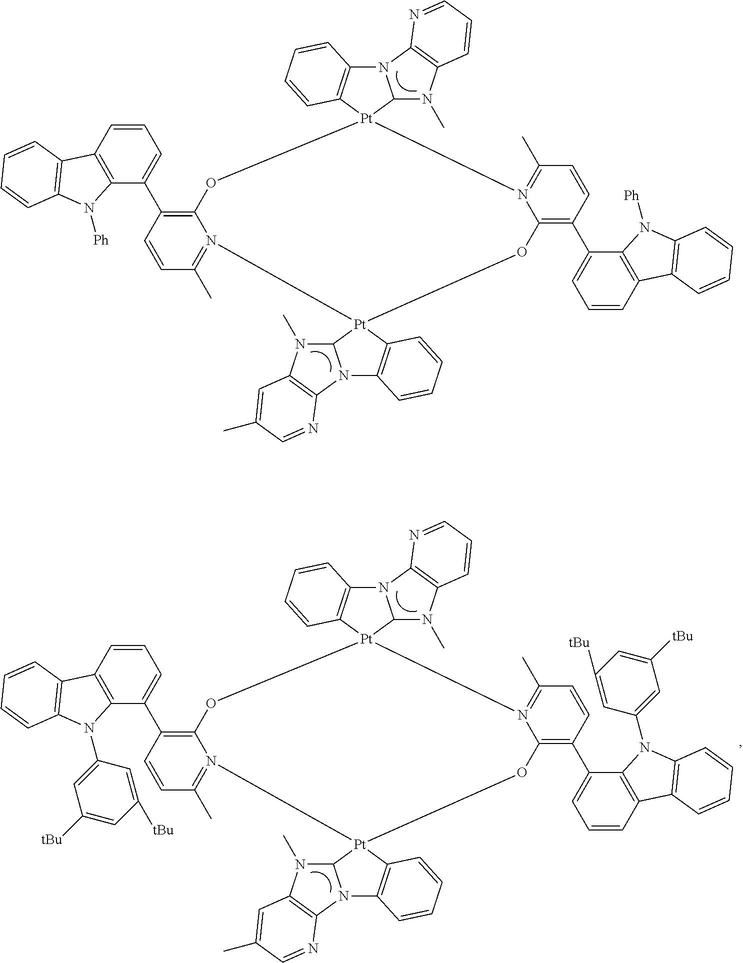

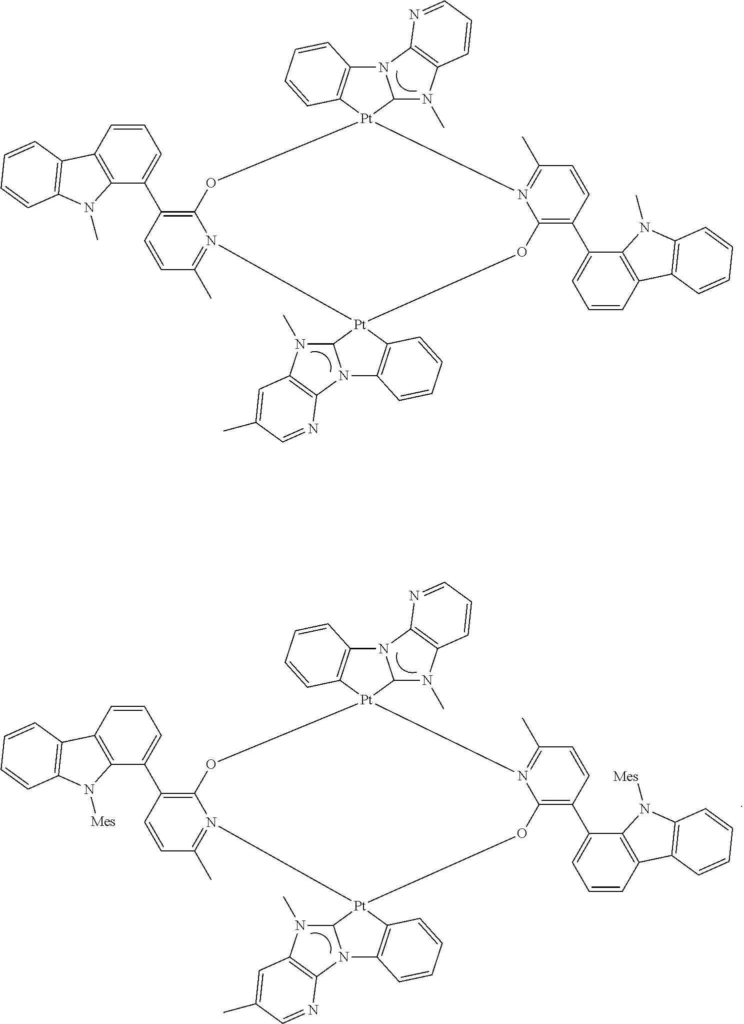

The photophysical properties of the dinuclear platinum(II) complexes disclosed herein can be evaluated by emission lifetime (“Tem” or “T”), radiative decay rate (“kᵣ”), non-radiative decay rate, emission quantum yield (“Φₑₘ”), and/or maximum emission wavelength (“λₘₐₓ”). Techniques for measuring the τₑₘ, kᵣ, kₙᵣ, Φₑₘ, and λₘₐₓ of the dinuclear platinum(II) complexes are known. For example, these parameters can be obtained by measuring the emission spectra of a platinum (II) complex. For example, based on the measured emission decay graph, the τₑₘ of the platinum (II) complex can be obtained as follows: (i) monitor the intensity of emission decay as a function of time using a Quanta Ray GCR 150-10 pulsed Nd:YAG laser system (pulse output: 355 nm), and (ii) determine the τₑₘ by fitting the exponential decay of formula (1) using Origin software, where I₀ is the initial emission intensity, I(t) is the emission intensity at time t, τ is the emission lifetime, and t is the time.

I(t)=I₀e^{-t/τ} formula (1)

The kᵣ of the platinum(II) complex can be obtained using kᵣ=Φₑₘ/τₑₘ. kᵣ=(1−Φₑₘ)/τₑₘ. The Φₑₘ values of these Pt complexes can be measured by known methods, such as direct measurements or relative methods. For example, the Φₑₘ of the disclosed dinuclear platinum(II) complexes in solutions or thin films, can be directly obtained by absolute measurement using Hamamatsu C11347 Quantaurus-QY Absolute PL quantum yield spectrometer (PL stands for photoluminescence). For example, the values for Φₑₘ are directly given by the software provided with the instrument. The λₘₐₓ of the dinuclear platinum(II) complexes can be directly measured from the emission spectra.

In some forms, the dinuclear platinum(II) complexes of any one of Formulae I-IV and Ia-IVa can have an emission lifetime (τₑₘ) of up to 2.5 μs, up to 2.0 μs, up to 1.9 μs, up to 1.8 μs, in a range from 0.5 μs to 2.5 μs, from 0.8 μs to 2.5 μs, from 1.0 μs to 2.5 μs, from 0.5 μs to 2.0 μs, from 0.8 μs to 2.0 μs, from 1.0 μs to 2.0 μs, from 0.5 μs to 1.9 μs, from 0.8 μs to 1.9 μs, from 1.0 μs to 1.9 μs, or from 1.2 μs to 1.9 μs, such as from 1.7 μs to 1.9 μs, in solution or in films at room temperature, such as obtained based on the emission spectra of the dinuclear platinum (II) complexes as described above.

In some forms, the dinuclear platinum(II) complexes of any one of Formulae I-IV and Ia-IVa can have a radiative decay rate (kᵣ) of at least 3.5×10⁵ s⁻¹, at least 4.0×10⁵ s⁻¹, at least 4.5×10⁵ s⁻¹, in a range from 3.5×10⁵ s⁻¹ to 10.0×10⁵ s⁻¹, from 3.5×10⁵ s⁻¹ to 8.0×10⁵ s⁻¹, from 3.5×10⁵ s⁻¹ to 6.0×10⁵ s⁻¹, from 3.5×10⁵ s⁻¹ to 5.5×10⁵ s⁻¹, from 4.0×10⁵ s⁻¹ to 10.0×10⁵ s⁻¹, from 4.0×10⁵ s⁻¹ to 8.0×10⁵ s⁻¹, from 4.0×10⁵ s⁻¹ to 6.0×10⁵ s⁻¹, from 4.0×10⁵ s⁻¹ to 5.5×10⁵ s⁻¹, from 4.2×10⁵ s⁻¹ to 10.0×10⁵ s⁻¹, from 4.2×10⁵ s⁻¹ to 8.0×10⁵ s⁻¹, from 4.2×10⁵ s⁻¹ to 6.0×10⁵ s⁻¹, or from 4.2×10⁵ s⁻¹ to 5.5×10⁵ s⁻¹, such as about 4.3×10⁵ s⁻¹ or about 5.5×10⁵ s⁻¹, in solution or in films at room temperature, such as obtained based on the emission spectra of the dinuclear platinum (II) complexes as described above.

In some forms, the dinuclear platinum(II) complexes of any one of Formulae I-IV and Ia-IVa can have a non-radiative decay rate (kₙᵣ) of up to 6.0×10⁵ s⁻¹, 5.0×10⁵ s⁻¹, 4.0×10⁵ s⁻¹, 3.0×10⁵ s⁻¹, 2.0×10⁵ s⁻¹, up to 1.8×10⁵ s⁻¹, up to 1.5×10⁵ s⁻¹, down to 0.15×10⁵ s⁻¹, in a range from 0.15×10⁵ s⁻¹ to 6.0×10⁵ s⁻¹, from 0.15×10⁵ s⁻¹ to 5.0×10⁵ s⁻¹, from 0.15×10⁵ s⁻¹ to 4.0×10⁵ s⁻¹, from 0.15×10⁵ s⁻¹ to 3.0×10⁵ s⁻¹, 0.15×10⁵ s⁻¹ to 2.0×10⁵ s⁻¹, from 0.16×10⁵ s⁻¹ to 2.0×10⁵ s⁻¹, from 0.15×10⁵ s⁻¹ to 1.8×10⁵ s⁻¹, from 0.16×10⁵ s⁻¹ to 1.8×10⁵ s⁻¹, from 0.15×10⁵ s⁻¹ to 1.6×10⁵ s⁻¹, from 0.16×10⁵ s⁻¹ to 1.6×10⁵ s⁻¹, from 0.15×10⁵ s⁻¹ to 1.5×10⁵ s⁻¹, such as from 0.16×10⁵ to 1.4×10⁵ s⁻¹, in solution or in films at room temperature, such as obtained based on the emission spectra of the dinuclear platinum (II) complexes as described above.

In some forms, the dinuclear platinum(II) complexes of any one of Formulae I-IV and Ia-IVa can have an emission quantum yield (Φₑₘ) of at least 60%, at least 65%, at least 70%, at least 75%, up to 99%, up to 98%, in a range from 60% to 97%, from 65% to 97%, from 70% to 97%, from 75% to 97%, from 65% to 99%, or from 75% to 99%, such as about 78% or about 97%, in solution or in films at room temperature, such as obtained based on the emission spectra of the dinuclear platinum(II) complexes as described above.

In some forms, the dinuclear platinum(II) complexes of any one of Formulae I-IV and Ia-IVa can have a maximum emission wavelength (λₘₐₓ) in a range from 600 nm to 1000 nm, from 600 nm to 900 nm, from 600 nm to 800 nm, from 600 nm to 760 nm, from 600 nm to 700 nm, from 600 nm to 680 nm, from 620 nm to 710 nm, or from 612 nm to 685 nm, obtained based on the emission spectra of the dinuclear platinum(II) complexes as described above. As used herein, near infrared (“Near-IR” or “NIR”) λₘₐₓ is in the range of 700 nm to 1000 nm, inclusive. As used herein, red λₘₐₓ is in the range of 600 nm to 700 nm, inclusive. A λₘₐₓ of exactly 700 nm can be considered either red or near infrared. However, in the context of a range of λₘₐₓ, whether 700 nm should be considered a near infrared λₘₐₓ or a red λₘₐₓ can be determined by whether 700 nm is the high endpoint or the low endpoint. In the context of a range of λₘₐₓ that spans below and above 700 nm, the range, and the 700 nm point, can be considered to encompass both red λₘₐₓ and near infrared λₘₐₓ.

In some forms, the dinuclear platinum(II) complexes of any one of Formulae I-IV and Ia-IVa can have a τₑₘ, a kᵣ, a kₙᵣ, a Φₑₘ, and/or a λₘₐₓ in any one of the above-described ranges.

Exemplary solutions suitable for measuring the τₑₘ, kᵣ, kₙᵣ, Φₑₘ, and/or λₘₐₓ of the dinuclear platinum(II) complexes include those that contain an organic solvent. Exemplary organic solvents suitable for use to form the measurement solutions include, but are not limited to, dichloromethane, chloroform, tetrahydrofuran, chlorobenzene, and toluene, and a combination thereof. Optionally, the solutions for measuring the τₑₘ, kᵣ, kₙᵣ, (Φₑₘ, and/or λₘₐₓ of the dinuclear platinum(II) complexes is degassed with an inert gas, such as nitrogen, argon, or helium, or a combination thereof. Optionally, the solutions for measuring the τₑₘ, kᵣ, kₙᵣ, Φₑₘ, and/or λₘₐₓ of the dinuclear platinum(II) complexes is deoxygenated by the known freeze-pump-thaw method.

Suitable thin films for measuring the τₑₘ, kᵣ, kₙᵣ, Φₑₘ, and/or λₘₐₓ of the dinuclear platinum(II) complexes include films having a thickness between 10 nm and 5 μm, inclusive, or between 10 nm and 200 nm, inclusive. The films can also contain organic compounds as hot materials. Exemplary organic compounds that can be used as a host material in the films include, but are not limited to, 1,3-bis(N-carbazolyl)benzene (mCP), 3,3′-di(9H-carbazol-9-yl)-1,1′-biphenyl (mCBP), poly(methyl methacrylate) (PMMA), polystyrene (PS), 2,8-bis(diphenylphosphoryl)dibenzo[b,d]furan (PPF), bis[2-(diphenylphosphino)phenyl]ether oxide (DPEPO).

B. Devices Containing Dinuclear Platinum(II) Complexes

Organic light-emitting components, such as light-emitting diodes (OLEDs) or light-emitting electrochemical cell (“LEEC”), containing one or more of the dinuclear platinum(II) complexes are described. In some forms, the organic light-emitting components also contain one or more organic dyes, such as multiple resonance red emitter (“MR—R1”). Other examples of organic light-emitting devices suitable for incorporation of the dinuclear platinum(II) complexes disclosed herein include, but are not limited to, light-emitting electrochemical cells (LEECs). Devices containing one or more OLEDs containing one or more of the dinuclear platinum(II) complexes include, but are not limited to, stationary visual display units, mobile visual display units, and illumination devices, such as smart phones, televisions, monitors, digital cameras, tablet computers, and lighting fixtures that usually operate at room temperatures, wearable devices, and medical monitoring devices.

In some forms, the dinuclear platinum(II) complexes can be incorporated in a light-emitting layer. The light-emitting layer further contains one or more organic dyes, such as MR—R1. When a dye is incorporated in the light-emitting layer, the dinuclear platinum(II) complexes and dye can have any suitable weight ratios, such as 20:1. In some forms, the one or more dinuclear platinum(II) complexes in the light emitting layer can act as a sensitizer to transfer energy to the organic dye. In some forms, the one or more dinuclear platinum(II) complexes in the light emitting layer can have a higher-lying singlet state than the organic dye.

In some forms, the light-emitting layer can be incorporated in an organic light-emitting component, such as an OLED. Organic light-emitting components can contain one or more light-emitting layers, where each light-emitting layer can contain one or more the disclosed dinuclear platinum(II) complexes. In some forms, the light-emitting layer or each light-emitting layer when two or more light-emitting layers are included in the organic light-emitting component further includes one or more host materials, such as those described above. Typically, the total concentration of the one or more host materials is greater than the total concentration of the one or more dinuclear platinum(II) complexes in the light-emitting layer or each light-emitting layer of the two or more light-emitting layers. The term “total concentration of the one or more dinuclear platinum(II) complexes” refers to the sum of the weight of the one or more dinuclear platinum(II) complexes relative to the sum of the weights of all of the materials used in one light-emitting layer in an organic light-emitting device, such as an OLED. The term “total concentration of the one or more one or more host materials” refers to the sum of the weight of the one or more host materials relative to the sum of the weights of all of the materials used in one light-emitting layer in an organic light-emitting device, such as an OLED.

The organic light-emitting devices can contain a suitable amount of the dinuclear platinum(II) complexes in the light-emitting layer or each light-emitting layer of the two or more light-emitting layers of the device. For example, the total concentration of the one or more dinuclear platinum(II) complexes in the light-emitting layer or each light-emitting layer of the two or more light-emitting layers is up to 50 wt %, up to 40 wt %, up to 30 wt %, up to 20 wt %, at least 1 wt %, in a range from about 1 wt % to about 50 wt %, from about 1 wt % to about 40 wt %, from about 1 wt % to about 30 wt %, from about 1 wt % to about 20 wt %, from about 2 wt % to about 50 wt %, from about 2 wt % to about 40 wt %, from about 2 wt % to about 30 wt %, from about 2 wt % to about 20 wt %, from about 4 wt % to about 50 wt %, from about 4 wt % to about 40 wt %, from about 4 wt % to about 30 wt %, from about 4 wt % to about 20 wt %, from about 1 wt % to about 16 wt %, from about 2 wt % to about 16 wt %, from about 4 wt % to about 16 wt %, such as about 4 wt %, about 8 wt %, or about 12 wt %.

In some forms, the organic light-emitting component, such as an OLED, can further include an anode, a cathode, a hole transport region, and/or an electron transport region. The hole transport region can include a hole injection layer and/or a hole transport layer, and optionally an electron blocking layer. The electron transport region can include an electron transport layer and/or an electron injection layer, and optionally a hole blocking layer. The light-emitting layer can be located in between the anode and the cathode. The hole transport region can be located in between the anode and the light-emitting layer. The electron transport region can be located in between the cathode and the light-emitting layer. The specific components and arrangement of the components in each of the hole transport region and the electron transport region depend on the specific use.

An exemplary OLED containing the disclosed dinuclear platinum(II) complexes is illustrated in FIG. 12. As shown in FIG. 12, the exemplary OLED 100 includes multiple layers, which are, from bottom to top, a substrate 101, an anode 102, a hole injection layer 103, a hole transport layer 104, an optional electron blocking layer 105, an emission layer 106, an optional hole blocking layer 107, an electron transport layer 108, an electron injection layer 109, and a cathode 110. The emission layer 106 is formed by one or more of the dinuclear platinum(II) complexes disclosed herein.

Suitable materials for forming the anode, the hole injection layer, the hole transport layer, the optional electron blocking layer, the optional hole blocking layer, the electron transport layer, the electron injection layer, and the cathode are known in the art, see, for example, those described in Hong, et al., Adv. Mater. 2021, 2005630; Lee, et al., InfoMat. 2021, 3, 61-81; and Jou, et al., J. Mater. Chem. C, 2015, 3, 2974-3002. The dimensions of each layer in the OLED, such as the shape, the length, the width, and/or the thickness of each layer can be varied depending on the specific use of the OLED. More specific exemplary OLEDs are described in the Examples below.

These organic light-emitting devices containing the disclosed dinuclear platinum(II) complexes can emit in the red to NIR regions (λₘₐₓ ranging from 610 nm to 1000 nm) with high efficiency (an Φₑₘ≥0.60 measured in thin films, such as about 0.81 or about 0.97; a τₑₘ≤2.5 μs, such as 1.7-1.9 μs; a kᵣ≥3.5×10⁵ s⁻¹, such as about 4.3×10⁵ s⁻¹ or about 5.5×10⁵ s⁻¹; and/or a kₙᵣ≤6×10⁵ s⁻¹, such as 0.16×10⁵-6×10⁵ s⁻¹ or 0.16×10⁵-1.4×10⁵ s⁻¹) at room temperature. The performance of OLEDs containing the disclosed dinuclear platinum(II) complexes can be evaluated using maximum brightness (L), maximum current efficiency (max CE), CE at 1000 cd m⁻², maximum power efficiency (max PE), PE at 1000 cd m⁻², maximum external quantum efficiency (max EQE), and/or EQE at 1000 cd m⁻². Techniques for measuring the brightness, current efficiency, power efficiency, and/or external quantum efficiency are known. For example, maximum brightness is measured at which any increase in voltage does not lead to an increase in brightness (the device may burn out if the voltage is further increased). For example, the EQE, CE, and PE of an electroluminescence device can be obtained by using a Keithley 2400 source-meter and an absolute external quantum efficiency measurement system (C9920-12, Hamamatsu Photonics), where all devices can be encapsulated in a 200-nm-thick Al₂O₃ thin film deposited by atomic layer deposition (ALD) in a Kurt J. Lesker SPECTROS ALD system before measurements.

In some forms, OLEDs containing from 4 wt % to 12 wt % of the disclosed dinuclear platinum(II) complexes can emit in the red to deep red region (λₘₐₓ in a range from about 600 nm to about 700 nm) with a maximum brightness (L) of at least 20000 cd m⁻², at least 25000 cd m⁻², at least 30000 cd m⁻², at least 35000 cd m⁻², at least 40000 cd m⁻², in a range from 20000 cd m⁻² to 100000 cd m⁻², from 25000 cd m⁻² to 100000 cd m⁻², from 30000 cd m⁻² to 100000 cd m⁻², from 35000 cd m⁻² to 100000 cd m⁻², from 40000 cd m⁻² to 100000 cd m⁻², from 20000 cd m⁻² to 80000 cd m⁻², from 25000 cd m⁻² to 80000 cd m⁻², from 30000 cd m⁻² to 80000 cd m⁻², from 35000 cd m⁻² to 80000 cd m⁻², from 40000 cd m⁻² to 80000 cd m⁻², from 20000 cd m⁻² to 60000 cd m⁻², from 25000 cd m⁻² to 60000 cd m⁻², from 30000 cd m⁻² to 60000 cd m⁻², from 35000 cd m⁻² to 60000 cd m⁻², from 40000 cd m⁻² to 60000 cd m⁻², from 20000 cd m⁻² to 50000 cd m⁻², from 25000 cd m⁻² to 50000 cd m⁻², from 30000 cd m⁻² to 50000 cd m⁻², from 35000 cd m⁻² to 50000 cd m⁻², or from 40000 cd m⁻² to 50000 cd m⁻².

In some forms, OLEDs containing from 4 wt % to 12 wt % of the disclosed dinuclear platinum(II) complexes can emit in the red to deep red region (λₘₐₓ in a range from about 600 nm to about 700 nm) with a CE at 1000 cd m⁻² of at least 20 cd/A, at least 22 cd/A, in a range from 20 cd/A to 60 cd/A, from 22 cd/A to 60 cd/A, from 20 cd/A to 50 cd/A, from 22 cd/A to 50 cd/A, from 20 cd/A to 40 cd/A, or from 20 cd/A to 30 cd/A.

In some forms, OLEDs containing from 4 wt % to 12 wt % of the disclosed dinuclear platinum(II) complexes can emit in the red to deep red region (λₘₐₓ in a range from about 600 nm to about 700 nm) with a PE at 1000 cd/m² of at least 10 1 m/W, in a range from 10 1 m/W to 60 1 m/W, from 15 1 m/W to 60 1 m/W, from 10 1 m/W to 50 1 m/W, from 15 1 m/W to 50 1 m/W, from 10 1 m/W to 40 1 m/W, from 15 1 m/W to 40 1 m/W, from 10 1 m/W to 30 1 m/W, from 15 1 m/W to 30 1 m/W, or from 10 1 m/W to 20 1 m/W.

In some forms, OLEDs containing from 4 wt % to 12 wt % of the disclosed dinuclear platinum(II) complexes can emit in the red to deep red region (λₘₐₓ in a range from about 600 nm to about 700 nm) with an EQE at 1000 cd/m² of at least 10%, at least 11%, at least 12%, at least 13%, at least 14%, at least 15%, in a range from 10% to 40%, from 10% to 20%, from 10% to 20%, from 11% to 40%, from 11% to 30%, from 11% to 20%, from 12% to 20%, from 12% to 40%, from 12% to 30%, from 13% to 20%, from 13% to 40%, from 13% to 30%, from 14% to 20%, from 14% to 40%, from 14% to 30%, from 15% to 40%, from 15% to 30%, or from 15% to 20%.

In some forms, OLEDs containing from 4 wt % to 12 wt % of the disclosed dinuclear platinum(II) complexes can emit in the red to deep red region (λₘₐₓ in a range from about 600 nm to about 700 nm) with a maximum brightness (L), a CE at 1000 cd m⁻², a PE at 1000 cd/m², and/or an EQE at 1000 cd/m² in any of the ranges described above.

In some forms, OLEDs containing from 4 wt % to 12 wt % of the disclosed dinuclear platinum(II) complexes can emit in the NIR region (λₘₐₓ in a range from about 700 nm to about 1000 nm) with a maximum brightness (L) of at least 1000 cd m⁻², at least 2000 cd m⁻² at least 3000 cd m⁻², at least 4000 cd m⁻², at least 4200 cd m⁻², at least 4500 cd m⁻², in a range from 1000 cd m⁻² to 40000 cd m⁻², from 1000 cd m⁻² to 40000 cd m⁻², from 1000 cd m⁻² to 40000 cd m⁻², from 4000 cd m⁻² to 40000 cd m⁻², from 4500 cd m⁻² to 40000 cd m⁻², from 1000 cd m⁻² to 30000 cd m⁻², from 2000 cd m⁻² to 30000 cd m⁻², from 3000 cd m⁻² to 30000 cd m⁻², from 4000 cd m⁻² to 30000 cd m⁻², from 4500 cd m⁻² to 30000 cd m⁻², from 1000 cd m⁻² to 20000 cd m⁻², from 2000 cd m⁻² to 20000 cd m⁻², from 3000 cd m⁻² to 20000 cd m⁻², from 4000 cd m⁻² to 20000 cd m⁻², from 4500 cd m⁻² to 20000 cd m⁻², from 1000 cd m⁻² to 10000 cd m⁻², from 2000 cd m⁻² to 10000 cd m⁻², from 3000 cd m⁻² to 10000 cd m⁻², from 4000 cd m⁻² to 10000 cd m⁻², or from 4500 cd m⁻² to 10000 cd m⁻².

In some forms, OLEDs containing from 4 wt % to 12 wt % of the disclosed dinuclear platinum(II) complexes can emit in the NIR region (λₘₐₓ in a range from about 700 nm to about 1000 nm) with a CE at 1000 cd m⁻² of at least 0.2 cd A⁻¹, at least 0.4 cd A⁻¹, at least 0.8 cd A⁻¹, in a range from 0.2 cd/A to 10 cd/A, from 0.4 cd/A to 10 cd/A, from 0.8 cd/A to 10 cd/A, from 0.2 cd/A to 8 cd/A, from 0.4 cd/A to 8 cd/A, from 0.8 cd/A to 8 cd/A, from 0.2 cd/A to 5 cd/A, from 0.4 cd/A to 5 cd/A, from 0.8 cd/A to 5 cd/A, from 0.2 cd/A to 3 cd/A, from 0.4 cd/A to 3 cd/A, from 0.8 cd/A to 3 cd/A, from 0.2 cd/A to 2 cd/A, from 0.4 cd/A to 2 cd/A, or from 0.8 cd/A to 2 cd/A.

In some forms, OLEDs containing from 4 wt % to 12 wt % of the disclosed dinuclear platinum(II) complexes can emit in the NIR region (λₘₐₓ in a range from about 700 nm to about 1000 nm) with a PE at 1000 cd/m² of at least 0.1 1 m/W, at least 0.2 1m/W, in a range from 0.1 1 m/W to 5 1 m/W, from 0.1 1 m/W to 4 1 m/W, from 0.1 1 m/W to 3 1 m/W, from 0.1 1 m/W to 2 1 m/W, from 0.1 1 m/W to 1 1 m/W, from 0.1 1 m/W to 0.5 1m/W, from 0.2 1 m/W to 5 1 m/W, from 0.2 1 m/W to 4 1 m/W, from 0.2 1 m/W to 3 1 m/W, from 0.2 1 m/W to 2 1 m/W, from 0.2 1 m/W to 1 1 m/W, or from 0.2 1 m/W to 0.5 1 m/W.

In some forms, OLEDs containing from 4 wt % to 12 wt % of the disclosed dinuclear platinum(II) complexes can emit in the NIR region (λₘₐₓ in a range from about 700 nm to about 1000 nm) with an EQE at 1000 cd/m² of at least 1%, at least 2%, at least 4%, at least 5%, at least 6%, in a range from 1% to 20%, from 1% to 18%, from 1% to 15%, from 1% to 10%, from 2% to 20%, from 2% to 18%, from 2% to 15%, from 2% to 10%, from 4% to 20%, from 4% to 18%, from 4% to 15%, from 4% to 10%, from 5% to 20%, from 5% to 18%, from 5% to 15%, or from 5% to 10%.

In some forms, OLEDs containing from 4 wt % to 12 wt % of the disclosed dinuclear platinum(II) complexes can emit in the NIR region (λₘₐₓ in a range from about 700 nm to about 1000 nm) with a maximum brightness (L), a CE at 1000 cd m⁻², a PE at 1000 cd/m², and/or an EQE at 1000 cd/m² in any of the ranges described above.

More specific examples of the maximum brightness, current efficiency, power efficiency, and external quantum efficiency of exemplary OLEDs containing exemplary dinuclear platinum(II) complexes disclosed herein are described in the Examples below.

### III. Methods of Making and Reagents Therefor

A. Dinuclear Platinum (II) Complexes

The dinuclear platinum(II) complexes and the ligands described herein can be synthesized using methods known in the art of organic chemical synthesis. For example, ligands can be purchased from commercial chemical manufacturers or may be prepared according to procedures reported and/or adapted from the literature. In some forms, 2-hydroxy-pyridine ligands described herein and used in the examples below can be readily obtained from commercial chemical manufacturers. Exemplary syntheses of imidazolyl N-heterocyclic carbene ligands are described in the Examples below. The selection of appropriate synthetic conditions, reagents, reaction workup conditions, purification techniques (as needed) are known to those in the field of synthesis. Exemplary and non-limiting syntheses of ligands and dinuclear platinum(II) complexes are discussed in the Examples below.

B. Organic Light-Emitting Components

Also described are methods of making organic light-emitting components, such as OLEDs, containing one or more dinuclear platinum(II) complexes described herein. Methods of preparing OLEDs containing one or more dinuclear platinum(II) emitter complexes, as described above, are well-known in the art of organic electronics. Such method of making OLEDs can involve vacuum deposition or solution processing techniques, such as spin-coating and ink-jet printing. The selection of suitable materials (anode, cathode, hole transport layer, electron transport layer, etc.) and fabrication parameters (such as deposition conditions or solvent selections) needed to fabricate OLEDs containing the dinuclear platinum(II) complexes described herein are known in the art. In some forms, preparation of the OLEDs can be via vacuum deposition or solution processing techniques such as spin-coating and ink printing (such as, ink-jet printing or roll-to-roll printing). An exemplary and non-limiting method of making an OLED containing one or more dinuclear platinum(II) complexes described herein is disclosed in the Examples.

### IV. Methods of Using

The dinuclear platinum(II) complexes described herein are emissive in the red to NIR spectral region (λₘₐₓ at 610-1000 nm, such as 612-685 nm), with a high emission quantum yield (i.e. Φₑₘ≥0.60 measured in thin films, such as about 0.78 or about 0.97), a short emission lifetime (i.e. τₑₘ≤2.5 μs, such as 1.7-1.9 μs), a fast radiative decay rate (i.e. kᵣ≥4.5×10⁵ s⁻¹, such as about 4.3×10⁵ s⁻¹ or about 5.5×10⁵ s⁻¹), and/or a slow non-radiative decay rate (i.e. kₙᵣ≤2×10⁵ s⁻¹, such as 0.16×10⁵-1.4×10⁵ s⁻¹), at room temperature or other low temperatures, such as at a temperature in the range from 285 K to 300 K. Accordingly, the dinuclear platinum(II) emitters complexes can be incorporated into organic electronic components including, but not limited to, OLEDs or a light-emitting electrochemical cell (LEEC). Such OLEDs can be used in commercial applications such smart phones, televisions, monitors, digital cameras, tablet computers, lighting fixtures that usually operate at room temperatures, a fixed visual display unit, mobile visual display unit, illumination unit, keyboard, clothes, ornaments, garment accessary, wearable devices, medical monitoring devices, wall paper, tablet PC, laptop, advertisement panel, panel display unit, household appliances, and office appliances.

The disclosed compositions and methods can be further understood through the following numbered paragraphs.

Paragraph 1. A dinuclear platinum(II) complex having a structure:

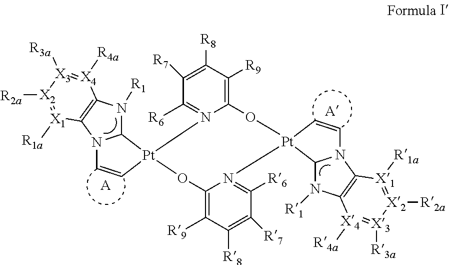

wherein:
(i) the complex is an overall neutral, negative, or positive charge;
(ii) X₁-X₄ and X′₁-X′₄ are independently carbon, nitrogen, sulfur, or oxygen;
(iii) R₁ₐ-R₄ₐ, R′₁ₐ-R′₄ₐ, R₁, R′₁, R₆-R₉, and R′₆-R′₉ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, unsubstituted C₂-C₂₀ heterocyclyl, borenium cation, phosphonyl, sulfinyl, or sulfonyl, or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, fused combinations thereof, or Ria and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof;
(iv) A and A′ are independently a substituted cycloalkyl, an unsubstituted cycloalkyl, a substituted cycloalkenyl, an unsubstituted cycloalkenyl, a substituted cycloalkynyl, an unsubstituted cycloalkynyl, a substituted heterocyclyl, an unsubstituted heterocyclyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, or fused combinations thereof; preferably A and A′ are independently a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; and
(v) each substituent is independently a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a carbonyl, an alkoxy, a halogen, a hydroxyl, a phenoxy, a thiol, an alkylthio, a phenylthio, an arylthio, a cyano, an isocyano, a nitro, a carboxyl, an amino, an amido, an oxo, a silyl, a sulfinyl, a sulfonyl, a sulfonic acid, a phosphonium, a phosphanyl, a phosphoryl, or a phosphonyl.

Paragraph 2. The dinuclear platinum(II) complex of paragraph 1, wherein the dinuclear platinum(II) has a structure:

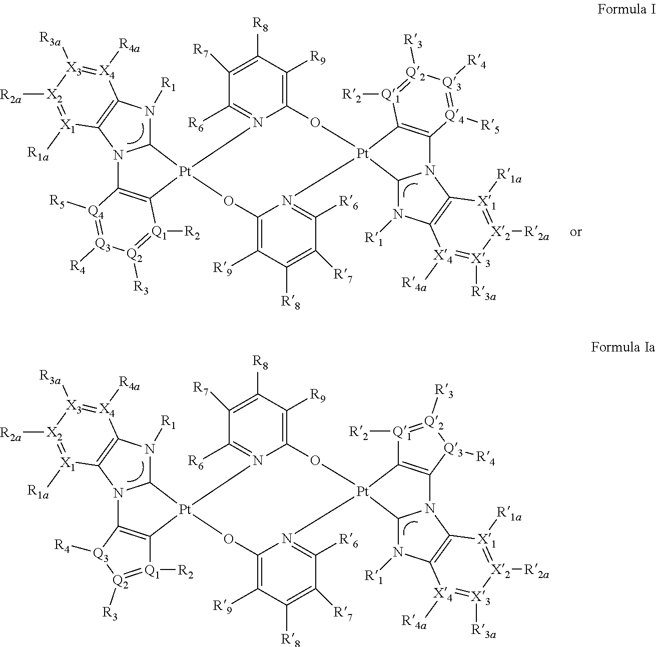

wherein:
(i) the complex has an overall neutral, negative, or positive charge;
(ii) Q₁-Q₄ and Q′₁-Q′₄ are independently carbon, nitrogen, sulfur, or oxygen; and (iii) R₂-R₅ and R′₂-R′₅ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl, borenium cation, phosphonyl, sulfinyl, or sulfonyl, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, fused combinations thereof, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof.

Paragraph 3. The complex of paragraph 1 or 2, wherein the complex has a structure:

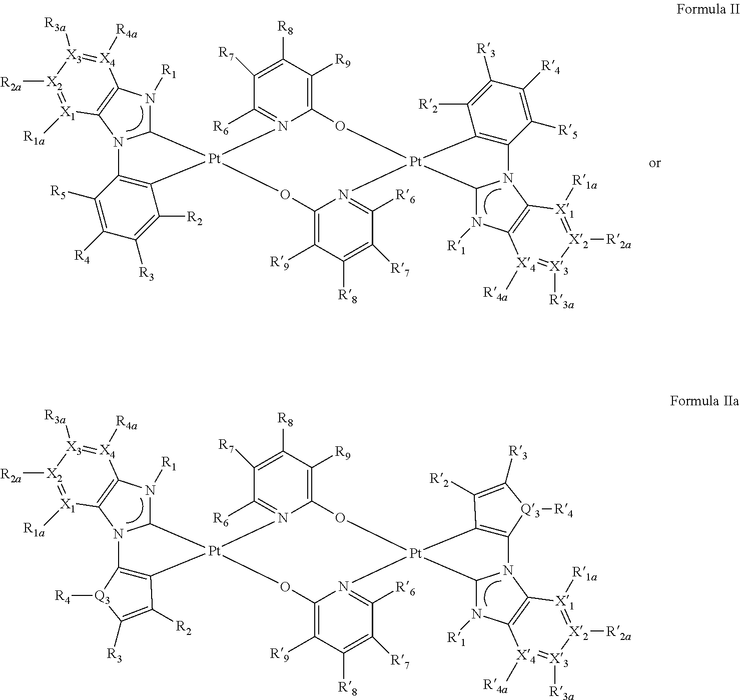

Paragraph 4. The complex of any one of paragraphs 1-3, wherein the complex has the structure:

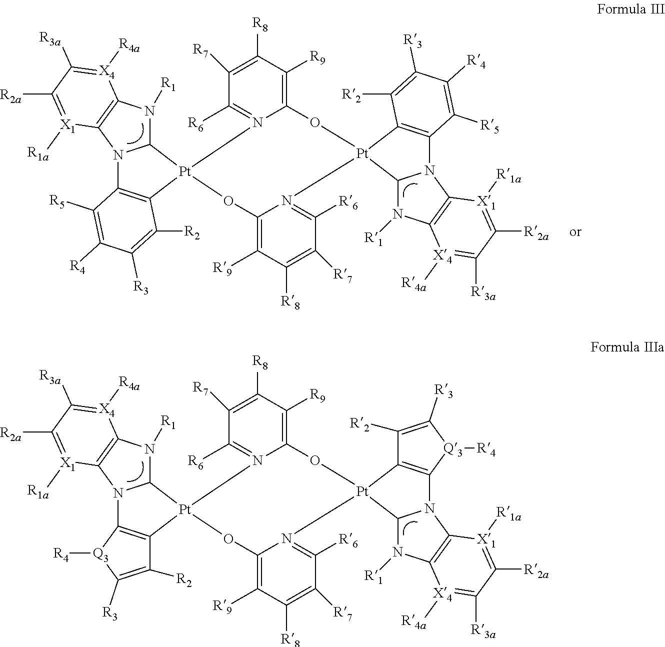

Paragraph 5. The complex of any one of paragraphs 1-4, wherein the complex has the structure:

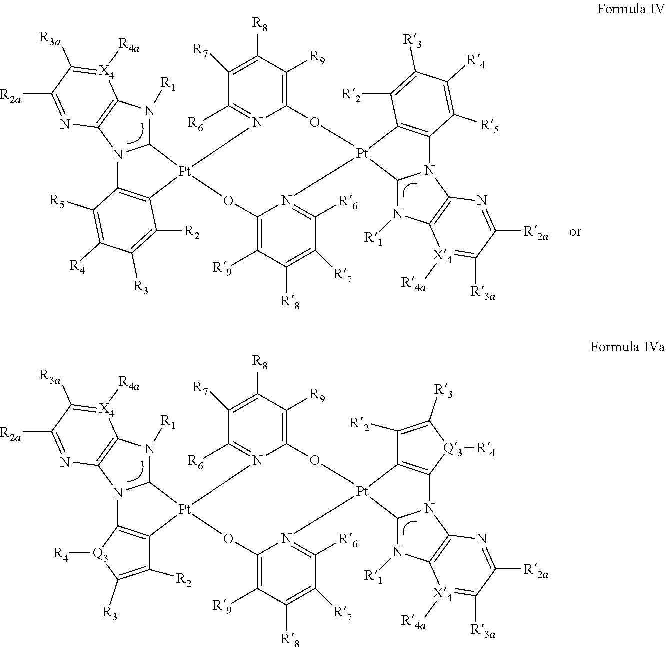

Paragraph 6. The complex of any one of paragraphs 1-5, wherein X₄ and X′₄ are carbon; and R₄ₐ and R′₄ₐ are independently hydrogen, substituted alkyl, unsubstituted alkyl, substituted aryl, unsubstituted aryl, hydroxyl, unsubstituted heteroaryl, substituted heteroaryl, unsubstituted polyaryl, substituted polyaryl, unsubstituted polyheteroaryl, substituted polyheteroaryl, substituted C₂-C₂₀ heterocyclyl, or unsubstituted C₂-C₂₀ heterocyclyl.

Paragraph 7. The complex of paragraph 6, wherein X₄ and X′₄ are carbon and R₄ₐ and R′₄ₐ are independently hydrogen, unsubstituted alkyl, unsubstituted aryl, unsubstituted polyaryl, hydroxyl, unsubstituted heteroaryl, unsubstituted polyheteroaryl, unsubstituted C₂-C₂₀ heterocyclyl, or unsubstituted alkylaryl, such as hydrogen.

Paragraph 8. The complex of any one of paragraphs 1-5, wherein X₄ and X′₄ are nitrogen; R₄ₐ and R′₄ₐ are absent, and optionally wherein R₂ₐ, R₃ₐ, R′₂ₐ, and R′₃ₐ are independently hydrogen, unsubstituted alkyl (e.g., methyl, ethyl, n-propyl, isopropyl, n-butyl, sec-butyl, isobutyl, tert-butyl, etc.), substituted alkyl, unsubstituted aryl (e.g., unsubstituted phenyl), or alkoxy (e.g., —O-alkyl, —O-aryl, —O-polyaryl, etc.), or R₂ₐ and R₃ₐ together and/or R′₂ₐ and R′₃ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl.

Paragraph 9. The complex of any one of paragraphs 1-4, wherein X₁-X₄ and X′₁-X′₄ are carbon; and R₁ₐ-R₄ₐ and R′₁ₐ-R′₄ₐ are independently hydrogen, unsubstituted alkyl (e.g., methyl, ethyl, n-propyl, isopropyl, n-butyl, sec-butyl, isobutyl, tert-butyl, etc.), substituted alkyl, unsubstituted aryl (e.g., unsubstituted phenyl), or alkoxy (e.g., —O-alkyl, —O-aryl, —O-polyaryl, etc.), or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, and/or R′₃ₐ and R′₄ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl, for example, R₁ₐ and R₂ₐ together, R₃ₐ and R₄ₐ together, R′₁ₐ and R′₂ₐ together, and R′₃ₐ and R′₄ₐ together, with the atom to which they are attached, form a substituted aryl or unsubstituted aryl, or R₂ₐ and R₃ₐ together and R′₂ₐ and R′₃ₐ together, with the atom to which they are attached, form a substituted aryl or unsubstituted aryl.

Paragraph 10. The complex of any one of paragraphs 2-9, wherein R₁-R₉ and R′₁-R′₉ are independently hydrogen, halogen, unsubstituted alkyl (e.g., methyl, ethyl, n-propyl, isopropyl, n-butyl, sec-butyl, isobutyl, tert-butyl, etc.), substituted alkyl, unsubstituted aryl, substituted aryl (e.g., mesitylene or other aryl substituted with one or more alkyls, such as methyl, ethyl, n-propyl, isopropyl, n-butyl, sec-butyl, isobutyl, tert-butyl, etc.), unsubstituted polyaryl, substituted polyaryl, hydroxyl, unsubstituted heteroaryl, substituted heteroaryl, unsubstituted polyheteroaryl, substituted polyheteroaryl, unsubstituted C₂-C₂₀ heterocyclyl, substituted C₂-C₂₀ heterocyclyl, unsubstituted alkylaryl, substituted alkylaryl, alkoxy (e.g., —O-alkyl, —O-aryl, —O— polyaryl, etc.), borenium cation (e.g., —B(Mes)₂), phosphonyl (e.g., —P(═O)(Ph)₂, —P(═O)(alkyl)₂, etc.), or sulfinyl (e.g., —S(═O)(Ph)₂, —S(═O)(alkyl)₂, etc.), or sulfonyl —S(═O)₂(Ph)₂, —S(═O)₂(alkyl)₂, etc.), or R₂ and R₃ together, R′₂ and R′₃ together, R₃ and R₄ together, R′₃ and R′₄ together, R₄ and R₅ together, R′₄ and R′₅ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof.

Paragraph 11. The complex of paragraph 10, wherein one or more of R₁-R₉ and R′₁-R′₉ is

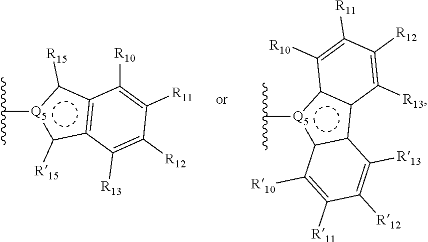

wherein Q₅ is nitrogen or carbon; and R₁₀-R₁₃, R₁₅, R′₁₅, and R′₁₀-R′₁₃ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl, such as hydrogen or unsubstituted alkyl.

Paragraph 12. The complex of paragraph 11, wherein Q₅ is nitrogen; and R₁₀-R₁₃, R₁₅, R′₁₅, and R′₁₀-R′₁₃ are independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen.

Paragraph 13. The complex of any one of paragraphs 2-12, wherein: (i) R₂ and R₃ together and/or R′₂ and R′₃ together, or (ii) R₃ and R₄ together and/or R′₃ and R′₄ together, or (iii) R₄ and R₅ together and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl.

Paragraph 14. The complex of paragraph 13, wherein: (i) R₂ and R₃ together and/or R′₂ and R′₃ together, or (ii) R₃ and R₄ together and/or R′₃ and R′₄ together, or (iii) R₄ and R₅ together and/or R′₄ and R′₅ together, form

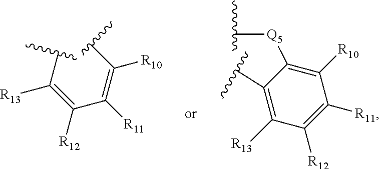

wherein Q₅ is NR₁₄, CR₁₆R₁₇, or sulfur, or oxygen; and R₁₀-R₁₄, R₁₆, and R₁₇ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl, optionally wherein Q₅ is NR₁₄, CR₁₆R₁₇, sulfur, or oxygen, such as oxygen; and R₁₀-R₁₄, R₁₆, and R₁₇ are independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen.

Paragraph 15. The complex of any one of paragraphs 2-14, wherein R₆-R₉ and R′₆-R′₉, are independently hydrogen, halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), phosphonyl (e.g., —P(═O)(Ph)₂, —P(═O)(alkyl)₂, etc.), substituted heteroaryl, or unsubstituted heteroaryl, or R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl or an unsubstituted aryl, such as a substituted phenyl or unsubstituted phenyl, optionally wherein at least one of R₆-R₉ and at least one of R′₆-R′₉ are not hydrogen.

Paragraph 16. The complex of any one of paragraphs 2-15, wherein Q₃ and Q′₃ of Formulae Ia-IVa are independently sulfur or oxygen.

Paragraph 17. The complex of any one of paragraphs 2-12, 15, and 16, wherein R₂, R₄, R₅, R′₂, R′₄, R′₅, R₇, R₈, R′₇, and R′₈ are hydrogen; and R₁, R₃, R₆, R₉, R′₁, R′₃, R′₆, and R′₉ are independently hydrogen, halogen, unsubstituted alkyl, unsubstituted aryl, substituted aryl (e.g., aryl substituted with one or more alkyls, such as methyl, ethyl, n-propyl, isopropyl, n-butyl, sec-butyl, isobutyl, tert-butyl, etc.), hydroxyl, unsubstituted heteroaryl (e.g., carbazolyl, fluorenyl, indenyl, indolyl, etc.), unsubstituted polyheteroaryl, unsubstituted C₂-C₂₀ heterocyclyl, unsubstituted alkylaryl, alkoxy (e.g., —O-alkyl such as methoxy, ethoxy, and phenoxy, —O-aryl, —O-polyaryl, etc.), borenium cation (e.g., —B(Mes)₂), phosphonyl (e.g. —P(═O)(Ph)₂), sulfinyl (e.g., —S(═O)(Ph)₂, —S(═O)(alkyl)₂, etc.), or sulfonyl —S(═O)₂(Ph)₂, —S(═O)₂(alkyl)₂, etc.), such as halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), or phosphonyl (e.g., —P(═O)(Ph)₂, —P(═O)(alkyl)₂, etc.).

Paragraph 18. The complex of paragraph 17, wherein R₁, R₆, R₉, R′₁, R′₆, and R′₉ are independently unsubstituted alkyl, unsubstituted aryl, or substituted aryl (e.g., phenyl substituted with one or more C₁-C₆ alkyls).

Paragraph 19. The complex of any one of paragraphs 1-18, wherein the complex has any one of the structures:

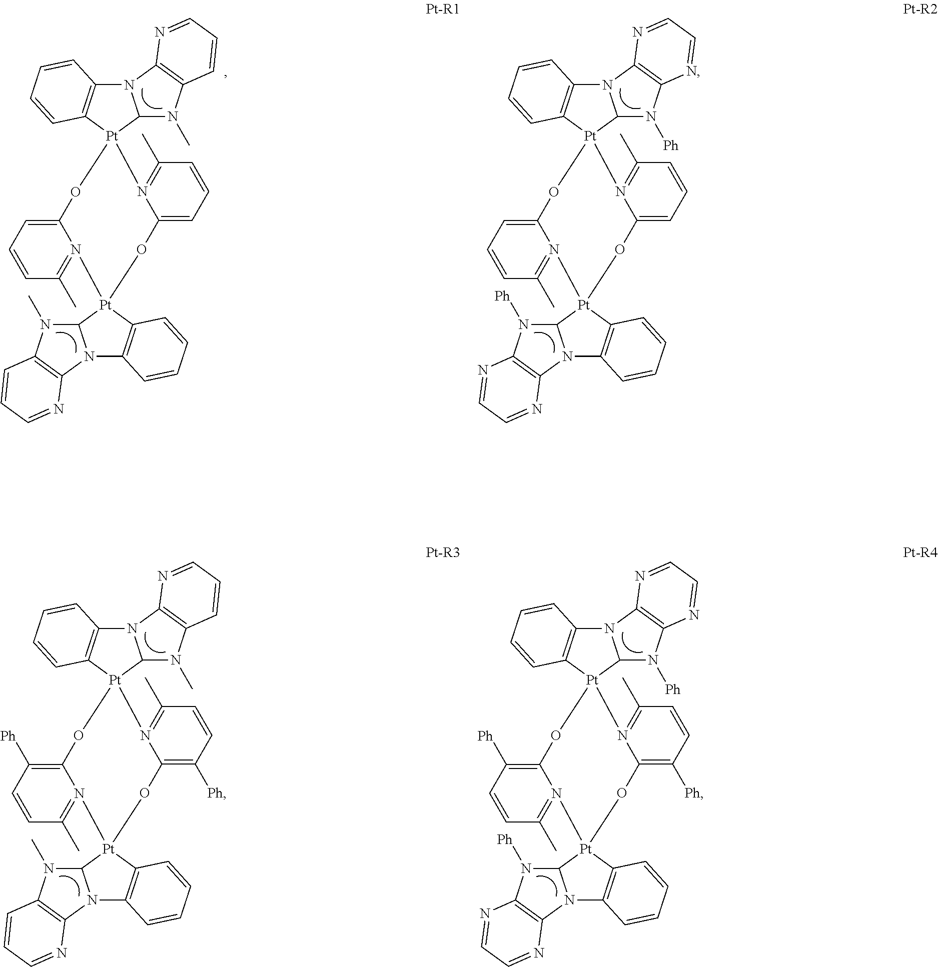

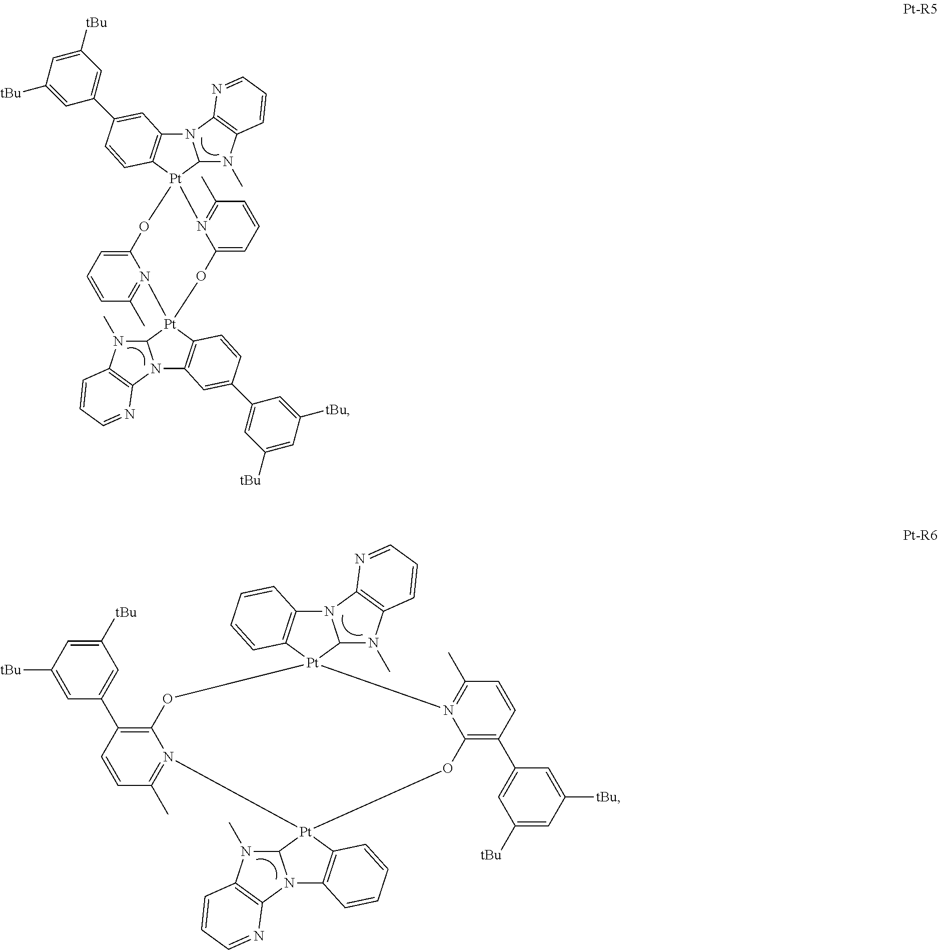

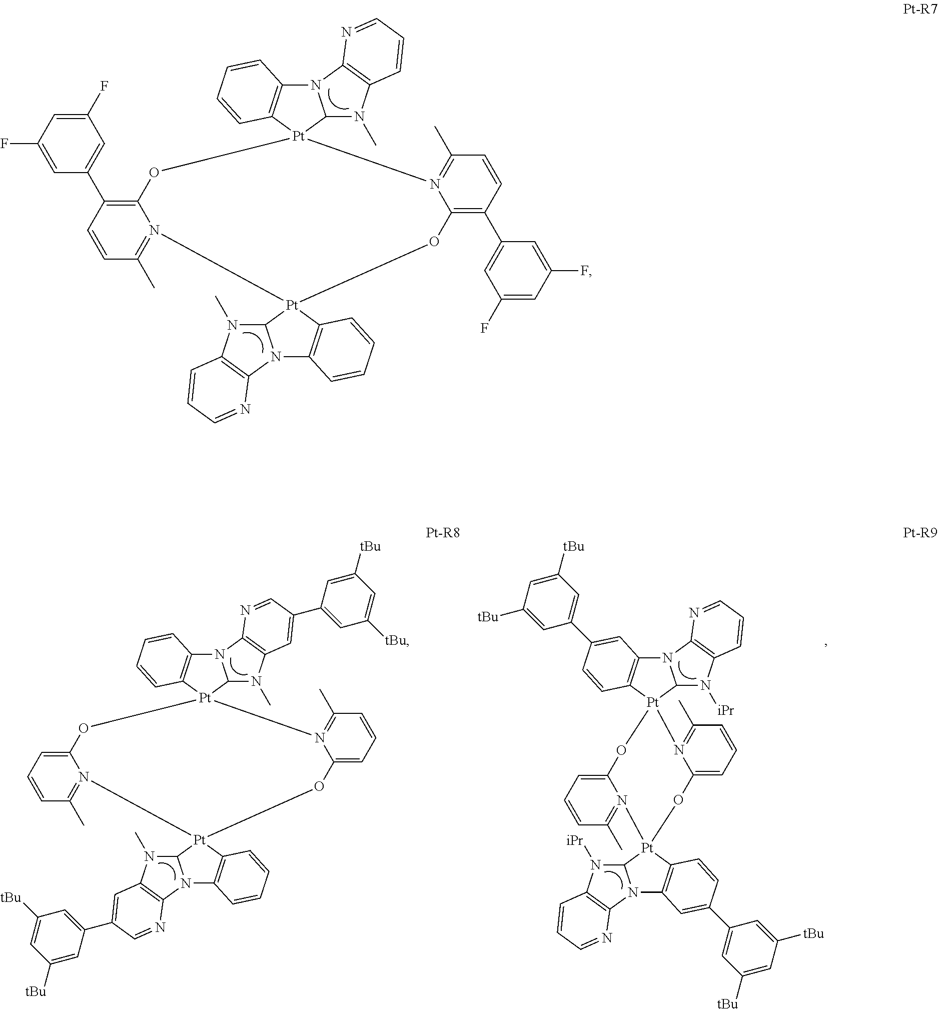

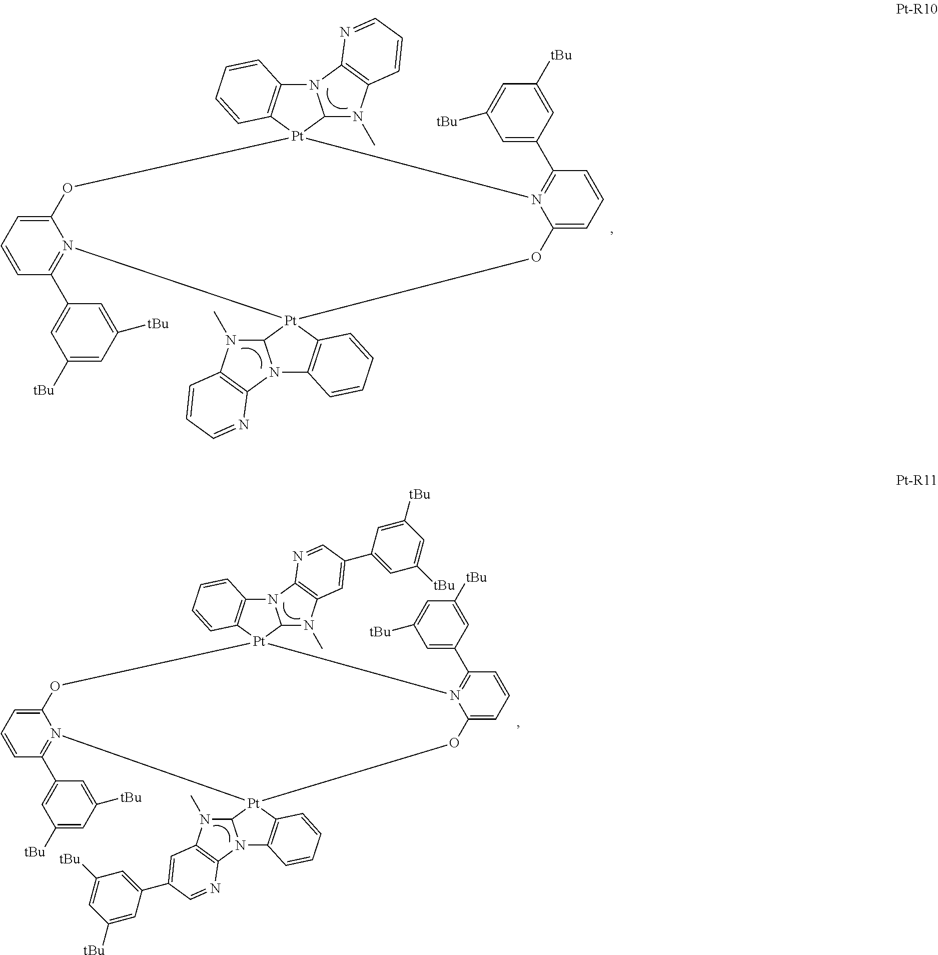

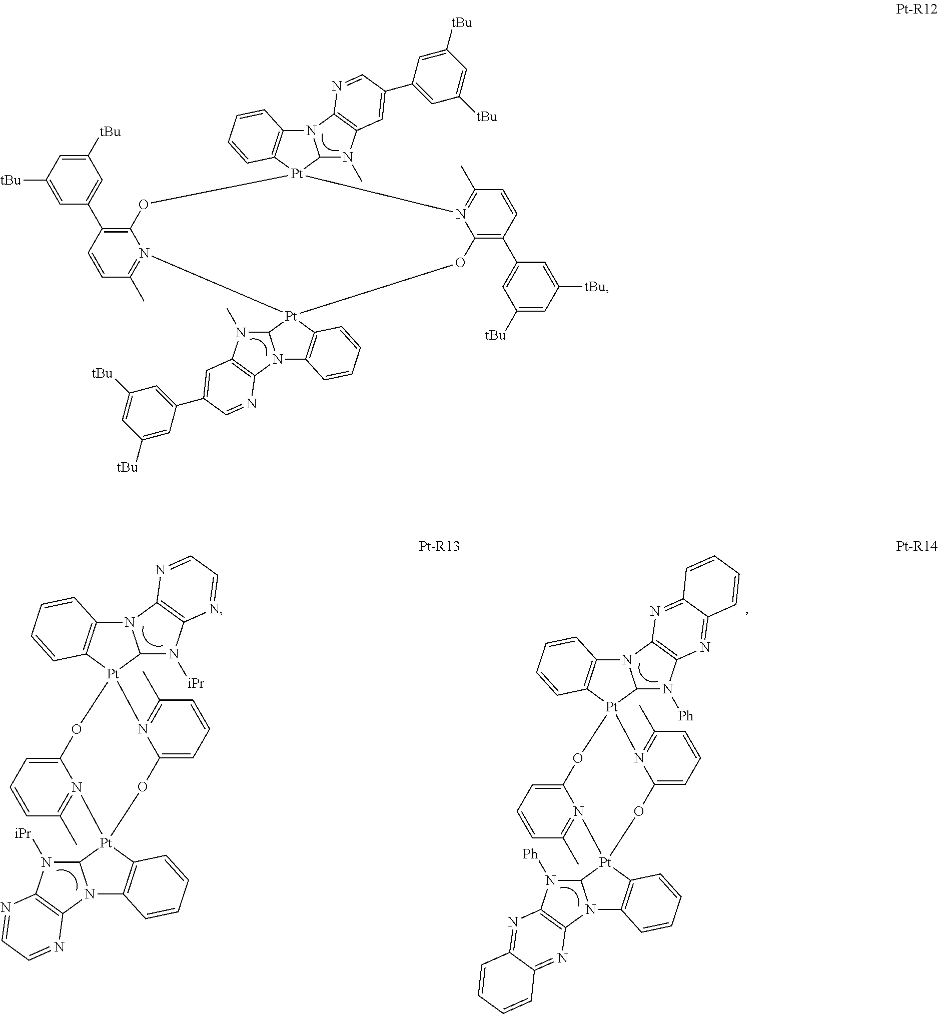

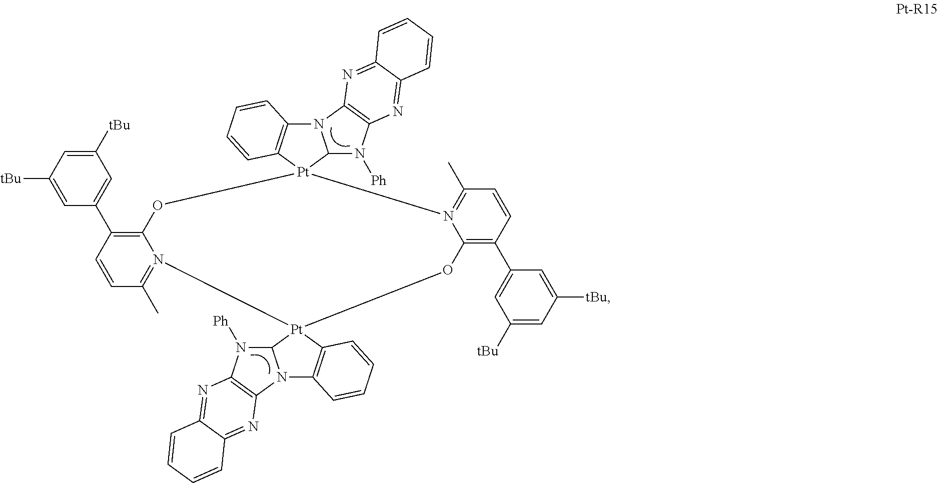

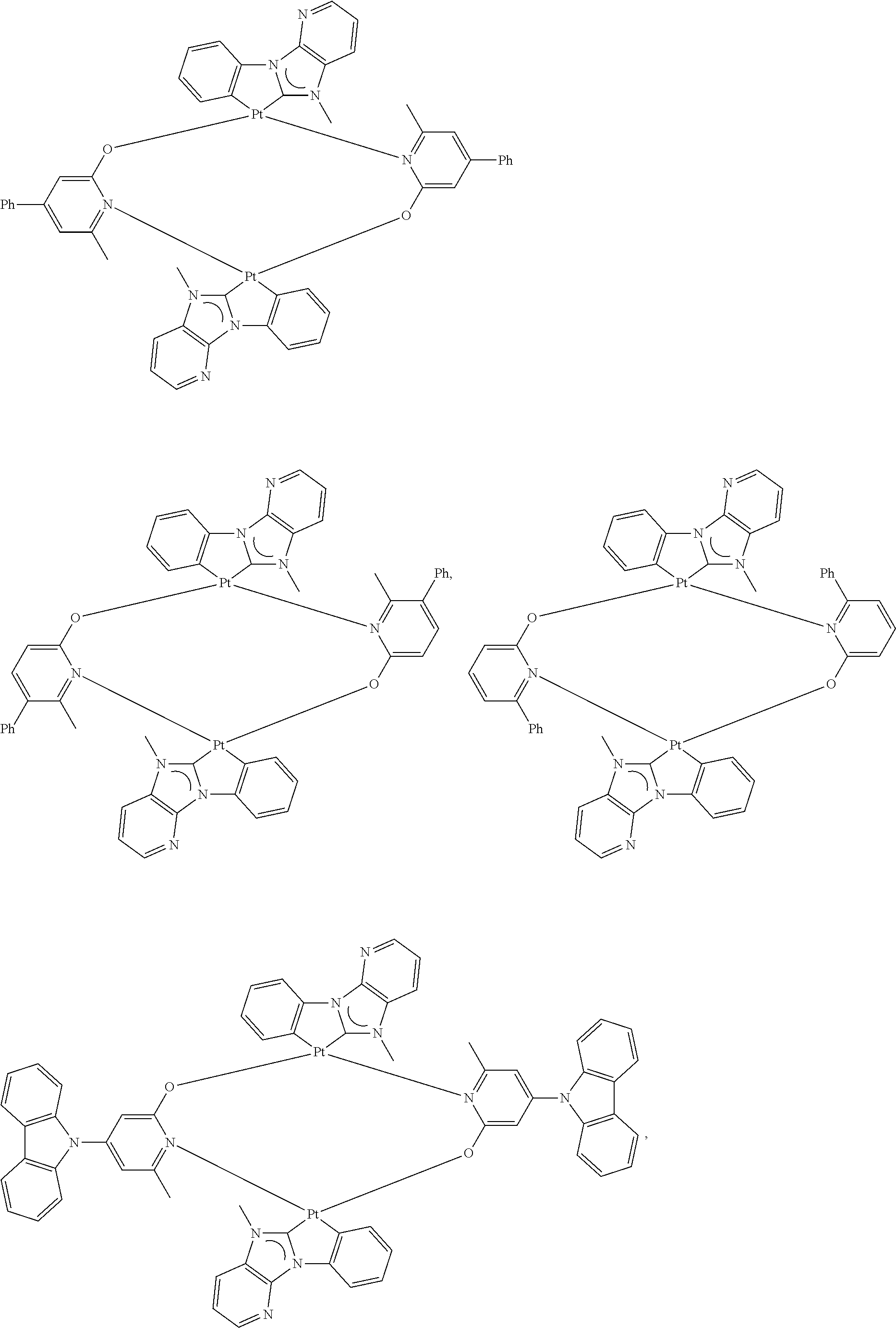

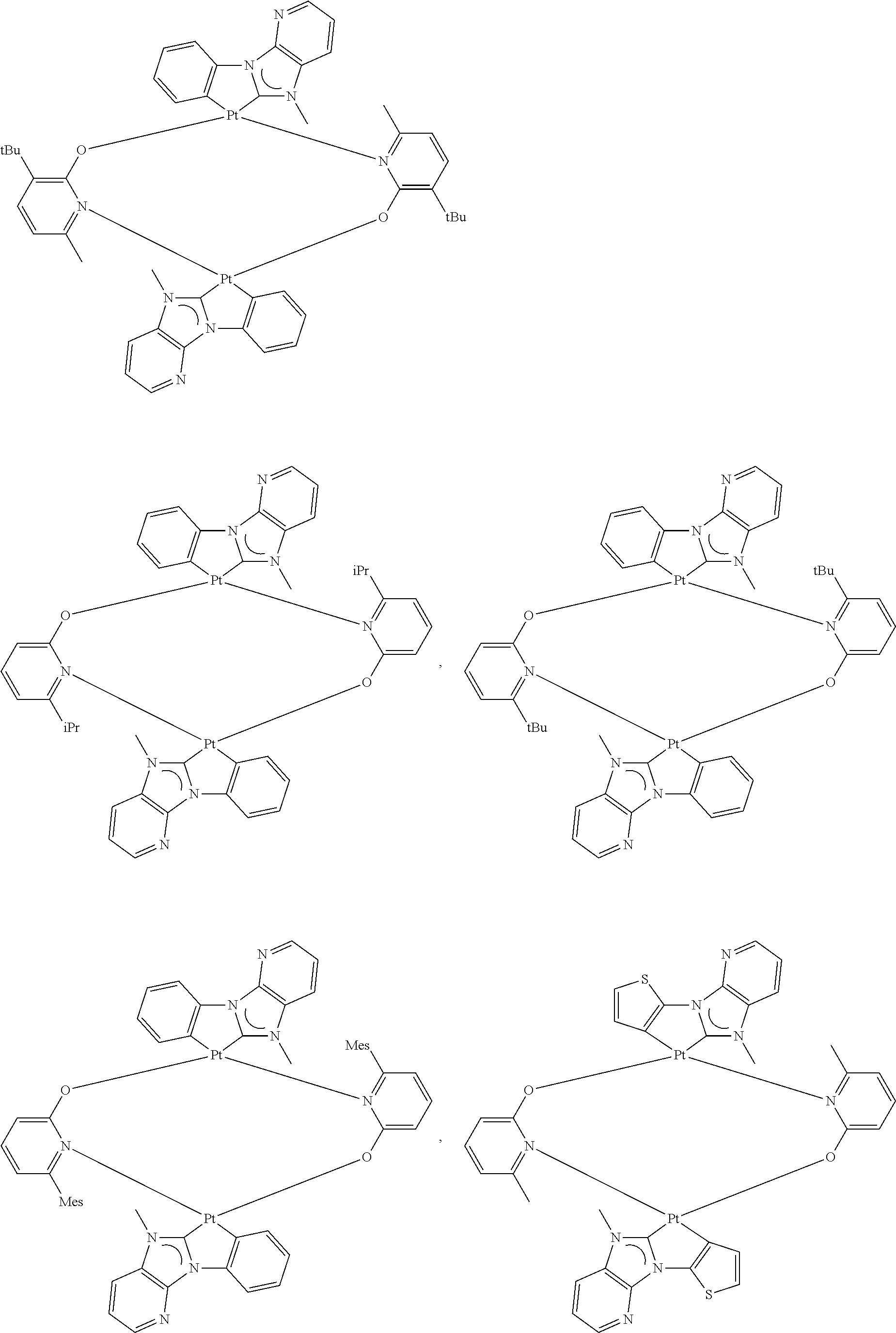

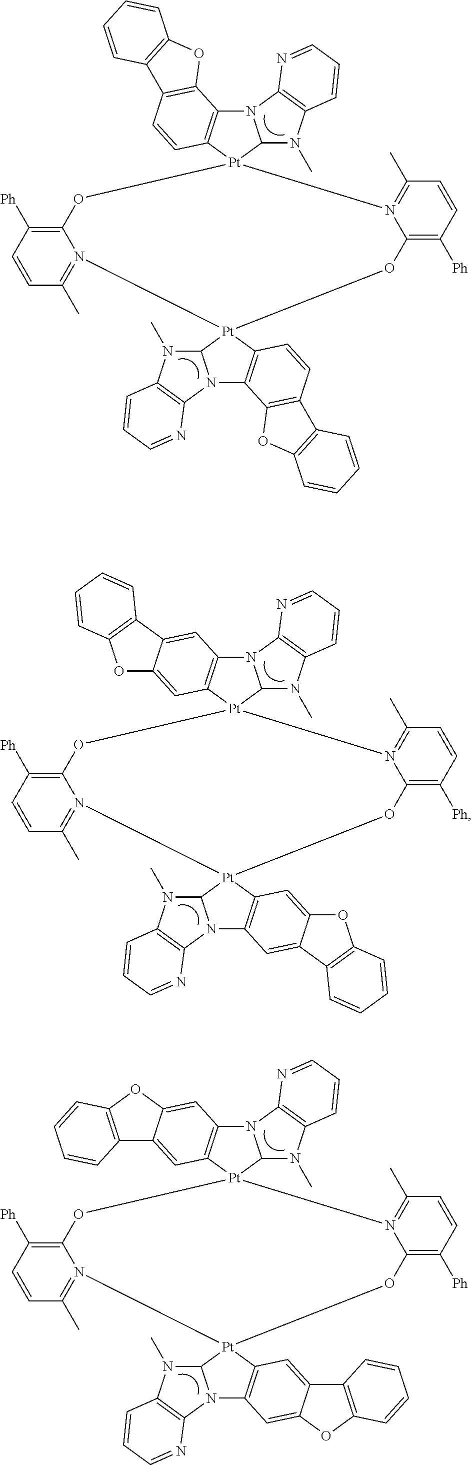

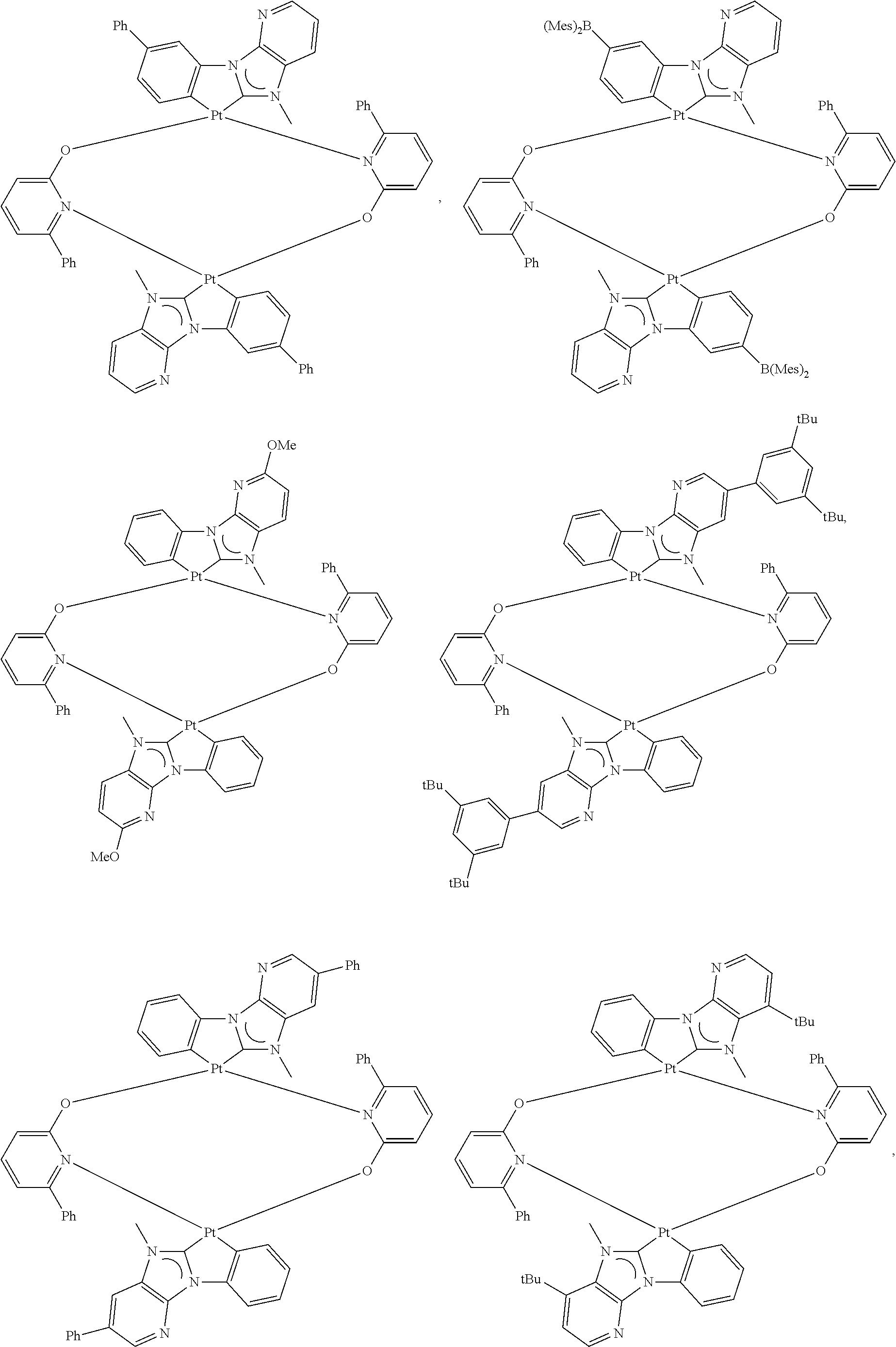

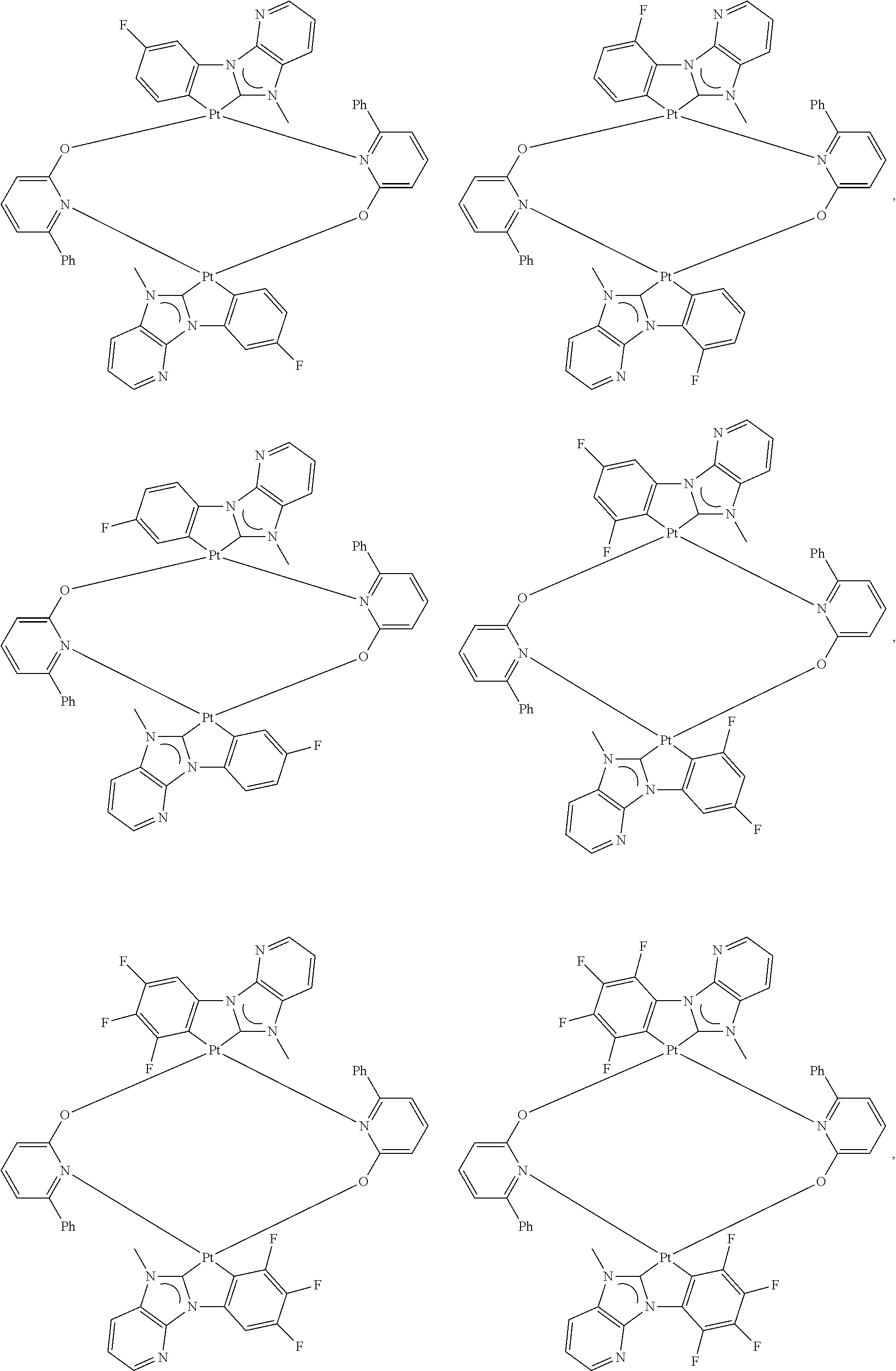

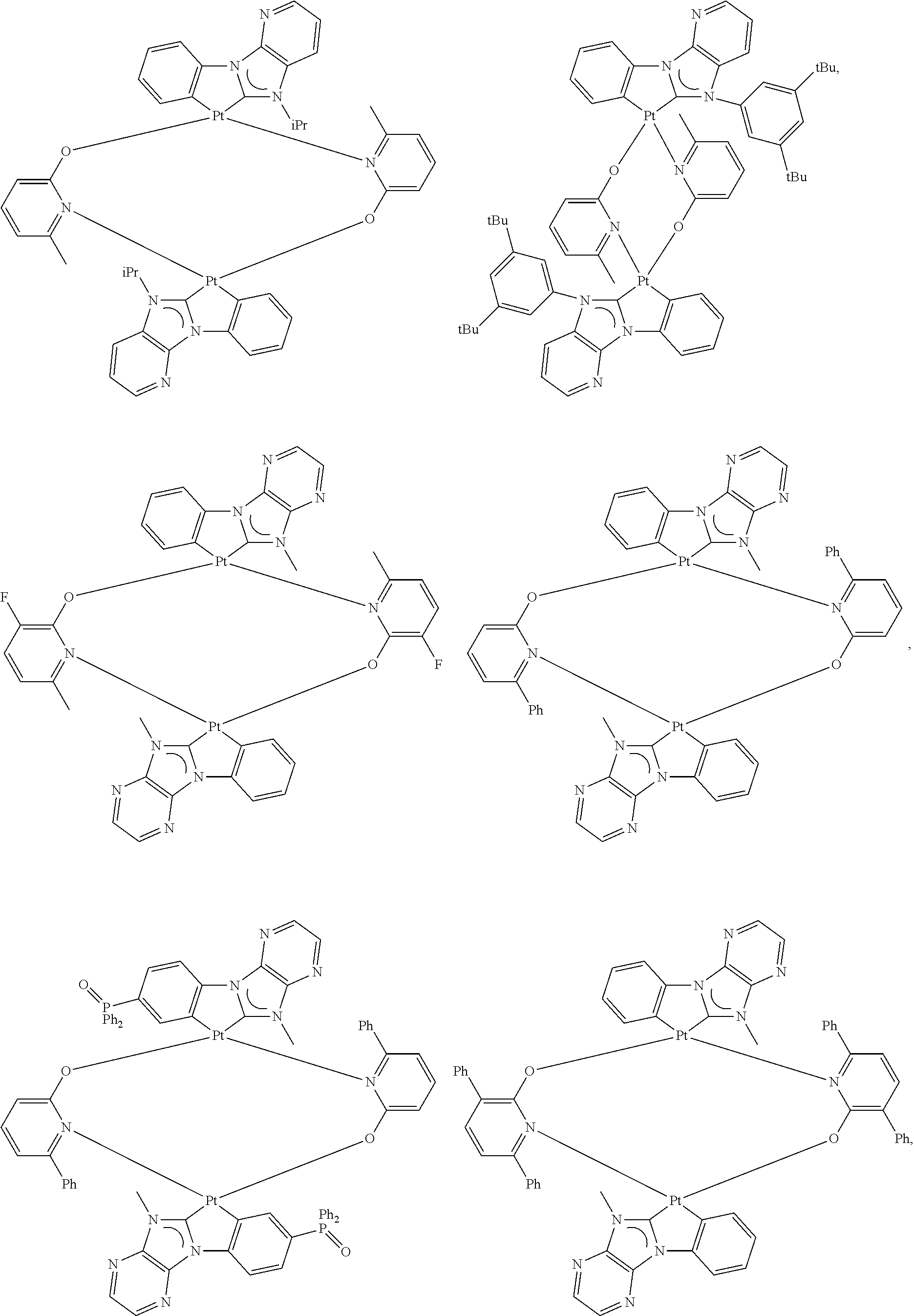

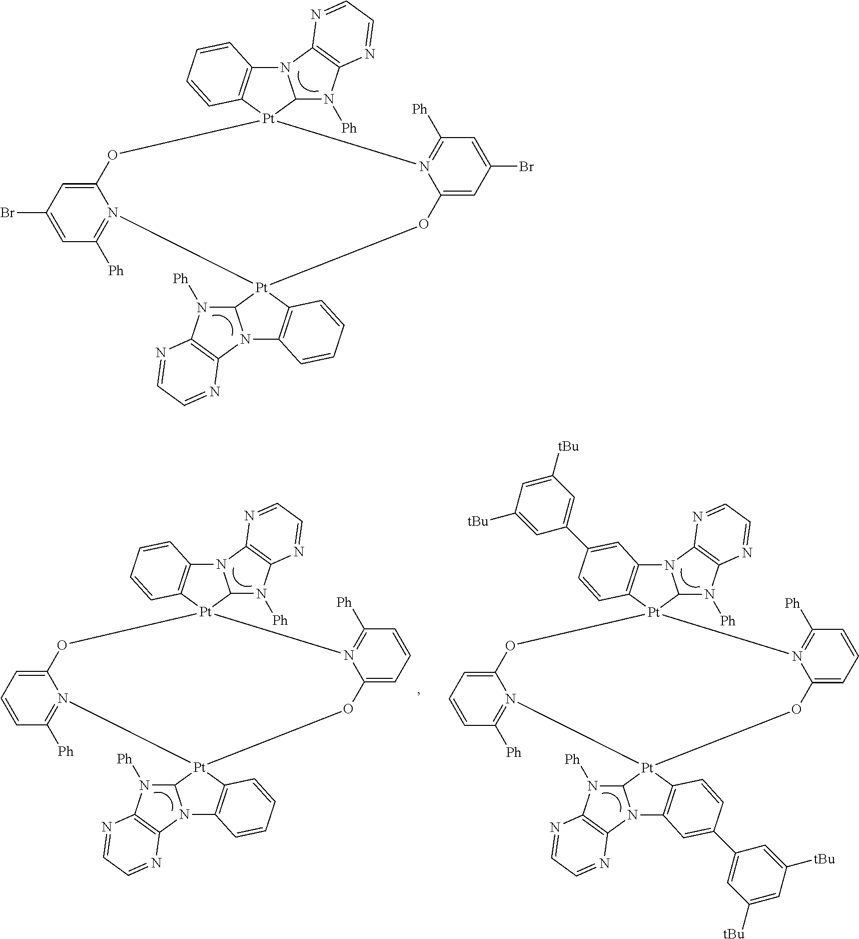

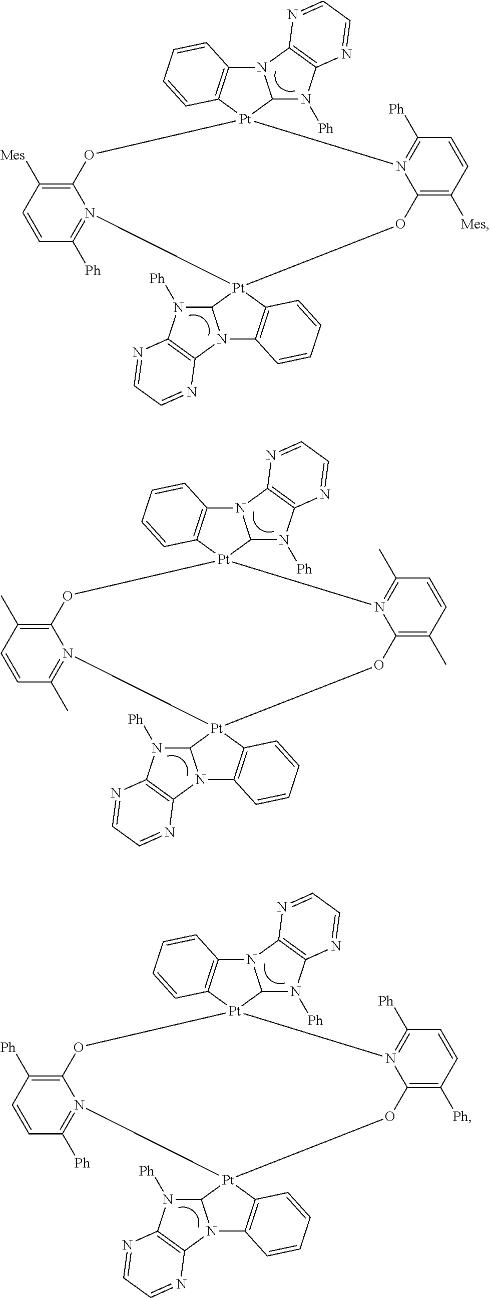

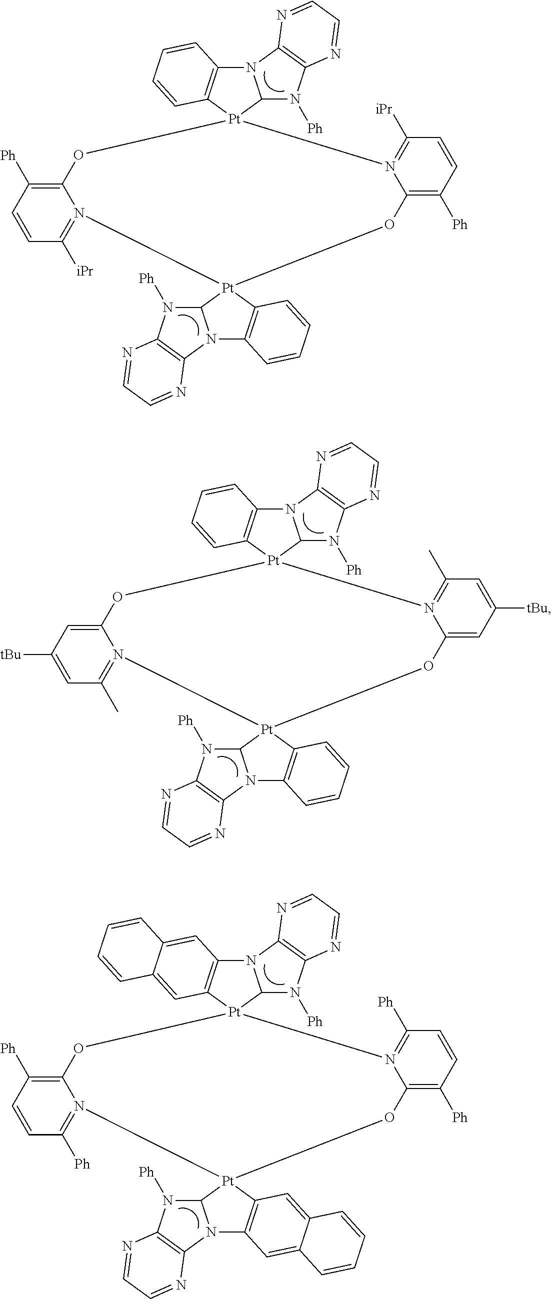

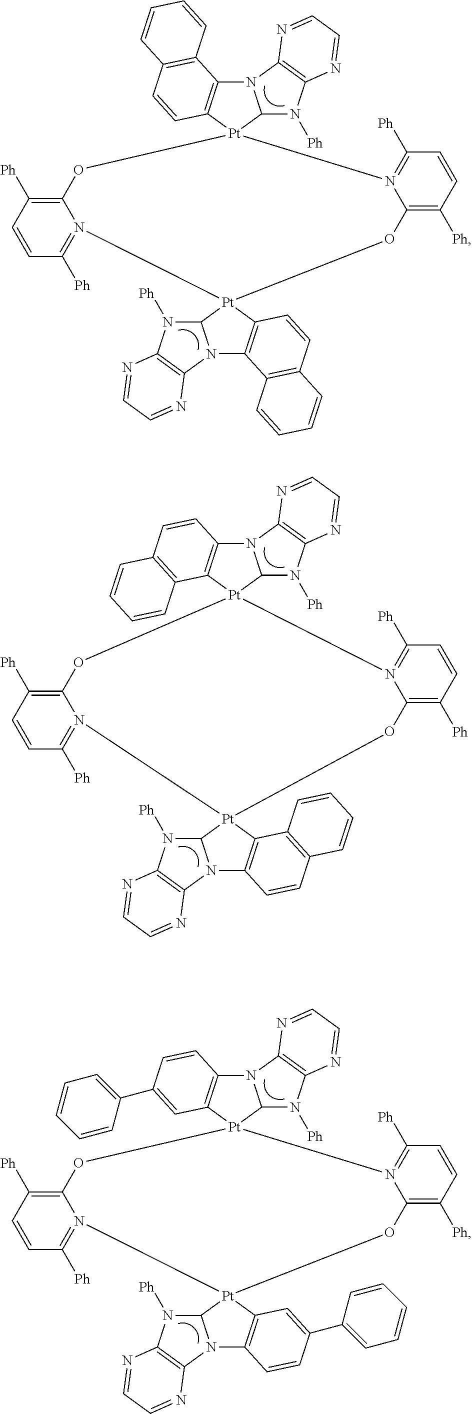

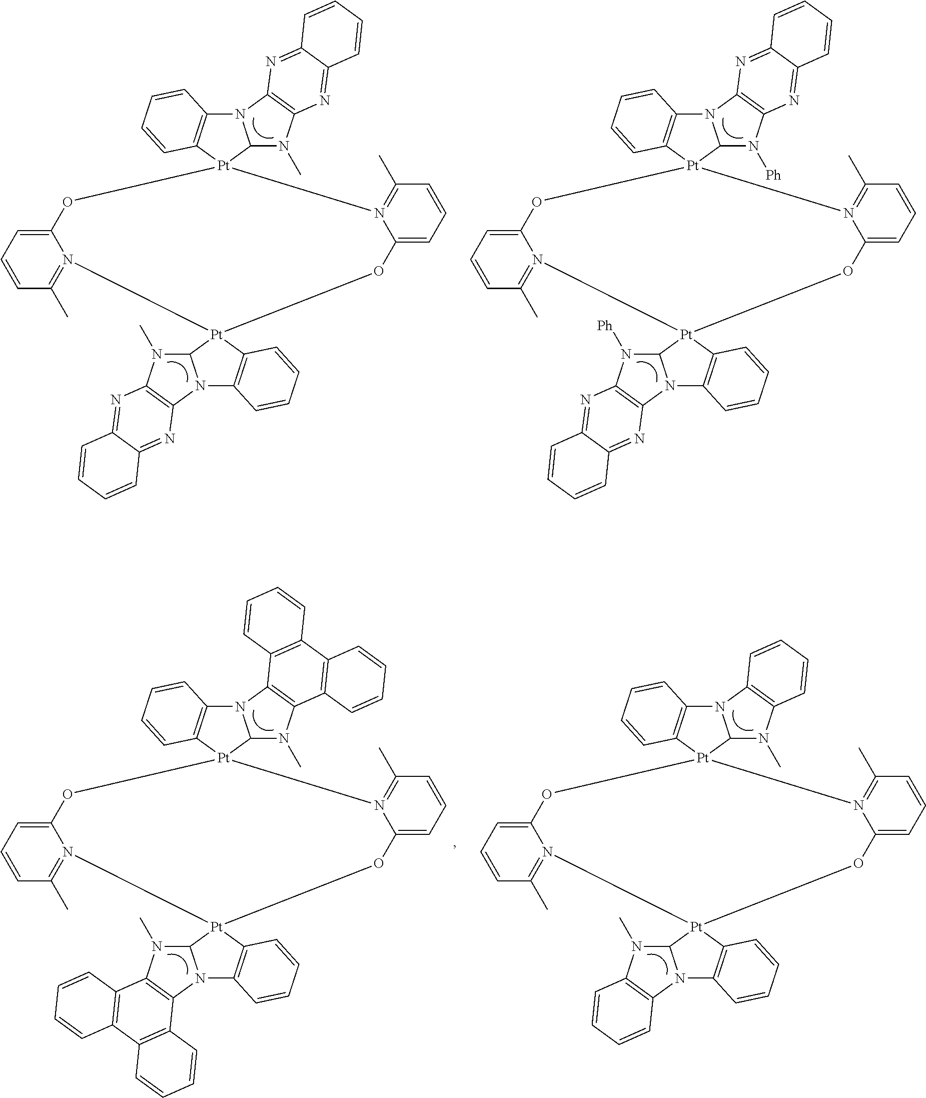

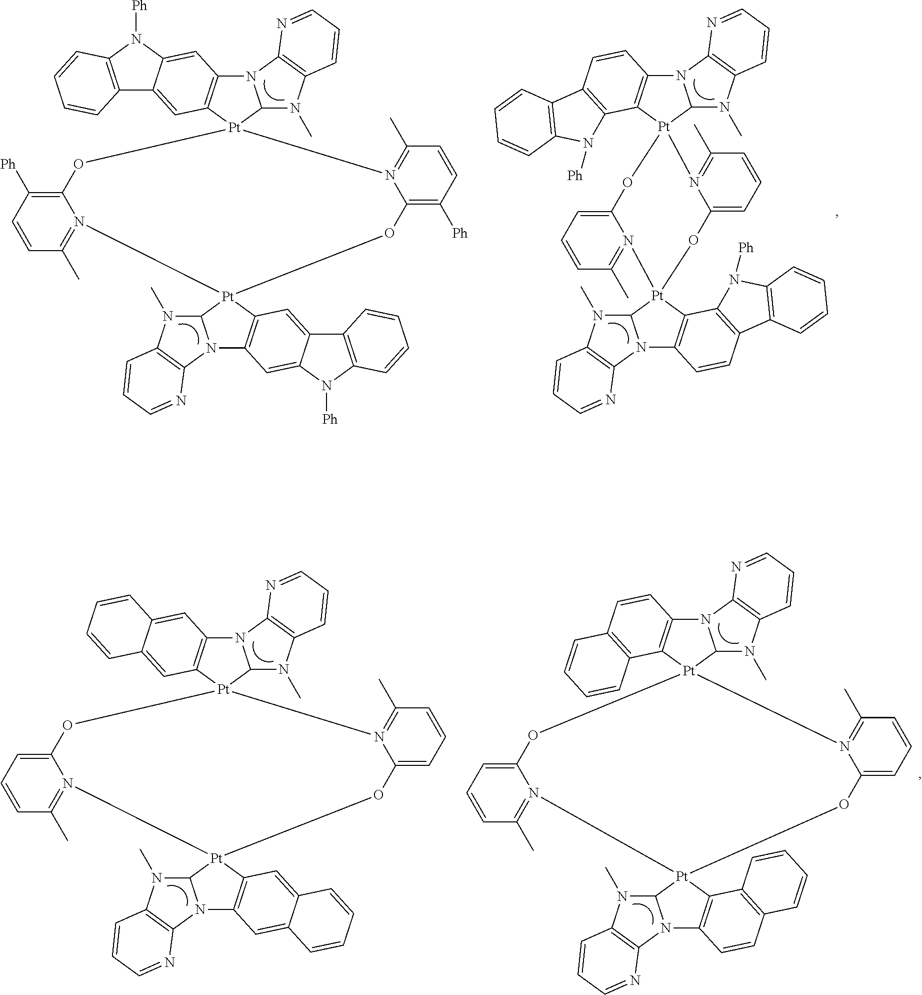

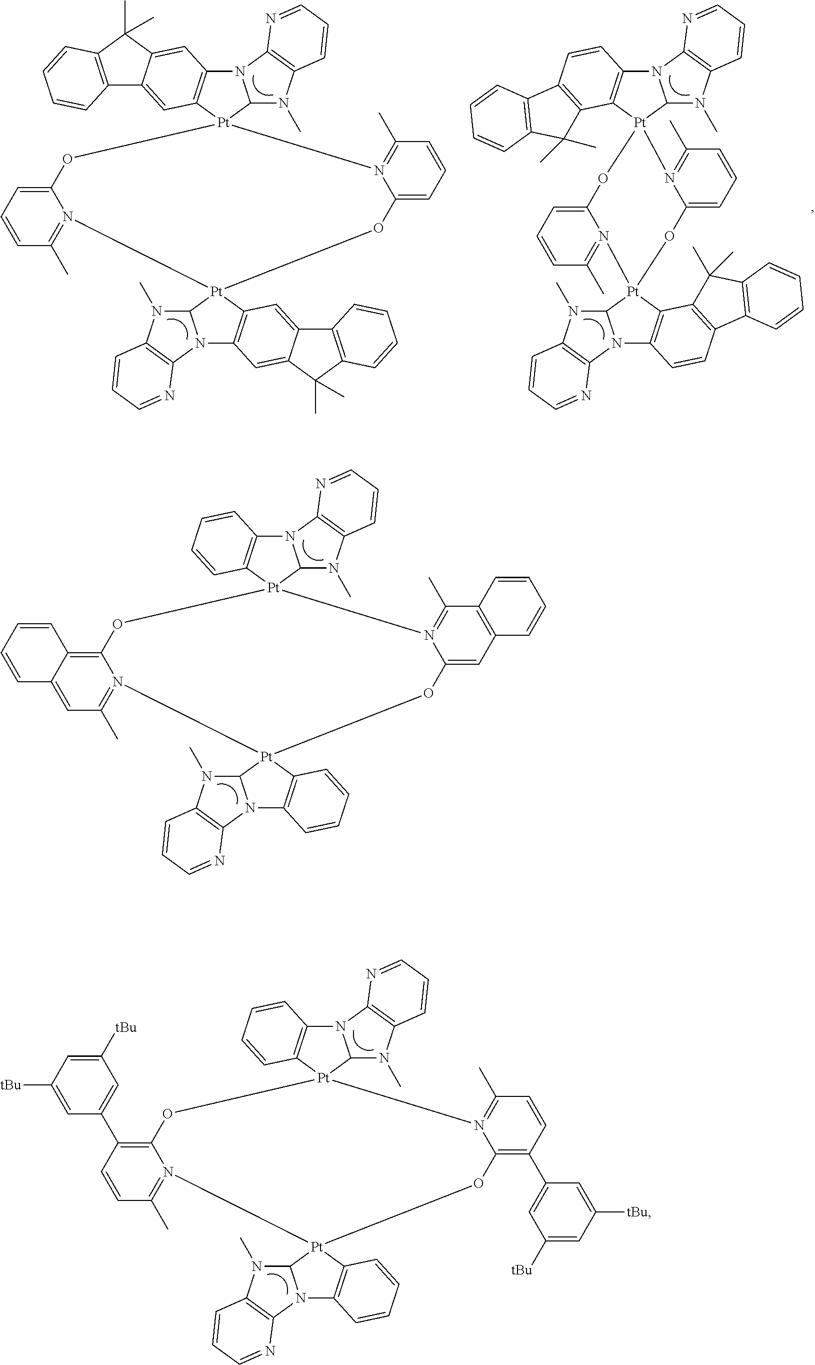

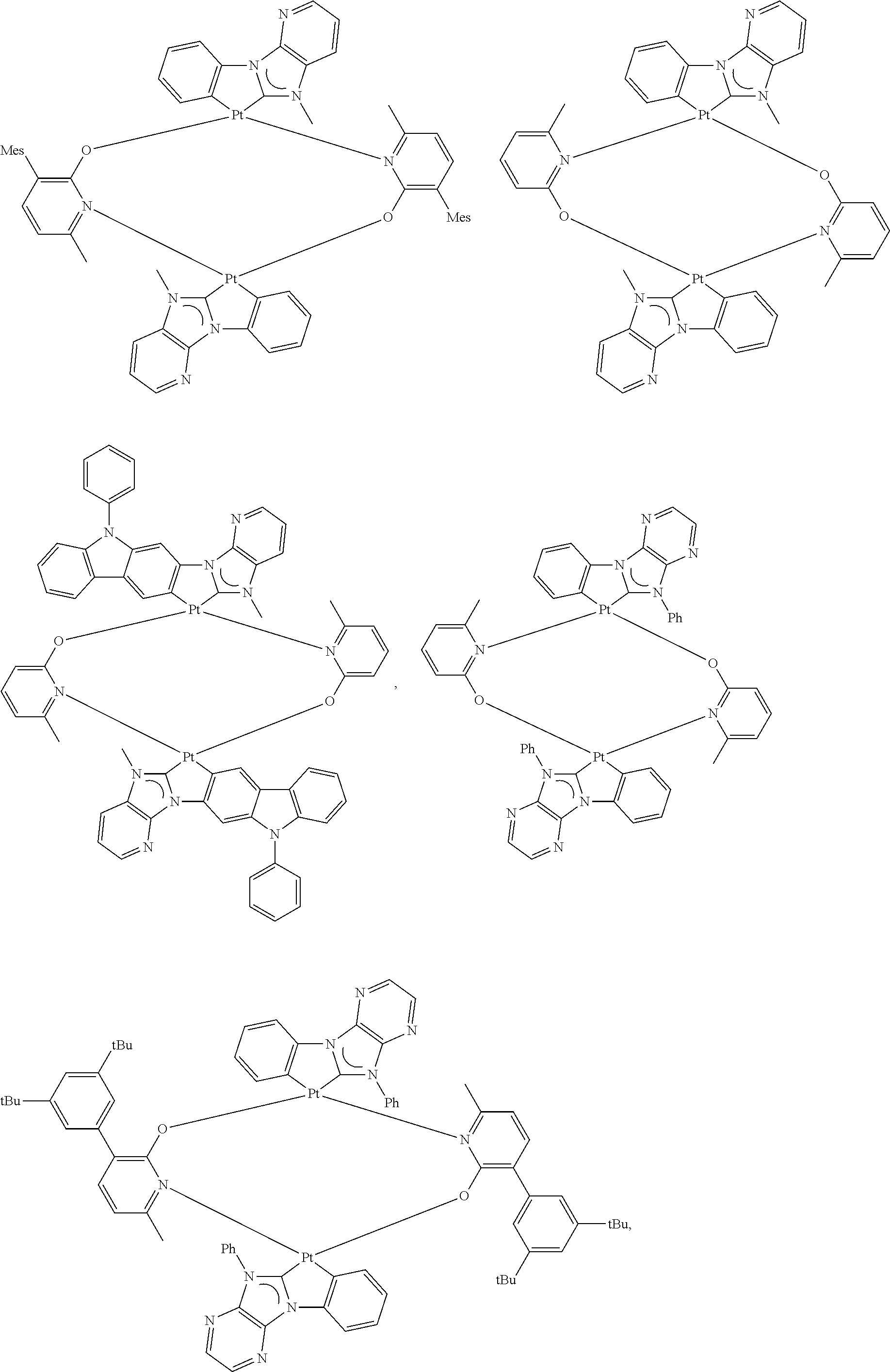

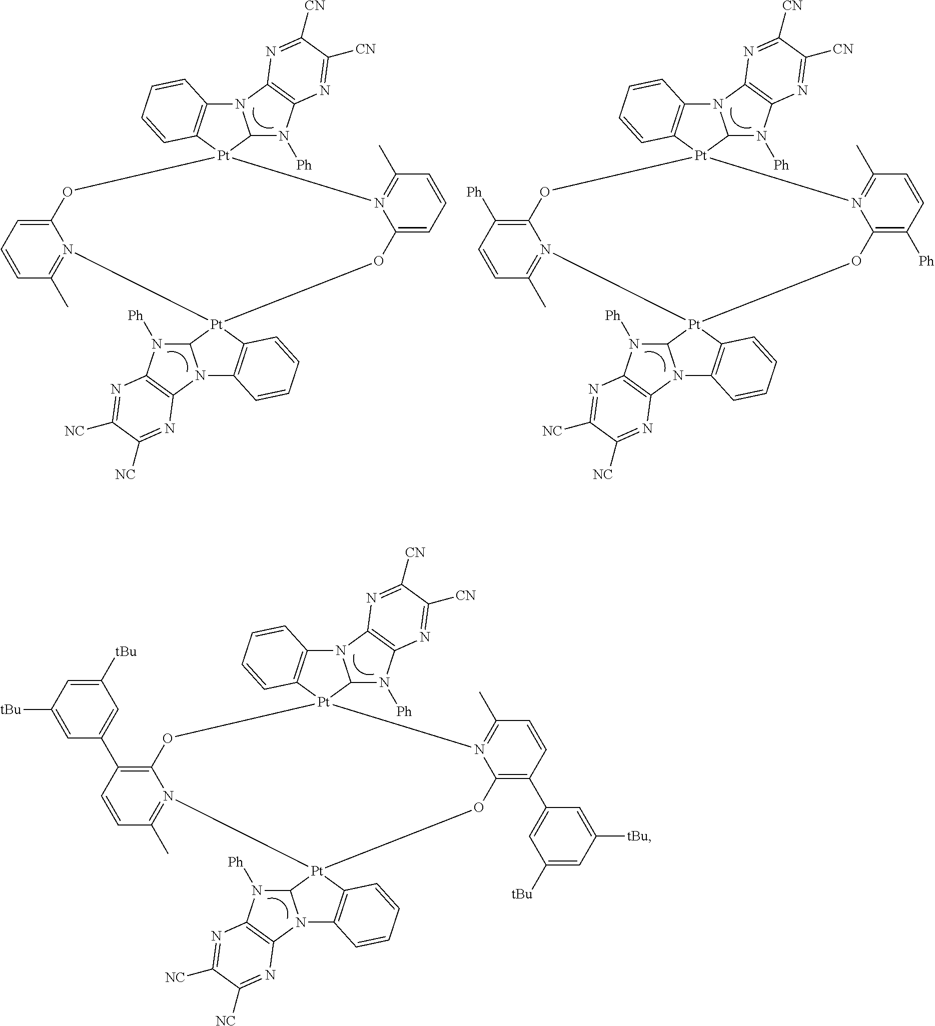

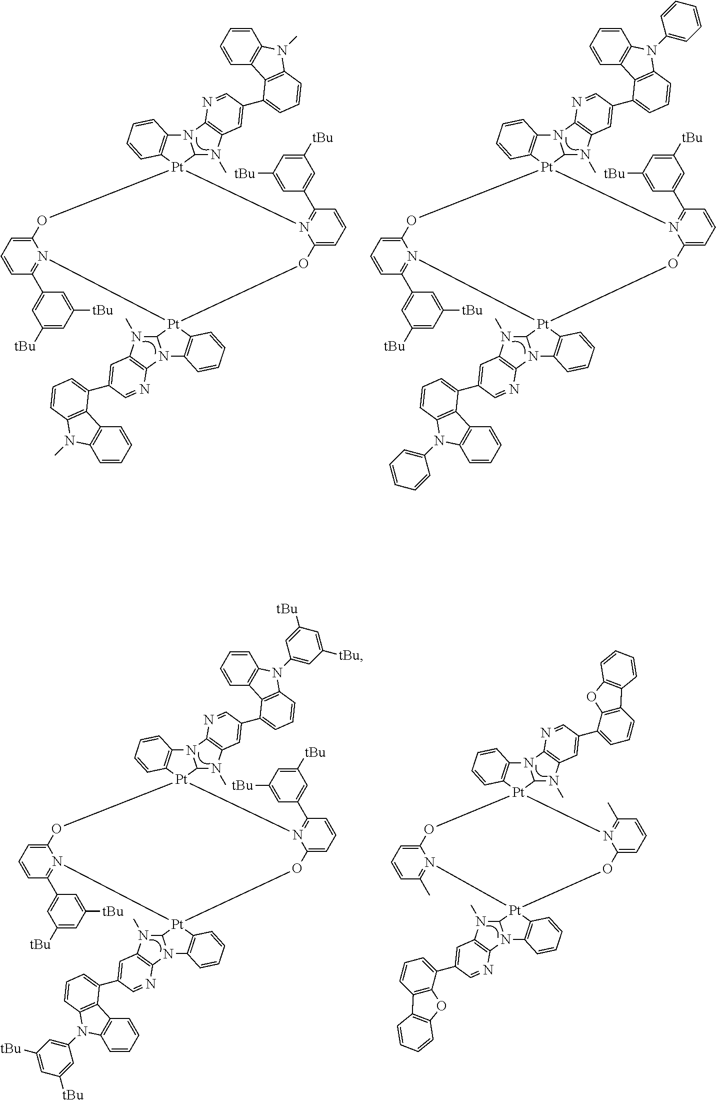

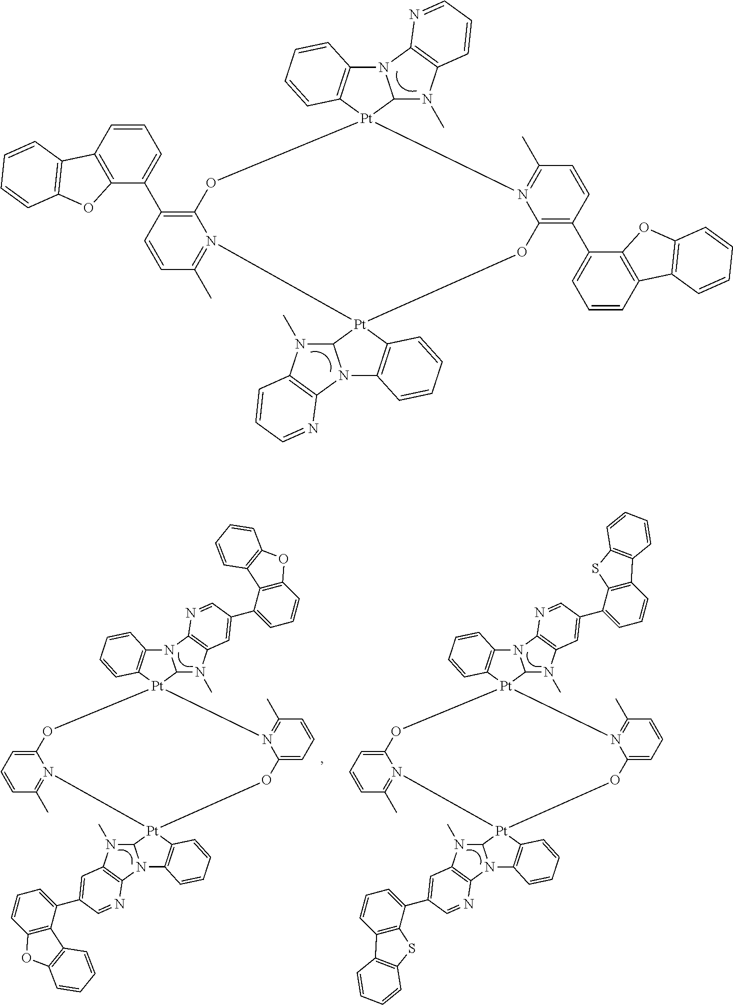

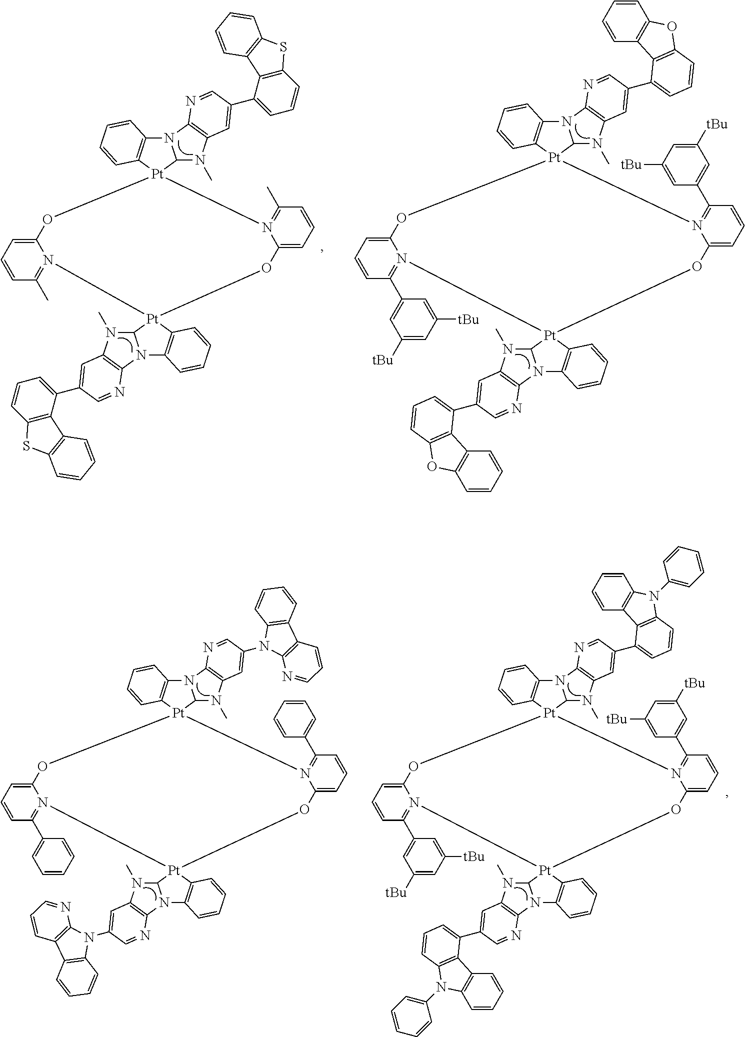

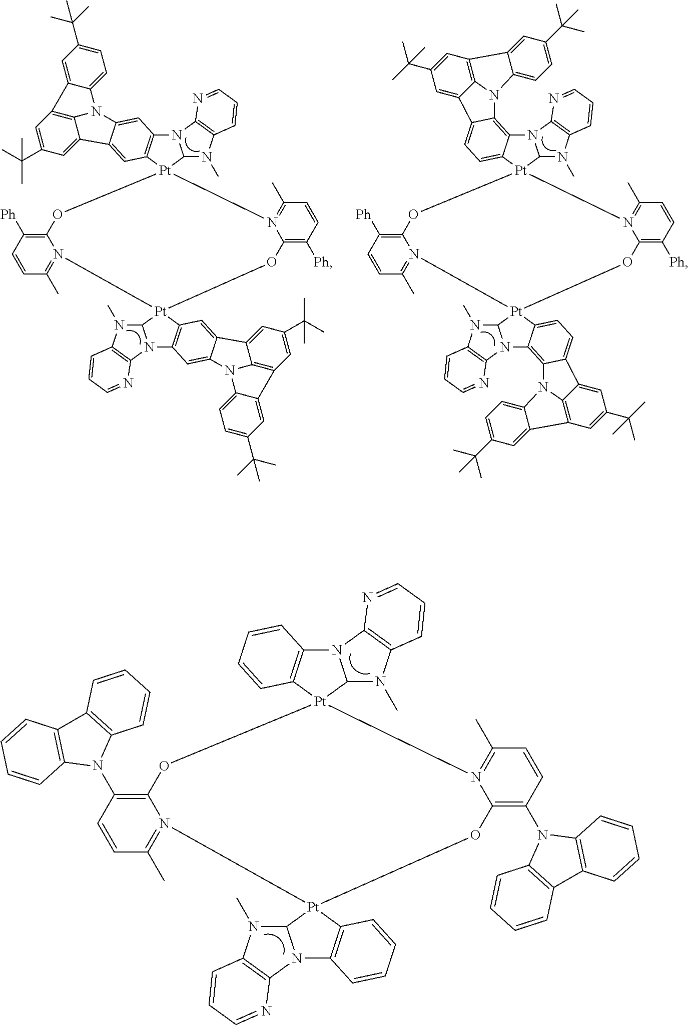

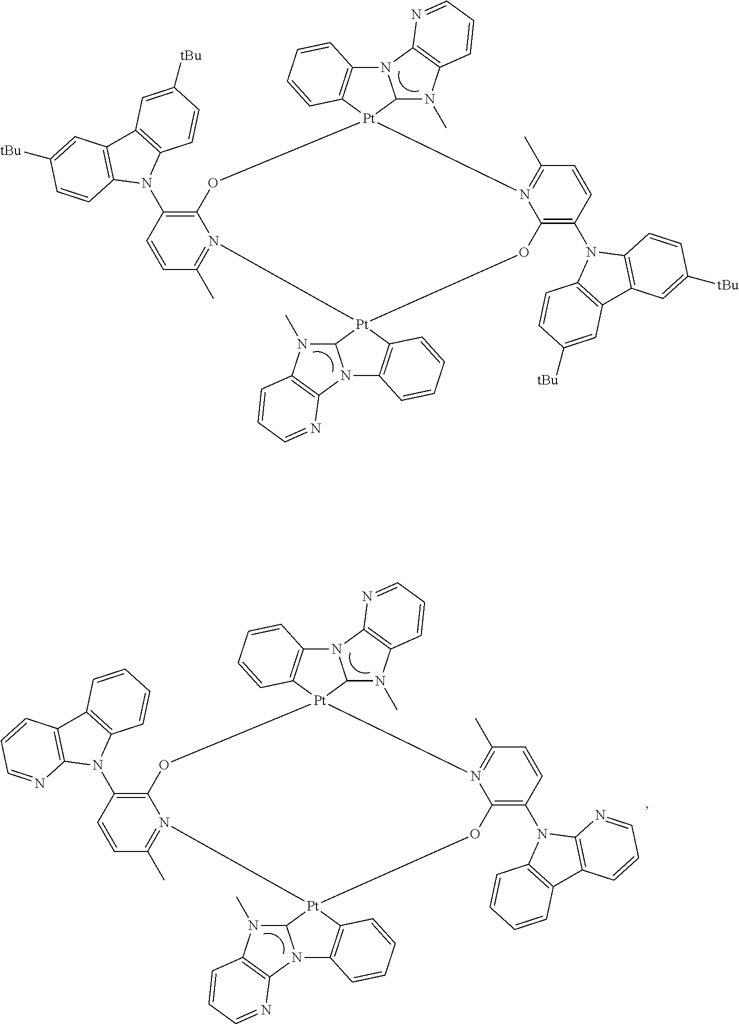

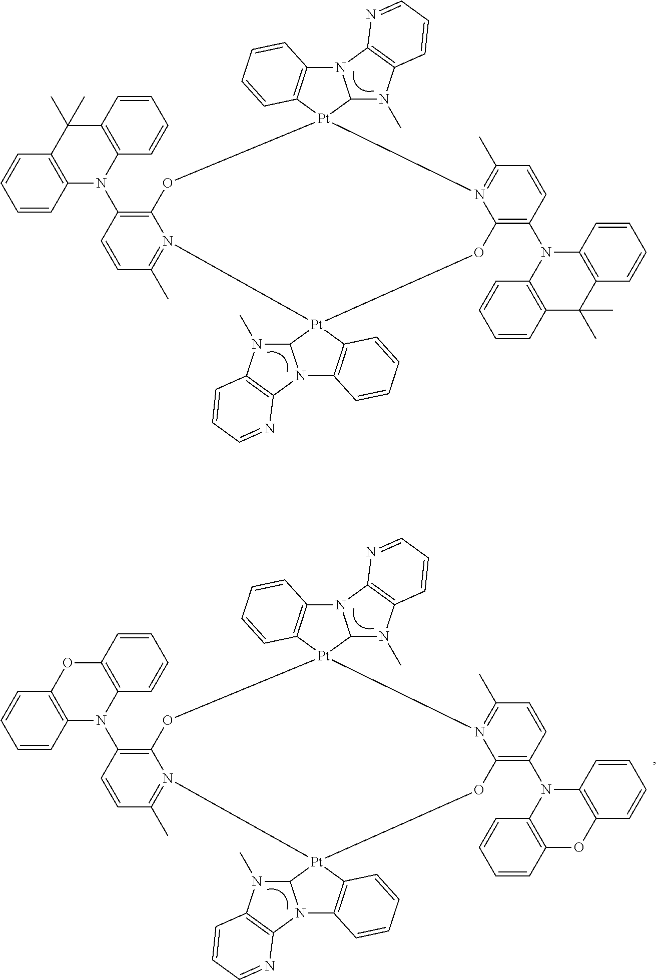

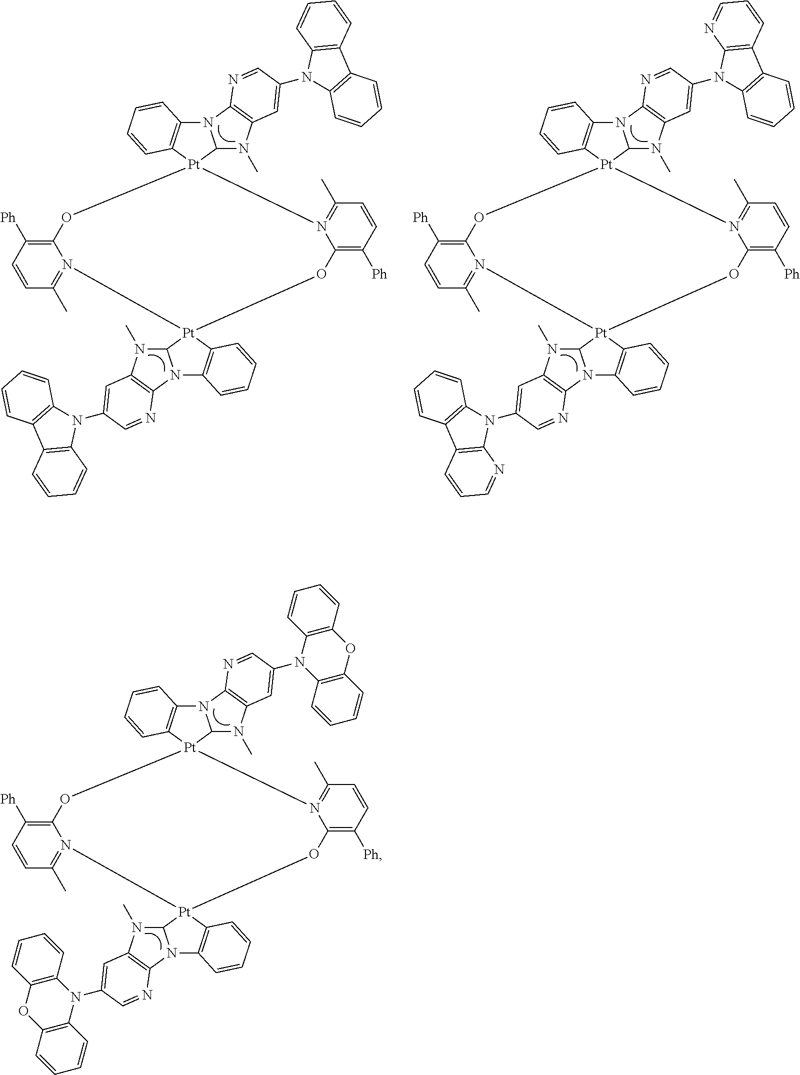

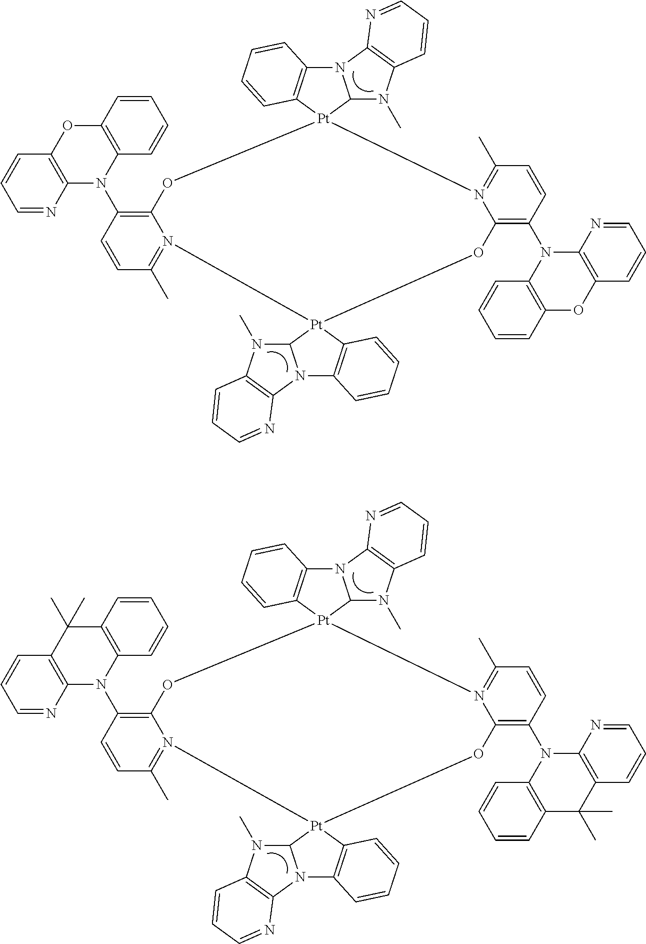

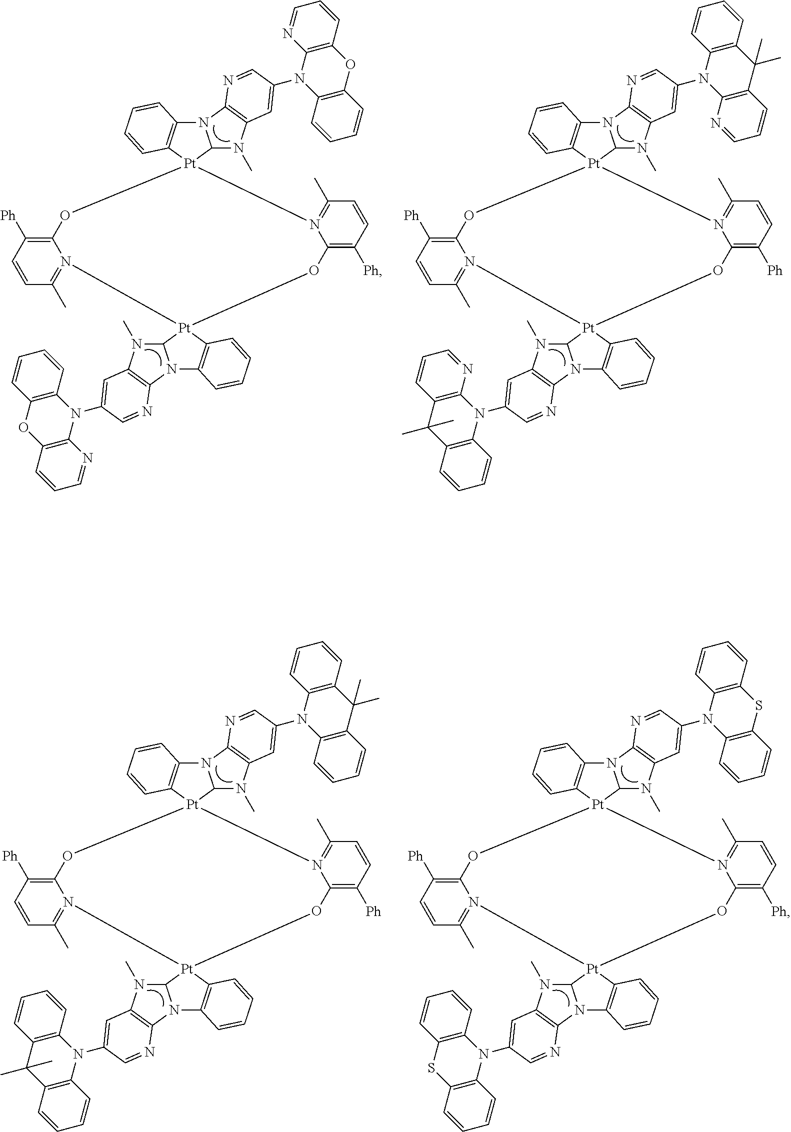

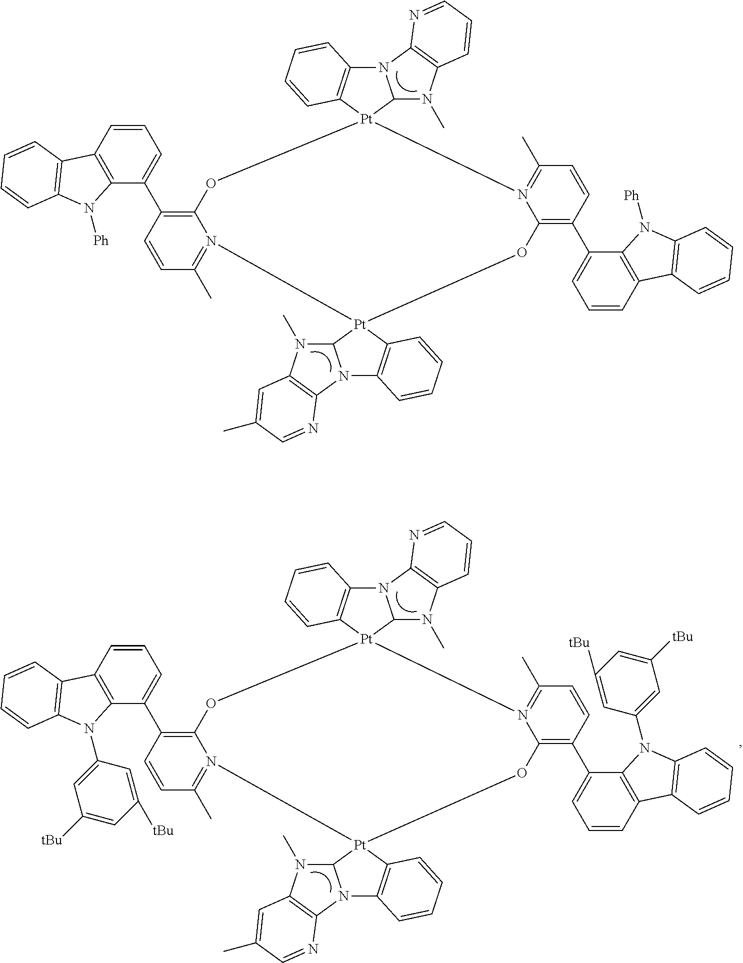

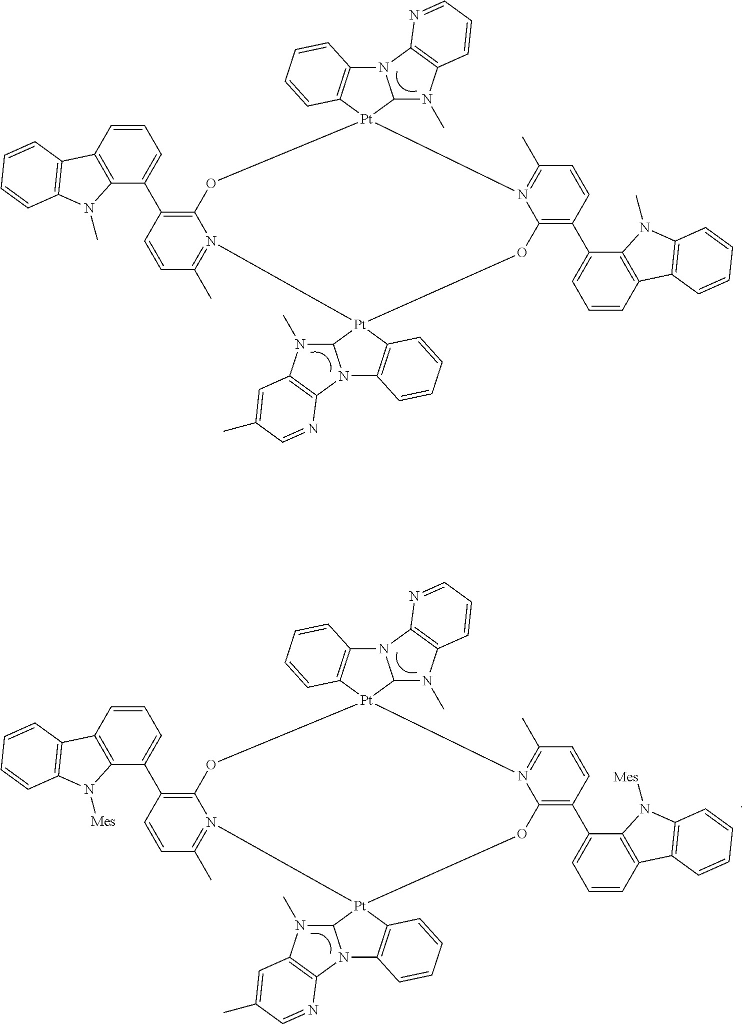

Paragraph 20. The complex of any one of paragraphs 1-19, wherein the complex has a maximum emission wavelength (λₘₐₓ) in a range from 600 nm to 1000 nm, from 600 nm to 900 nm, from 600 nm to 800 nm, from 600 nm to 700 nm, from 600 nm to 680 nm, from 620 nm to 710 nm, or from 612 nm to 685 nm.

Paragraph 21. The complex of paragraph 20, wherein the complex has an emission lifetime (τₑₘ) of up to 2.5 μs, up to 2.0 μs, up to 1.9 μs, up to 1.8 μs, in a range from 0.5 μs to 2.5 μs, from 0.5 μs to 2.0 μs, from 0.8 μs to 2.0 μs, from 1.0 μs to 2.0 μs, from 0.5 μs to 1.9 μs, from 0.8 μs to 1.9 μs, from 1.0 μs to 1.9 μs, from 1.2 μs to 1.9 μs, or from 1.4 μs to 1.9 μs; a radiative decay rate (kᵣ) of at least 3.5×10⁵ s⁻¹, at least 4.0×10⁵ s⁻¹, at least 4.5×10⁵ s⁻¹, in a range from 3.5×10⁵ s⁻¹ to 10.0×10⁵ s⁻¹, from 3.5×10⁵ s⁻¹ to 8.0×10⁵ s⁻¹, from 3.5×10⁵ s⁻¹ to 6.0×10⁵ s⁻¹, from 3.5×10⁵ s⁻¹ to 5.5×10⁵ s⁻¹, from 4.0×10⁵ s⁻¹ to 10.0×10⁵ s⁻¹, from 4.0×10⁵ s⁻¹ to 8.0×10⁵ s⁻¹, from 4.0×10⁵ s⁻¹ to 6.0×10⁵ s⁻¹, from 4.0×10⁵ s⁻¹ to 5.5×10⁵ s⁻¹, from 4.2×10⁵ s⁻¹ to 10.0×10⁵ s⁻¹, from 4.2×10⁵ s⁻¹ to 8.0×10⁵ s⁻¹, from 4.2×10⁵ s⁻¹ to 6.0×10⁵ s⁻¹, from 4.2×10⁵ s⁻¹ to 5.5×10⁵ s⁻¹, or from 4.3×10⁵ s⁻¹ to 5.5×10⁵ s⁻¹; a non-radiative decay rate (kₘr) of up to 2.0×10⁵ s⁻¹, up to 1.8×10⁵ s⁻¹, up to 1.5×10⁵ s⁻¹, down to 0.15×10⁵ s⁻¹, in a range from 0.15×10⁵ s⁻¹ to 2.0×10⁵ s⁻¹, from 0.16×10⁵ s⁻¹ to 2.0×10⁵ s⁻¹, from 0.15×10⁵ s⁻¹ to 1.8×10⁵ s⁻¹, from 0.16×10⁵ s⁻¹ to 1.8×10⁵ s⁻¹, from 0.15×10⁵ s⁻¹ to 1.6×10⁵ s⁻¹, from 0.16×10⁵ s⁻¹ to 1.6×10⁵ s⁻¹, from 0.15×10⁵ s⁻¹ to 1.5×10⁵ s⁻¹, or from 0.16×10⁵ s⁻¹ to 1.4×10⁵ s⁻¹; and/or an emission quantum yield (Φₑₘ) of at least 60%, at least 65%, at least 70%, at least 75%, in a range from 60% to 97%, from 65% to 97%, from 70% to 97%, from 75% to 97%, from 75% to 99%, or from 78% to 97%, measured in solution or films, at room temperature.

Paragraph 22. An organic light-emitting component comprising a light-emitting layer or two or more light-emitting layers, wherein the light-emitting layer or each light-emitting layer of the two or more light-emitting layers comprises one or more dinuclear platinum(II) complexes of any one of paragraphs 1 to 21, and optionally wherein the organic light-emitting component emits light in the red, deep red, and/or NIR region(s).

Paragraph 23. The organic light-emitting component of paragraph 22, wherein the light emitting layer or each light-emitting layer of the two or more light-emitting layers further comprises one or more host materials, and wherein the total concentration of the one or more host materials is greater than the total concentration of the one or more complexes in the light-emitting layer or each light-emitting layer of the two or more light-emitting layers.

Paragraph 24. The organic light-emitting component of paragraph 22 or 23, wherein the total concentration of the one or more dinuclear platinum(II) complexes in the light-emitting layer or each light-emitting layer of the two or more light-emitting layers is up to 50 wt %, up to 40 wt %, up to 30 wt %, up to 20 wt %, at least 1 wt %, in a range from about 1 wt % to about 50 wt %, from about 1 wt % to about 40 wt %, from about 1 wt % to about 30 wt %, from about 1 wt % to about 20 wt %, from about 2 wt % to about 50 wt %, from about 2 wt % to about 40 wt %, from about 2 wt % to about 30 wt %, from about 2 wt % to about 20 wt %, from about 4 wt % to about 50 wt %, from about 4 wt % to about 40 wt %, from about 4 wt % to about 30 wt %, from about 4 wt % to about 20 wt %, from about 1 wt % to about 16 wt %, from about 2 wt % to about 16 wt %, from about 4 wt % to about 16 wt %, such as about 4 wt %, about 8 wt %, or about 12 wt %.

Paragraph 25. The organic light-emitting component of any one of paragraphs 22-24 further comprising an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located in between the anode and the light-emitting layer, and
wherein the electron transport region is located in between the cathode and the light emitting layer.

Paragraph 26. The organic light-emitting component of any one of paragraphs 22-25, wherein the organic light-emitting component emits light in the red to deep red region.

Paragraph 27. The organic light-emitting component of paragraph 26, wherein the organic light-emitting component has a maximum brightness (L) of at least 20000 cd m⁻², at least 25000 cd m⁻², at least 30000 cd m⁻², at least 35000 cd m⁻², at least 40000 cd m⁻², in a range from 20000 cd m⁻² to 100000 cd m⁻², from 30000 cd m⁻² to 100000 cd m⁻², from 20000 cd m⁻² to 80000 cd m⁻², from 30000 cd m⁻² to 80000 cd m⁻², from 20000 cd m⁻² to 60000 cd m⁻², from 30000 cd m⁻² to 60000 cd m⁻², from 20000 cd m⁻² to 50000 cd m⁻² from 30000 cd m⁻² to 100000 cd m⁻², from 20000 cd m⁻² to 50000 cd m⁻², from 30000 cd m⁻² to 50000 cd m⁻², from 35000 cd m⁻² to 100000 cd m⁻², from 40000 cd m⁻² to 100000 cd m⁻², from 35000 cd m⁻² to 80000 cd m⁻², from 40000 cd m⁻² to 80000 cd m⁻², from 35000 cd m⁻² to 60000 cd m⁻², from 40000 cd m⁻² to 60000 cd m⁻², from 35000 cd m⁻² to 50000 cd m⁻², or from 40000 cd m⁻² to 50000 cd m⁻²; a current efficiency (CE) at 1000 cd/m² of at least 20 cd A⁻¹, at least 22 cd/A, in a range from 20 cd/A to 60 cd/A, from 22 cd/A to 60 cd/A, from 20 cd/A to 50 cd/A, from 22 cd/A to 50 cd/A, from 20 cd/A to 40 cd/A, or from 20 cd/A to 30 cd/A; a power efficiency (PE) at 1000 cd/m² of at least 10 1 m/W, in a range from 10 1 m/W to 60 1 m/W, from 15 1 m/W to 60 1 m/W, from 10 1m/W to 50 1 m/W, from 15 1 m/W to 50 1 m/W, from 10 1 m/W to 40 1 m/W, from 15 1 m/W to 40 1 m/W, from 10 1 m/W to 30 1 m/W, from 15 1 m/W to 30 1 m/W, or from 10 1 m/W to 20 1 m/W; and/or an external quantum efficiency (EQE) at 1000 cd/m² of at least 10%, at least 11%, at least 12%, at least 13%, at least 14%, at least 15%, in a range from 10% to 40%, from 10% to 20%, from 10% to 20%, from 11% to 40%, from 11% to 30%, from 11% to 20%, from 12% to 20%, from 12% to 40%, from 12% to 30%, from 13% to 20%, from 13% to 40%, from 13% to 30%, from 14% to 20%, from 14% to 40%, from 14% to 30%, from 15% to 40%, from 15% to 30%, or from 15% to 20%.

Paragraph 28. The organic light-emitting component of any one of paragraphs 22-25, wherein the organic light-emitting component emits light in the NIR region.

Paragraph 29. The organic light-emitting component of paragraph 28, wherein the organic light-emitting component has an L of at least 1000 cd m⁻², at least 1500 cd m⁻², at least 2000 cd m⁻², at least 3000 cd m⁻², at least 4000 cd m⁻², at least 4200 cd m⁻², at least 4500 cd m⁻², in a range from 1000 cd m⁻² to 40000 cd m⁻², from 1500 cd m⁻² to 40000 cd m⁻², from 2000 cd m⁻² to 40000 cd m⁻², from 3000 cd m⁻² to 40000 cd m⁻², from 4000 cd m⁻² to 40000 cd m⁻², from 4500 cd m⁻² to 40000 cd m⁻², from 1000 cd m⁻² to 30000 cd m⁻², from 2000 cd m⁻² to 30000 cd m⁻², from 3000 cd m⁻² to 30000 cd m⁻², from 4000 cd m⁻² to 30000 cd m⁻², from 4500 cd m⁻² to 30000 cd m⁻², from 1000 cd m⁻² to 20000 cd m⁻², from 2000 cd m⁻² to 20000 cd m⁻², from 3000 cd m⁻² to 20000 cd m⁻², from 4000 cd m⁻² to 20000 cd m⁻², from 4500 cd m⁻² to 20000 cd m⁻², from 1000 cd m⁻² to 10000 cd m⁻², from 2000 cd m⁻² to 10000 cd m⁻², from 3000 cd m⁻² to 10000 cd m⁻², from 4000 cd m⁻² to 10000 cd m⁻², or from 4500 cd m⁻² to 10000 cd m⁻²; a CE at 1000 cd m⁻² of at least 0.2 cd A⁻¹, at least 0.4 cd A⁻¹, at least 0.8 cd A⁻¹, in a range from 0.2 cd/A to 10 cd/A, from 0.2 cd/A to 8 cd/A, from 0.2 cd/A to 5 cd/A, from 0.2 cd/A to 3 cd/A, from 0.2 cd/A to 2 cd/A, from 0.4 cd/A to 10 cd/A, from 0.4 cd/A to 8 cd/A, from 0.4 cd/A to 5 cd/A, from 0.4 cd/A to 3 cd/A, from 0.4 cd/A to 2 cd/A, from 0.8 cd/A to 10 cd/A, from 0.8 cd/A to 8 cd/A, from 0.8 cd/A to 5 cd/A, from 0.8 cd/A to 3 cd/A, or from 0.8 cd/A to 2 cd/A; a PE at 1000 cd/m² of at least 0.1 1 m/W, at least 0.2 1 m/W, in a range from 0.1 1 m/W to 5 1 m/W, from 0.1 1 m/W to 4 1 m/W, from 0.1 1 m/W to 3 1 m/W, from 0.1 1m/W to 2 1 m/W, from 0.1 1 m/W to 1 1 m/W, from 0.1 1 m/W to 0.5 1 m/W, from 0.2 1 m/W to 5 1 m/W, from 0.2 1 m/W to 4 1 m/W, from 0.2 1 m/W to 3 1 m/W, from 0.2 1 m/W to 2 1m/W, from 0.2 1 m/W to 1 1 m/W, or from 0.2 1 m/W to 0.5 1 m/W; and/or an EQE at 1000 cd/m² of at least 1%, at least 2%, at least 4%, at least 5%, at least 6%, in a range from 1% to 20%, from 2% to 20%, from 4% to 20%, from 5% to 20%, from 5% to 18%, from 1% to 15%, from 2% to 15%, from 4% to 15%, from 5% to 15%, from 1% to 10%, from 2% to 10%, from 4% to 10%, or from 5% to 10%.

Paragraph 30. The organic light-emitting component of any one of paragraphs 22-29, wherein the organic light-emitting component is an organic light-emitting diode (“OLED”) or a light-emitting electrochemical cell (“LEEC”).

Paragraph 31. The organic light-emitting component of any one of paragraphs 22-30, wherein the light-emitting layer or each of the light-emitting layer of the two or more light-emitting layers is formed by vacuum-evaporation deposition, spin-coating, ink-printing, or roll-to-roll printing.

Paragraph 32. The organic light-emitting component of any one of paragraphs 22-31, wherein the light emitting layer or each light-emitting layer of the two or more light-emitting layers further comprises an organic dye, and wherein the one or more dinuclear platinum(II) complexes act(s) as a sensitizer to transfer energy to the organic dye.

Paragraph 33. The organic light-emitting component of any one of paragraphs 22-31, wherein the light emitting layer or each light-emitting layer of the two or more light-emitting layers further comprises an organic dye, and wherein the one or more dinuclear platinum(II) complexes have a higher-lying singlet state than the organic dye.

Paragraph 34. A device comprising one or more organic light-emitting components of any one of paragraphs 22-33, wherein the device is a stationary visual display unit, a mobile visual display unit, an illumination device, a wearable device, a phototherapy device, or a medical monitoring device.

### EXAMPLES

### Example 1: Synthesis and Characterization of Dinuclear Platinum(II) Complexes

The efficient red or NIR emitters are based on the molecular system of dinuclear cyclometalated platinum(II) carbene complexes containing 2-oxy-pyridine (N\hat{ }O) bridging ligands. Without being bound to theories, it is believed that the use of N\hat{ }O bridging ligands allow strong metal-metal interactions between two platinum(II) metal centers in a paddle-wheel structure, which give rise to low-energy MMLCT excited states. These dinuclear platinum(II) emitters show red to deep-red (λₘₐₓ at 612-685 nm) or NIR photoluminescence with high emission quantum yields of up to about 0.97 in thin films at room temperature. The emission lifetimes are down to 1.7-1.9 μs and the radiative decay rates reach high values of about 5.9×10⁵ s⁻¹. Results of the doped OLEDs using the dinuclear platinum(II) emitters demonstrate electroluminescence spanning from red to NIR spectral region (λₘₐₓ at 615-706 nm) with an EQE of 9.1-31.9%, at 1000 cd m⁻².

### Materials and Methods

### Synthesis and Characterization of Exemplary Dinuclear Platinum(II) Complexes

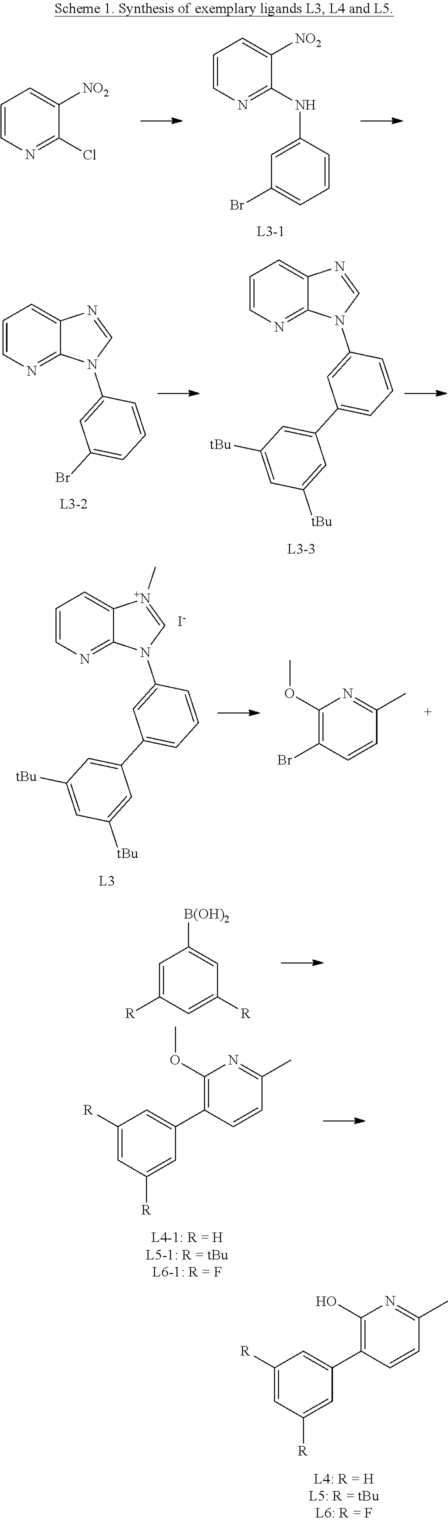

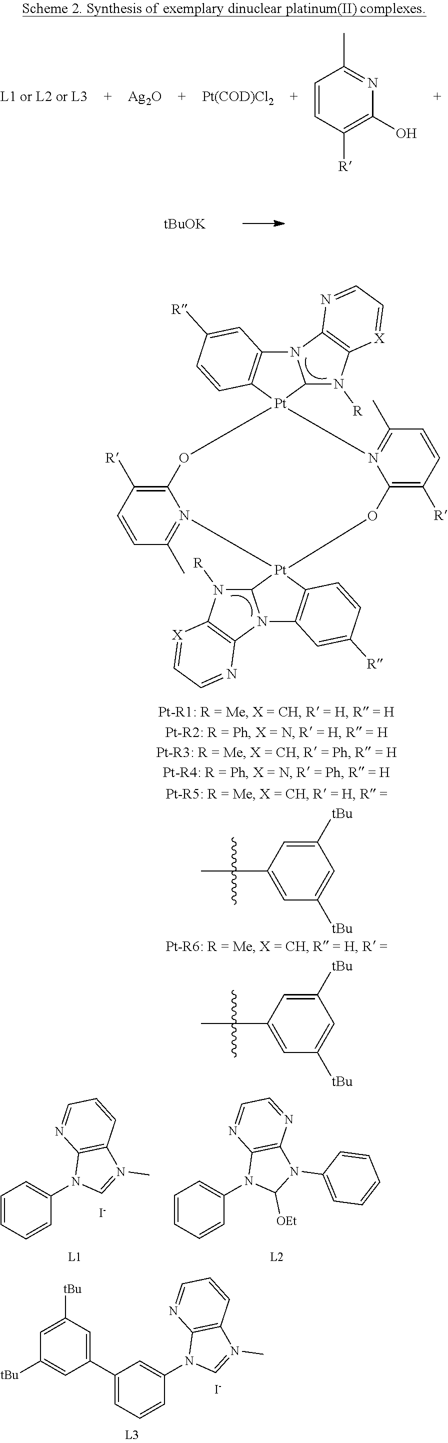

The chemical reagents used for synthesis were purchased from commercial sources such as Dieckmann, Tiv Scientific, J & K Scientific, BLDpharm, Bidepharm, Strem Chemicals. They were directly used without further processing. The solvents used for synthesis were purchased from Duksan, RCI Labscan, Scharlau. They were directly used without further processing. ¹H and ¹³C NMR spectra were recorded on DPX-400 or DPX-500 Bruker FT-NMR spectrometer. The chemical shift of proton or carbon signals are calibrated by the corresponding solvent residual signals. High resolution mass spectra were measured with Bruker Impact II mass spectrometer.

L1 and L2 were synthesized according to reported procedure (Unger, et al., Angew. Chem. Int. Ed. 2010, 49, 10214-10216; Pinter, et al., Chem. Eur. J. 2019, 25, 14495-14499). L3, L4, and L5 were synthesized following the procedures described below and as shown in Scheme 1 above.

N-(3-bromophenyl)-3-nitropyridin-2-amine (L3-1) was synthesized as follows. 3-bromoaniline (1.09 mL, 10.0 mmol) and 2-chloro-3-nitropyridine (1.90 g, 12.0 mmol) were heated in ethylene glycol (10 mL) at 140° C. for 24 h. After cooling down to room temperature, the reaction mixture was diluted with ethyl acetate, then washed with water and brine. The organic fraction was dried over anhydrous Na₂SO₄ and the crude was concentrated under reduced pressure. The crude product was further purified by flash column chromatography on silica gel using n-hexane/ethyl acetate (15:1) as eluent to afford the desired compound (L3-1) as orange solid. Yield: 93%. ¹H NMR (400 MHz, CD₂Cl₂): δ 10.07 (s, 1H), 8.51 (t, J=5.9 Hz, 2H), 8.02 (s, 1H), 7.53 (d, J=7.6 Hz, 1H), 7.26 (dt, J=15.7, 7.9 Hz, 2H), 6.90 (dd, J=8.3, 4.6 Hz, 1H). 3-(3-bromophenyl)-3-H-imidazo[4,5b]pyridine (L3-2) was synthesized as follows. A mixture of L3-1 (2.73 g, 9.28 mmol), formic acid (23.0 mL, 608 mmol), ammonium chloride (2.59 g, 46.4 mmol) and iron powder (2.48 g, 46.4 mmol) were refluxed in 2-propanol (40 mL) for 48 h. Afterward, the reaction mixture was cooled to room temperature and the solvents were removed under reduced pressure. The residue was extracted with DCM and pass through a short pad of Celite. The organic extract was washed with 5% NaHCO₃ and brine, and then dried over anhydrous Na₂SO₄. The volatile was removed under reduced pressure. The crude product was further purified by flash column chromatography on silica gel using n-hexane/ethyl acetate (3:1) as eluent to afford compound (L3-2) as white solid. Yield: 30%. ¹H NMR (500 MHz, CDCl₃): δ 8.49 (dd, J=4.7, 1.2 Hz, 1H), 8.40 (s, 1H), 8.18 (dd, J=8.1, 1.3 Hz, 1H), 8.00 (t, J=1.9 Hz, 1H), 7.77 (dd, J=8.0, 1.2 Hz, 1H), 7.59 (dd, J=8.1, 0.7 Hz, 1H), 7.46 (t, J=8.1 Hz, 1H), 7.35 (dd, J=8.1, 4.8 Hz, 1H).

3-(3′,5′-di-tert-butyl-[1,1′-biphenyl]-3-yl)-3H-imidazo[4,5-b]pyridine (L3-3) was synthesized as follows. To a solution mixture of THF/water (20.0 mL, 3:1), L3-2 (0.548 g, 2.00 mmol), (3,5-di-tert-butylphenyl) boronic acid (0.702 g, 3.00 mmol), potassium carbonate (0.829 g, 6.00 mmol) and tetrakis(triphenylphosphine) palladium(0) (0.116 g, 0.100 mmol) were added under argon atmosphere. The reaction mixture was refluxed for 24 h. After cooling down to room temperature, the crude product was diluted with ethyl acetate and washed with water three times. The organic fraction was dried over Na₂SO₄ and concentrated under reduced pressure. The resulting residue was purified by flash chromatography on silica gel using n-hexane/ethyl acetate (3:1) as eluent to afford compound (L3-3) as white solid. Yield: 79%. ¹H NMR (400 MHz, CDCl₃): δ 8.48 (d, J=4.7 Hz, 1H), 8.42 (s, 1H), 8.19 (dd, J=8.0, 1.1 Hz, 1H), 7.90 (s, 1H), 7.74 (dt, J=7.2, 1.8 Hz, 1H), 7.70-7.62 (m, 2H), 7.49 (t, J=1.6 Hz, 1H), 7.45 (d, J=1.6 Hz, 2H), 7.34 (dd, J=8.1, 4.8 Hz, 1H), 1.39 (s, 18H).

3-(3′,5′-di-tert-butyl-[1,1′-biphenyl]-3-yl)-1-methyl-3H-imidazo[4,5-b]pyridin-1-ium iodide (L3) was synthesized as follows. L3-3 (0.500 g, 1.30 mmol) and methyl iodide (0.406 mL, 6.52 mmol) were dissolved in THF (10 mL) and stirred at 100° C. in a sealed tube for 48 h. The solid was filtered and washed with diethyl ether to afford compound (L3) as light beige solid. Yield: 86%. ¹H NMR (500 MHz, DMSO): δ 10.47 (s, 1H), 8.82 (d, J=4.6 Hz, 1H), 8.72 (d, J=8.4 Hz, 1H), 8.14 (s, 1H), 7.96 (d, J=7.8 Hz, 1H), 7.90 (dd, J=7.7, 5.5 Hz, 2H), 7.81 (d, J=7.8 Hz, 1H), 7.50 (d, J=14.9 Hz, 3H), 4.23 (s, 3H), 1.36 (s, 18H).

L4-1 was synthesized as follows. Phenylboronic acid (0.44 g, 3.60 mmol), K₂CO₃ (1.68 g, 12.13 mmol), Pd(PPh₃)₄ (0.16 g, 0.14 mmol) and 3-bromo-2-methoxy-6-methylpyridine (0.70 g, 0.35 mmol) was refluxed in 20 mL toluene/H₂O/EtOH (12:3:5) for 24 h. After the reaction was cooled to room temperature, all volatiles were removed under reduced pressure. The residue was extracted with DCM/H₂O. The organic fraction was dried with MgSO₄, filtered and concentrated under reduced pressure. The residue was purified with silica gel column chromatography using EA/hexane as eluent to obtain the product as colorless oil. Yield: quan. ¹H NMR (300 MHz, CDCl₃): δ 7.54 (d, J=7.2 Hz, 2H), 7.50 (d, J=7.4 Hz, 1H), 7.41 (t, J=7.4 Hz, 2H), 7.36-7.28 (m, 1H), 6.81 (d, J=7.4 Hz, 1H), 3.96 (s, 3H), 2.49 (s, 3H). HRMS (EI) for C₁₃H₁₃NO [M]⁺: calcd 199.0997, found 199.0998.

L4 was synthesized as follows. L4-1 (0.75 g, 3.64 mmol) and BBr₃ (17.32 mL, 2M in DCM, 34.64 mmol) were stirred overnight in 20 mL dry DCM at room temperature. Water was added to the reaction mixture and extracted with DCM. The combined organic layers were dried over anhydrous MgSO4, and the volatiles were removed in vacuo. The crude product was washed with MeOH to give the desired product as a beige solid. Yield: 48%. ¹H NMR (300 MHz, DMSO): δ 11.78 (s, 1H), 7.70 (d, J=7.3 Hz, 2H), 7.55 (d, J=7.1 Hz, 1H), 7.35 (t, J=7.3 Hz, 2H), 7.31-7.22 (m, 1H), 6.10 (d, J=6.9 Hz, 1H), 2.20 (s, 3H). HRMS (EI) for C₁₂H₁₁NO [M]⁺: calcd 185.0841, found 185.0842.

L5-1 was synthesized as follows. (3,5-di-tert-butylphenyl)boronic acid (1.81 g, 7.72 mmol), K₂CO₃ (3.59 g, 25.98 mmol), Pd(PPh₃)₄ (0.17 g, 0.15 mmol) and 3-Bromo-2-methoxy-6-methylpyridine (1.50 g, 7.42 mmol) were refluxed in 30 mL toluene/H₂O/EtOH (12:3:5) for 24 h. After the reaction was cooled to room temperature, all volatiles were removed under reduced pressure. The residue was extracted with DCM/H₂O. The organic fraction was dried with MgSO₄, filtered and concentrated under reduced pressure. The residue was purified with silica gel column chromatography using EA/hexane as eluent to obtain the product as colorless oil. Yield: quan. ¹H NMR (500 MHz, CDCl₃): δ 7.52 (d, J=7.3 Hz, 1H), 7.40 (s, 3H), 6.80 (d, J=7.4 Hz, 1H), 3.96 (s, 3H), 1.36 (s, 18H). HRMS (EI) for C₂₁H₂₉NO [M]⁺: calcd 311.2249, found 311.2248.

L5 was synthesized as follows. L5-1 (1.48 g, 2.17 mmol) and BBr₃ (10.84 mL, 2M in HCl, 21.69 mmol) were stirred overnight in 20 mL dry DCM at room temperature. Water was added to the reaction mixture and extracted with DCM. The combined organic layers were dried over anhydrous MgSO4, and the volatiles were removed in vacuo. The crude product was washed with MeOH to give the desired product as a light-yellow solid. Yield: 99%. ¹H NMR (500 MHz, CDCl₃): δ 13.15 (s, 1H), 7.61 (s, 2H), 7.55 (d, J=7.1 Hz, 1H), 7.39 (s, 1H), 6.15 (d, J=7.1 Hz, 1H), 2.39 (s, 3H), 1.36 (s, 18H). HRMS (EI) for C₂₀H₂₈NO [M]⁺: calcd 297.2093, found 297.2093.

L6-1 was synthesized as follows. (3,5-difluorophenyl)boronic acid (0.41 g, 2.57 mmol), K₂CO₃ (1.20 g, 8.66 mmol), Pd(PPh₃)₄ (0.11 g, 0.10 mmol), and 3-Bromo-2-methoxy-6-methylpyridine (0.50 g, 2.48 mmol) were refluxed in 20 mL toluene/H2O/EtOH (12:3:5) for 24 h. After the reaction was cooled to room temperature, all volatiles were removed under reduced pressure. The residue was extracted with DCM/H₂O. The organic fraction was dried with MgSO₄, filtered and concentrated under reduced pressure. The residue was purified with silica gel column chromatography using EA/hexane as eluent to obtain the product as a white solid. Yield: 88%. ¹H NMR (500 MHz, CDCl₃): δ 7.49 (d, J=7.5 Hz, 1H), 7.15-7.04 (m, 1H), 6.81 (d, J=7.5 Hz, 1H), 6.76 (tt, J=8.9, 2.2 Hz, 1H), 3.97 (s, 3H), 2.49 (s, 3H). ¹⁹F NMR (471 MHz, CDCl₃): δ−110.69 (t, J=6.9 Hz). HRMS (EI) for C₁₃H₁₁NF₂O [M]⁺: calcd 235.0809, found 235.0795.

L6 was synthesized as follows. 3-(3,5-difluorophenyl)-2-methoxy-6-methylpyridine (1.20 g, 5.10 mmol) and BBr₃ (25.51 mL, 2M in DCM, 51.01 mmol) were stirred overnight in 20 mL dry DCM at room temperature. Water was added to the reaction mixture and extracted with DCM. The combined organic layers were dried over anhydrous MgSO4, and the volatiles were removed in vacuo. The crude product was washed with MeOH to give the desired product as a light pink solid. Yield: 87%. ¹H NMR (500 MHz, CDCl₃): δ 11.86 (br, 1H), 7.57 (d, J=7.0 Hz, 1H), 7.34 (d, J=6.9 Hz, 2H), 6.76 (tt, J=8.9, 2.1 Hz, 1H), 6.17 (d, J=7.1 Hz, 1H), 2.39 (s, 3H). ¹⁹F NMR (471 MHz, CDCl₃): δ−110.63 (t, J=8.1 Hz). HRMS (EI) for C₁₂H₉NF₂O [M]⁺: calcd 221.0652, found 221.0645.

L1, L2, or L3 (1 eq.) and silver(I) oxide (0.6 eq) were added to a two-neck flask. After addition of dry DMF (1 mL per 0.1 mmol of imidazolium salt), the reaction mixture was stirred under argon atmosphere for 24 hours at 50° C. in the absence of light. Dichloro(1,5-cyclooctadiene)platinum(II) (1 eq.) was then added, and the mixture was stirred for 2 hours at 50° C., and then for 24 hours at 125° C. Afterwards, potassium tert-butoxide (4.01 eq.) and 2-methyl-6-hydroxypyridine (4.03 eq.) were added and the mixture was stirred for 24 hours at room temperature and then for further 24 hours at 100° C. After reaction, the mixture was cooled to room temperature, all volatiles were removed under reduced pressure. The crude product was washed with water and purified by flash chromatography on silica gel using DCM/hexane as eluent. Complexes Pt—R4 to Pt—R15 were prepared by the same method as Pt—R1 to Pt—R₃.

Pt—R1: Yield: 24%. ¹H NMR (500 MHz, CD₂Cl₂): δ 8.01 (dd, J=4.9, 1.3 Hz, 2H), 7.69 (dd, J=7.8, 1.1 Hz, 2H), 7.30-7.26 (m, 4H), 7.19-7.15 (m, 2H), 7.00 (td, J=7.6, 1.2 Hz, 2H), 6.70 (td, J=7.4, 1.3 Hz, 2H), 6.49 (d, J=8.4 Hz, 2H), 6.45-6.30 (m, 4H), 3.15 (s, 6H), 2.75 (s, 6H). HRMS (ESI) for C₃₈H₃₃Pt₂N₈O₂[M+H]⁺: calcd 1023.2022, found 1023.1994.

Pt—R2: Yield: 24%. ¹H NMR (500 MHz, CD₂Cl₂): δ 8.29 (d, J=2.8 Hz, 2H), 8.20 (d, J=2.8 Hz, 2H), 7.88-7.63 (m, 4H), 7.53 (d, J=6.4 Hz, 2H), 7.30 (s, 2H), 7.19-6.98 (m, 6H), 6.73-6.67 (m, 2H), 6.58-6.53 (m, 2H), 6.12 (t, J=7.3 Hz, 2H), 5.94 (d, J=8.4 Hz, 2H), 5.86 (d, J=7.0 Hz, 2H), 2.53 (s, 6H). HRMS (ESI) for C₄₆H₃₅Pt₂N₁₀O₂ [M+H]⁺: calcd 1149.2240, found 1149.2220.

Pt—R3: Yield: 47%. 1H NMR (500 MHz, CD₂Cl₂): δ 8.01 (dd, J=4.9, 1.1 Hz, 2H), 7.69 (d, J=7.4 Hz, 2H), 7.60 (d, J=7.3 Hz, 4H), 7.41-7.35 (m, 6H), 7.30-7.25 (m, 4H), 7.18-7.15 (m, 2H), 7.02 (t, J=7.2 Hz, 2H), 6.74 (t, J=7.4 Hz, 2H), 6.56 (d, J=6.8 Hz, 2H), 6.38 (d, J=7.4 Hz, 2H), 3.18 (s, 6H), 2.42 (s, 6H). HRMS (ESI) for C₅₀H₄₁Pt₂N₈O₂ [M+H]⁺: calcd 1175.2648, found 1175.2609.

Pt—R4: Yield: 22%. ¹H NMR (500 MHz, CD₂Cl₂) δ 8.30 (d, J=2.7 Hz, 2H), 8.22 (d, J=2.7 Hz, 2H), 8.04-7.73 (m, 4H), 7.65 (d, J=7.3 Hz, 2H), 7.50 (d, J=7.8 Hz, 4H), 7.41-7.35 (m, 4H), 7.31-7.23 (m, 4H), 7.08 (s, br, 4H), 6.99 (d, J=6.4 Hz, 2H), 6.86 (d, J=7.2 Hz, 2H), 6.63-6.51 (m, 2H), 6.25-6.14 (m, 2H), 5.90 (d, J=7.2 Hz, 2H), 2.03 (s, 7H). HRMS (ESI) for C₅₈H₄₃Pt₂N₁₀O₂ [M+H]⁺: calcd 1301.2866, found 1301.2826.

Pt—R5: Yield: 62%. ¹H NMR (500 MHz, CD₂Cl₂): δ 8.12-8.00 (m, 4H), 7.49-7.39 (m, 6H), 7.34-7.24 (m, 4H), 7.20-7.13 (m, 2H), 7.01 (d, J=7.7 Hz, 2H), 6.51 (d, J=8.5 Hz, 2H), 6.44 (d, J=7.8 Hz, 2H), 6.39 (d, J=7.0 Hz, 2H), 3.21 (s, 1H), 2.78 (s, 1H), 1.42 (s, 6H).

Pt—R6: Yield: 21%. ¹H NMR (500 MHz, CD₂Cl₂): δ 8.00 (d, J=4.8 Hz, 1H), 7.69 (d, J=7.7 Hz, 1H), 7.46 (s, 2H), 7.38 (d, J=7.2 Hz, 1H), 7.35 (s, 1H), 7.29 (d, J=8.0 Hz, 1H), 7.16 (dd, J=7.8, 5.1 Hz, 1H), 7.03 (t, J=7.5 Hz, 1H), 6.76 (t, J=7.4 Hz, 1H), 6.64 (d, J=7.5 Hz, 1H), 6.30 (d, J=7.2 Hz, 1H), 3.20 (s, 3H), 2.30 (s, 3H), 1.36 (s, 18H). HRMS (ESI) for C₆₆H₇₃Pt₂N₈O₂ [M+H]⁺: calcd 1399.5152, found 1399.5085.

Pt—R7: Yield: 21%. ¹H NMR (500 MHz, CD₂Cl₂): δ 8.04 (dd, J=4.9, 1.2 Hz, 2H), 7.68 (dd, J=7.7, 1.0 Hz, 2H), 7.43 (d, J=7.4 Hz, 2H), 7.30 (dd, J=8.0, 1.2 Hz, 2H), 7.28-7.22 (m, 4H), 7.18 (dd, J=8.0, 4.9 Hz, 2H), 7.01 (td, J=7.6, 1.0 Hz, 2H), 6.79-6.68 (m, 4H), 6.54 (dd, J=7.5, 0.9 Hz, 2H), 6.41 (d, J=7.4 Hz, 2H), 3.20 (s, 6H), 2.51 (s, 6H). ¹⁹F NMR (471 MHz, CD₂Cl₂): δ−112.24 (t, J=8.3 Hz, 4F).

Pt—R8: Yield: 41%. ¹H NMR (500 MHz, CD₂Cl₂) δ=8.17 (d, J=1.8, 2H), 7.87 (m, 2H), 7.56 (t, J=1.6, 2H), 7.45 (d, J=1.7, 4H), 7.38 (d, J=1.8, 2H), 7.29 (dd, J=8.4, 7.2, 2H), 7.06 (m, 2H), 6.74 (td, J=7.4, 1.1, 2H), 6.51 (d, J=8.5, 2H), 6.40 (m, 4H), 3.20 (s, 6H), 2.77 (s, 6H), 1.43 (s, 36H).

Pt—R9: Yield: 40%. ¹H NMR (500 MHz, CD₂Cl₂) δ 8.55 (s, 2H), 8.27 (d, J=4.8 Hz, 2H), 7.71 (d, J=8.1 Hz, 2H), 7.40 (d, J=9.9 Hz, 6H), 7.29 (t, J=7.7 Hz, 2H), 7.07 (dd, J=7.9, 5.0 Hz, 2H), 6.99 (d, J=7.8 Hz, 2H), 6.55 (d, J=8.4 Hz, 2H), 6.35 (d, J=7.9 Hz, 2H), 6.28 (d, J=6.9 Hz, 2H), 5.95 (dt, J=13.6, 6.8 Hz, 2H), 2.64 (s, 6H), 1.54 (s, 6H), 1.38 (s, 36H), 0.64 (d, J=6.9 Hz, 6H).

Pt—R10: Yield: 55%. ¹H NMR (500 MHz, CD₂Cl₂) δ=8.00 (m, 6H), 7.51 (t, J=7.7, 2H), 7.36 (d, J=7.5, 3H), 7.28 (s, 2H), 7.14 (d, J=8.0, 2H), 7.09 (m, 2H), 6.78 (m, 4H), 6.67 (d, J=6.7, 2H), 6.62 (t, J=7.2, 2H), 6.48 (d, J=7.1, 2H), 3.17 (s, 6H), 1.28 (s, 36H). Two views of an X-ray single crystal structure of Pt—R10 are shown in FIGS. 22A and 22B.

Pt—R11: Yield: 30%. ¹H NMR (500 MHz, CD₂Cl₂) δ=8.23 (d, J=1.8, 2H), 8.01 (s, 4H), 7.52 (ddd, J=20.4, 8.2, 4.4, 6H), 7.43 (d, J=1.7, 4H), 7.30 (s, 2H), 7.26 (d, J=1.8, 2H), 6.84 (t, J=7.5, 2H), 6.80 (m, 2H), 6.68 (dd, J=16.0, 7.4, 4H), 6.54 (d, J=7.1, 2H), 3.24 (s, 6H), 1.42 (s, 36H), 1.30 (s, 36H).

Pt—R12: Yield: 52%. ¹H NMR (500 MHz, CD₂Cl₂) δ=8.16 (d, J=1.8, 2H), 7.88 (m, 2H), 7.57 (t, J=1.6, 2H), 7.47 (dd, J=10.2, 1.8, 8H), 7.40 (dd, J=4.5, 2.7, 4H), 7.36 (t, J=1.7, 2H), 7.08 (td, J=7.6, 1.1, 2H), 6.79 (td, J=7.4, 1.1, 2H), 6.66 (d, J=6.6, 2H), 6.32 (d, J=7.3, 2H), 3.26 (s, 6H), 2.31 (s, 6H), 1.44 (s, 36H), 1.37 (s, 36H).

Pt—R13: Yield: 10%. ¹H NMR (500 MHz, CD₂Cl₂) δ=8.19 (dd, J=10.5, 2.8, 4H), 7.97 (d, J=7.7, 2H), 7.29 (m, 2H), 6.89 (t, J=7.5, 2H), 6.64 (t, J=7.4, 2H), 6.55 (d, J=8.4, 2H), 6.37 (d, J=7.5, 2H), 6.30 (d, J=6.9, 2H), 5.80 (dt, J=13.6, 6.8, 2H), 2.62 (s, 6H), 1.58 (d, J=6.8, 6H), 0.80 (d, J=6.9, 6H).

Pt—R14: Yield: 10%. ¹H NMR (500 MHz, CD₂Cl₂) δ=8.26 (m, 2H), 8.07 (d, J=7.7, 2H), 8.01 (dd, J=8.2, 0.9, 2H), 7.86 (m, 4H), 7.79 (m, 2H), 7.62 (d, J=7.3, 2H), 7.34 (s, 2H), 7.16 (t, J=6.8, 6H), 6.74 (m, 2H), 6.30 (t, J=7.5, 2H), 6.00 (d, J=8.4, 2H), 5.92 (t, J=7.3, 2H), 5.88 (d, J=7.1, 2H), 2.53 (s, 6H).

Pt—R15: Yield: 17%. ¹H NMR (500 MHz, CD₂Cl₂) δ=8.27 (d, J=8.3, 2H), 8.11 (s, 2H), 8.04 (m, 4H), 7.84 (ddd, J=22.5, 15.2, 7.4, 6H), 7.38 (s, 6H), 7.33 (s, 2H), 7.16 (s, 2H), 7.01 (s, 4H), 6.92 (d, J=7.3, 2H), 6.29 (t, J=7.5, 2H), 6.01 (t, J=7.2, 2H), 5.92 (d, J=7.3, 2H), 1.89 (s, 6H), 1.41 (s, 36H).

Fabrication and Characterization of OLEDs

Indium-tin-oxide (ITO) coated glass with a sheet resistance of 10 Ω/sq was used as the anode substrate. Before film deposition, patterned ITO substrates were cleaned with detergent, rinsed in de-ionized water, acetone, and isopropanol, and then dried in an oven for 1 h in a cleanroom. The slides were then treated in an ultraviolet-ozone chamber for 5 min. The OLEDs were fabricated in a Kurt J. Lesker SPECTROS vacuum deposition system with a base pressure of 10⁻⁷ mbar. In the vacuum chamber, organic materials were thermally deposited in sequence at a rate of 0.5 Å s⁻¹. The doping process in the EMLs was realized using co-deposition technology. Afterward, LiF (1.2 nm) and Al (100 nm) were thermally deposited at rates of 0.02 and 0.2 nm s⁻¹, respectively. The film thicknesses were determined in situ with calibrated oscillating quartz-crystal sensors.

Current density-brightness-voltage characteristics, EL spectra, and EQE of EL device were obtained by using a Keithley 2400 source-meter and an absolute external quantum efficiency measurement system (C9920-12, Hamamatsu Photonics). All devices were encapsulated in a 200-nm-thick Al₂O₃ thin film deposited by atomic layer deposition (ALD) in a Kurt J. Lesker SPECTROS ALD system before measurements.

Results

Photophysical Properties of Dinuclear Platinum(II) Complexes

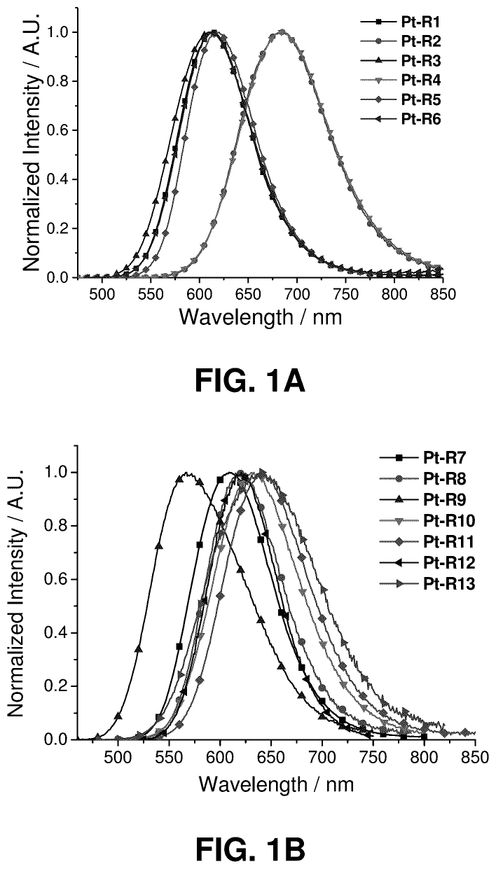

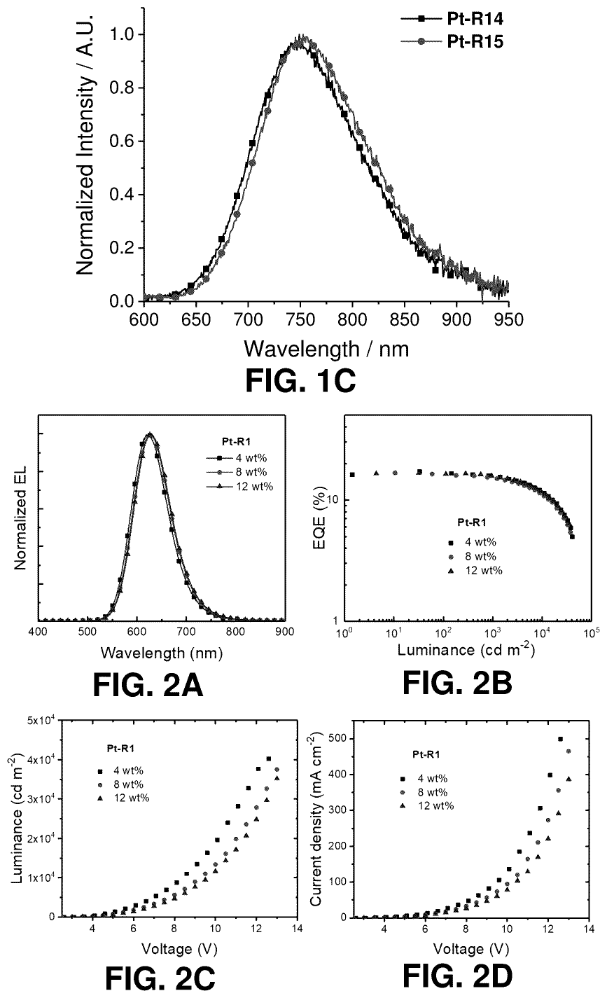

The dinuclear platinum(II) complexes (Pt—R1 to Pt—R6) display red to deep-red photoluminescence at 612 and 685 nm with quantum yields of 0.78-0.97 in PMMA films (FIG. 1A). The short emission lifetimes are down to 1.7-1.9 μs, giving rise to high radiative rate constant (kᵣ) of 4.3×10⁵ s⁻¹-5.5×10⁵ s⁻¹ and unprecedented low non-radiative decay rate constant (kₙᵣ) as low as 0.16×10⁵ s⁻¹. The dinuclear Pt(II) complexes (Pt—R7, Pt—R8, Pt—R9, Pt—R10, Pt—R11, Pt—R12, Pt—R13) display strong red phosphorescence with emission maxima at 607-641 nm and quantum yield of 0.80-0.95 in PMMA films at room temperature (FIG. 1B). The emission lifetimes are 1.4-2.1 μs, giving rise to large radiative rate constant of 4.3-6.4×10⁵ s⁻¹. Complexes Pt—R14 and Pt—R15 with π-extended conjugation at NHC moiety are near-infrared emissive in PMMA films at room temperature (FIG. 1C), showing emission maxima at 749-752 nm, quantum yield of 0.42-0.53 and large radiative rate constant of 4.2-5.3×10⁵ s⁻¹. The emission data and related photophysical data are shown in Table 1.

TABLE 1
Emission data of Pt-R1-Pt-R15 at room temperature.

| | | λₑₘ/ | FWHM/ | | τₑₘ^{#} | kᵣ/kₙᵣ |
|---|---|---|---|---|---|---|
| | Medium | nm | nm | Φₑₘ^{#} | [μs] | [×10⁵ s⁻¹] |
| Pt-R1 | 4 wt % in | 612 | 85 | 0.91 | 1.7 | 5.4/0.53 |
| | PMMA | | | | | |
| Pt-R2 | 4 wt % in | 685 | 106 | 0.78 | 1.8 | 4.3/1.2 |
| | PMMA | | | | | |
| Pt-R3 | 4 wt % in | 612 | 94 | 0.94 | 1.7 | 5.5/0.35 |
| | PMMA | | | | | |
| Pt-R4 | 4 wt % in | 684 | 107 | 0.76 | 1.7 | 4.5/1.4 |
| | PMMA | | | | | |
| Pt-R5 | 4 wt % in | 618 | 81 | 0.97 | 1.9 | 5.1/0.16 |
| | PMMA | | | | | |
| Pt-R6 | 4 wt % in | 614 | 85 | 0.87 | 1.8 | 4.8/0.72 |
| | PMMA | | | | | |
| Pt-R7 | 4 wt % in | 607 | 85 | 0.91 | 1.7 | 5.4/0.53 |
| | PMMA | | | | | |
| Pt-R8 | 4 wt % in | 621 | 86 | 0.95 | 1.7 | 5.6/0.29 |
| | PMMA | | | | | |
| Pt-R9 | 4 wt % in | 567 | 105 | 0.79 | 1.8 | 4.4/1.2 |
| | PMMA | | | | | |
| Pt-R10 | 4 wt % in | 631 | 97 | 0.90 | 2.1 | 4.3/0.48 |
| | PMMA | | | | | |
| Pt-R11 | 4 wt % in | 641 | 97 | 0.91 | 1.6 | 5.7/0.56 |
| | PMMA | | | | | |
| Pt-R12 | 4 wt % in | 621 | 78 | 0.90 | 1.4 | 6.4/0.71 |
| | PMMA | | | | | |
| Pt-R13 | 4 wt % in | 641 | 125 | 0.80 | 1.8 | 4.4/1.1 |
| | PMMA | | | | | |
| Pt-R14 | 4 wt % in | 749 | 118 | 0.53 | 1.0 | 5.3/4.7 |
| | PMMA | | | | | |
| Pt-R15 | 4 wt % in | 752 | 123 | 0.42 | 1.0 | 4.2/5.8 |
| | PMMA | | | | | |

^{#}Measured under nitrogen atmosphere.

OLED Performance

Vacuum-deposited devices fabricated with Pt—R1 exhibited red electroluminescence with CIE coordinates of (0.63, 0.37) at doping concentrations of 4-12 wt % (FIGS. 2A-2D). The external quantum efficiency (“EQE”) and current efficiency (“CE”) of the device doped with 4 wt % Pt—R1 were 15.7% and 23.4 cd/A, respectively, at 1000 cd m⁻² The performance data of the device with Pt—R1 are shown in Table 2.

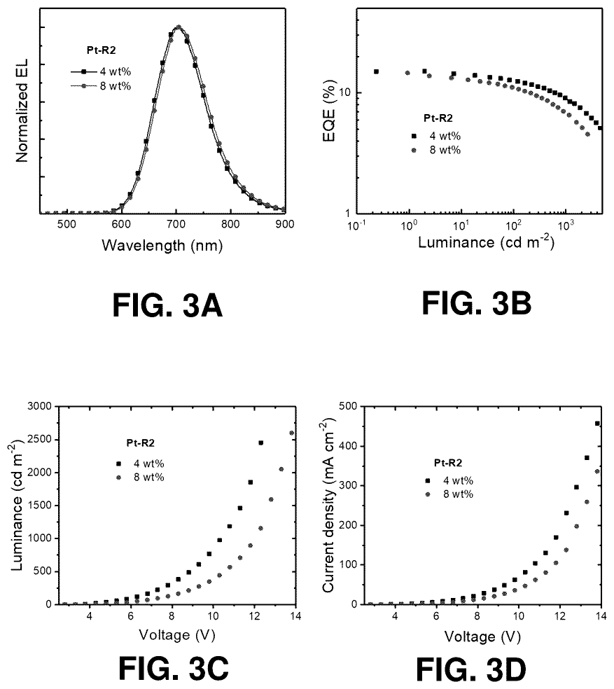

Vacuum-deposited devices fabricated with Pt—R2 exhibited NIR electroluminescence with λₘₐₓ at 702-706 nm (FIGS. 3A-3D). The EQE of the device doped with 4 wt % Pt—R2 was 9.1% at 1000 cd m⁻². The performance data of the device with Pt—R2 are shown in Table 3. The λ^{em} of the OLED fabricated with Pt—R2 red-shifted to above 700 nm compared to the λₑₘ of Pt—R2 measured in a thin film (about 685 nm as shown in Table 1). The observed red-shift is mainly due to the different molecular packing of the Pt emitters in different host materials.

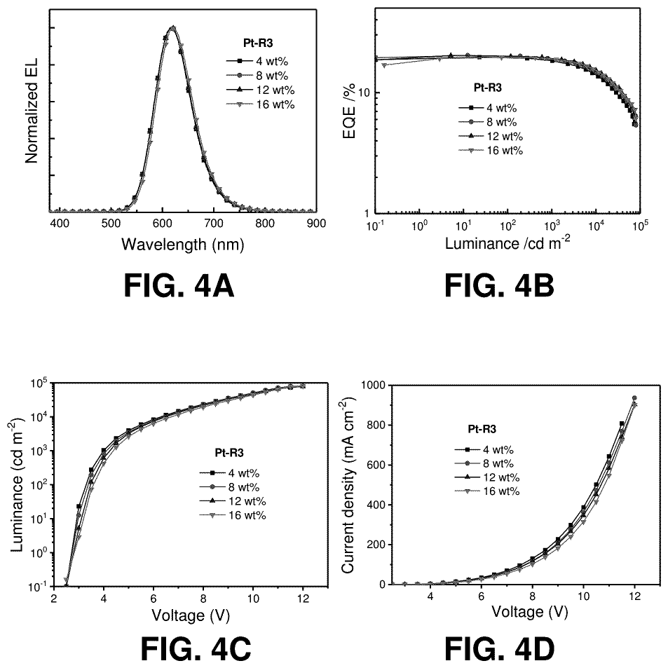

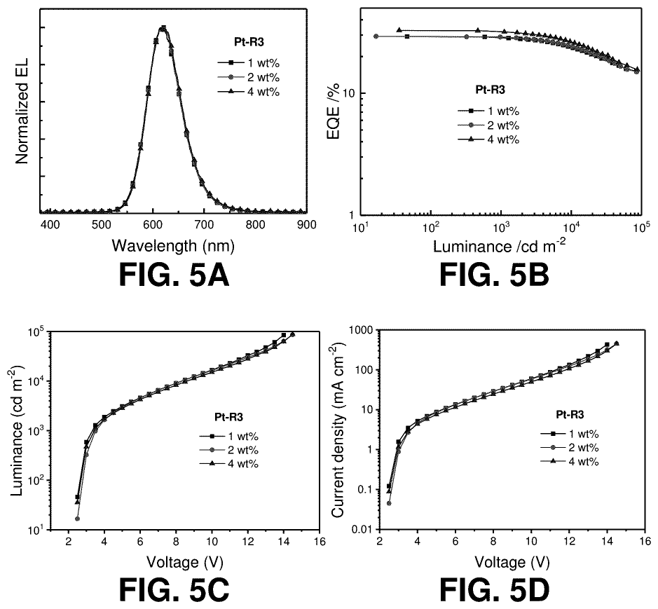

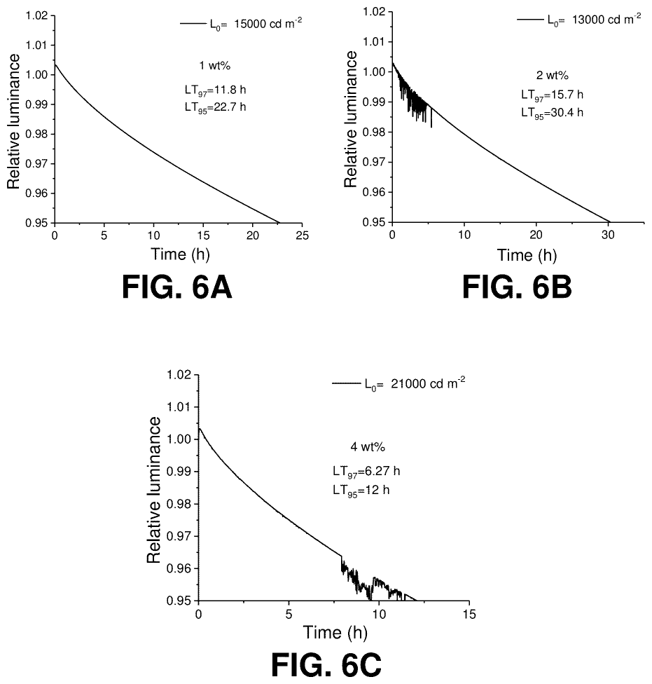

Two vacuum-deposited devices fabricated with Pt—R₃ both exhibited red electroluminescence with λₘₐₓ at 615-621 nm (first device: FIGS. 4A-4D; second device: FIGS. 5A-5D). The EQE of the device doped with 4 wt % Pt—R3 in DMIC-Cz: DMIC-Trz co-host (the second device) was 31.9% at 1000 cd m⁻². The performance data of the two devices fabricated with Pt—R3 are shown in Table 4 and Table 5, respectively. The device lifetime data of the second device fabricated with Pt—R3 are shown in FIGS. 6A-6C and summarized in Table 6.

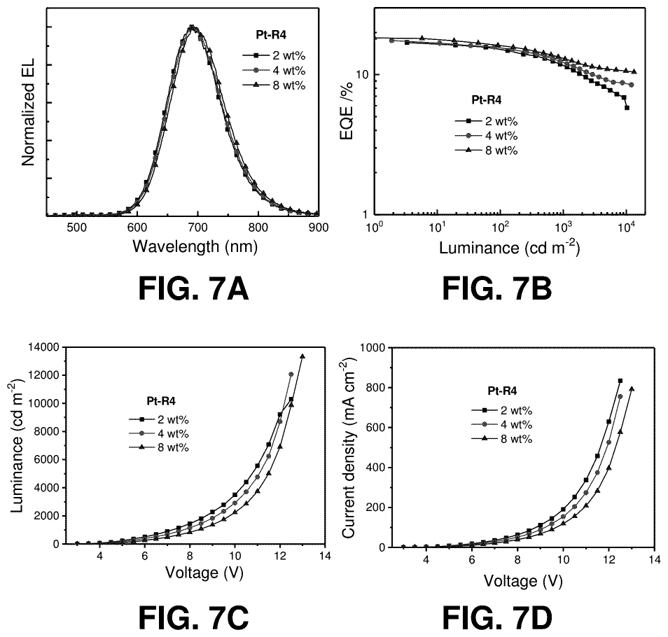

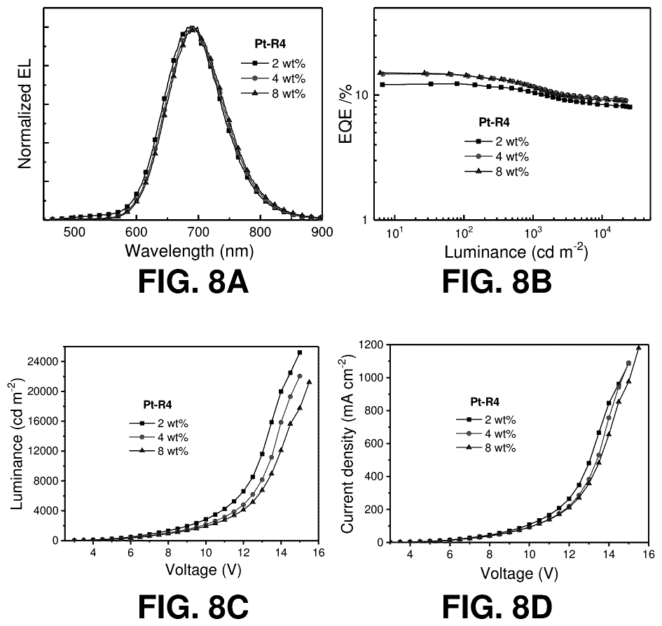

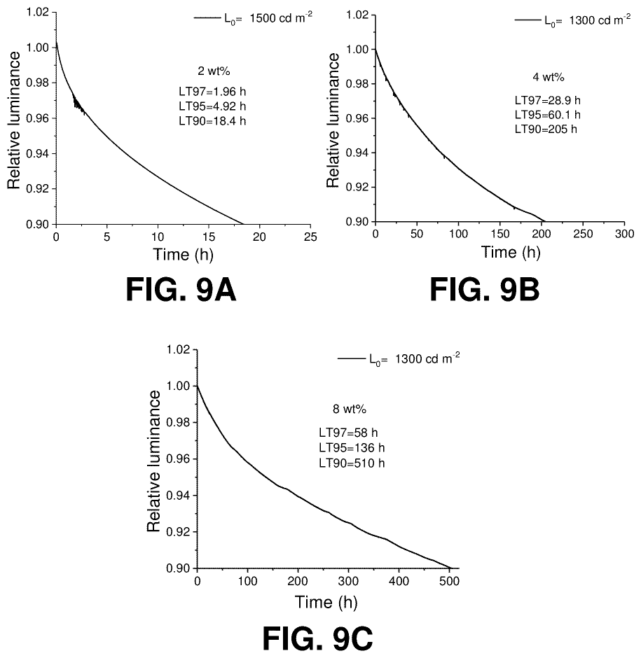

Two vacuum-deposited devices fabricated with Pt—R4 both exhibited deep red to NIR electroluminescence with λₘₐₓ at 690-698 nm (first device: FIGS. 7A-7D; second device: FIGS. 8A-8D). The EQE of the device doped with 8 wt % Pt—R4 in TCTA: TPBi co-host (first device) was 13.0% at 1000 cd m⁻². The performance data of the two devices fabricated with Pt—R4 are shown in Table 7 and Table 8, respectively. The device lifetime data of the second device fabricated with Pt—R4 are shown in FIGS. 9A-9C and summarized in Table 9.

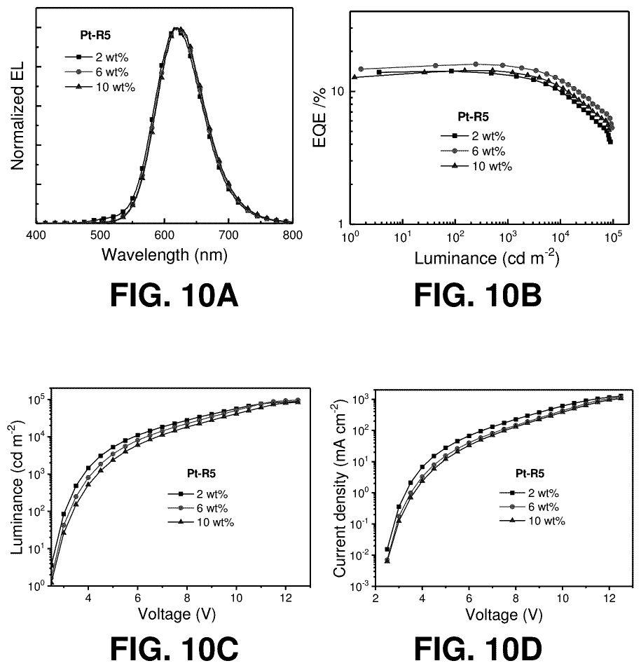

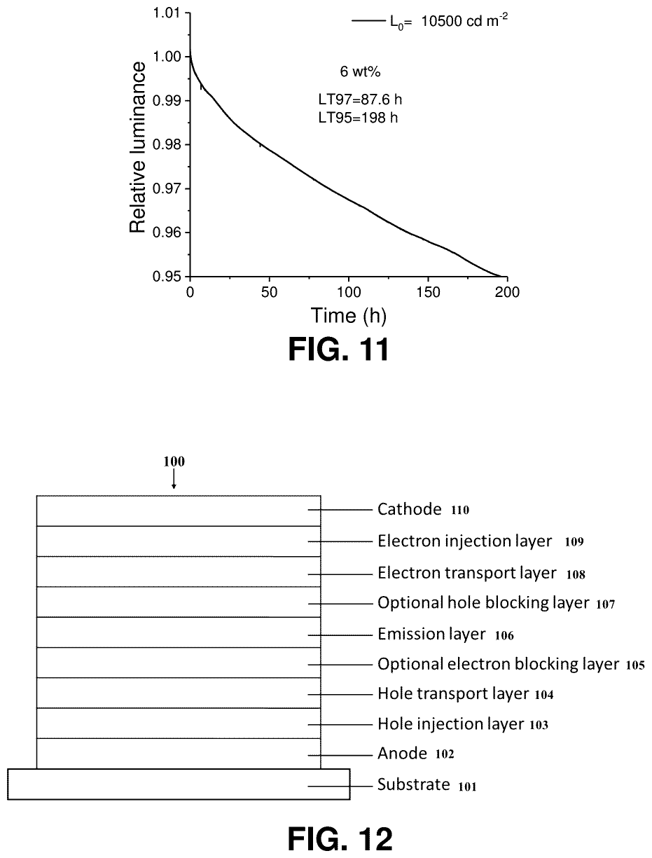

Vacuum-deposited devices fabricated with Pt—R5 exhibited red electroluminescence with λₘₐₓ at 615-620 nm (FIGS. 10A-10D). The EQE of the device doped with 6 wt % Pt—R5 in RH host was 15.6% at 1000 cd m⁻². The performance data of the devices fabricated with Pt—R5 are shown in Table 10. The device lifetime data of the device fabricated with Pt—R5 is shown in FIG. 11 and summarized in Table 11.

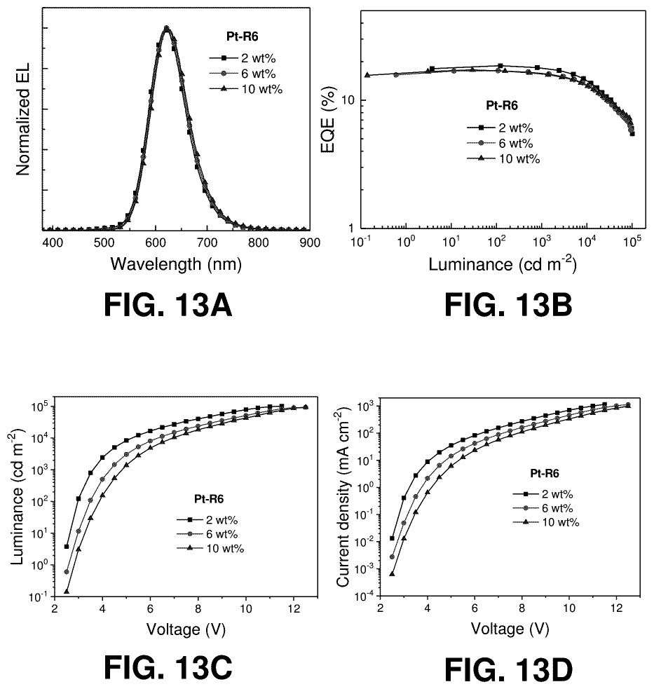

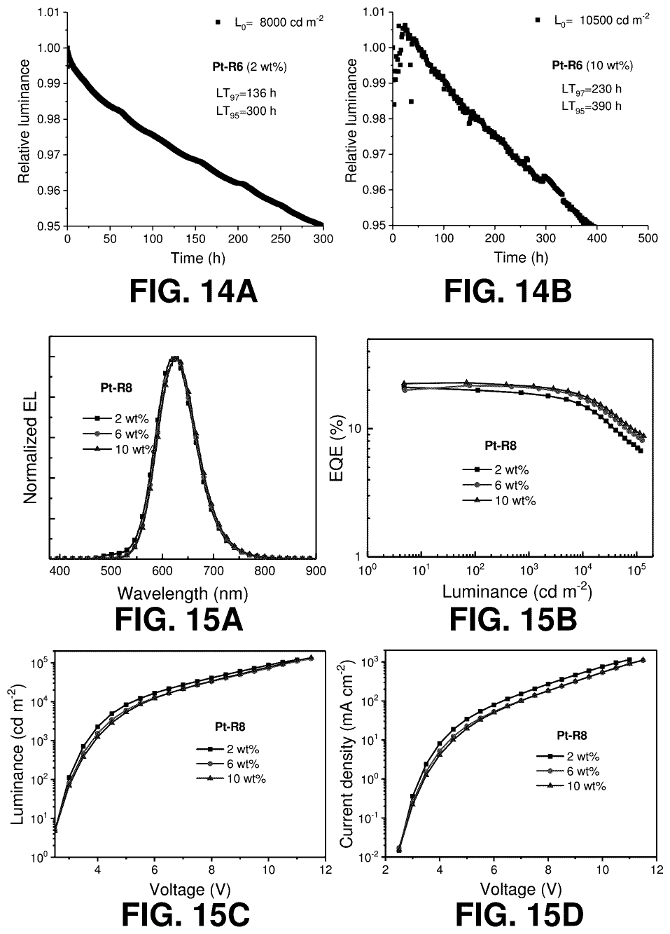

Vacuum-deposited devices fabricated with Pt—R₆ exhibited red electroluminescence (FIGS. 13A-13D). The performance data of the devices fabricated with Pt—R6 are shown in Table 12. The device lifetime data of the device fabricated with Pt—R6 is shown in FIGS. 14A and 14B and summarized in Table 13.

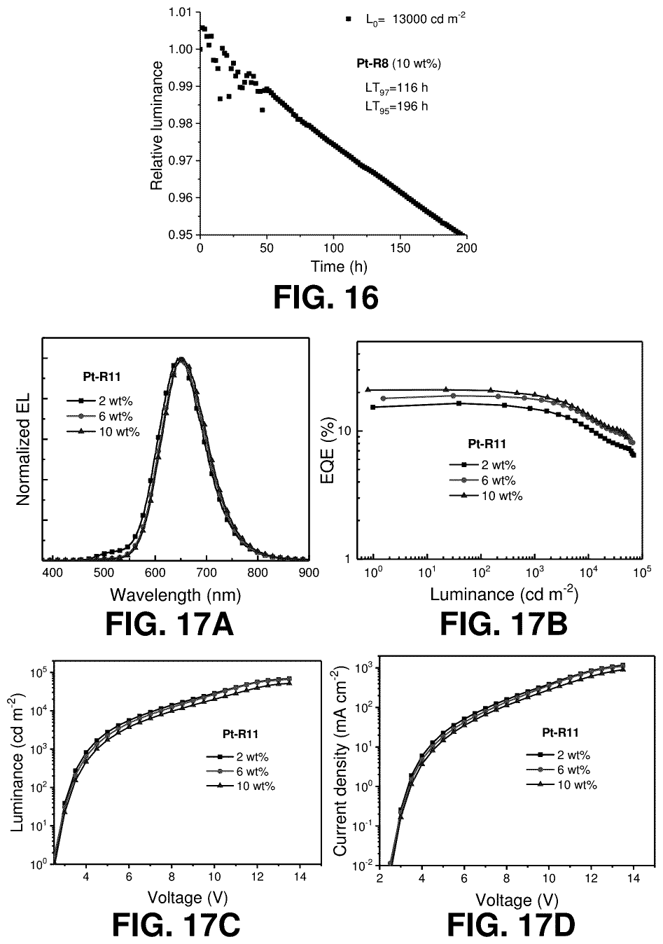

Vacuum-deposited devices fabricated with Pt—R8 exhibited red electroluminescence (FIGS. 15A-15D). The performance data of the devices fabricated with Pt—R₈ are shown in Table 14. The device lifetime data of the device fabricated with Pt—R8 is shown in FIG. 16 and summarized in Table 15.

Vacuum-deposited devices fabricated with Pt—R11 exhibited red electroluminescence (FIGS. 17A-17D). The performance data of the devices fabricated with Pt—R11 are shown in Table 16.

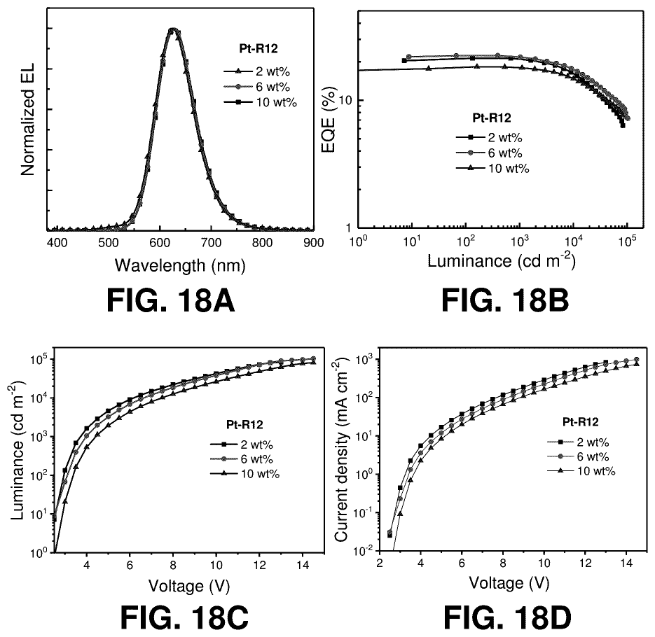

Vacuum-deposited devices fabricated with Pt—R12 exhibited red electroluminescence (FIGS. 18A-18D). The performance data of the devices fabricated with Pt—R12 are shown in Table 17.

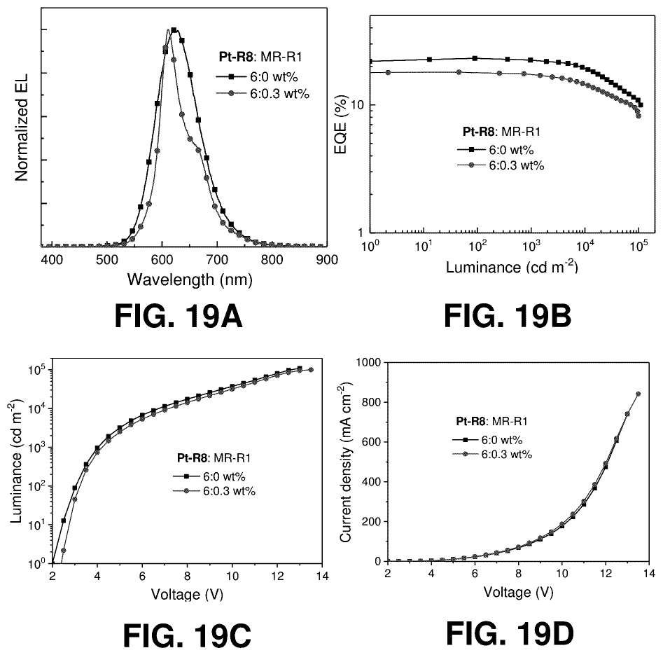

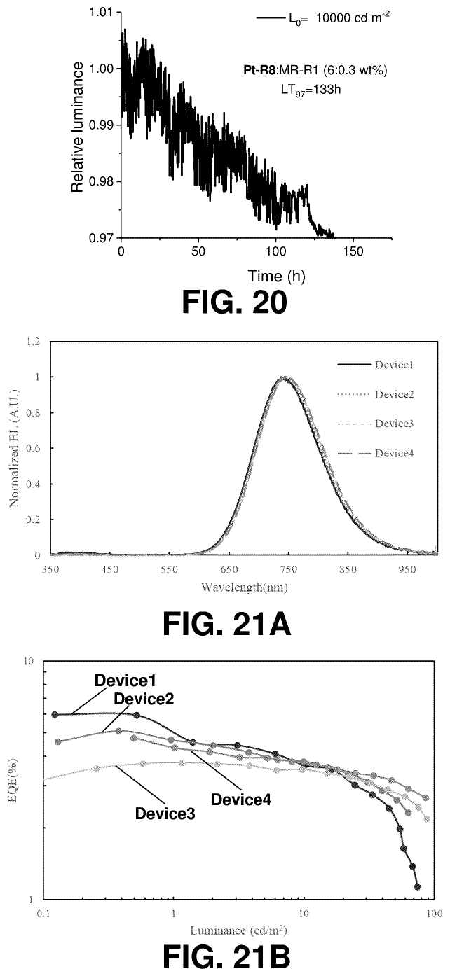

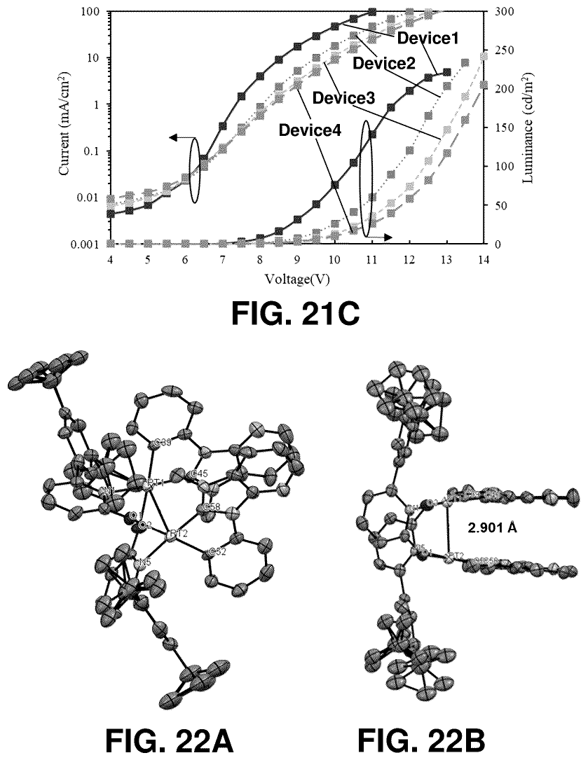

The operational lifetime LT₉₅ of the devices based on these dinuclear Pt emitters is over 21200 hours, which is a new record high for Pt-red OLEDs in the literature. Additionally, red hyperfluorescence OLED was fabricated using Pt—R8 as sensitizer and MR—R1 as dye. The electroluminescence of the devices fabricated with Pt—R8 and MR—R1 is shown in FIGS. 19A-19D, and the performance data are shown in Table 18. The device lifetime data of the device fabricated with Pt—R8 and MR—R1 is shown in FIG. 20 and summarized in Table 19. The device displayed narrowband electroluminescence with FWHM of 57 nm and exceptionally long operational lifetime LT₉₇ of about 6600 hours. The solution-processed NIR OLEDs based on Pt—R14, displayed maximum EQE up to 6.0% (FIGS. 21A-21C, and Table 20).

Further, the vacuum-deposited devices fabricated with Pt—R2 and Pt—R5, respectively, are compared with other platinum(II) red emitters. The performance data are shown in Table 21.

TABLE 2
Performance data of vacuum-deposited devices with Pt-R1*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R1 conc. | [cd m⁻²] | Max | m⁻² | Max | cd m⁻² | Max | cd m⁻² | CIE [(x, y)] | [nm] | λmax [nm] |
| 4 wt % | 41000 | 24.85 | 23.39 | 28.63 | 15.81 | 17.11 | 15.71 | 0.62, 0.38 | 86 | 622 |
| 8 wt % | 37600 | 21.84 | 20.38 | 23.77 | 11.88 | 16.72 | 15.17 | 0.63, 0.37 | 87 | 628 |
| 12 wt % | 35200 | 21 | 20.28 | 21.72 | 11.59 | 16.62 | 15.8 | 0.63, 0.37 | 87 | 628 |

*Device structure (a single layer of light emitting layer containing Pt-R1): ITO/HAT-CN (5 nm)/TAPC (40 nm)/TCTA (10 nm)/TCTA: TPBi: Pt-R1 (20 nm)/TPBi (50 nm)/LiF (1 nm)/Al (100 nm).

TABLE 3
Performance data of vacuum-deposited devices with Pt-R2*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R2 conc. | [cd m⁻²] | Max | m⁻² | Max | cd m⁻² | Max | cd m⁻² | CIE [(x, y)] | [nm] | λmax [nm] |
| 4 wt % | 4540 | 1.7 | 1.19 | 1.73 | 0.36 | 15.1 | 9.06 | 0.70, 0.30 | 109 | 702 |
| 8 wt % | 2600 | 2 | 0.84 | 1.9 | 0.22 | 14.64 | 6.76 | 0.70, 0.30 | 110 | 706 |

*Device structure (a single layer of light-emitting layer containing Pt-R2): ITO/HAT-CN (5 nm)/TAPC (40 nm)/TCTA (10 nm)/TCTA:TPBi:Pt-R2 (20 nm)/TPBi (50 nm)/LiF (1 nm)/Al (100 nm).

TABLE 4
Performance data of a first vacuum-deposited device with Pt-R3*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R3 conc. | [cd m⁻²] | Max | m⁻² | Max | cd m⁻² | Max | cd m⁻² | CIE [(x, y)] | [nm] | λmax [nm] |
| 4 wt % | 73100 | 32.3 | 30.2 | 38.7 | 23.7 | 19.6 | 18.3 | 0.61, 0.39 | 83 | 615 |
| 8 wt % | 80600 | 32.5 | 30.7 | 39.1 | 24.1 | 20.3 | 19.2 | 0.61, 0.39 | 83 | 618 |
| 12 wt % | 76600 | 29.9 | 28.3 | 34.4 | 20.9 | 20.2 | 19.2 | 0.62, 0.38 | 83 | 619 |
| 16 wt % | 80200 | 28.5 | 27.8 | 30.9 | 20.6 | 19.6 | 19.1 | 0.62, 0.38 | 83 | 620 |

*Device structure: ITO/HAT-CN (5 nm)/TAPC (40 nm)/TCTA (10 nm)/TCTA:TPBi:Pt-R3 (20 nm)/TPBi (50 nm)/LiF (1 nm)/Al (100 nm).

TABLE 5
Performance data of a second vacuum-deposited device with Pt-R3*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R3 conc. | [cd m⁻²] | Max | m⁻² | Max | cd m⁻² | Max | cd m⁻² | CIE [(x, y)] | [nm] | λmax [nm] |
| 1 wt % | 84600 | 37.7 | 37 | 42.7 | 36.2 | 29.2 | 28.6 | 0.62, 0.38 | 77 | 621 |
| 2 wt % | 85700 | 37.1 | 36.6 | 46.7 | 32.9 | 29.3 | 28.8 | 0.62, 0.38 | 77 | 620 |
| 4 wt % | 87200 | 40.6 | 39.7 | 51 | 35.8 | 32.7 | 31.9 | 0.62, 0.37 | 77 | 620 |

*Device structure: ITO/HAT-CN (10 nm)/FSFA (120 nm)/FSF4A (5 nm)/Pt-R3:DMIC-Cz:DMIC-Trz (30 nm)/ANT-Biz (5 nm)/ANT-Biz:Liq (1:1) (25 nm)/Liq (2 nm)/Al (100 nm).

TABLE 6
Lifetime measurement data for the
second OLED containing Pt-R3*.

| Pt-R3 conc. | L₀ (cd m⁻²)** | LT97 (h) | LT95 (h) |
|---|---|---|---|
| 1 wt % | 15000 | 11.8 | 22.7 |
| 2 wt % | 13000 | 15.7 | 30.4 |
| 4 wt % | 21000 | 6.27 | 12 |

*Device structure: ITO/HAT-CN (10 nm)/FSFA (120 nm)/FSF4A (5 nm)/Pt-R3:DMIC-Cz:DMIC-Trz (30 nm)/ANT-Biz (5 nm)/ANT-Biz:Liq (1:1) (25 nm)/Liq (2 nm)/Al (100 nm).
**The initial luminance intensity at which LT is measured refers to L₀.

TABLE 7
Performance data of a first vacuum-deposited device with Pt-R4*

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R4 conc. | [cd m⁻²] | Max | m⁻² | Max | cd m⁻² | Max | cd m⁻² | CIE [(x, y)] | [nm] | λmax [nm] |
| 2 wt % | 10400 | 3.62 | 2.47 | 3.79 | 1.07 | 17 | 11.6 | 0.67, 0.32 | 104 | 690 |
| 4 wt % | 12100 | 3.31 | 2.31 | 3.47 | 0.93 | 17.5 | 12.2 | 0.68, 0.31 | 104 | 694 |
| 8 wt % | 13320 | 2.96 | 2.09 | 3.1 | 0.77 | 18.3 | 13 | 0.69, 0.31 | 104 | 694 |

*Device structure: ITO/HAT-CN (5 nm)/TAPC (40 nm)/TCTA (10 nm)/TCTA:TPBi:Pt-R4 (20 nm)/TPBi (50 nm)/LiF (1 nm)/Al (100 nm).

TABLE 8
Performance data of a second vacuum-deposited device with Pt-R4*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R4 conc. | [cd m⁻²] | Max | m⁻² | Max | cd m⁻² | Max | cd m⁻² | CIE [(x, y)] | [nm] | λmax [nm] |
| 2 wt % | 25200 | 3.57 | 3.03 | 3.67 | 1.28 | 12.3 | 10.5 | 0.65, 0.34 | 109 | 691 |
| 4 wt % | 22100 | 3.29 | 2.62 | 3.44 | 1.03 | 14.7 | 11.7 | 0.67, 0.32 | 109 | 698 |
| 8 wt % | 21200 | 3.03 | 2.32 | 3.11 | 0.88 | 15 | 11.5 | 0.68, 0.32 | 109 | 698 |

*Device structure: ITO/HAT-CN (10 nm)/BPBPA (120 nm)/EB (5 nm)/Pt-R4:RH (40 nm)/HB (5 nm)/ZADN:Liq (35:65) (35 nm)/Liq (2 nm)/Al (100 nm).

TABLE 9
Lifetime measurement data for the
second OLED containing Pt-R4*.

| Pt-R4 conc. | L₀ (cd m⁻²)** | LT97 (h) | LT95 (h) | LT90 (h) |
|---|---|---|---|---|
| 2 wt % | 1500 | 1.96 | 4.92 | 18.4 |
| 4 wt % | 1300 | 28.9 | 60.1 | 205 |
| 8 wt % | 1300 | 58 | 136 | 510 |

*Device structure: ITO/HAT-CN (10 nm)/BPBPA (120 nm)/EB (5 nm)/Pt-R4:RH (40 nm)/HB (5 nm)/ZADN:Liq (35:65) (35 nm)/Liq (2 nm)/Al (100 nm).
**The initial luminance intensity at which LT is measured refers to L₀.

TABLE 10
Performance data of vacuum-deposited device with Pt-R5*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R5 conc. | [cd m⁻²] | Max | m⁻² | Max | cd m⁻² | Max | cd m⁻² | CIE [(x, y)] | [nm] | λmax [nm] |
| 2 wt % | 89300 | 23.7 | 22.2 | 29.2 | 18.7 | 14.2 | 13.3 | 0.60, 0.39 | 87 | 615 |
| 6 wt % | 96200 | 25 | 24.5 | 28.9 | 19.2 | 16 | 15.6 | 0.61, 0.38 | 87 | 620 |
| 10 wt % | 83100 | 21.8 | 21.2 | 24.3 | 15 | 14.4 | 13.9 | 0.62, 0.38 | 87 | 620 |

*Device structure: ITO/HAT-CN (10 nm)/BPBPA (40 nm)/EB (5 nm)/Pt-R5:RH (40 nm)/HB (5 nm)/ZADN:Liq (35:65) (35 nm)/Liq (2 nm)/Al (100 nm).

TABLE 11
Lifetime measurement data for the OLED containing Pt-R5*

| | L₀ | LT@L₀ | | | LT@1000 cd m⁻² | |
|---|---|---|---|---|---|---|
| Conc. | [cd m⁻²] | LT97 [h] | LT95 [h] | n | LT97 [h] | LT95 [h] |
| 6 wt/wt % | 10500 | 88 | 198 | 1.7 | 4792 | 10781 |

Assume n = 1.7 in LT(L₁) = LT(L₀) × (L₀/L₁)ⁿ
*Device structure (a single layer of light emitting layer containing Pt-R5): ITO/HAT-CN (10 nm)/BPBPA (40 nm)/EB (5 nm)/Pt-R5:RH (40 nm)/HB (5 nm)/ ZADN:Liq (35:65) (35 nm)/Liq (2 nm)/Al (100 nm).
**The initial luminance intensity at which LT is measured refers to L₀.

TABLE 12
Performance data of vacuum-deposited devices with Pt-R6*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R6 conc. | [cd m⁻²] | Max | m⁻² | Max | cd m⁻² | Max | cd m⁻² | CIE [(x, y)] | [nm] | λmax [nm] |
| 2 wt % | 102000 | 30 | 28.8 | 35.7 | 26.6 | 18.6 | 17.9 | 0.61, 0.38 | 83 | 620 |
| 6 wt % | 93400 | 24 | 22.9 | 27.9 | 17 | 17 | 16.3 | 0.62, 0.38 | 84 | 621 |
| 10 wt % | 93000 | 24.6 | 23 | 28 | 15.5 | 17.2 | 16.2 | 0.63, 0.37 | 84 | 624 |

*Device structure (a single layer of light emitting layer containing Pt-R6):ITO/HAT-CN (10 nm)/BPBPA (40 nm)/EB (5 nm)/Pt-R6:RH (40 nm)/HB (5 nm)/ZADN:Liq (35:65) (35 nm)/Liq (2 nm)/Al (100 nm).

TABLE 13
Device lifetime measurement for Pt-R6*.

| | L₀ | LT@L₀ | | | LT@1000 cd m⁻² | |
|---|---|---|---|---|---|---|
| Conc. | [cd m⁻²] | LT97 [h] | LT95 [h] | n | LT97 [h] | LT95 [h] |
| 2 wt/wt % | 8000 | 136 | 300 | 1.7 | 4664 | 10289 |
| 10 wt/wt % | 10500 | 230 | 390 | 1.7 | 12524 | 21237 |

Assume n = 1.7 in LT(L₁) = LT(L₀) × (L₀/L₁)ⁿ
*Device structure (a single layer of light emitting layer containing Pt-R6): ITO/HAT-CN (10 nm)/BPBPA (40 nm)/EB (5 nm)/Pt-R6:RH (40 nm)/HB (5 nm)/ZADN:Liq (35:65) (35 nm)/Liq (2 nm)/Al (100 nm).

TABLE 14
Performance data of vacuum-deposited devices with Pt-R8*.

| | | CE [cd A⁻¹] | | PE [lm W⁻¹] | | EQE [%] | | | | |
|---|---|---|---|---|---|---|---|---|---|---|
| | L | | at 1000 cd | | at 1000 | | at 1000 | | FWHM | |
| Pt-R8 conc. | [cd m⁻²] | Max | m⁻² | Max | cd m⁻² | Max | cd m⁻² | CIE [(x, y)] | [nm] | λmax [nm] |
| 2 wt % | 119000 | 32.5 | 29.1 | 40.9 | 25.9 | 21 | 18.9 | 0.61, 0.39 | 91 | 625 |
| 6 wt % | 128000 | 31 | 30.1 | 35.9 | 25.3 | 21.7 | 20.9 | 0.62, 0.38 | 89 | 625 |
| 10 wt % | 136000 | 31.7 | 29.9 | 39.2 | 23.6 | 22.8 | 21.4 | 0.62, 0.38 | 89 | 630 |

*Device structure (a single layer of light emitting layer containing Pt-R8): ITO/HAT-CN (10 nm)/BPBPA (40 nm)/EB (5 nm)/Pt-R8:RH (40 nm)/HB (5 nm)/ZADN:Liq (35:65) (35 nm)/Liq (2 nm)/Al (100 nm).

TABLE 15
Device lifetime measurement for Pt-R8*.

| | L₀ | LT@L₀ | | | LT@1000 cd m⁻² | |
|---|---|---|---|---|---|---|
| Conc. | [cd m⁻²] | LT97 [h] | LT95 [h] | n | LT97 [h] | LT95 [h] |
| 10 wt/wt % | 13000 | 116 | 196 | 1.7 | 9082 | 15345 |

Assume n = 1.7 in LT(L₁) = LT(L₀) × (L₀/L₁)ⁿ
*Device structure (a single layer of light emitting layer containing Pt-R8): ITO/HAT-CN (10 nm)/BPBPA (40 nm)/EB (5 nm)/Pt-R8:RH (40 nm)/HB (5 nm)/ZADN:Liq (35:65) (35 nm)/Liq (2 nm)/Al (100 nm).

TABLE 16
Performance data of vacuum-deposited devices with Pt-R11*.

| | | CE [cd A⁻¹] | | PE [lm W⁻¹] | | EQE [%] | | | | |
|---|---|---|---|---|---|---|---|---|---|---|
| Pt-R11 | L | | at 1000 cd | | at 1000 | | at 1000 | | FWHM | |
| conc. | [cd m⁻²] | Max | m⁻² | Max | cd m⁻² | Max | cd m⁻² | CIE [(x, y)] | [nm] | λmax [nm] |
| 2 wt % | 69500 | 15.1 | 13.6 | 17.7 | 10.4 | 16.4 | 14.9 | 0.62, 0.37 | 106 | 650 |
| 6 wt % | 66500 | 14.1 | 13.3 | 16.8 | 9.9 | 18.8 | 17.7 | 0.64, 0.35 | 104 | 649 |
| 10 wt % | 51500 | 13.6 | 12.4 | 17.1 | 8.7 | 21 | 19.1 | 0.65, 0.35 | 105 | 652 |

*Device structure (a single layer of light emitting layer containing Pt-R11): ITO/HAT-CN (10 nm)/BPBPA (40 nm)/NPB-BC (5 nm)/Pt-R11:RH (40 nm)/HB (5 nm)/ZADN:Liq (35:65) (35 nm)/Liq (2 nm)/Al (100 nm).

TABLE 17
Performance data of vacuum-deposited devices with Pt-R12*.

| | | CE [cd A⁻¹] | | PE [lm W⁻¹] | | EQE [%] | | | | |
|---|---|---|---|---|---|---|---|---|---|---|
| Pt-R12 | L | | at 1000 cd | | at 1000 | | at 1000 | | FWHM | |
| conc. | [cd m⁻²] | Max | m⁻² | Max | cd m⁻² | Max | cd m⁻² | CIE [(x, y)] | [nm] | λmax [nm] |
| 2 wt % | 83300 | 30.4 | 30.1 | 36 | 26.9 | 21.3 | 21.1 | 0.62, 0.38 | 88 | 623 |
| 6 wt % | 104000 | 29.8 | 29.1 | 36 | 22.8 | 22.3 | 21.7 | 0.63, 0.37 | 88 | 626 |
| 10 wt % | 89000 | 23.6 | 23.5 | 27.2 | 16.4 | 18.2 | 18 | 0.63, 0.37 | 88 | 626 |

*Device structure (a single layer of light emitting layer containing Pt-R12): ITO/HAT-CN (10 nm)/BPBPA (40 nm)/NPB-BC (5 nm)/Pt-R12:RH (40 nm)/HB (5 nm)/ZADN:Liq (35:65) (35 nm)/Liq (2 nm)/Al (100 nm).

TABLE 18
Performance data of vacuum-deposited hyperfluorescence devices with Pt-R8 and MR-R1*.

| | | CE [cd A⁻¹] | | PE [lm W⁻¹] | | EQE [%] | | | | |
|---|---|---|---|---|---|---|---|---|---|---|
| Pt-R8:MR- | L | | at 1000 cd | | at 1000 | | at 1000 | | FWHM | |
| R1 | [cd m⁻²] | Max | m⁻² | Max | cd m⁻² | Max | cd m⁻² | CIE [(x, y)] | [nm] | λmax [nm] |
| 6:0 | 110000 | 34 | 32.9 | 50.6 | 25.9 | 23.1 | 22.4 | 0.62, 0.38 | 90 | 620 |
| wt %/wt % | | | | | | | | | | |
| 06:00.3 | 99400 | 25.9 | 24.9 | 40.1 | 18.4 | 18 | 17.2 | 0.63, 0.37 | 57 | 611 |
| wt %/wt % | | | | | | | | | | |

*Device structure (a single layer of light emitting layer containing Pt-R8 and MR-R1): ITO/HAT-CN (10 nm)/BPBPA (40 nm)/EB (5 nm)/Pt-R8:MR-R1:RH (40 nm)/HB (5 nm)/ZADN:Liq (35:65) (35 nm)/Liq (2 nm)/Al (100 nm).

TABLE 19
Device lifetime measurement for Pt-R8 and MR-R1*.

| Conc. of | | | | LT₉₇@1000 |
|---|---|---|---|---|
| Pt-R8:MR-R1 | L₀ [cd m⁻²] | LT₉₇@L₀ | n | cd m⁻² |
| 6:0.3 wt %/wt % | 10000 | 133 | 1.7 | 6666 |

Assume n = 1.7 in LT(L₁) = LT(L₀) × (L₀/L₁)ⁿ
*Device structure: (a single layer of light emitting layer containing Pt-R8 and MR-R1):ITO/HAT-CN (10 nm)/BPBPA (40 nm)/EB (5 nm)/PT-R8:MR-R1:RH (40 nm)/HB (5 nm)/ZADN:Liq (35:65) (35 nm)/Liq (2 nm)/Al (100 nm).

TABLE 20
Performance data of vacuum-deposited NIR-emitting devices with Pt-R14*.

| NIR- | | | | | | | | |
|---|---|---|---|---|---|---|---|---|
| emitting | Pt-R14 | L | CE [cd A⁻¹] | PE [lm W⁻¹] | EQE [%] | | FWHM | |
| device | conc. | [cd m⁻²] | Max | Max | Max | CIE [(x, y)] | [nm] | λmax [nm] |
| Device 1 | 2 wt % | 221 | 0.28 | 0.13 | 6 | 0.62, 0.29 | 127 | 743 |
| Device 2 | 4 wt % | 268 | 0.19 | 0.08 | 5.1 | 0.68, 0.29 | 129 | 745 |
| Device 3 | 6 wt % | 319 | 0.13 | 0.05 | 3.7 | 0.69, 0.29 | 131 | 746 |
| Device 4 | 8 wt % | 342 | 0.15 | 0.06 | 4.8 | 0.70, 0.29 | 130 | 746 |

*Device structure (a single layer of light emitting layer containing Pt-R14): ITO/PEDOT:PSS(40 nm)/PVK(10 nm)/ Pt-R14:CBP /DPEPO (10 nm)/TPBi (40 nm)/Liq (2 nm)/Al (100 nm).

TABLE 21
Comparison with other Pt(II) red emitters

| | | | Current data | | Comparative |
|---|---|---|---|---|---|
| | Current data | Current data | for Pt-R2 | Comparative | Compound |
| | for Pt-R5 | for Pt-R6 | (4 wt %) | Compound | Pt1a** and |
| | (6 wt %) | (10 wt %) | (NIR) | Pt1* | Pt2a*** |
| kr; knr | 5.1 × 10⁵; | 4.8 × 10⁵; | 4.8 × 10⁵; | 1.0 × 10⁵; | Pt1a: 3.8 × 10⁵; |
| [s⁻¹] | 1.6 × 10⁴ | 7.2 × 10⁴ | 1.5 × 10⁵ | 1.2 × 10⁵ | 1.0 × 10⁵ |
| | | | | | Pt2a (NIR): |
| | | | | | 3.8 × 10⁵; |
| | | | | | 2.1 × 10⁵ |
| CIE (x, y) | (0.61, 0.38) | (0.63, 0.37) | (0.70, 0.30) | (0.58, 0.35) | Pt1a: (0.63, |
| | | | | | 0.37); |
| | | | | | Pt1a: (0.60, |
| | | | | | 0.40); |
| | | | | | Pt2a (NIR): ca. |
| | | | | | (0.70, 0.30) |
| Maximum | 96200 | 93000 | 4540 | 17570 | 75000; 58400; |
| Brightness | | | | | 10500 |
| L [cd/m²] | | | | | |
| CE @1000 | 24.5 | 23.0 | 1.2 | 19.5 | 28.7; 35.1; NA |
| cd/m² | | | | | |
| (cd/A) | | | | | |
| PE @1000 | 19.2 | 15.5 | 0.36 | 20.0 | 15.5; 30.7; NA |
| cd/m² | | | | | (max. radiance: |
| [lm/W] | | | | | 4.2 mW) |
| EQE | 15.6 | 16.2 | 9.1 | 14.5 | 18.7; 18.9; 13.0 |
| @1000 | | | | | |
| cd/m² [%] | | | | | |
| LT | LT95@1000 | LT95@1000 | NA | NA | LT95@1000 |
| | nits: | nits: | | | nits: |
| | ca. 10800 h | ca. 21200 h | | | ca. 9300 h |

*Pt1: 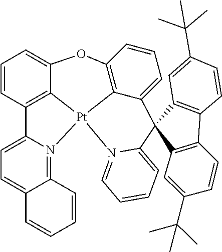
**Pt1a: 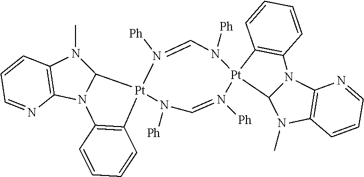
***Pt2a:

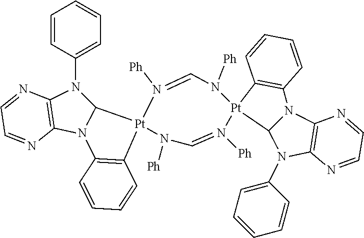

Unless defined otherwise, all technical and scientific terms used herein have the same meanings as commonly understood by one of skill in the art to which the disclosed invention belongs. Publications cited herein and the materials for which they are cited are specifically incorporated by reference. Further, unless otherwise indicated, use of the expression “wt %” refers to “wt/wt %.”

Those skilled in the art will recognize, or be able to ascertain using no more than routine experimentation, many equivalents to the specific embodiments of the invention described herein. Such equivalents are intended to be encompassed by the following claims.

Y. Unger, D. Meyer, O. Molt, C. Schildknecht, I. Münster, G. Wagenblast, T. Strassner, Angew. Chem. Int. Ed. 2010, 49, 10214-10216.

P. Pinter, J. Soellner, T. Strassner, Chem. Eur. J. 2019, 25, 14495-14499.

We claim:

1. A dinuclear platinum(II) complex having a structure: 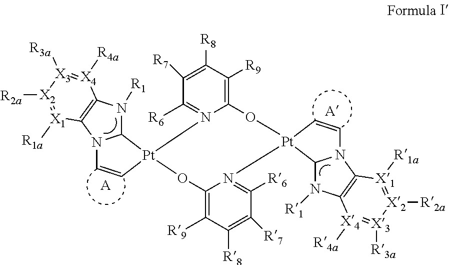
wherein:
(i) the complex is an overall neutral, negative, or positive charge;
(ii) X₁-X₄ and X′₁-X′₄ are independently carbon, nitrogen, sulfur, or oxygen;
(iii) R₁ₐ-R₄ₐ, R′₁ₐ-R′₄ₐ, R₁, R′₁, R₆-R₉, and R′₆-R′₉ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, unsubstituted C₂-C₂₀ heterocyclyl, borenium cation, phosphonyl, sulfinyl, or sulfonyl, or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, fused combinations thereof, or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, R′₃ₐ and R′₄ₐ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof;
(iv) A and A′ are independently a substituted cycloalkyl, an unsubstituted cycloalkyl, a substituted cycloalkenyl, an unsubstituted cycloalkenyl, a substituted cycloalkynyl, an unsubstituted cycloalkynyl, a substituted heterocyclyl, an unsubstituted heterocyclyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, or fused combinations thereof; preferably A and A′ are independently a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof; and
(v) each substituent is independently a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a carbonyl, an alkoxy, a halogen, a hydroxyl, a phenoxy, a thiol, an alkylthio, a phenylthio, an arylthio, a cyano, an isocyano, a nitro, a carboxyl, an amino, an amido, an oxo, a silyl, a sulfinyl, a sulfonyl, a sulfonic acid, a phosphonium, a phosphanyl, a phosphoryl, or a phosphonyl.

2. The dinuclear platinum(II) complex of claim 1, wherein the dinuclear platinum(II) has a structure: 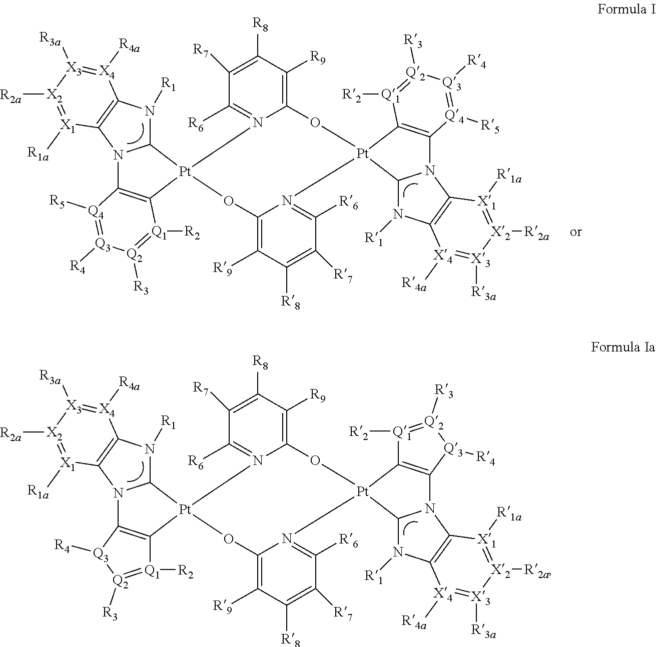
wherein:
(i) the complex has an overall neutral, negative, or positive charge;
(ii) Q₁-Q₄ and Q′₁-Q′₄ are independently carbon, nitrogen, sulfur, or oxygen; and
(iii) R₂-R₅ and R′₂-R′₅ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl, borenium cation, phosphonyl, sulfinyl, or sulfonyl, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, fused combinations thereof, or R₂ and R₃ together, R₃ and R₄ together, R₄ and R₅ together, R′₂ and R′₃ together, R′₃ and R′₄ together, and/or R′₄ and R′₅ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof.

3. The complex of claim 1, wherein the complex has a structure:

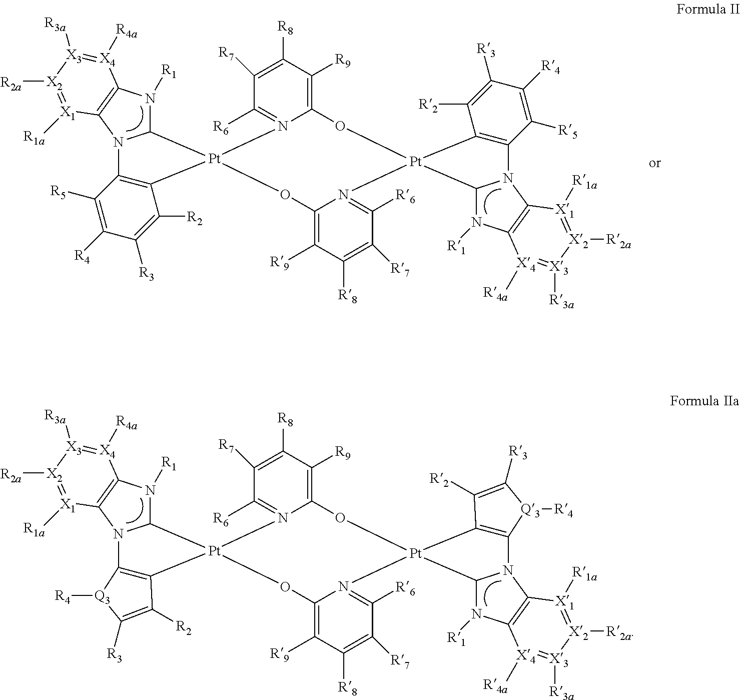

4. The complex of claim 1, wherein the complex has the structure:

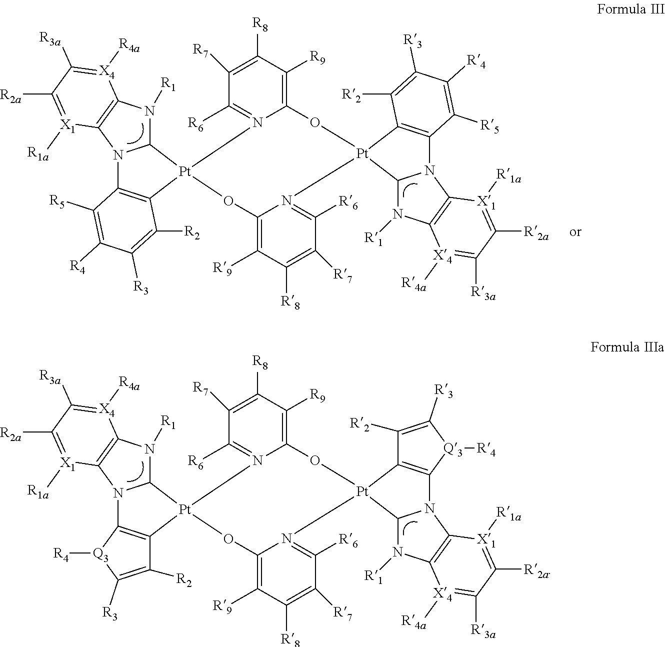

5. The complex of claim 1, wherein the complex has the structure:

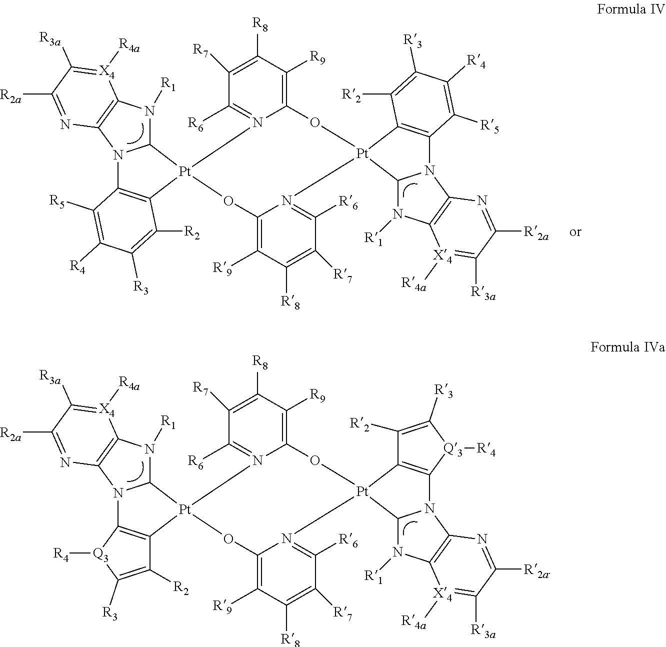

6. The complex of claim 1, wherein X₄ and X′₄ are carbon; and R₄ₐ and R′₄ₐ are independently hydrogen, substituted alkyl, unsubstituted alkyl, substituted aryl, unsubstituted aryl, hydroxyl, unsubstituted heteroaryl, substituted heteroaryl, unsubstituted polyaryl, substituted polyaryl, unsubstituted polyheteroaryl, substituted polyheteroaryl, substituted C₂-C₂₀ heterocyclyl, or unsubstituted C₂-C₂₀ heterocyclyl.

7. The complex of claim 6, wherein X₄ and X′₄ are carbon and R₄ₐ and R′₄ₐ are independently hydrogen, unsubstituted alkyl, unsubstituted aryl, unsubstituted polyaryl, hydroxyl, unsubstituted heteroaryl, unsubstituted polyheteroaryl, unsubstituted C₂-C₂₀ heterocyclyl, or unsubstituted alkylaryl, such as hydrogen.

8. The complex of claim 1, wherein X₄ and X′₄ are nitrogen; R₄ₐ and R′₄ₐ are absent, and optionally wherein R₂ₐ, R₃ₐ, R′₂ₐ, and R′₃ₐ are independently hydrogen, unsubstituted alkyl (e.g., methyl, ethyl, n-propyl, isopropyl, n-butyl, sec-butyl, isobutyl, tert-butyl, etc.), substituted alkyl, unsubstituted aryl (e.g., unsubstituted phenyl), or alkoxy (e.g., —O-alkyl, —O-aryl, —O-polyaryl, etc.), or R₂ₐ and R₃ₐ together and/or R′₂ₐ and R′₃ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl.

9. The complex of claim 1, wherein X₁-X₄ and X′₁-X′₄ are carbon; and R₁ₐ-R₄ₐ and R′₁ₐ-R′₄ₐ are independently hydrogen, unsubstituted alkyl (e.g., methyl, ethyl, n-propyl, isopropyl, n-butyl, sec-butyl, isobutyl, tert-butyl, etc.), substituted alkyl, unsubstituted aryl (e.g., unsubstituted phenyl), or alkoxy (e.g., —O-alkyl, —O-aryl, —O-polyaryl, etc.), or R₁ₐ and R₂ₐ together, R₂ₐ and R₃ₐ together, R₃ₐ and R₄ₐ together, R′₁ₐ and R′₂ₐ together, R′₂ₐ and R′₃ₐ together, and/or R′₃ₐ and R′₄ₐ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof, such as a substituted aryl or unsubstituted aryl, for example, Ria and R₂ₐ together, R₃ₐ and R₄ₐ together, R′₁ₐ and R′₂ₐ together, and R′₃ₐ and R′₄ₐ together, with the atom to which they are attached, form a substituted aryl or unsubstituted aryl, or R₂ₐ and R₃ₐ together and R′₂ₐ and R′₃ₐ together, with the atom to which they are attached, form a substituted aryl or unsubstituted aryl.

10. The complex of claim 2, wherein R₁-R₉ and R′₁-R′₉ are independently hydrogen, halogen, unsubstituted alkyl (e.g., methyl, ethyl, n-propyl, isopropyl, n-butyl, sec-butyl, isobutyl, tert-butyl, etc.), substituted alkyl, unsubstituted aryl, substituted aryl (e.g., mesitylene or other aryl substituted with one or more alkyls, such as methyl, ethyl, n-propyl, isopropyl, n-butyl, sec-butyl, isobutyl, tert-butyl, etc.), unsubstituted polyaryl, substituted polyaryl, hydroxyl, unsubstituted heteroaryl, substituted heteroaryl, unsubstituted polyheteroaryl, substituted polyheteroaryl, unsubstituted C₂-C₂₀ heterocyclyl, substituted C₂-C₂₀ heterocyclyl, unsubstituted alkylaryl, substituted alkylaryl, alkoxy (e.g., —O-alkyl, —O-aryl, —O-polyaryl, etc.), borenium cation (e.g., —B(Mes)₂), phosphonyl (e.g., —P(═O)(Ph)₂, —P(═O)(alkyl)₂, etc.), or sulfinyl (e.g., —S(═O)(Ph)₂, —S(═O)(alkyl)₂, etc.), or sulfonyl —S(═O)₂(Ph)₂, —S(═O)₂(alkyl)₂, etc.), or R₂ and R₃ together, R′₂ and R′₃ together, R₃ and R₄ together, R′₃ and R′₄ together, R₄ and R₅ together, R′₄ and R′₅ together, R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted heterocyclyl, an unsubstituted heterocyclyl, or fused combinations thereof.

11. The complex of claim 10, wherein one or more of R₁-R₉ and R′₁-R′₉ is(are) 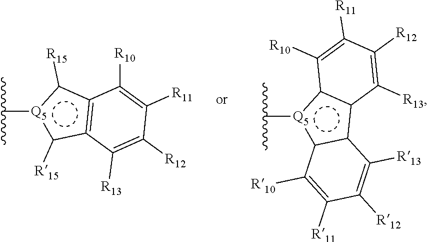
wherein Q₅ is nitrogen or carbon; and R₁₀-R₁₃, R₁₅, R′₁₅, and R′₁₀-R′₁₃ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl.

12. The complex of claim 11, wherein Q₅ is nitrogen; and R₁₀-R₁₃, R₁₅, R′₁₅, and R′₁₀-R′₁₃ are independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen.

13. The complex of claim 2, wherein: (i) R₂ and R₃ together and/or R′₂ and R′₃ together, or (ii) R₃ and R₄ together and/or R′₃ and R′₄ together, or (iii) R₄ and R₅ together and/or R′₄ and R′₅ together, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl.

14. The complex of claim 13, wherein: (i) R₂ and R₃ together and/or R′₂ and R′₃ together, or (ii) R₃ and R₄ together and/or R′₃ and R′₄ together, or (iii) R₄ and R₅ together and/or R′₄ and R′₅ together, form 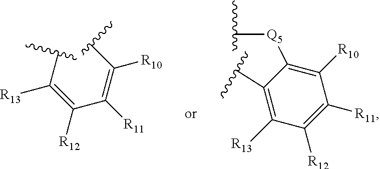
wherein Q₅ is NR₁₄, CR₁₆R₁₇, or sulfur, or oxygen; and R₁₀-R₁₄, R₁₆, and R₁₇ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₂-C₂₀ heterocyclyl, or unsubstituted C₂-C₂₀ heterocyclyl, optionally wherein Q₅ is NR₁₄, CR₁₆R₁₇, sulfur, or oxygen, such as oxygen; and R₁₀-R₁₄, R₁₆, and R₁₇ are independently absent, hydrogen, substituted alkyl, unsubstituted alkyl, substituted phenyl group, unsubstituted phenyl, alkoxy, halogen, borenium cation (e.g., —B(Mes)₂), phosphonyl, or sulfinyl, such as hydrogen or unsubstituted alkyl.

15. The complex of claim 2, wherein R₆-R₉ and R′₆-R′₉, are independently hydrogen, halogen, unsubstituted alkyl (e.g., methyl, ethyl, n-propyl, isopropyl, n-butyl, sec-butyl, isobutyl, tert-butyl, etc.), substituted alkyl, unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), phosphonyl (e.g., —P(═O)(Ph)2, —P(═O)(alkyl)2, etc.), substituted heteroaryl, or unsubstituted heteroaryl, or R₆ and R₇ together, R₇ and R₈ together, R₈ and R₉ together, R′₆ and R′₇ together, R′₇ and R′₈ together, and/or R′₈ and R′₉ together, with the atom to which they are attached, form a substituted aryl or an unsubstituted aryl, such as a substituted phenyl or unsubstituted phenyl, optionally wherein at least one of R₆-R₉ and at least one of R′₆-R′₉ are not hydrogen.

16. The complex of claim 2, wherein Q₃ and Q′₃ of Formulae Ia-IVa are independently sulfur or oxygen.

17. The complex of claim 2, wherein R₂, R₄, R₅, R′₂, R′₄, R′₅, R₇, R₈, R′₇, and R′₈ are hydrogen; and R₁, R₃, R₆, R₉, R′₁, R′₃, R′₆, and R′₉ are independently hydrogen, halogen, unsubstituted alkyl, substituted alkyl, unsubstituted aryl, substituted aryl (e.g., aryl substituted with one or more alkyls, such as methyl, ethyl, n-propyl, isopropyl, n-butyl, sec-butyl, isobutyl, tert-butyl, etc.), hydroxyl, unsubstituted heteroaryl (e.g., carbazolyl, fluorenyl, indenyl, indolyl, etc.), unsubstituted polyheteroaryl, unsubstituted C₂-C₂₀ heterocyclyl, unsubstituted alkylaryl, alkoxy (e.g., —O-alkyl such as methoxy, ethoxy, and phenoxy, —O-aryl, —O-polyaryl, etc.), borenium cation (e.g., —B(Mes)₂), phosphonyl (e.g. —P(═O)(Ph)₂), sulfinyl (e.g., —S(═O)(Ph)₂, —S(═O)(alkyl)₂, etc.), or sulfonyl —S(═O)₂(Ph)₂, —S(═O)₂(alkyl)₂, etc.), such as halogen, unsubstituted alkyl (e.g., methyl, ethyl, n-propyl, isopropyl, n-butyl, sec-butyl, isobutyl, tert-butyl, etc.), unsubstituted aryl (e.g., unsubstituted phenyl), substituted aryl (e.g., mesitylene or other aryl substituted with one or more alkyls, such as methyl, ethyl, n-propyl, isopropyl, n-butyl, sec-butyl, isobutyl, tert-butyl, etc.), borenium cation (e.g., —B(Mes)₂), or phosphonyl (e.g., —P(═O)(Ph)₂, —P(═O)(alkyl)₂, etc.).

18. The complex of claim 17, wherein R₁, R₆, R₉, R′₁, R′₆, and R′₉ are independently unsubstituted alkyl, unsubstituted aryl, or substituted aryl (e.g., phenyl substituted with one or more C₁-C₆ alkyls).

19. The complex of claim 1, wherein the complex has any one of the structures:

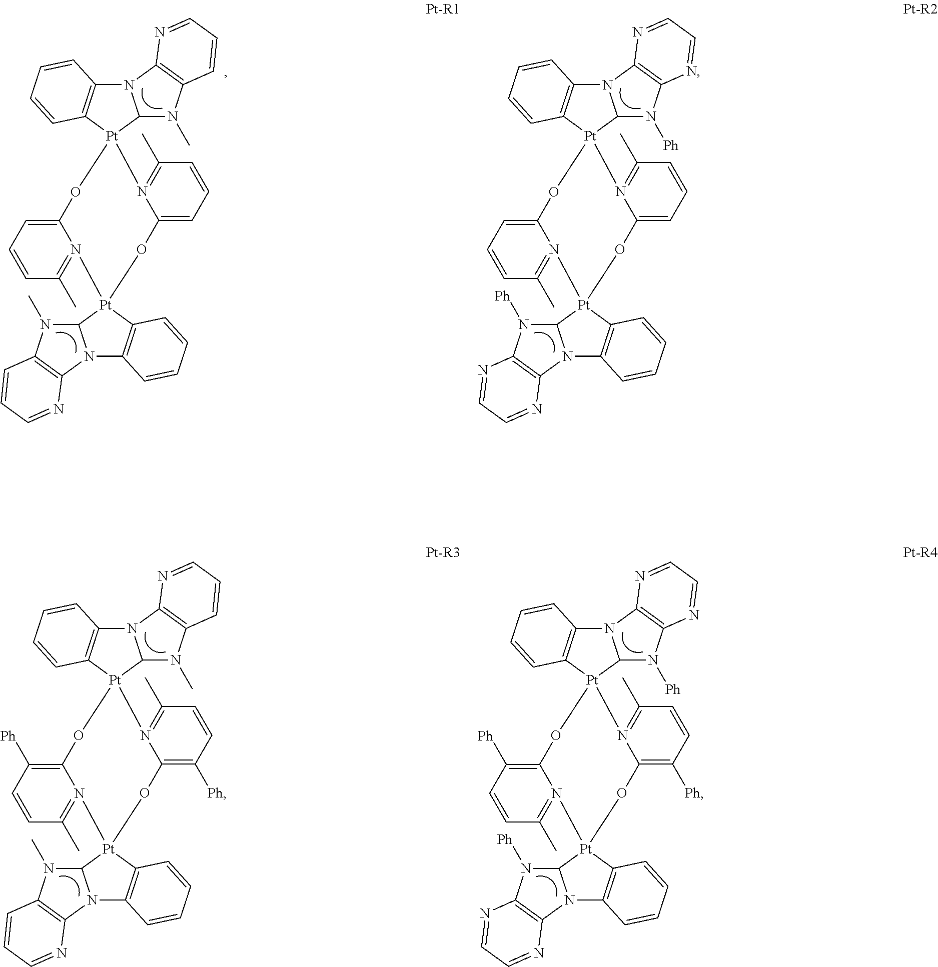

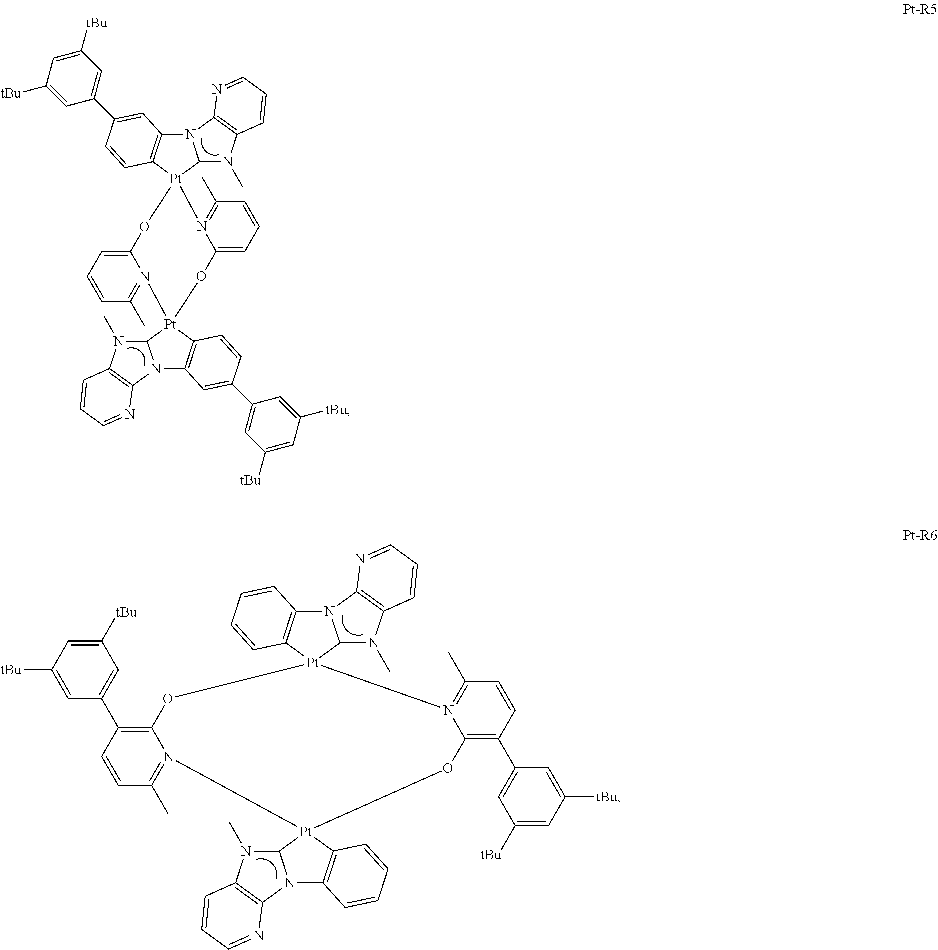

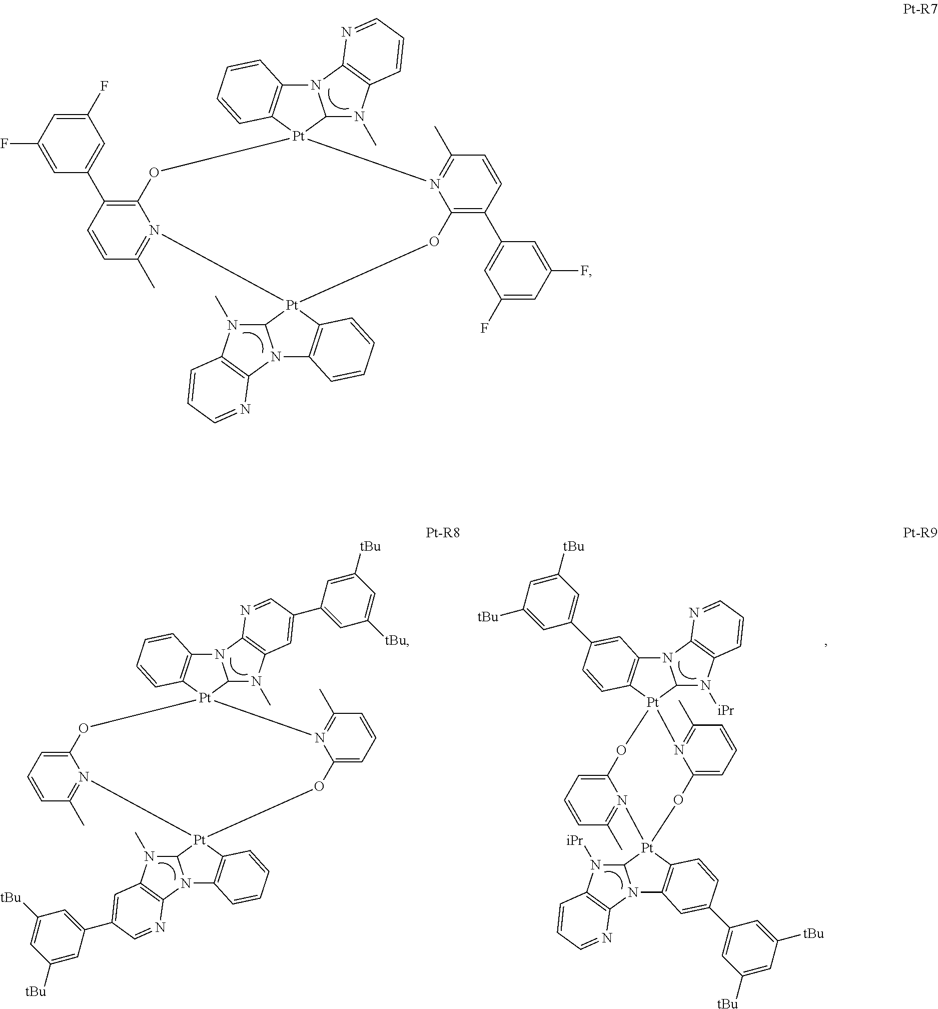

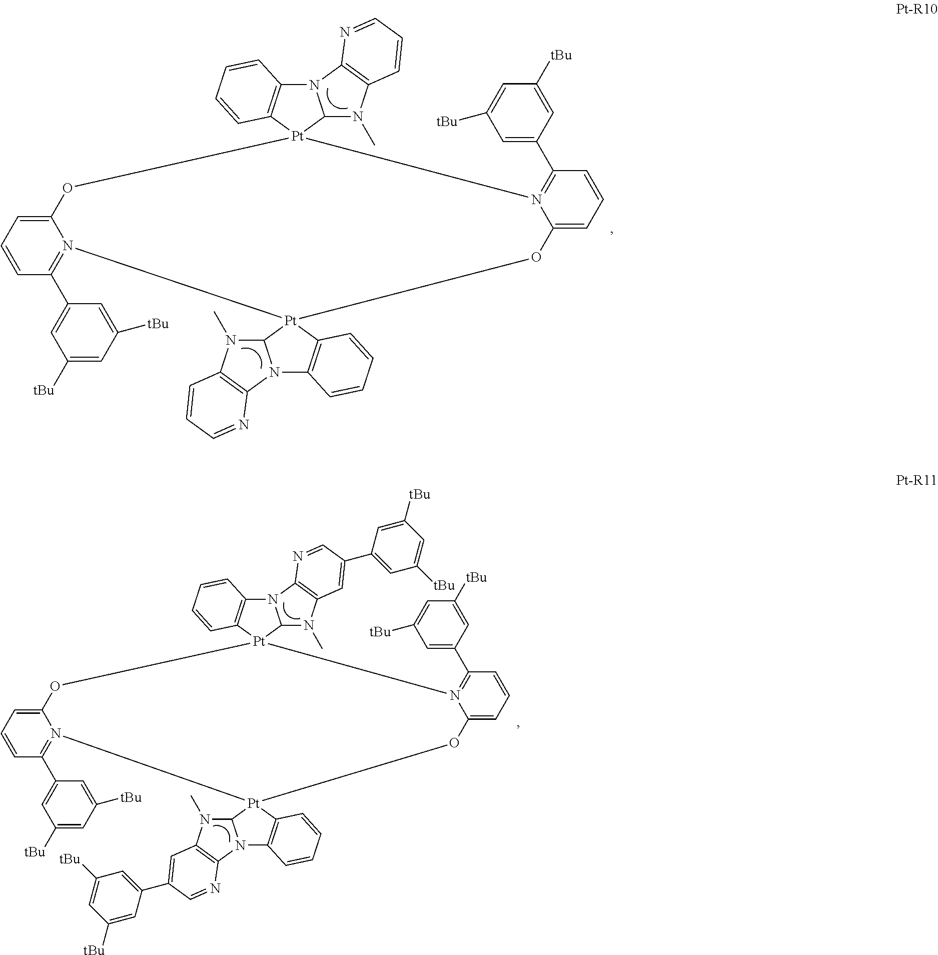

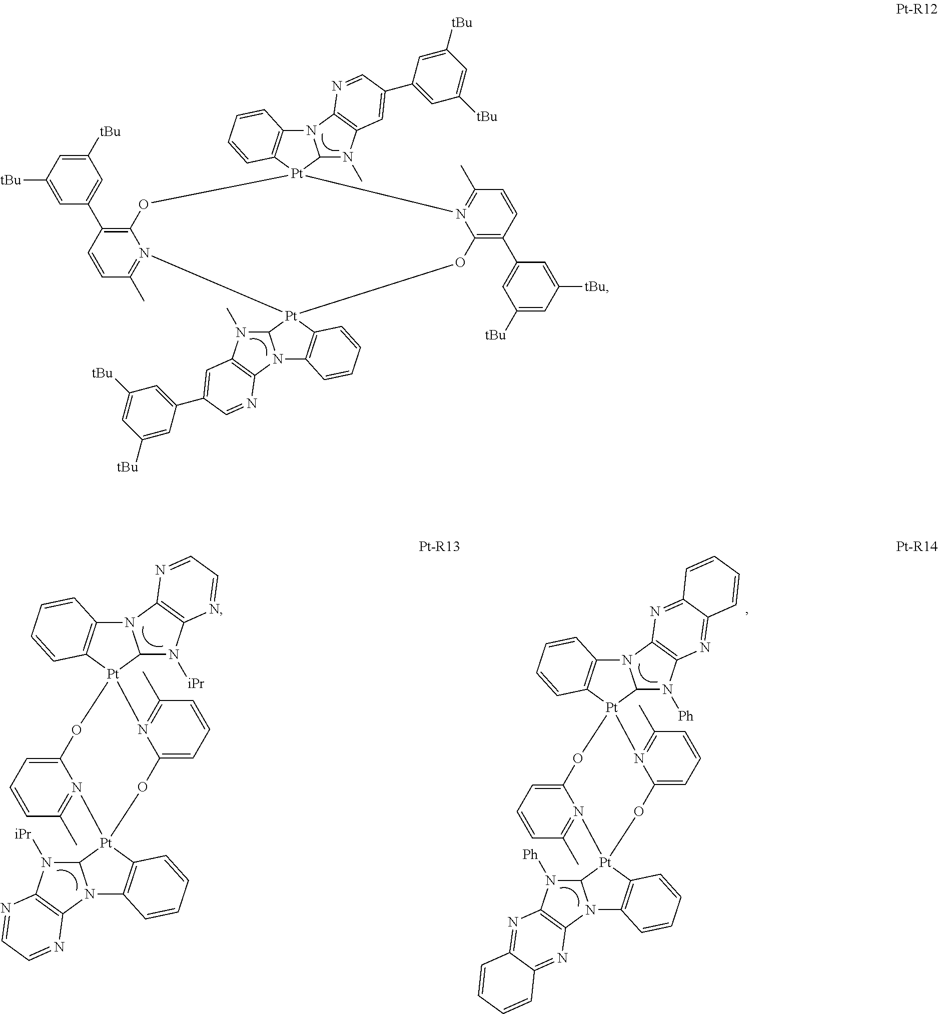

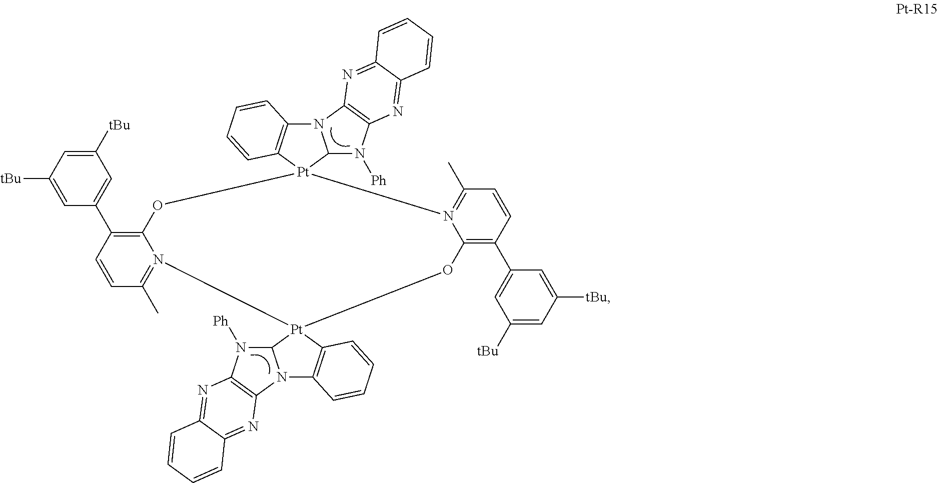

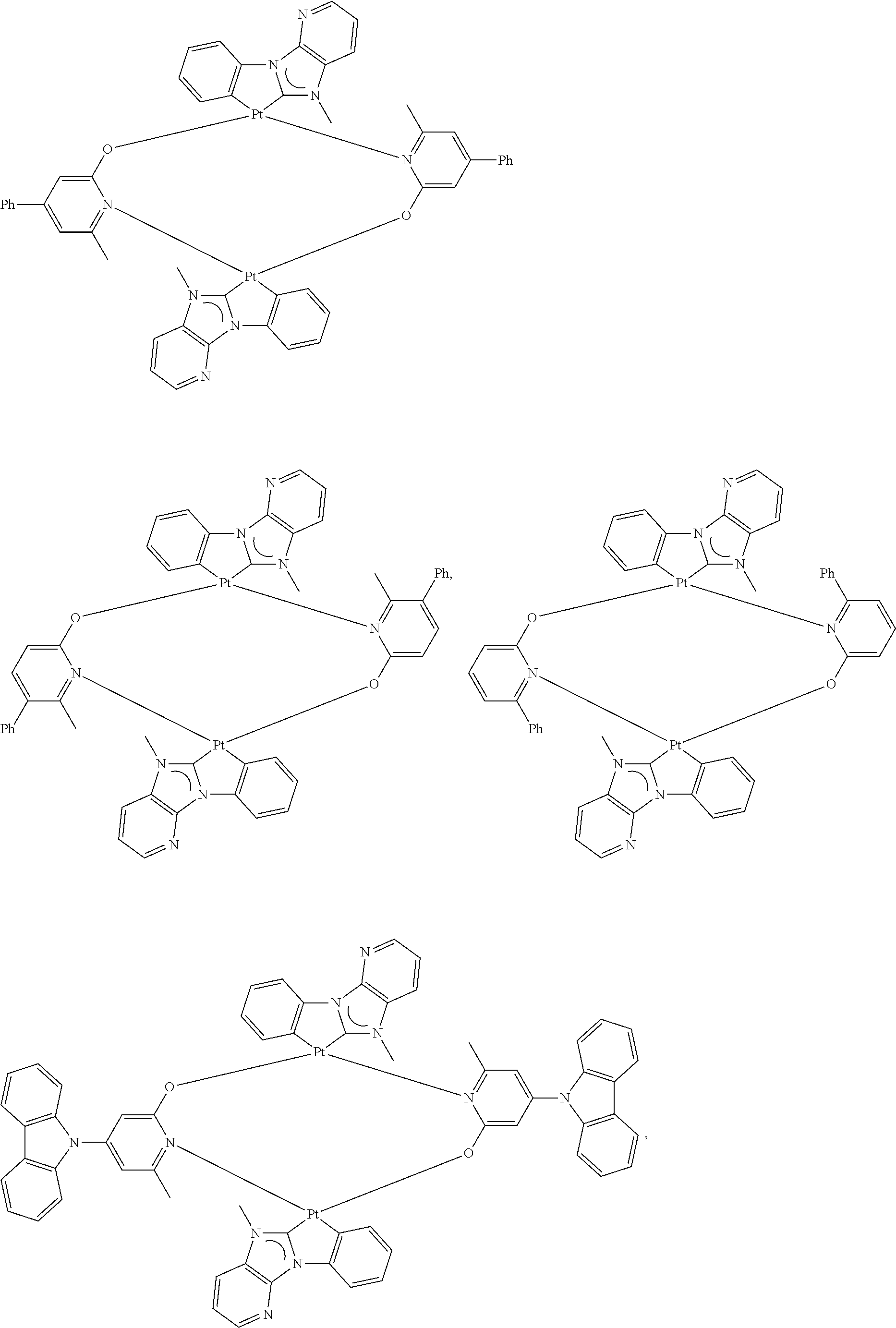

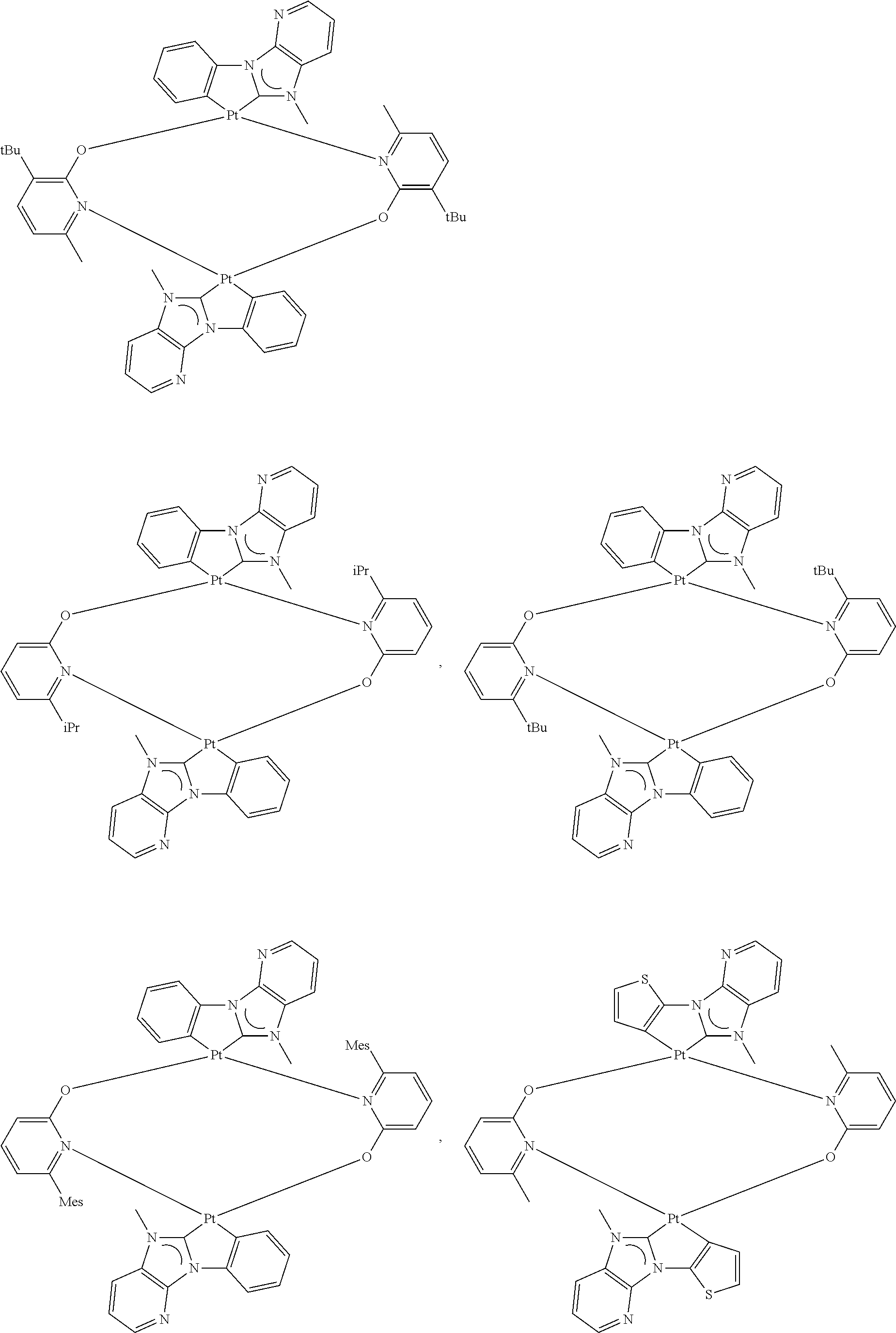

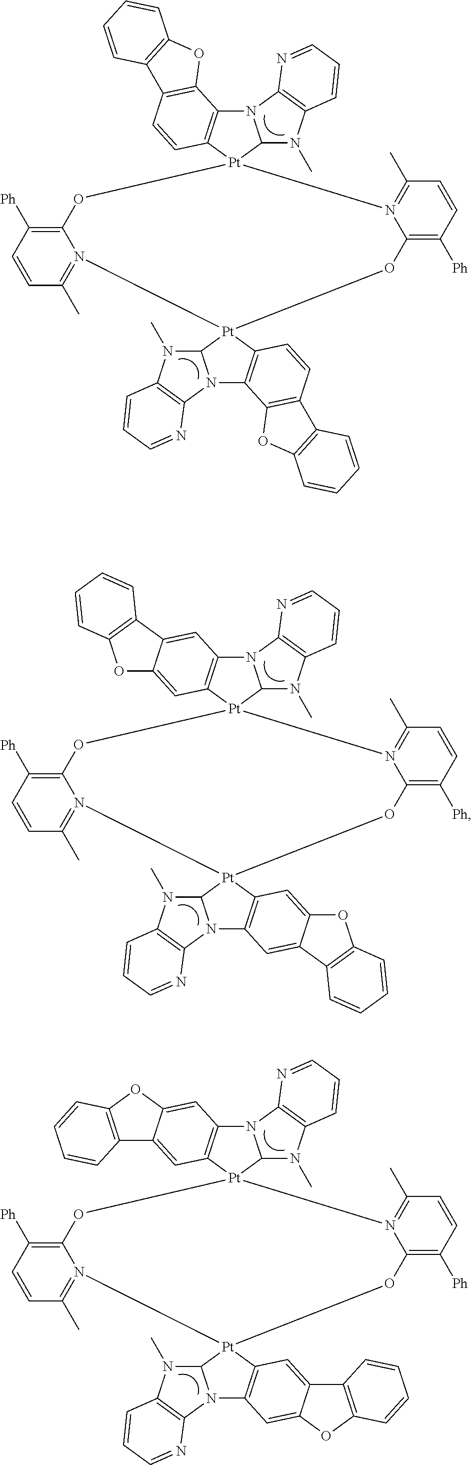

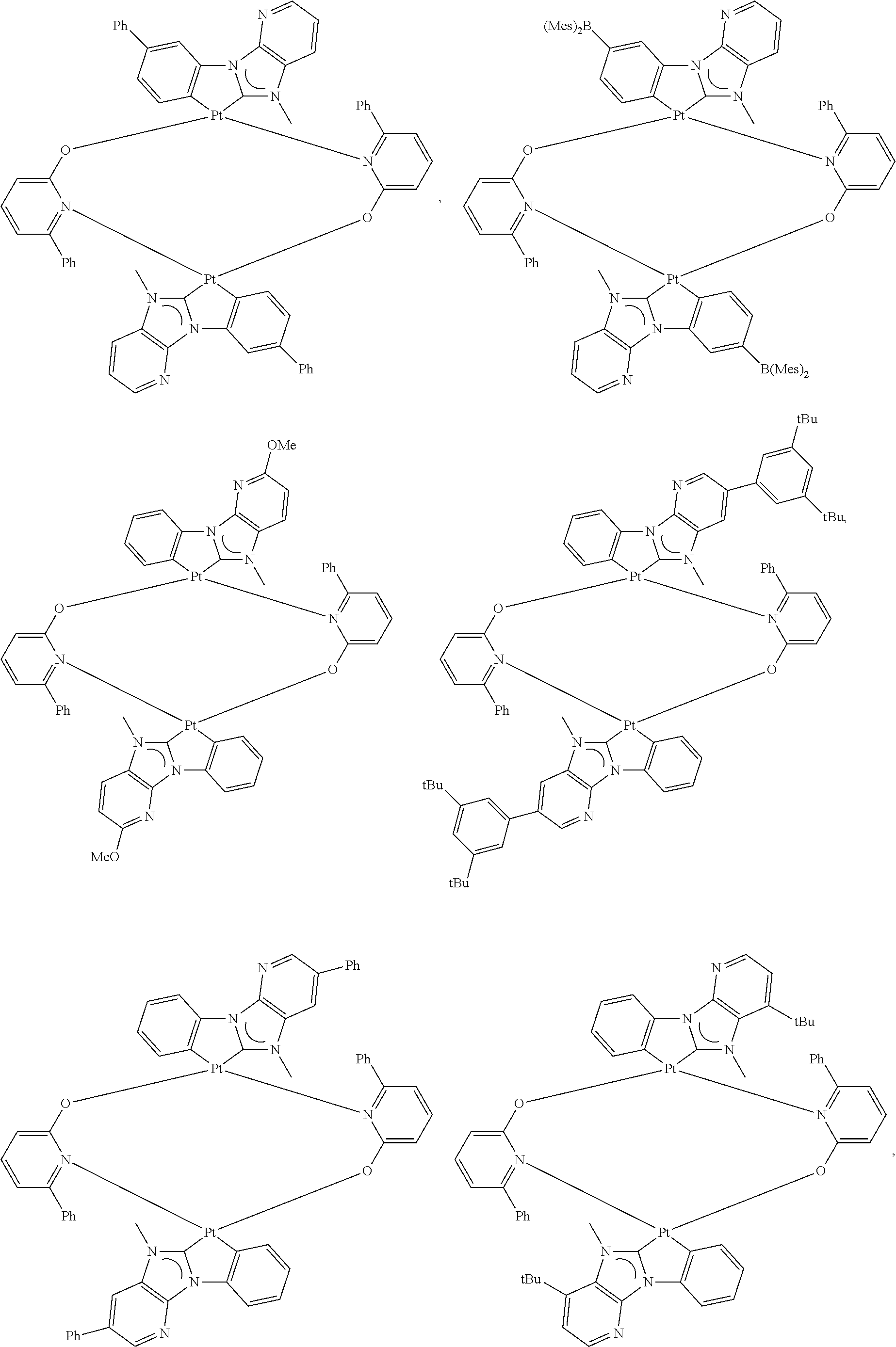

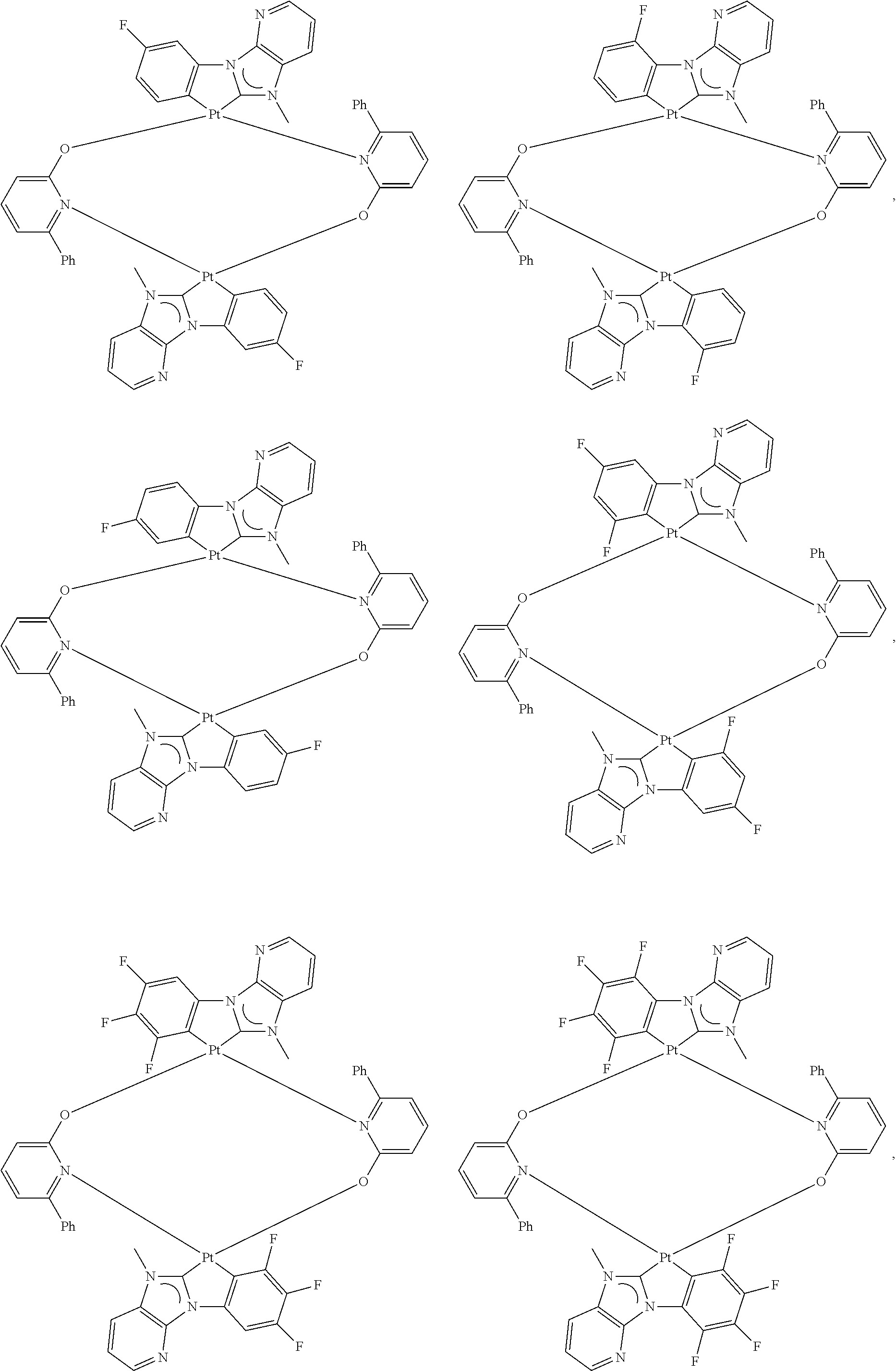

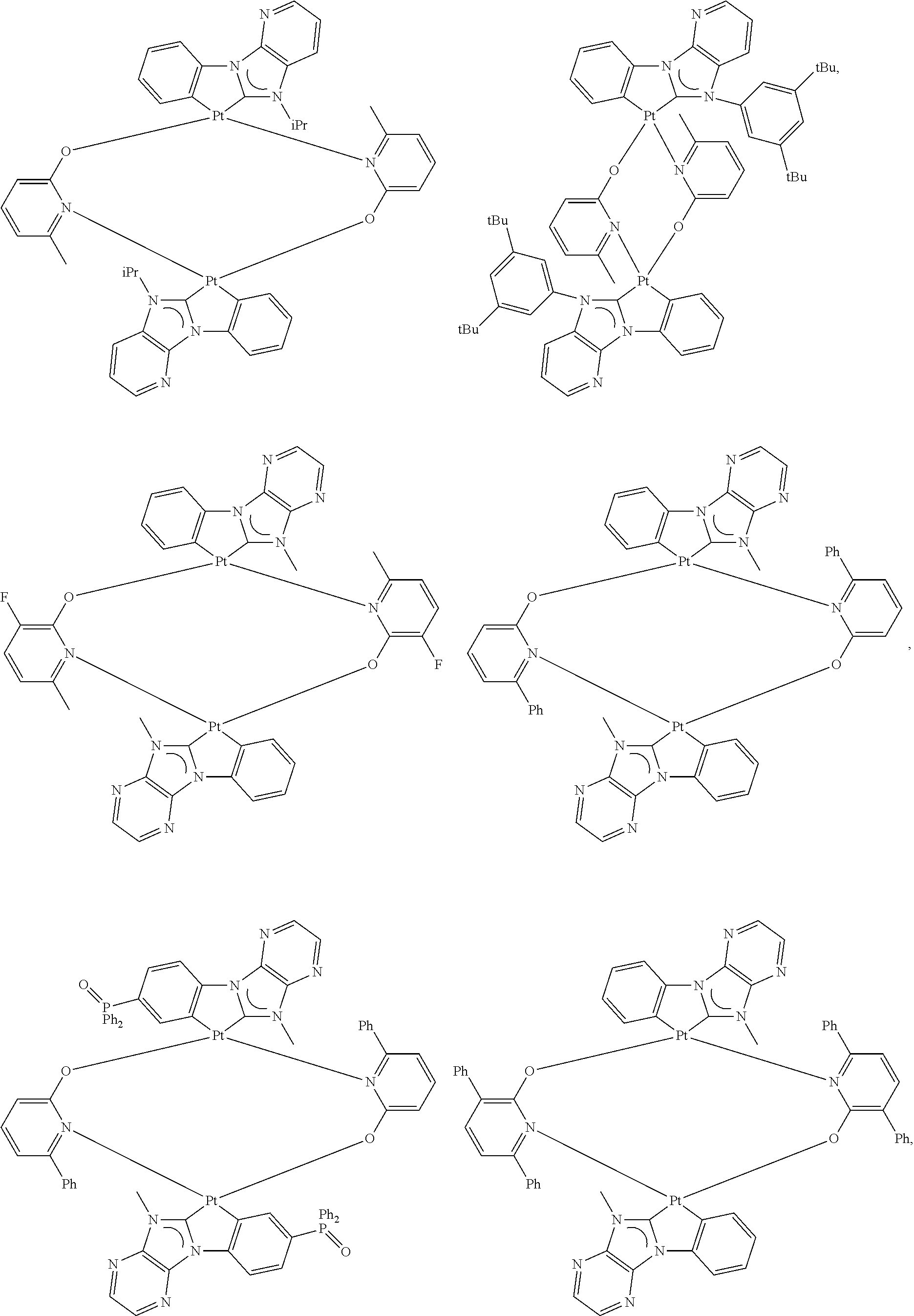

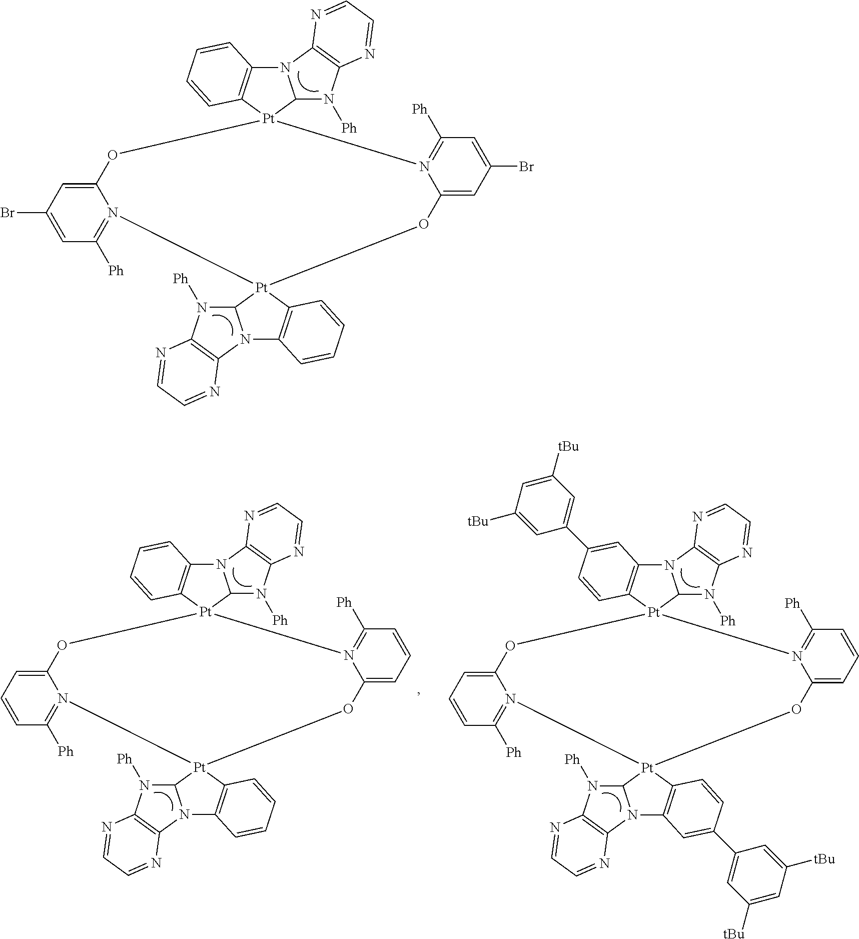

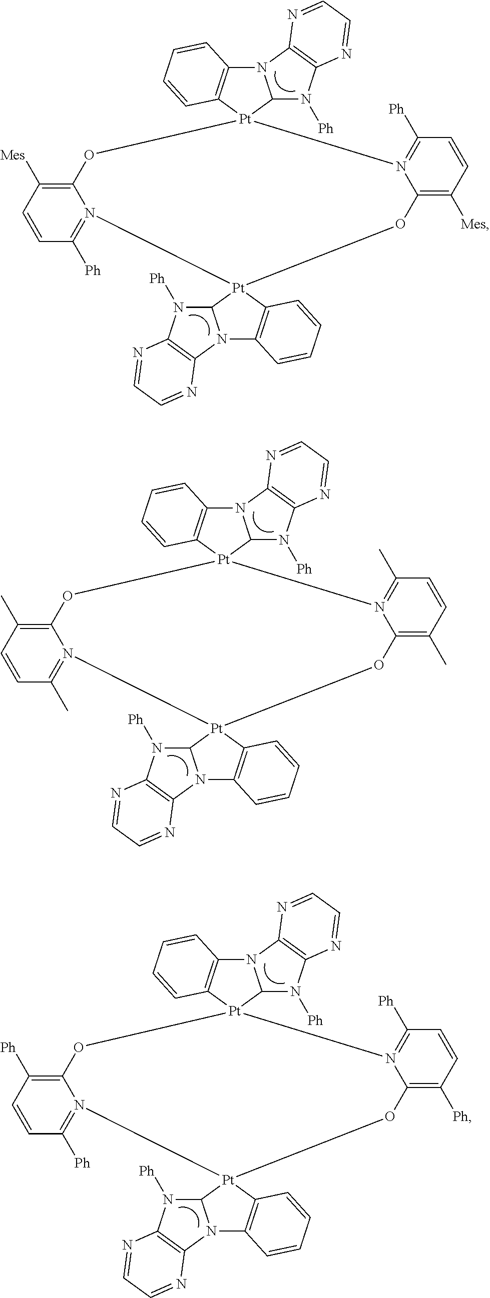

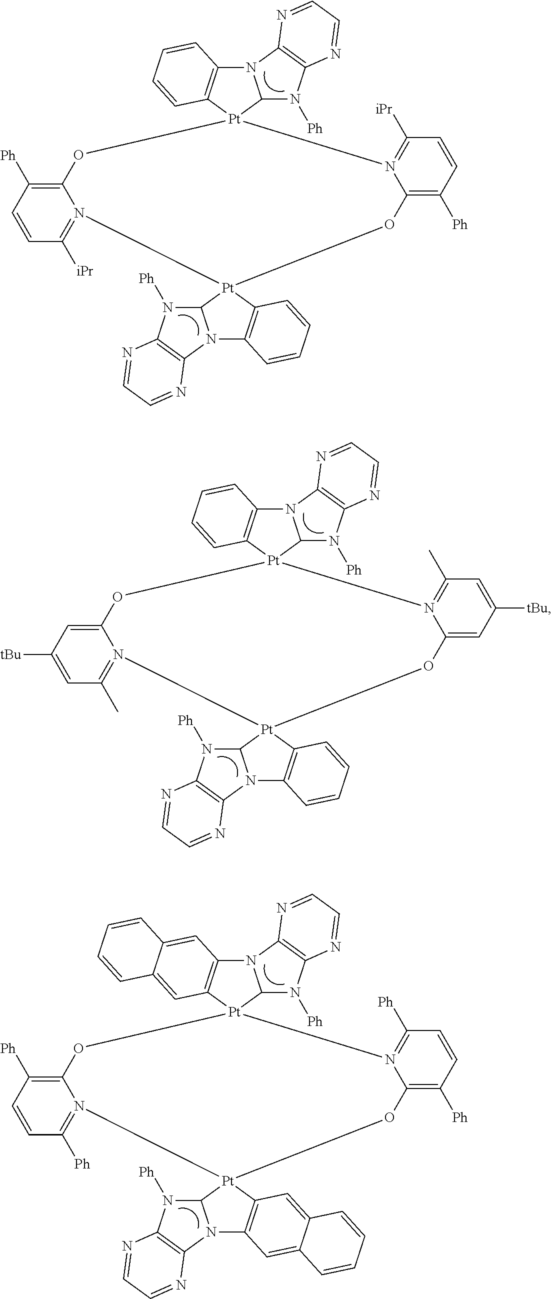

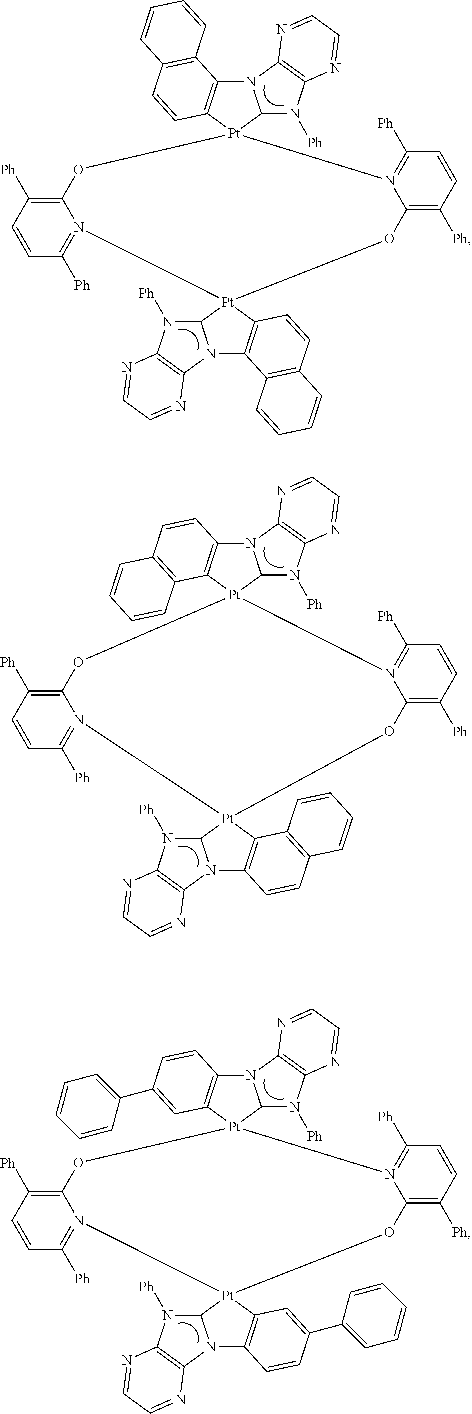

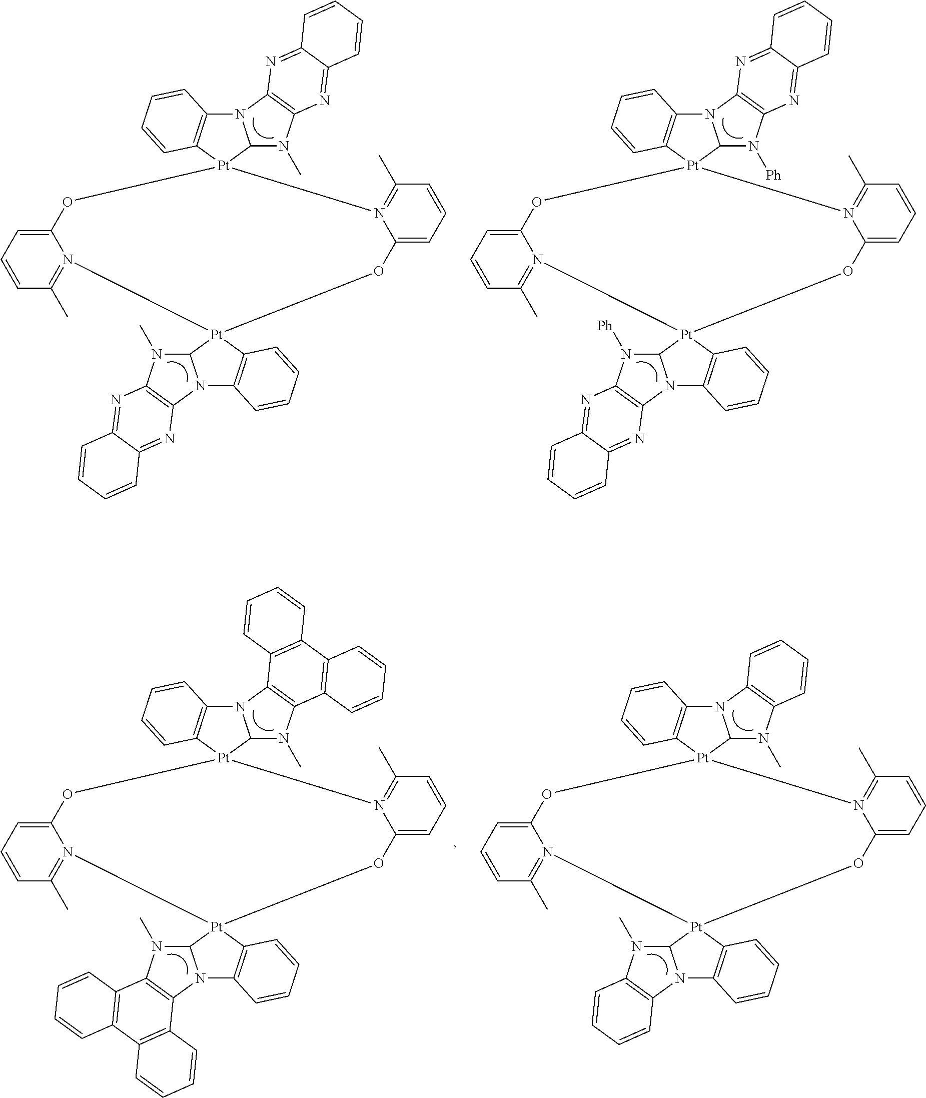

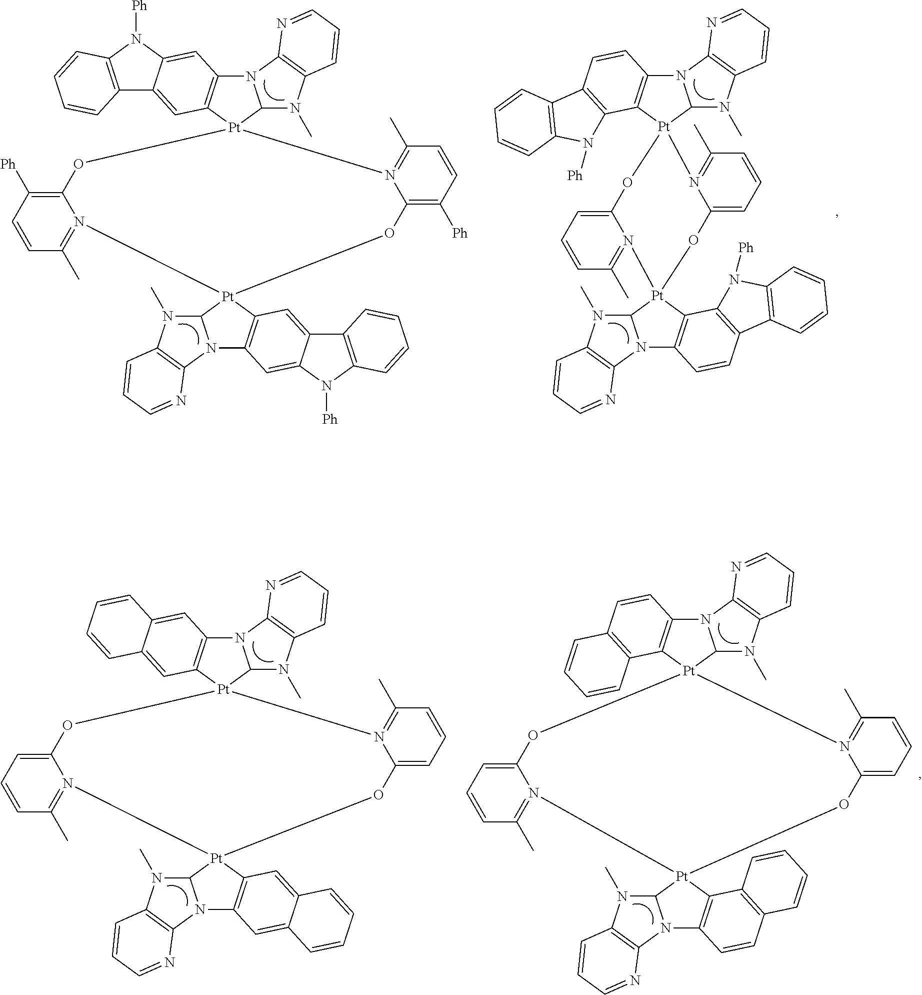

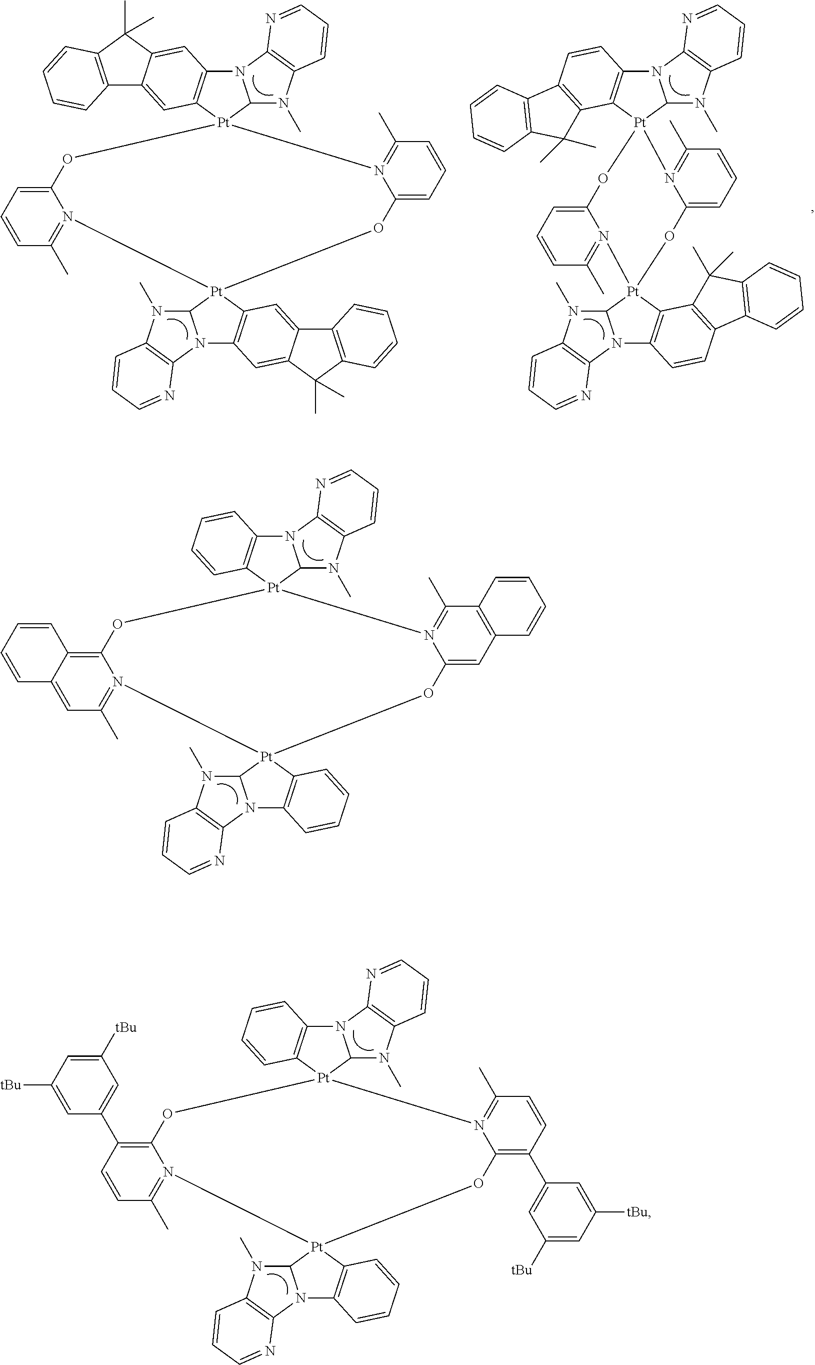

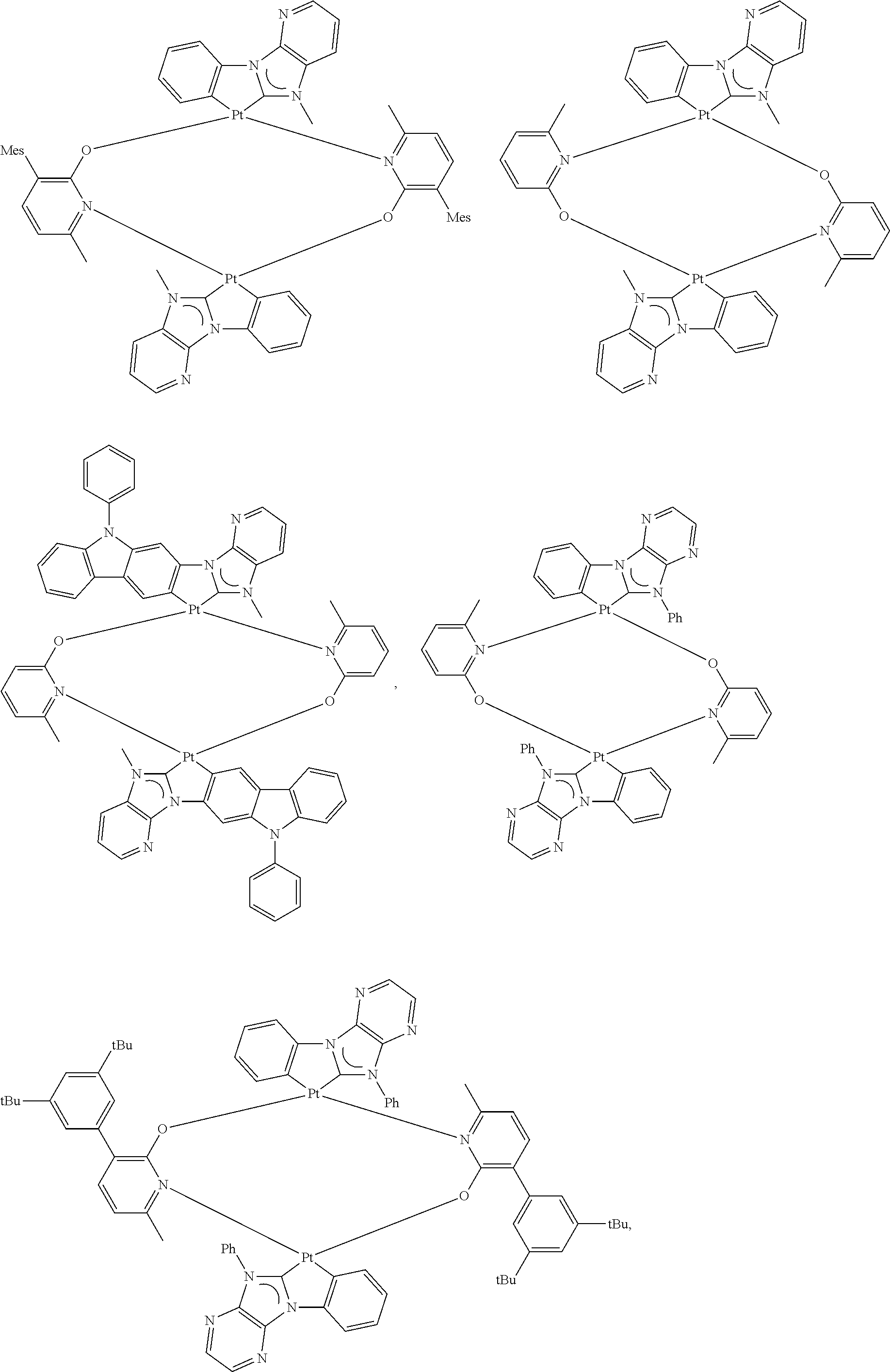

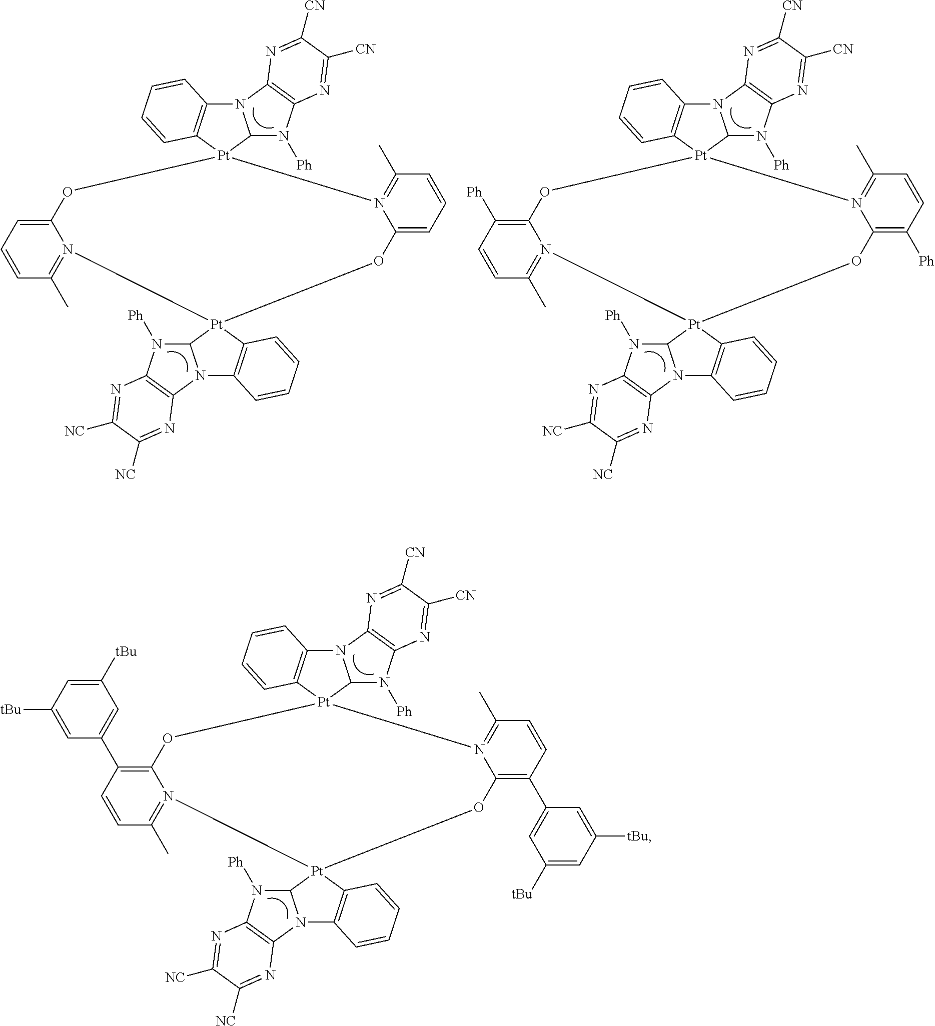

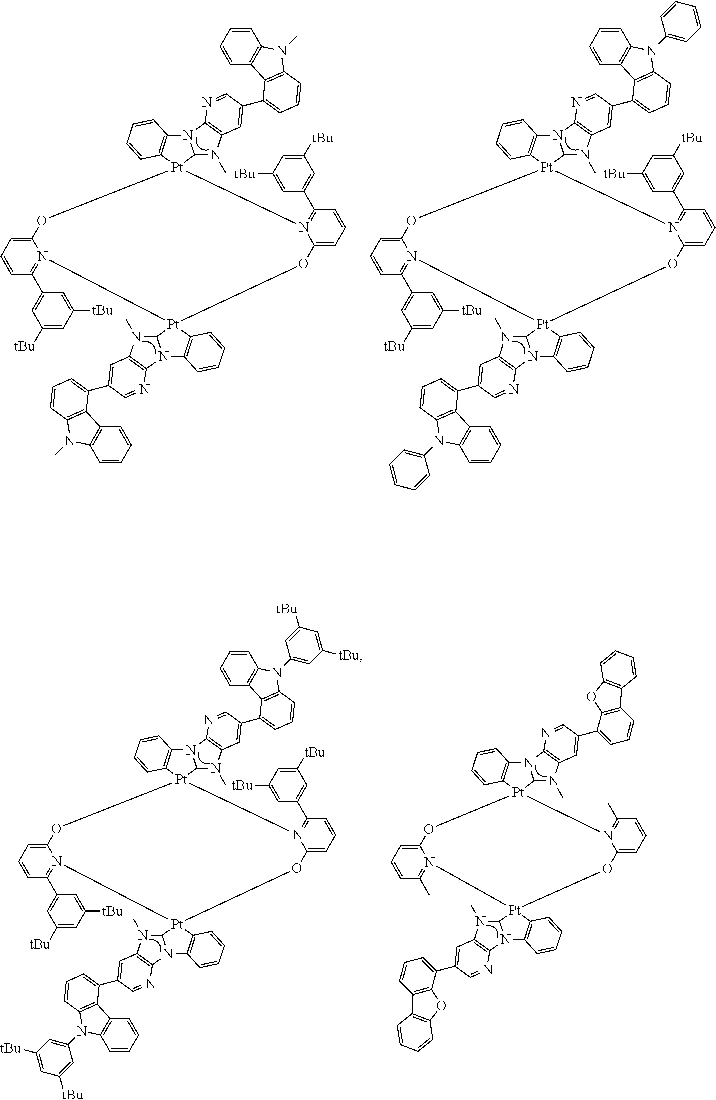

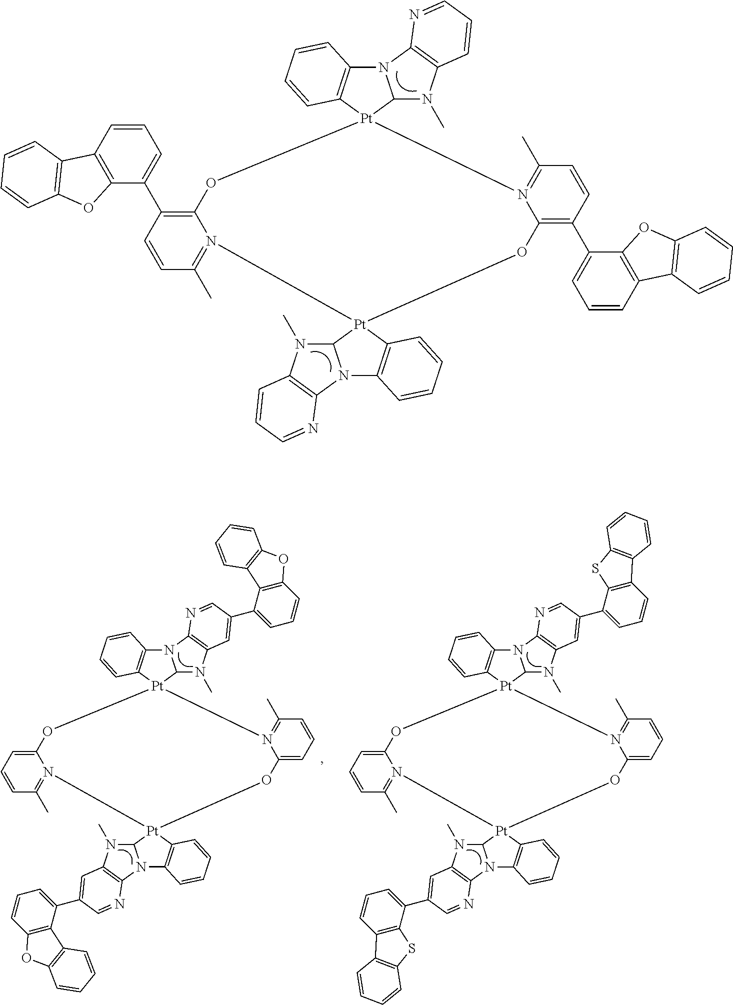

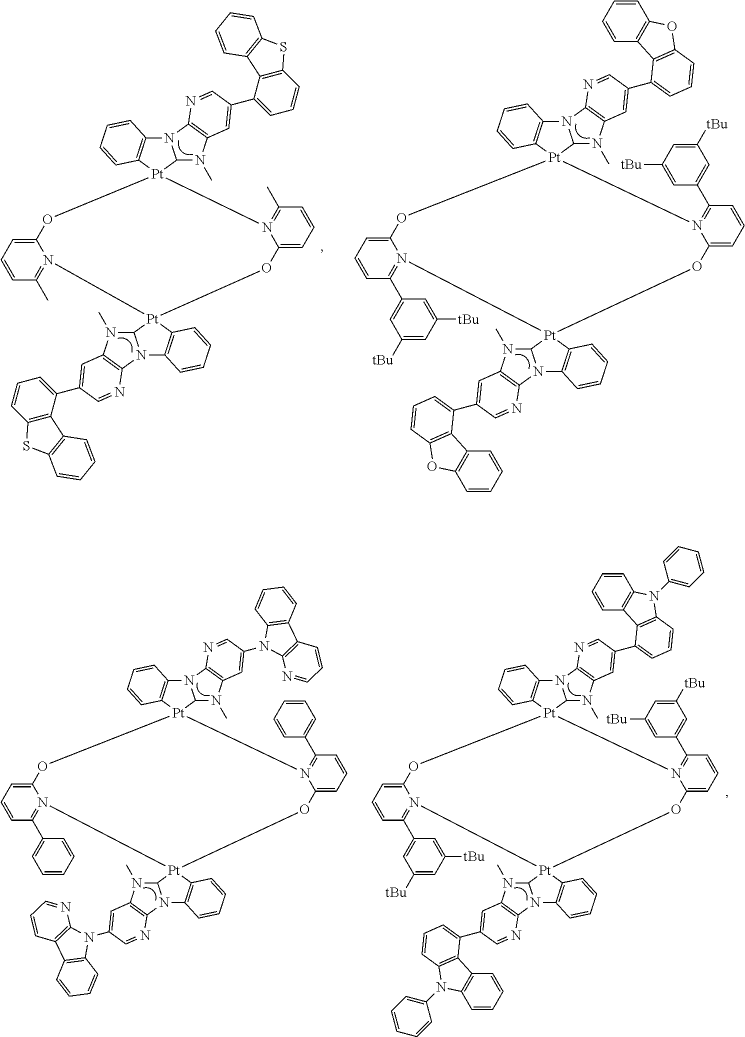

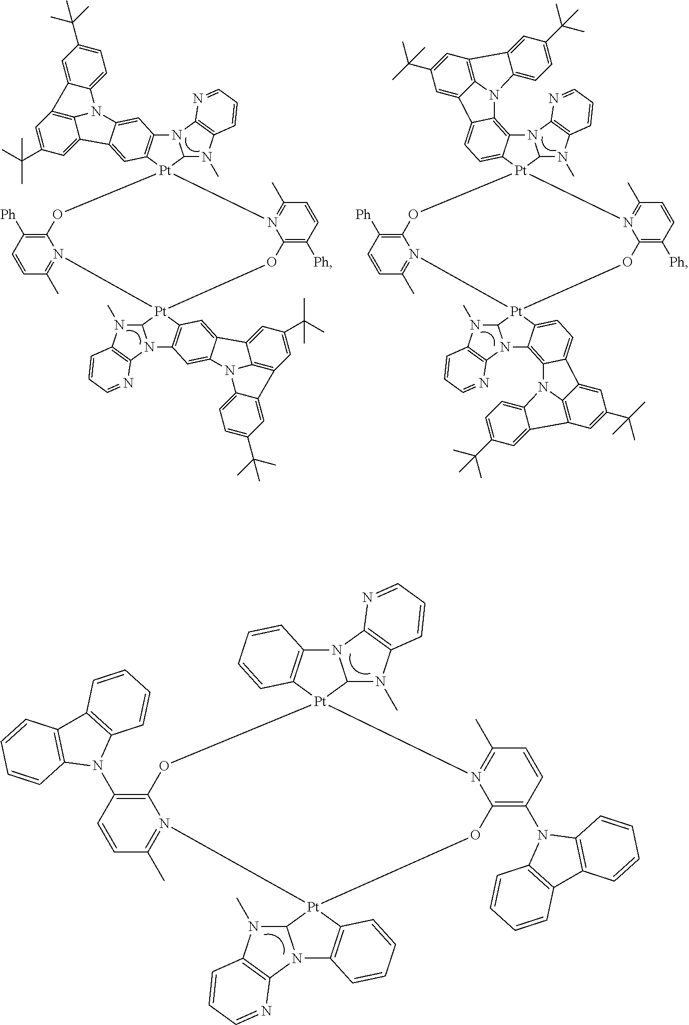

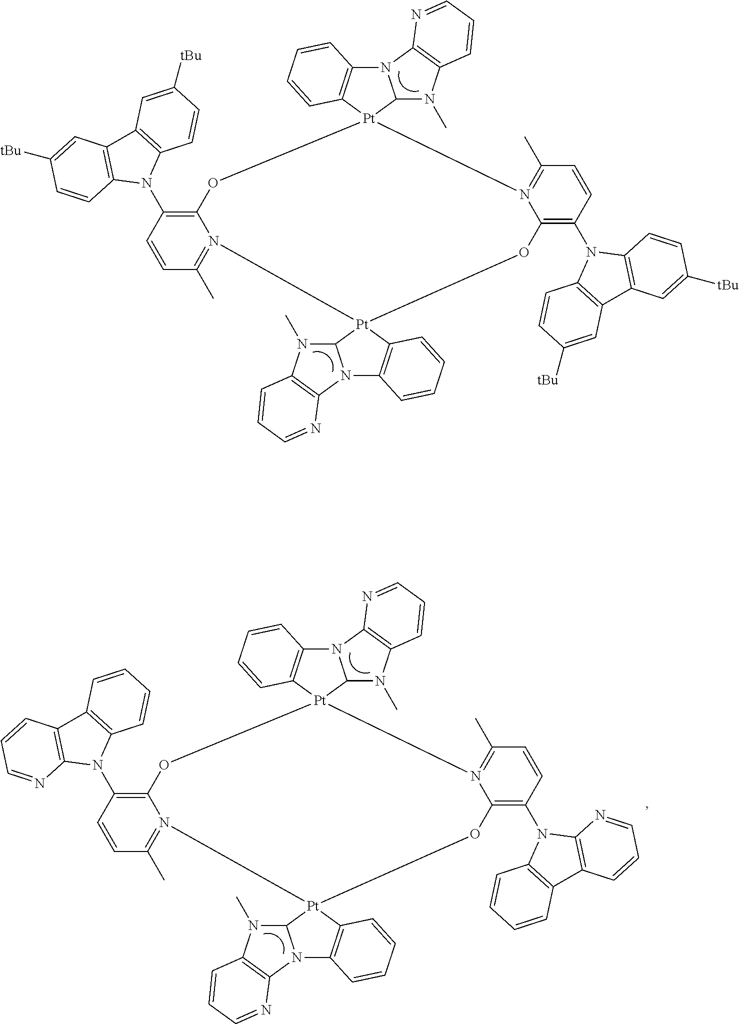

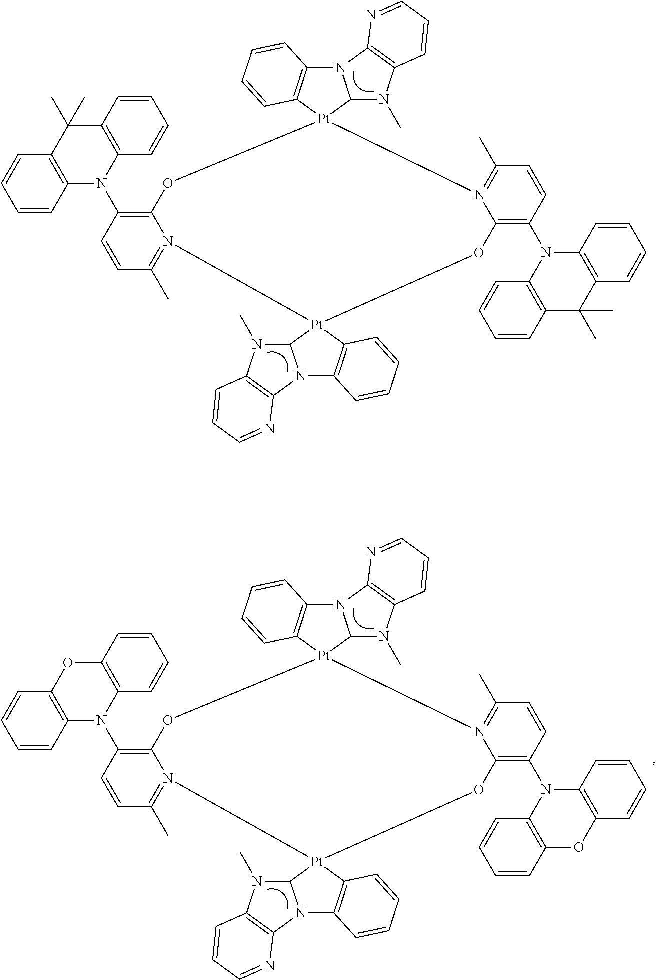

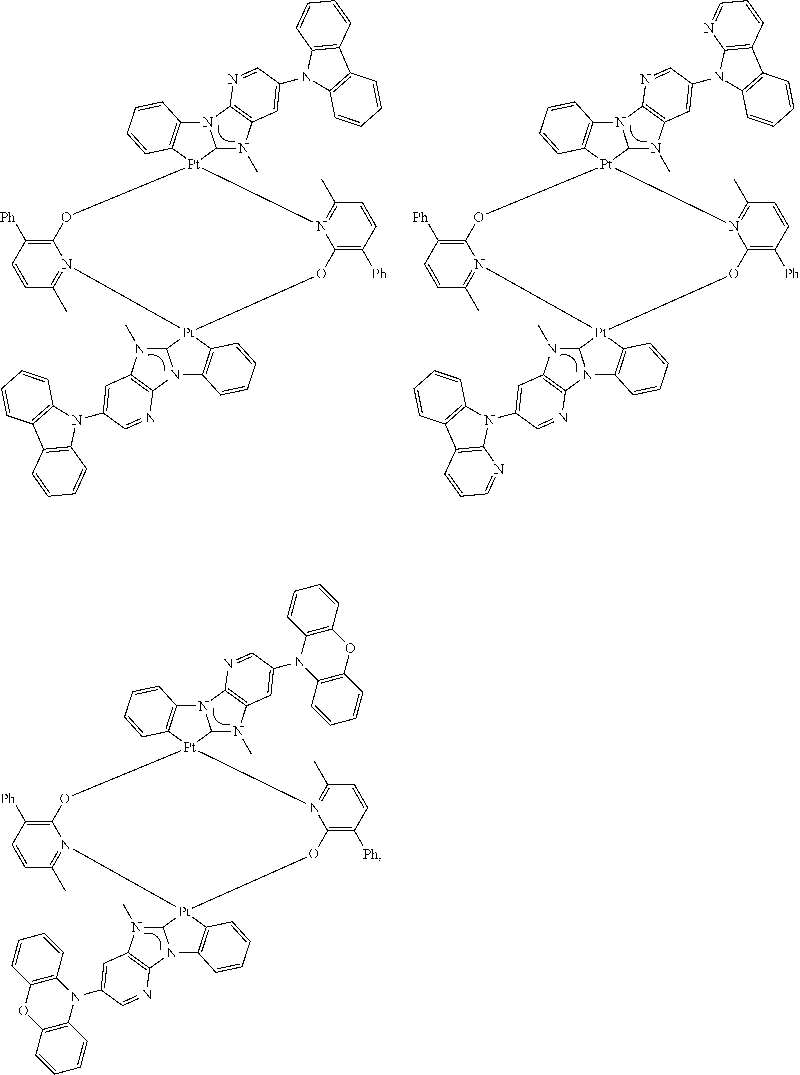

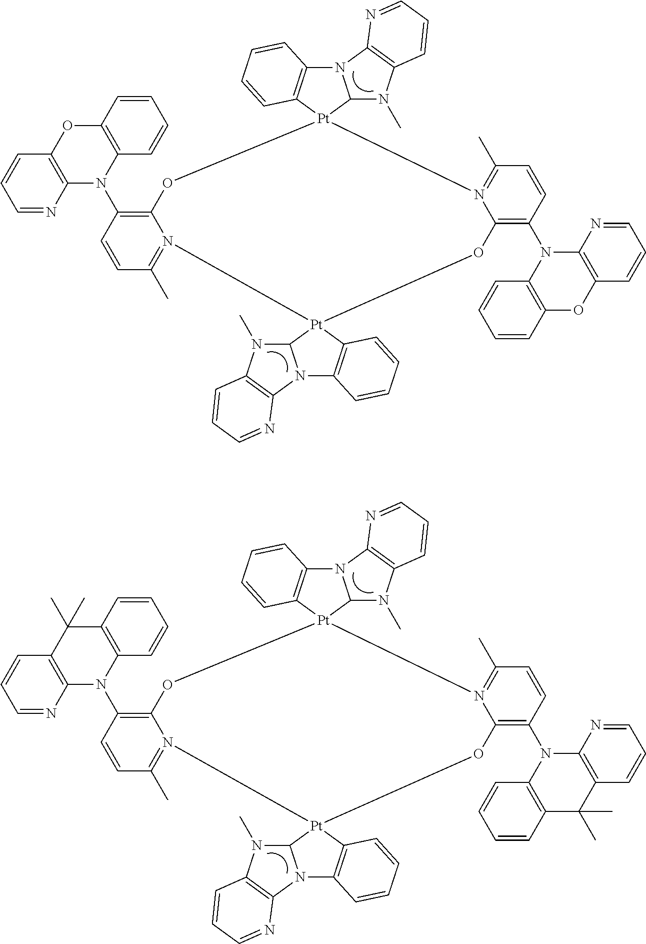

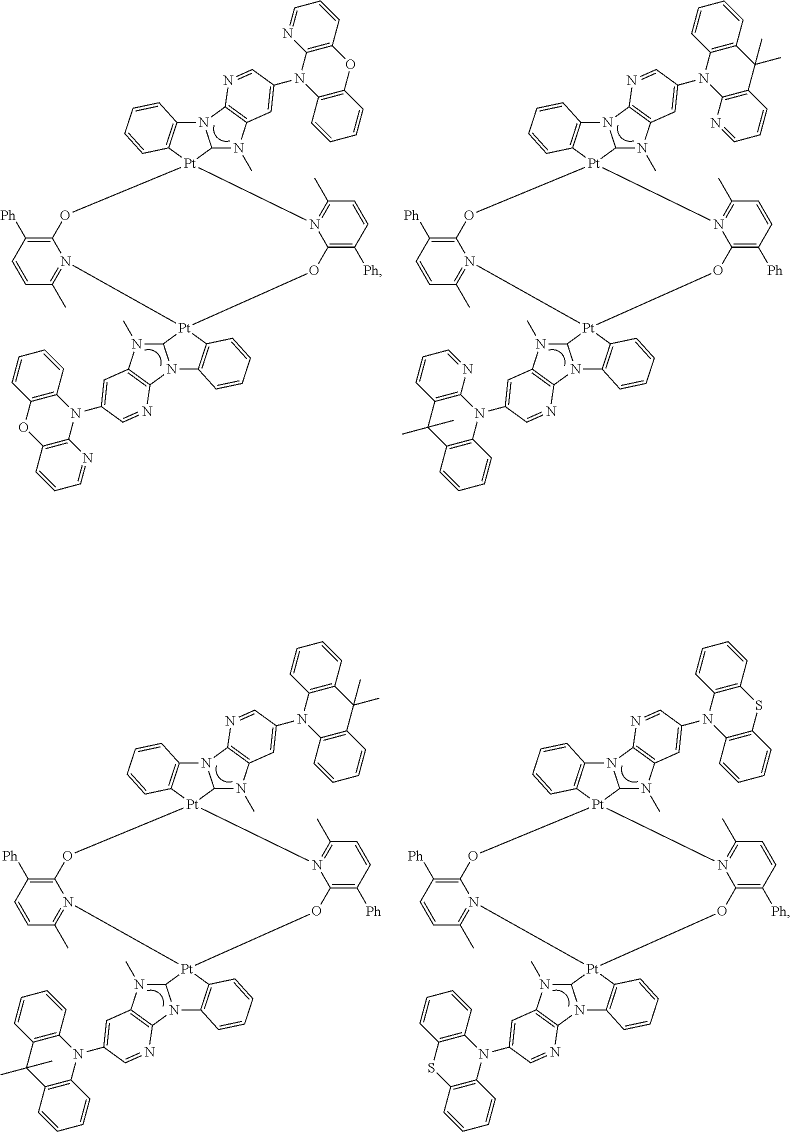

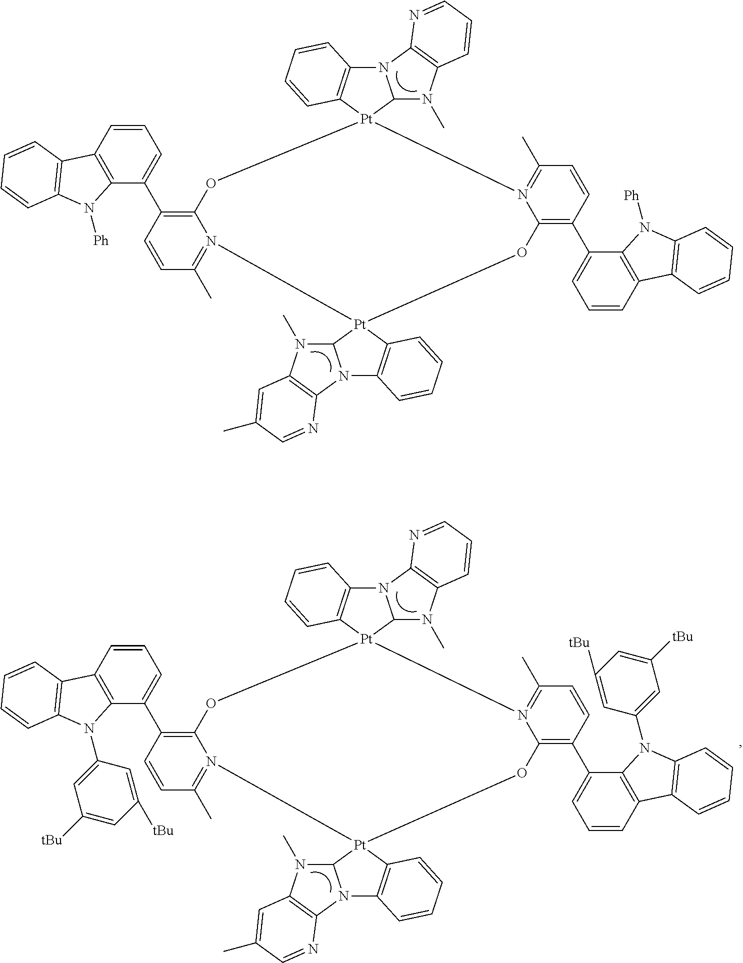

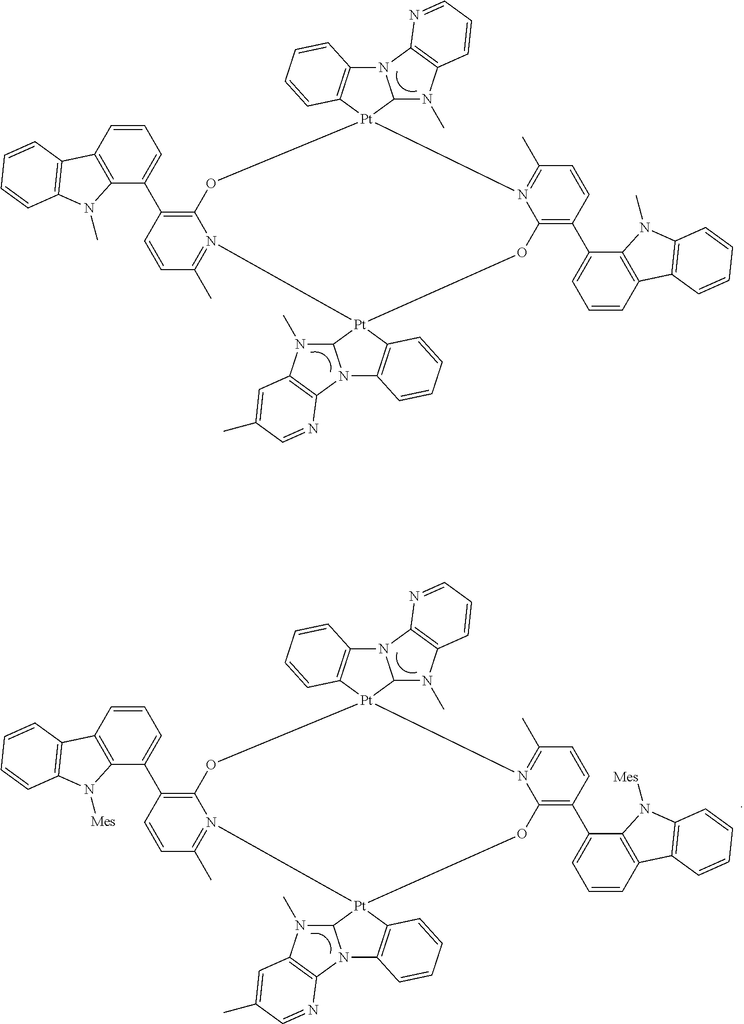

20. The complex of claim 1, wherein the complex has a maximum emission wavelength (λₘₐₓ) in a range from 600 nm to 1000 nm, from 600 nm to 900 nm, from 600 nm to 800 nm, from 600 nm to 700 nm, from 600 nm to 680 nm, from 620 nm to 710 nm, or from 612 nm to 685 nm.

21. The complex of claim 20, wherein the complex has an emission lifetime (τₑₘ) of up to 2.5 μs, up to 2.0 μs, up to 1.9 μs, up to 1.8 μs, in a range from 0.5 μs to 2.5 μs, from 0.5 μs to 2.0 μs, from 0.8 μs to 2.0 μs, from 1.0 μs to 2.0 μs, from 0.5 μs to 1.9 μs, from 0.8 μs to 1.9 μs, from 1.0 μs to 1.9 μs, from 1.2 μs to 1.9 μs, or from 1.4 μs to 1.9 μs; a radiative decay rate (kᵣ) of at least 3.5×10⁵ s⁻¹, at least 4.0×10⁵ s⁻¹, at least 4.5×10⁵ s⁻¹, in a range from 3.5×10⁵ s⁻¹ to 10.0×10⁵ s⁻¹, from 3.5×10⁵ s⁻¹ to 8.0×10⁵ s⁻¹, from 3.5×10⁵ s⁻¹ to 6.0×10⁵ s⁻¹, from 3.5×10⁵ s⁻¹ to 5.5×10⁵ s⁻¹, from 4.0×10⁵ s⁻¹ to 10.0×10⁵ s⁻¹, from 4.0×10⁵ s⁻¹ to 8.0×10⁵ s⁻¹, from 4.0×10⁵ s⁻¹ to 6.0×10⁵ s⁻¹, from 4.0×10⁵ s⁻¹ to 5.5×10⁵ s⁻¹, from 4.2×10⁵ s⁻¹ to 10.0×10⁵ s⁻¹, from 4.2×10⁵ s⁻¹ to 8.0×10⁵ s⁻¹, from 4.2×10⁵ s⁻¹ to 6.0×10⁵ s⁻¹, from 4.2×10⁵ s⁻¹ to 5.5×10⁵ s⁻¹, or from 4.3×10⁵ s⁻¹ to 5.5×10⁵ s⁻¹; a non-radiative decay rate (kₙᵣ) of up to 2.0×10⁵ s⁻¹, up to 1.8×10⁵ s⁻¹, up to 1.5×10⁵ s⁻¹, down to 0.15×10⁵ s⁻¹, in a range from 0.15×10⁵ s⁻¹ to 2.0×10⁵ s⁻¹, from 0.16×10⁵ s⁻¹ to 2.0×10⁵ s⁻¹, from 0.15×10⁵ s⁻¹ to 1.8×10⁵ s⁻¹, from 0.16×10⁵ s⁻¹ to 1.8×10⁵ s⁻¹, from 0.15×10⁵ s⁻¹ to 1.6×10⁵ s⁻¹, from 0.16×10⁵ s⁻¹ to 1.6×10⁵ s⁻¹, from 0.15×10⁵ s⁻¹ to 1.5×10⁵ s⁻¹, or from 0.16×10⁵ s⁻¹ to 1.4×10⁵ s⁻¹; and/or an emission quantum yield (Φₑₘ) of at least 60%, at least 65%, at least 70%, at least 75%, in a range from 60% to 97%, from 65% to 97%, from 70% to 97%, from 75% to 97%, from 75% to 99%, or from 78% to 97%, measured in solution or films, at room temperature.

22. An organic light-emitting component comprising a light-emitting layer or two or more light-emitting layers, wherein the light-emitting layer or each light-emitting layer of the two or more light-emitting layers comprises one or more dinuclear platinum(II) complexes of claim 1, optionally wherein the organic light-emitting component emits light in the red, deep red, and/or NIR region(s).

23. The organic light-emitting component of claim 22, wherein the light emitting layer or each light-emitting layer of the two or more light-emitting layers further comprises one or more host materials, and wherein the total concentration of the one or more host materials is greater than the total concentration of the one or more complexes in the light-emitting layer or each light-emitting layer of the two or more light-emitting layers.

24. The organic light-emitting component of claim 22, wherein the total concentration of the one or more dinuclear platinum(II) complexes in the light-emitting layer or each light-emitting layer of the two or more light-emitting layers is up to 50 wt %, up to 40 wt %, up to 30 wt %, up to 20 wt %, at least 1 wt %, in a range from about 1 wt % to about 50 wt %, from about 1 wt % to about 40 wt %, from about 1 wt % to about 30 wt %, from about 1 wt % to about 20 wt %, from about 2 wt % to about 50 wt %, from about 2 wt % to about 40 wt %, from about 2 wt % to about 30 wt %, from about 2 wt % to about 20 wt %, from about 4 wt % to about 50 wt %, from about 4 wt % to about 40 wt %, from about 4 wt % to about 30 wt %, from about 4 wt % to about 20 wt %, from about 1 wt % to about 16 wt %, from about 2 wt % to about 16 wt %, from about 4 wt % to about 16 wt %, such as about 4 wt %, about 8 wt %, or about 12 wt %.

25. The organic light-emitting component of claim 22 further comprising an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located in between the anode and the light-emitting layer, and
wherein the electron transport region is located in between the cathode and the light emitting layer.

26. The organic light-emitting component of claim 22, wherein the organic light-emitting component emits light in the red to deep red region.

27. The organic light-emitting component of claim 26, wherein the organic light-emitting component has a maximum brightness (L) of at least 20000 cd m⁻², at least 25000 cd m⁻², at least 30000 cd m⁻², at least 35000 cd m⁻², at least 40000 cd m⁻², in a range from 20000 cd m⁻² to 100000 cd m⁻², from 30000 cd m⁻² to 100000 cd m⁻², from 20000 cd m⁻² to 80000 cd m⁻², from 30000 cd m⁻² to 80000 cd m⁻², from 20000 cd m⁻² to 60000 cd m⁻², from 30000 cd m⁻² to 60000 cd m⁻², from 20000 cd m⁻² to 50000 cd m⁻² from 30000 cd m⁻² to 100000 cd m⁻², from 20000 cd m⁻² to 50000 cd m⁻², from 30000 cd m⁻² to 50000 cd m⁻², from 35000 cd m⁻² to 100000 cd m⁻², from 40000 cd m⁻² to 100000 cd m⁻², from 35000 cd m⁻² to 80000 cd m⁻², from 40000 cd m⁻² to 80000 cd m⁻², from 35000 cd m⁻² to 60000 cd m⁻², from 40000 cd m⁻² to 60000 cd m⁻², from 35000 cd m⁻² to 50000 cd m⁻², or from 40000 cd m⁻² to 50000 cd m⁻²; a current efficiency (CE) at 1000 cd/m² of at least 20 cd A⁻¹, at least 22 cd/A, in a range from 20 cd/A to 60 cd/A, from 22 cd/A to 60 cd/A, from 20 cd/A to 50 cd/A, from 22 cd/A to 50 cd/A, from 20 cd/A to 40 cd/A, or from 20 cd/A to 30 cd/A; a power efficiency (PE) at 1000 cd/m² of at least 10 1 m/W, in a range from 10 1 m/W to 60 1m/W, from 15 1 m/W to 60 1 m/W, from 10 1 m/W to 50 1 m/W, from 15 1 m/W to 50 1 m/W, from 10 1 m/W to 40 1 m/W, from 15 1 m/W to 40 1 m/W, from 10 1 m/W to 30 1 m/W, from 15 1m/W to 30 1 m/W, or from 10 1 m/W to 20 1 m/W; and/or an external quantum efficiency (EQE) at 1000 cd/m² of at least 10%, at least 11%, at least 12%, at least 13%, at least 14%, at least 15%, in a range from 10% to 40%, from 10% to 20%, from 10% to 20%, from 11% to 40%, from 11% to 30%, from 11% to 20%, from 12% to 20%, from 12% to 40%, from 12% to 30%, from 13% to 20%, from 13% to 40%, from 13% to 30%, from 14% to 20%, from 14% to 40%, from 14% to 30%, from 15% to 40%, from 15% to 30%, or from 15% to 20%.

28. The organic light-emitting component of claim 22, wherein the organic light-emitting component emits light in the NIR region.

29. The organic light-emitting component of claim 28, wherein the organic light-emitting component has an L of at least 1000 cd m⁻², at least 1500 cd m⁻², at least 2000 cd m⁻², at least 3000 cd m⁻², at least 4000 cd m⁻², at least 4200 cd m⁻², at least 4500 cd m⁻², in a range from 1000 cd m⁻² to 40000 cd m⁻², from 1500 cd m⁻² to 40000 cd m⁻², from 2000 cd m⁻² to 40000 cd m⁻², from 3000 cd m⁻² to 40000 cd m⁻², from 4000 cd m⁻² to 40000 cd m⁻², from 4500 cd m⁻² to 40000 cd m⁻², from 1000 cd m⁻² to 30000 cd m⁻², from 2000 cd m⁻² to 30000 cd m⁻², from 3000 cd m⁻² to 30000 cd m⁻², from 4000 cd m⁻² to 30000 cd m⁻², from 4500 cd m⁻² to 30000 cd m⁻², from 1000 cd m⁻² to 20000 cd m⁻², from 2000 cd m⁻² to 20000 cd m⁻², from 3000 cd m⁻² to 20000 cd m⁻², from 4000 cd m⁻² to 20000 cd m⁻², from 4500 cd m⁻² to 20000 cd m⁻², from 1000 cd m⁻² to 10000 cd m⁻², from 2000 cd m⁻² to 10000 cd m⁻², from 3000 cd m⁻² to 10000 cd m⁻², from 4000 cd m⁻² to 10000 cd m⁻², or from 4500 cd m⁻² to 10000 cd m⁻²; a CE at 1000 cd m⁻² of at least 0.2 cd A⁻¹, at least 0.4 cd A⁻¹, at least 0.8 cd A⁻¹, in a range from 0.2 cd/A to 10 cd/A, from 0.2 cd/A to 8 cd/A, from 0.2 cd/A to 5 cd/A, from 0.2 cd/A to 3 cd/A, from 0.2 cd/A to 2 cd/A, from 0.4 cd/A to 10 cd/A, from 0.4 cd/A to 8 cd/A, from 0.4 cd/A to 5 cd/A, from 0.4 cd/A to 3 cd/A, from 0.4 cd/A to 2 cd/A, from 0.8 cd/A to 10 cd/A, from 0.8 cd/A to 8 cd/A, from 0.8 cd/A to 5 cd/A, from 0.8 cd/A to 3 cd/A, or from 0.8 cd/A to 2 cd/A; a PE at 1000 cd/m² of at least 0.1 1 m/W, at least 0.2 1m/W, in a range from 0.1 1 m/W to 5 1 m/W, from 0.1 1 m/W to 4 1 m/W, from 0.1 1 m/W to 3 1m/W, from 0.1 1 m/W to 2 1 m/W, from 0.1 1 m/W to 1 1 m/W, from 0.1 1 m/W to 0.5 1 m/W, from 0.2 1 m/W to 5 1 m/W, from 0.2 1 m/W to 4 1 m/W, from 0.2 1 m/W to 3 1 m/W, from 0.2 1m/W to 2 1 m/W, from 0.2 1 m/W to 1 1 m/W, or from 0.2 1 m/W to 0.5 1 m/W; and/or an EQE at 1000 cd/m² of at least 1%, at least 2%, at least 4%, at least 5%, at least 6%, in a range from 1% to 20%, from 2% to 20%, from 4% to 20%, from 5% to 20%, from 5% to 18%, from 1% to 15%, from 2% to 15%, from 4% to 15%, from 5% to 15%, from 1% to 10%, from 2% to 10%, from 4% to 10%, or from 5% to 10%.

30. The organic light-emitting component of claim 22, wherein the organic light-emitting component is an organic light-emitting diode (“OLED”) or a light-emitting electrochemical cell (“LEEC”).

31. The organic light-emitting component of claim 22, wherein the light-emitting layer or each of the light-emitting layer of the two or more light-emitting layers is formed by vacuum-evaporation deposition, spin-coating, ink-printing, or roll-to-roll printing.

32. The organic light-emitting component of claim 22, wherein the light emitting layer or each light-emitting layer of the two or more light-emitting layers further comprises an organic dye, and wherein the one or more dinuclear platinum(II) complexes act(s) as a sensitizer to transfer energy to the organic dye.

33. The organic light-emitting component of claim 22, wherein the light emitting layer or each light-emitting layer of the two or more light-emitting layers further comprises an organic dye, and wherein the one or more dinuclear platinum(II) complexes have a higher-lying singlet state than the organic dye.

34. A device comprising one or more organic light-emitting components of claim 22, wherein the device is a stationary visual display unit, a mobile visual display unit, an illumination device, a wearable device, a phototherapy device, or a medical monitoring device.
